(19) United States
(12) Patent Application Publication
(10) Pub. No.: US 2016/0190474 A1
(43) Pub. Date: Jun. 30, 2016

(54) ORGANIC LIGHT-EMITTING DEVICES

(71) Applicant: SAMSUNG DISPLAY CO., LTD., Yongin-City (KR)

(72) Inventors: Sehun KIM, Yongin-City (KR); Mikyung KIM, Yongin-City (KR); Kwanhee LEE, Yongin-City (KR); Hyein JEONG, Yongin-City (KR); Changwoong CHU, Yongin-City (KR)

(21) Appl. No.: 14/740,764

(22) Filed: Jun. 16, 2015

(30) Foreign Application Priority Data
Dec. 26, 2014 (KR) 10-2014-0191125

(51) Int. Cl. H01L 51/00; C09K 11/02

(52) U.S. Cl. CPC H01L 51/0072; C09K 11/025; H01L 51/0067; H01L 51/0071; H01L 51/0074; H01L 51/0054; H01L 51/5012

(57) ABSTRACT

An organic light-emitting device including a first electrode; a second electrode opposite to the first electrode; and an organic layer between the first electrode and the second electrode, the organic layer including an emission layer, wherein the organic layer includes a first compound and a second compound, the first compound being represented by one of the following Formulae 1-1 to 1-3, and the second compound being represented by the following Formula 2:

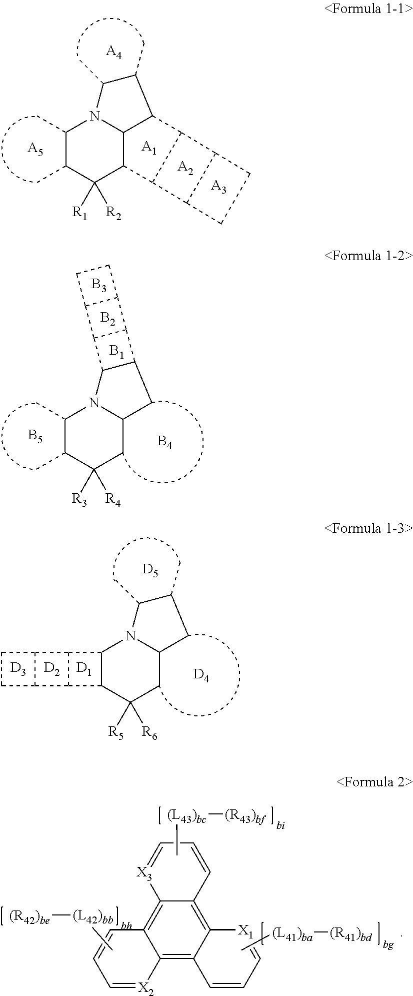

### CROSS-REFERENCE TO RELATED APPLICATION

Korean Patent Application No. 10-2014-0191125, filed on Dec. 26, 2014, in the Korean Intellectual Property Office, and entitled: “Organic Light-Emitting Devices,” is incorporated by reference herein in its entirety.

### BACKGROUND

1. Field

Embodiments relate to organic light-emitting devices.

2. Description of the Related Art

Organic light-emitting devices (OLEDs), which are self-emitting devices, have advantages such as wide viewing angles, excellent contrast, quick response, high brightness, excellent driving voltage characteristics, and can provide multicolored images.

An organic light-emitting device may have a structure in which a first electrode, a hole transport region, an emission layer, an electron transport region, and a second electrode are sequentially disposed in this order on a substrate. Holes injected from the first electrode move to the emission layer via the hole transport region, while electrons injected from the second electrode move to the emission layer via the electron transport region. Carriers such as the holes and electrons recombine in the emission layer to generate exitons. When the excitons drop from an excited state to a ground state, light is emitted.

### SUMMARY

Embodiments are directed to organic light-emitting devices.

One or more embodiments of the present disclosure include organic light-emitting devices having high efficiency and long lifetime.

According to one or more embodiments of the present disclosure, an organic light-emitting device includes: a first electrode; a second electrode disposed opposite to the first electrode; and an organic layer disposed between the first electrode and the second electrode and including an emission layer,

wherein the organic layer includes a first compound and a second compound, the first compound is represented by one of Formulae 1-1 to 1-3, and the second compound is represented by Formula 2:

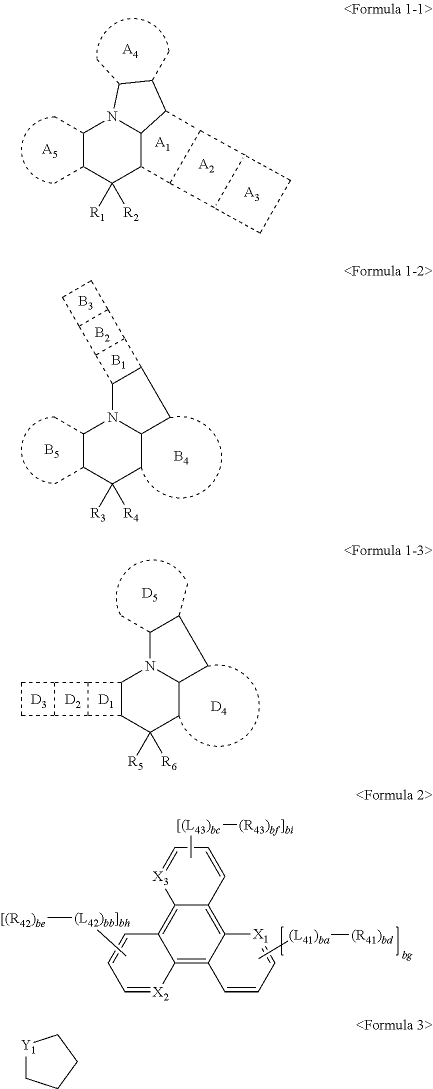

wherein, in Formulae 1-1 to 1-3 and Formula 2,

A₁ ring, A₂ ring, and A₃ ring are condensed together, B₁ ring, B₂ ring, and B₃ ring are condensed together, and D₁ ring, D₂ ring, and D₃ ring are condensed together;

A₂ ring, B₂ ring, and D₂ ring are each represented by Formula 3, where Y₁ in Formula 3 is O, S, or N-(L₁)ₐₐ-(R₁₁)_{ab};

A₁ ring, A₃ ring to A₅ ring, B₁ ring, B₃ ring to B₅ ring, D₁ ring, and D₃ ring to D₅ ring are each independently a substituted or unsubstituted benzene ring or a substituted or unsubstituted naphthalene ring;

R₁ to R₆ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₁₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein R₁ and R₂, R₃ and R₄, and R₅ and R₆ are non-ring forming substituents which are not linked to each other and do not form a ring;

X₁ is N or C(R₅₁), X₂ is N or C(R₅₂), X₃ is N or C(R₅₃);

L₁, and L₄₁ to L₄₃ are each independently selected from

a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group;

aa, and ba to bc are each independently selected from 0, 1, 2, and 3, *-(L₁)ₐₐ-*′ is a single bond when aa is 0, *-(L₄₁)_{ba}-*′ is a single bond when ba is 0, *-(L₄₂)_{bb}-*′ is a single bond when bb is 0, *-(L₄₃)_{bc}-*′ is a single bond when bc is 0, at least two L₁s are the same or differ when aa is 2 or greater, at least two L₁s are the same or differ when ba is 2 or greater, at least two L₄₂s are the same or differ when bb is 2 or greater, and at least two L₄₃s are the same or differ when bc is 2 or greater;

R₁₁, R₄₁ to R₄₃, and R₅₁ to R₅₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and N(Q₆)(Q₇);

ab, and bd to bf are each independently selected from 1, 2, and 3, at least two R₁₁s are the same or differ when ab is 2 or greater, at least two R₄₁s are the same or differ when bd is 2 or greater, at least two R₄₂s are the same or differ when be is 2 or greater, and at least two R₄₃s are the same or differ when bf is 2 or greater;

bg to bi are each independently selected from 0, 1, 2, and 3, except for where bg to bi are all 0; and

at least one substituent of the substituted benzene ring, the substituted naphthalene ring, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is selected from

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group,

a C₁-C₆₀ alkyl group, a C₂-C₆₀ alkenyl group, a C₂-C₆₀ alkynyl group, and a Cᵣ C₆₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇),

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₆₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇), and

—Si(Q₃₁)(Q₃₂)(Q₃₃), —B(Q₃₄)(Q₃₅), and —N(Q₃₆)(Q₃₇),

wherein Q₁ to Q₇, Q₁₁ to Q₁₇, Q₂₁ to Q₂₇, and Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

### BRIEF DESCRIPTION OF THE DRAWING

Features will be apparent to those of skill in the art by describing in detail exemplary embodiments with reference to the attached drawing in which:

FIG. 1 illustrates a schematic view of a structure of an organic light-emitting device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

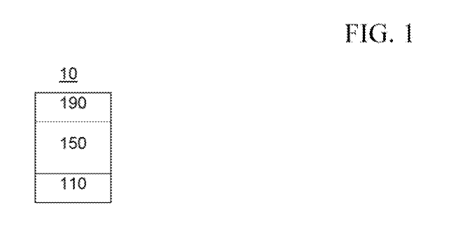

FIG. 1 illustrates a schematic sectional view of an organic light-emitting device 10 according to an embodiment. Referring to FIG. 1, the organic light-emitting device 10 may include a first electrode 110, an organic layer 150, and a second electrode 190.

A substrate (not shown) may be disposed under the first electrode 110 or on the second electrode 190 in FIG. 1. The substrate may be a glass or transparent plastic substrate with good mechanical strength, thermal stability, transparency, surface smoothness, ease of handling, and water resistance.

For example, the first electrode 110 may be formed by depositing or sputtering a first electrode-forming material on the substrate 11. When the first electrode 110 is an anode, a material having a high work function may be used as the first electrode-forming material to facilitate hole injection. The first electrode 110 may be a reflective electrode, a semi-transmissive electrode, or a transmissive electrode. Transparent and conductive materials such as ITO, IZO, SnO₂, and ZnO may be used to form the first electrode. For example, when the first electrode 110 is a semi-transmissive electrode or a reflective electrode, a material for the first electrode 110 may be at least one selected from magnesium (Mg), aluminum (Al), aluminum-lithium (Al—Li), calcium (Ca), magnesium-indium (Mg—In), and magnesium-silver (Mg—Ag).

The first electrode 110 may have a single-layer structure or a multi-layer structure including a plurality of layers. For example, the first electrode 110 may have a three-layered structure of ITO/Ag/ITO, but is not limited thereto.

The organic layer 150 may be disposed on the first electrode 110. The organic layer 150 may include an emission layer (EML). The organic layer 150 may further include a hole transport region disposed between the first electrode 110 and the EML, and an electron transport region disposed between the EML and the second electrode 190.

The organic layer 150 may include a first compound and a second compound. In an implementation, the first compound may be represented by one of Formulae 1-1 to 1-3, and the second compound may be represented by Formula 2.

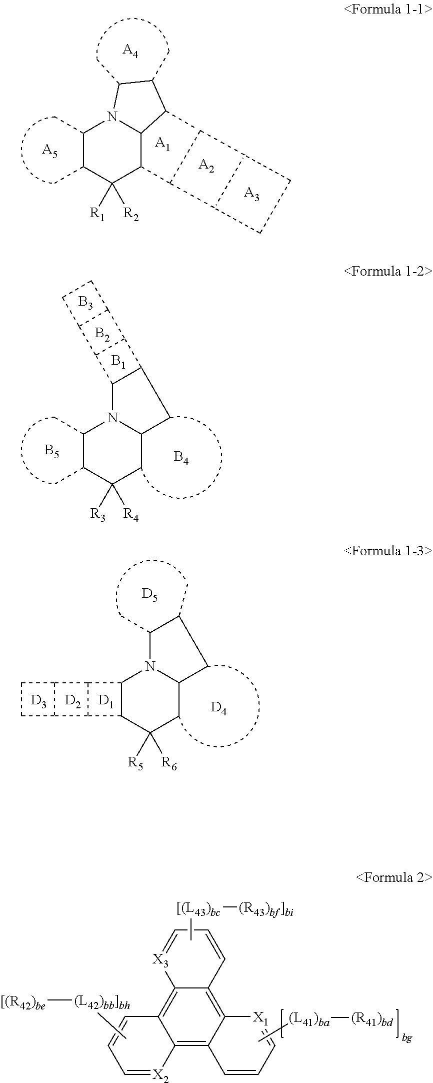

In Formulae 1-1 to 1-3,

ring A₁, ring A₂, and ring A₃ may be condensed together, ring B₁, ring B₂, and ring B₃ may be condensed together, and ring D₁, ring D₂, and ring D₃ may be condensed together;

ring A₂, ring B₂, and ring D₂ may each independently be represented by Formula 3, in which Y₁ in Formula 3 may be O, S, or N-(L₁)ₐₐ-(R₁₁)_{ab};

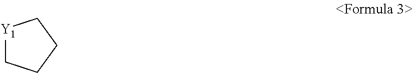

ring A₁, ring A₃ to ring A₅, ring B₁, ring B₃ to ring B₅, ring D₁, and ring D₃ to ring D₅ may each independently be or include, e.g., a substituted or unsubstituted benzene ring or a substituted or unsubstituted naphthalene ring;

R₁ to R₆ may each independently be selected from or include, e.g., a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group. In an implementation, R₁ to R₆, e.g., R₁ and R₂, may be non-ring forming substituents which are not linked to each other and do not form a ring.

In some embodiments, in Formulae 1-1 to 1-3,

R₁ to R₆ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₁-C₆₀ alkoxy group, and a substituted or unsubstituted C₆-C₆₀ aryl group.

In some embodiments, in Formulae 1-1 to 1-3,

R₁ to R₆ may each independently be selected from, but not limited to,

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group,

a C₁-C₂₀ alkyl group and a C₁-C₂₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, and a naphthyl group,

a phenyl group, a naphthyl group, a fluorenyl group, a phenanthrenyl group, an anthracenyl group, a fluoranthenyl group, a triphenylenyl group, a pyrenyl group, and a chrysenyl group, and

a phenyl group, a naphthyl group, a fluorenyl group, a phenanthrenyl group, an anthracenyl group, a fluoranthenyl group, a triphenylenyl group, a pyrenyl group, and a chrysenyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, and a chrysenyl group.

For example, in Formulae 1-1 to 1-3, R₁ to R₆ may each independently be a methyl group or a phenyl group.

In Formula 2, X₁ may be N or C(R₅₁), X₂ may be N or C(R₅₂), and X₃ may be N or C(R₅₃).

In Formulae 1-1 to 1-3 and Formula 2,

L₁ and L₄₁ to L₄₃ may each independently be selected from or include, e.g., a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted heteroarylene group, a substituted or unsubstituted divalent non-aromatic condensed polycyclic group, and a substituted or unsubstituted divalent non-aromatic condensed heteropolycyclic group; and

aa, and ba to bc may each independently be selected from 0, 1, 2, and 3, *-(L₁)ₐₐ-′ is a single bond when aa is 0, *-(L₄₁)_{ba}-′ is a single bond when ba is 0, *-(L₄₂)_{bb}-′ is a single bond when bb is 0, *-(L₄₃)_{bc}-′ is a single bond when bc is 0, at least two L₁s are the same or differ when aa is 2 or greater, at least two L₄₁s are the same or differ when ba is 2 or greater, at least two L₄₂s are the same or differ when bb is 2 or greater, and at least two L₄₃s are the same or differ when bc is 2 or greater.

In some embodiments, in Formulae 1-1 to 1-3 and Formula 2,

L₁ and L₄₁ to L₄₃ may each independently be selected from:

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, and

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group.

In some other embodiments, in Formulae 1-1 to 1-3 and Formula 2,

L₁ and L₄₁ to L₄₃ may each independently be selected from:

a phenylene group, a naphthylene group, a fluorenylene group, a phenanthrenylene group, an anthracenylene group, a triphenylenylene group, a pyrenylene group, and a chrysenylene group, and

a phenylene group, a naphthylene group, a fluorenylene group, a phenanthrenylene group, an anthracenylene group, a triphenylenylene group, a pyrenylene group, and a chrysenylene group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a triphenylenyl group, a pyrenyl group, and a chrysenyl group.

In some embodiments, in Formulae 1-1 to 1-3 and Formula 2,

L₁ and L₄₁ to L₄₃ may each independently be a group represented by one of Formulae 4-1 to 4-39:

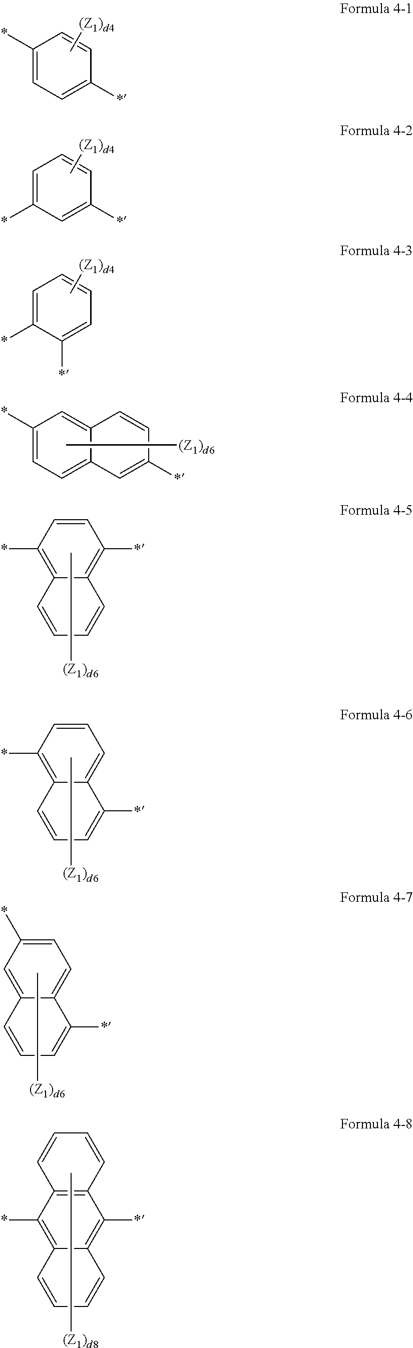

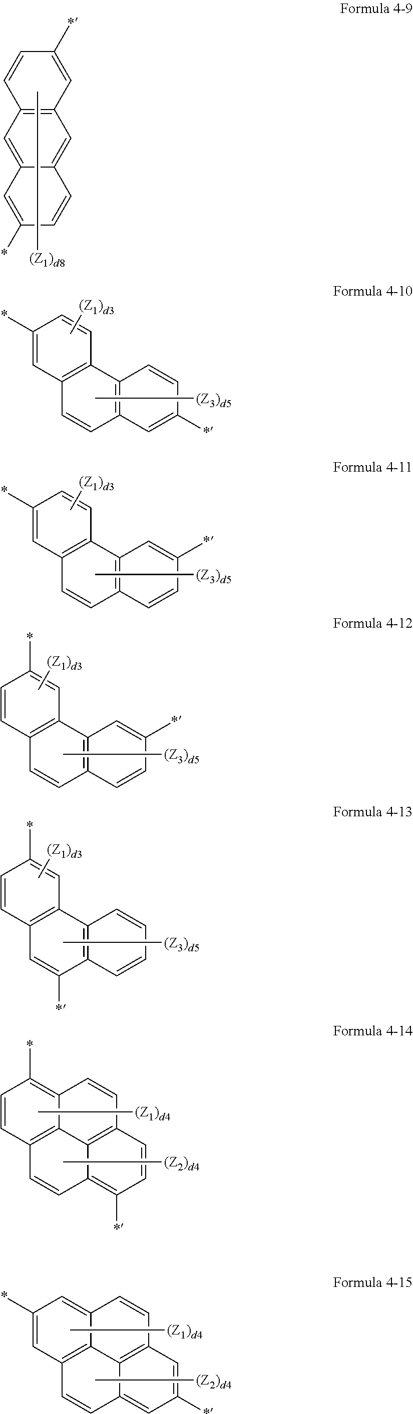

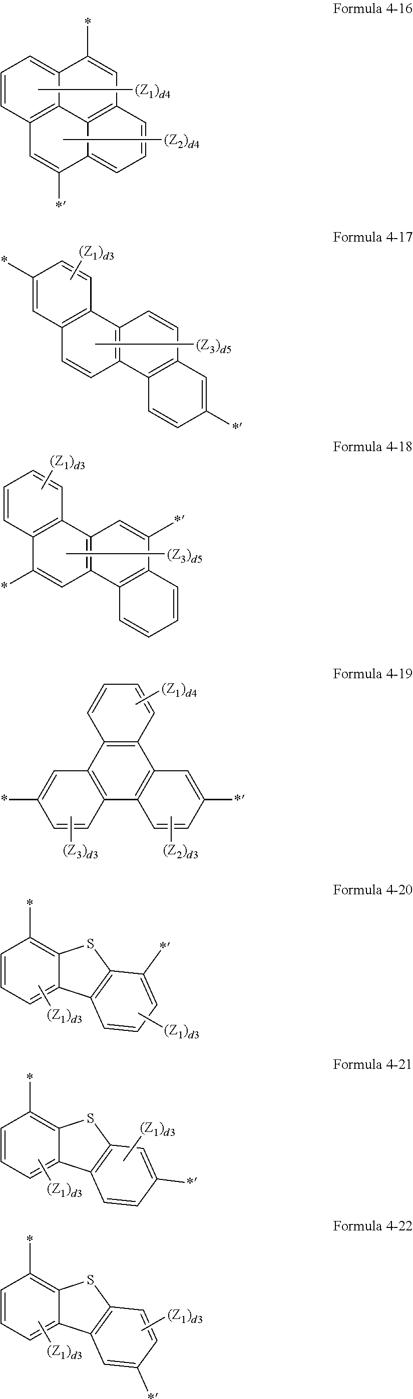

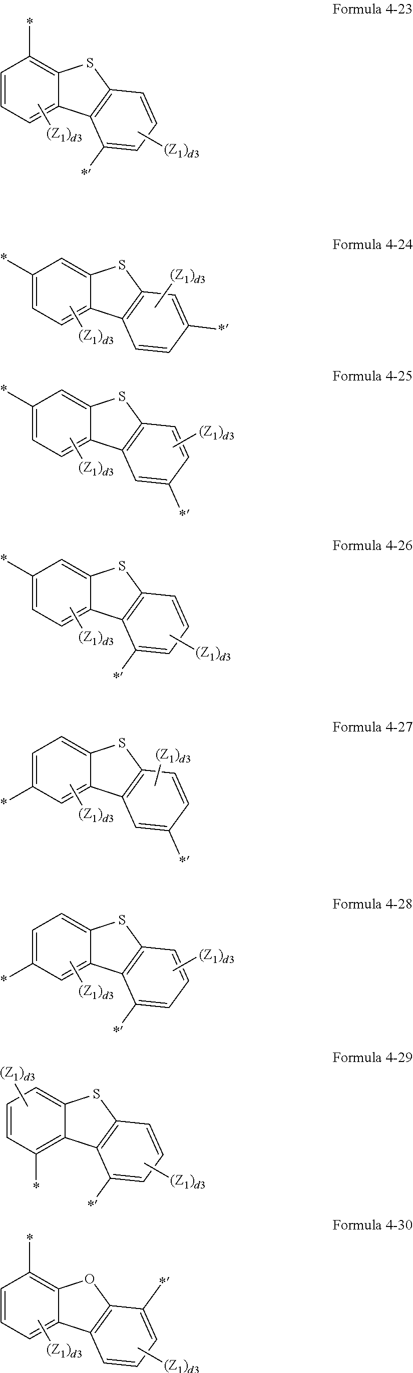

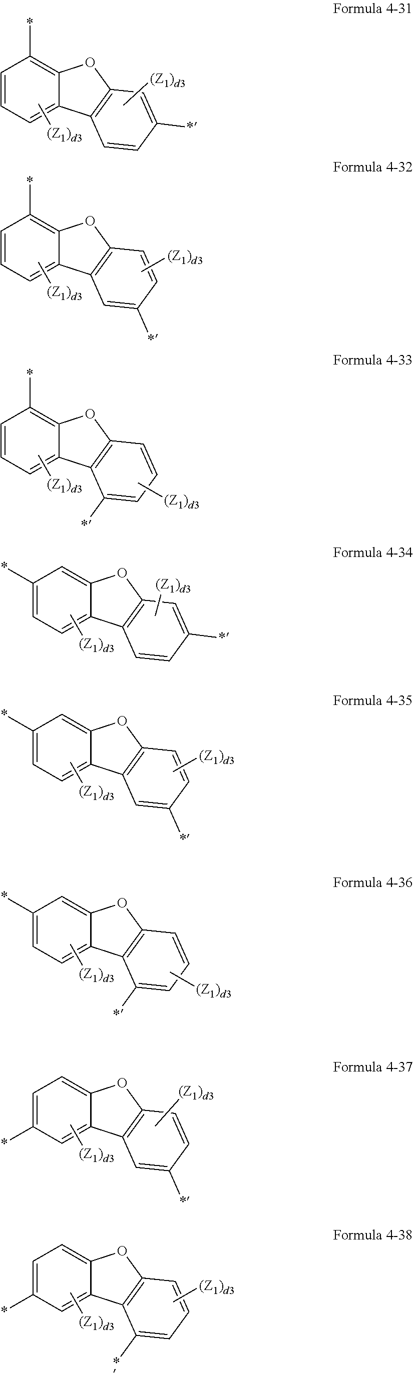

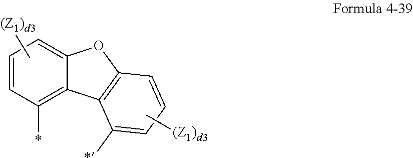

In Formulae 4-1 to 4-39,

Z₁ to Z₃ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

d3 may be an integer selected from 1 to 3; d4 may be an integer selected from 1 to 4; d5 may be an integer selected from 1 to 5; d6 may be an integer selected from 1 to 6; d8 may be an integer selected from 1 to 8; and * and *′ may be each a binding site with an adjacent atom.

In some embodiments, in Formulae 1-1 to 1-3 and Formula 2,

L₁ and L₄₁ to L₄₃ may each independently be a group represented by one of Formulae 5-1 to 5-26; and aa, ba, and be may be each independently 0 or 1.

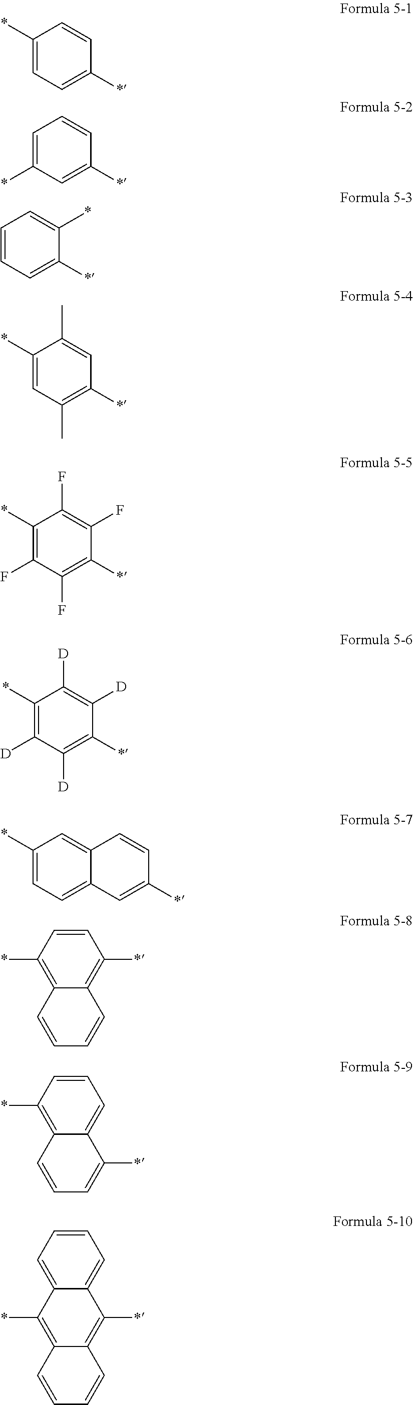

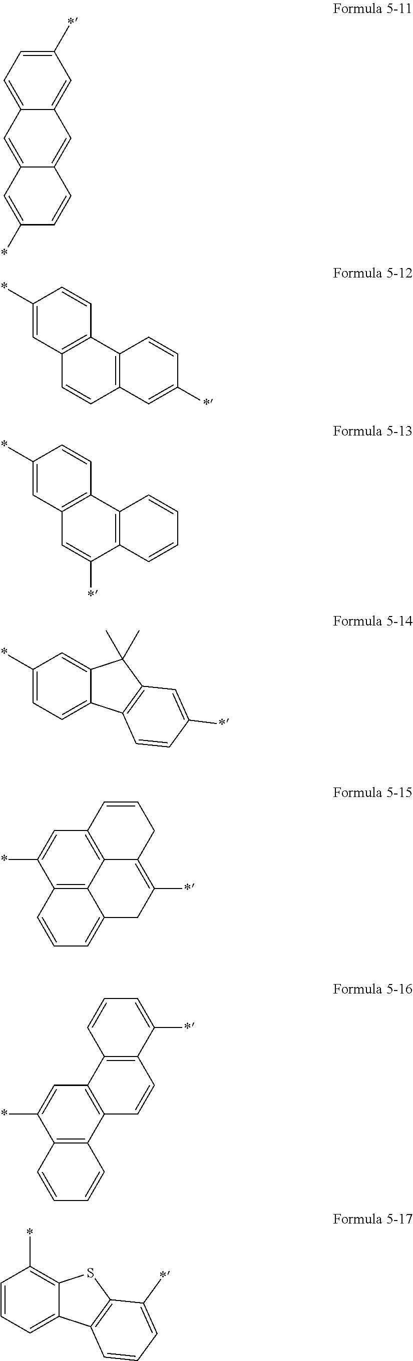

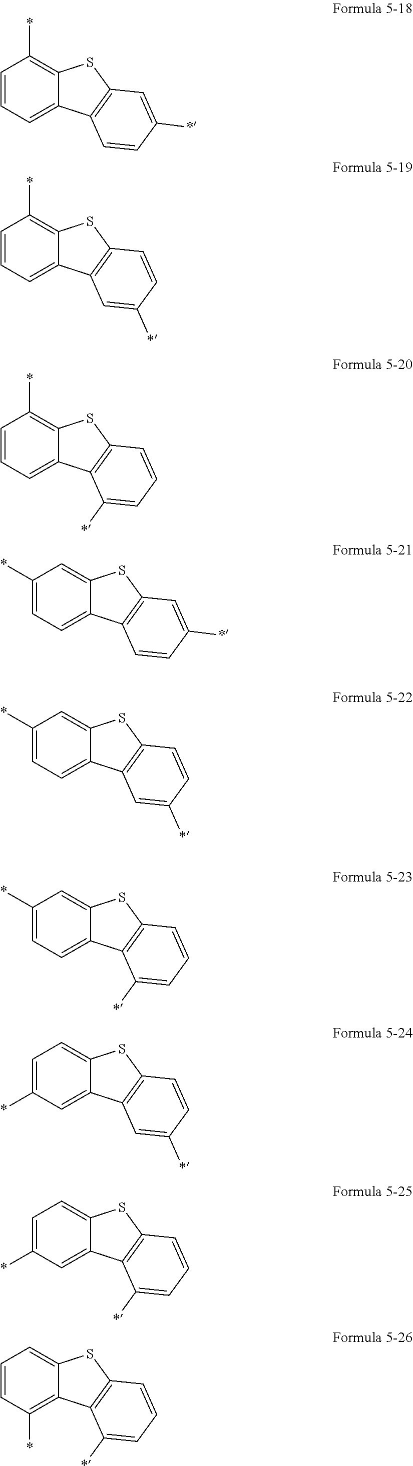

In Formulae 5-1 to 5-26, * and *′ may be each a binding site with an adjacent atom.

For example, in Formulae 1-1 to 1-3 and Formula 2,

L₁ and L₄₁ to L₄₃ may each independently be represented by one of Formulae 6-1 to 6-12; and aa, and ba to be may be each independently 0 or 1:

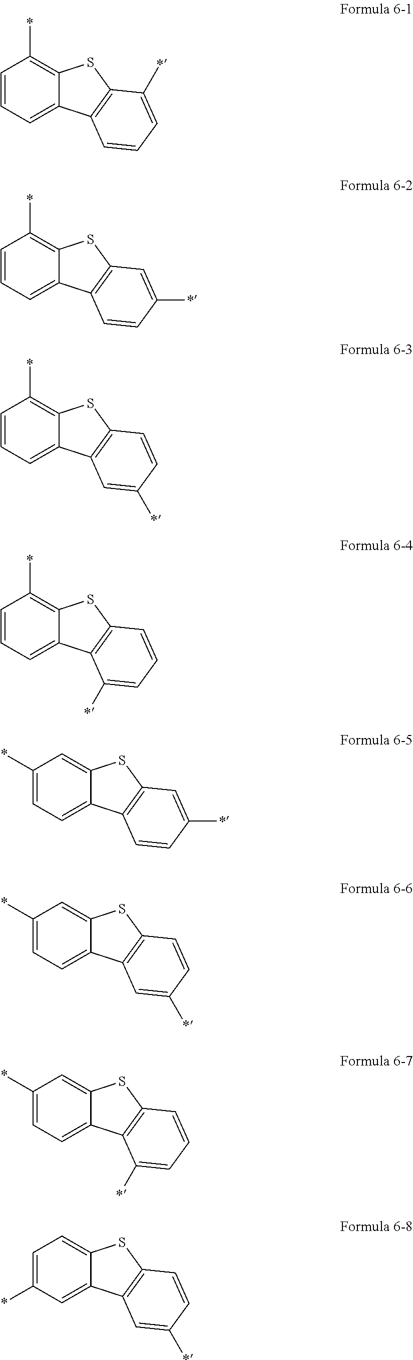

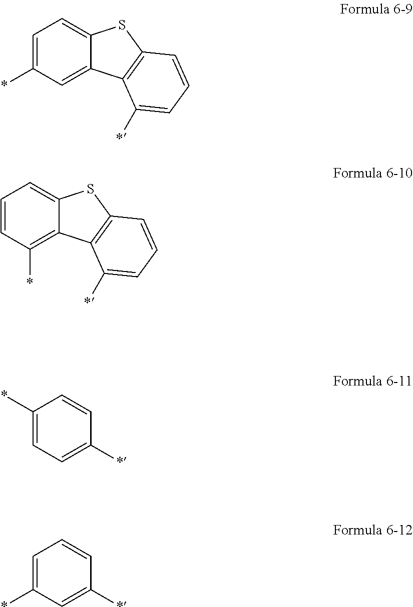

In Formulae 6-1 to 6-12, * and *′ may be each a binding site with an adjacent atom.

In Formulae 1-1 to 1-3 and Formula 2,

R₁₁, R₄₁ to R₄₃, and R₅₁ to R₅₃ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and N(Q₆)(Q₇);

ab, and bd to bf may each independently be selected from 1, 2, and 3, at least two R₁₁s may be the same or differ when ab is 2 or greater, at least two R₄₁s may be the same or differ when bd is 2 or greater, at least two R₄₂s may be the same or differ when be is 2 or greater, and at least two R₄₃s may be the same or differ when bf is 2 or greater; and

bg to bi may each independently be selected from 0, 1, 2, and 3. In an implementation, bg, bh, and bi may not all be 0.

In some embodiments, the first compound may be represented by one of Formulae 1-1(A), 1-1(B), 1-2(A), 1-2(B), 1-3(A), and 1-3(B).

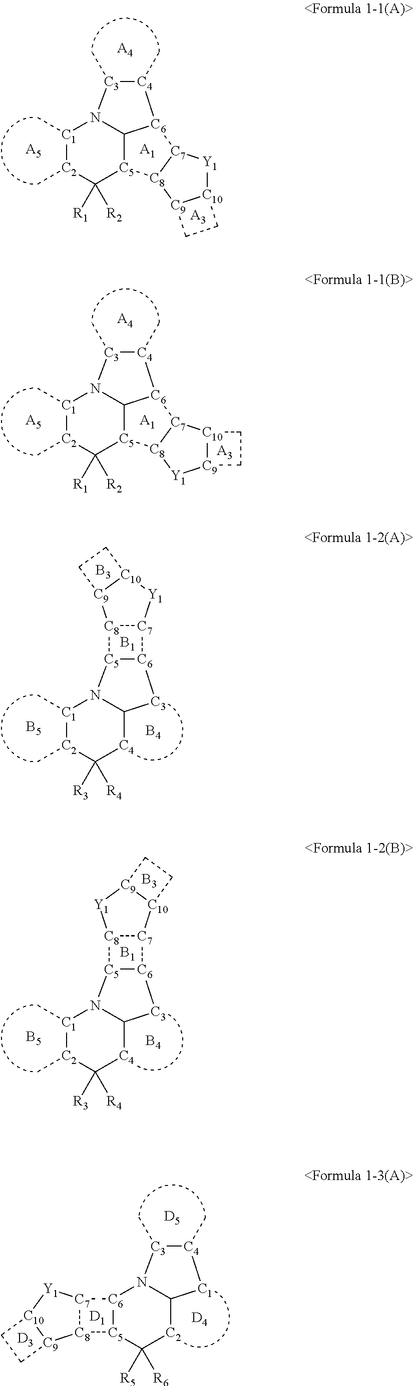

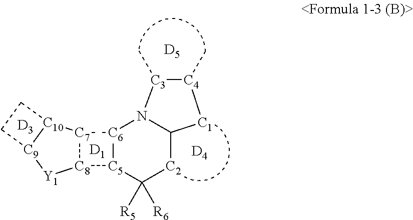

In Formulae 1-1(A), 1-1(B), 1-2(A), 1-2(B), 1-3(A), and 1-3(B),

C₁ to C₁₀ may be numbered to indicate chemically distinct carbon atoms;

A₁ ring may be represented by one of Formulae 5-1(1) and 5-1(2);

B₁ ring may be represented by one of Formulae 5-2(1) to 5-2(5);

D₁ ring may be represented by one of Formulae 5-3(1) to 5-3(5);

A₃ ring may be represented by one of Formulae 6-1(1) to 6-1(4);

B₃ ring may be represented by one of Formulae 6-2(1) to 6-2(4);

D₃ ring may be represented by one of Formulae 6-3(1) to 6-3(4);

A₄ ring may be represented by one of Formulae 7-1(1) to 7-1(4);

B₄ ring may be represented by one of Formulae 7-2(1) to 7-2(3);

D₄ ring may be represented by one of Formulae 7-3(1) to 7-3(3);

A₅ ring and B₅ ring may be each independently represented by one of Formulae 8-1(1) to 8-1(4); and

D₅ ring may be represented by one of Formulae 8-3(1) to 8-3(4):

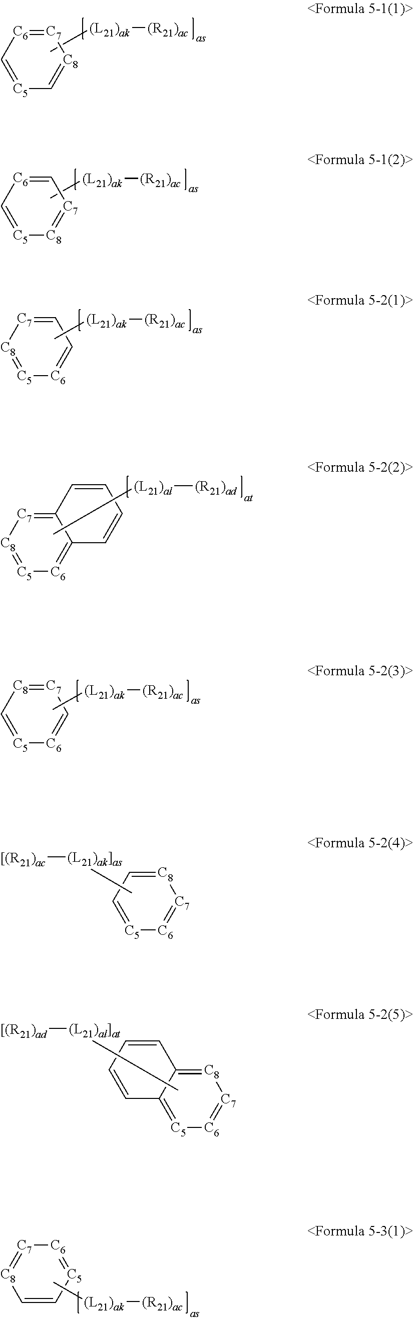

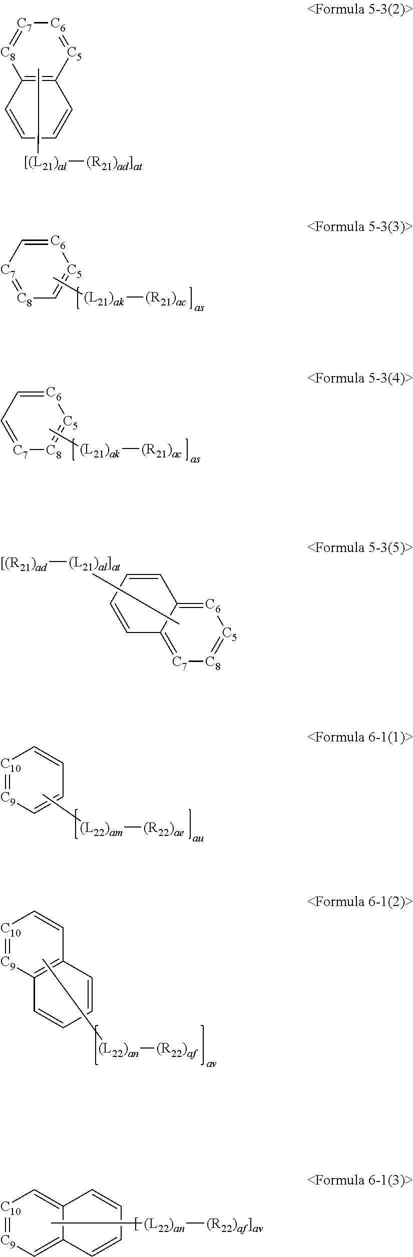

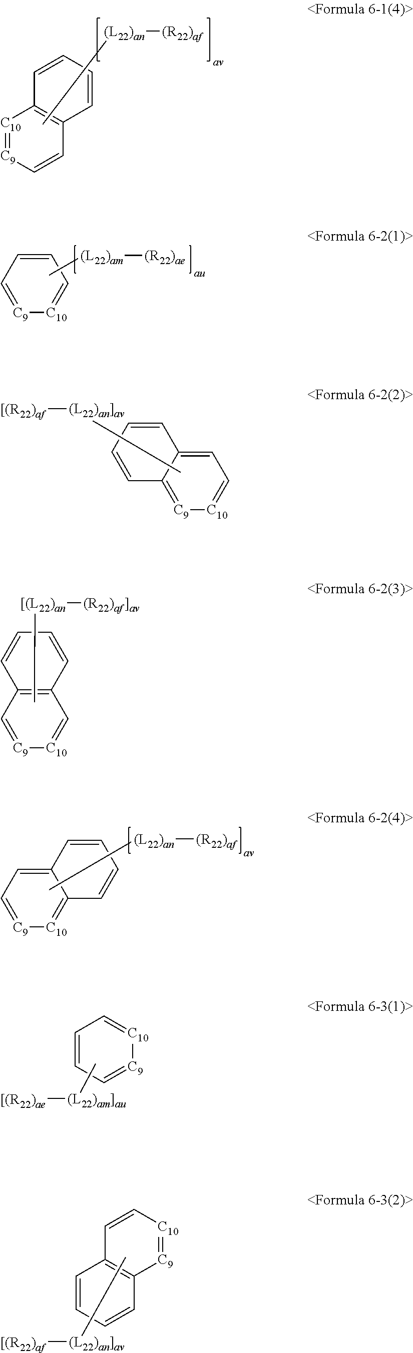

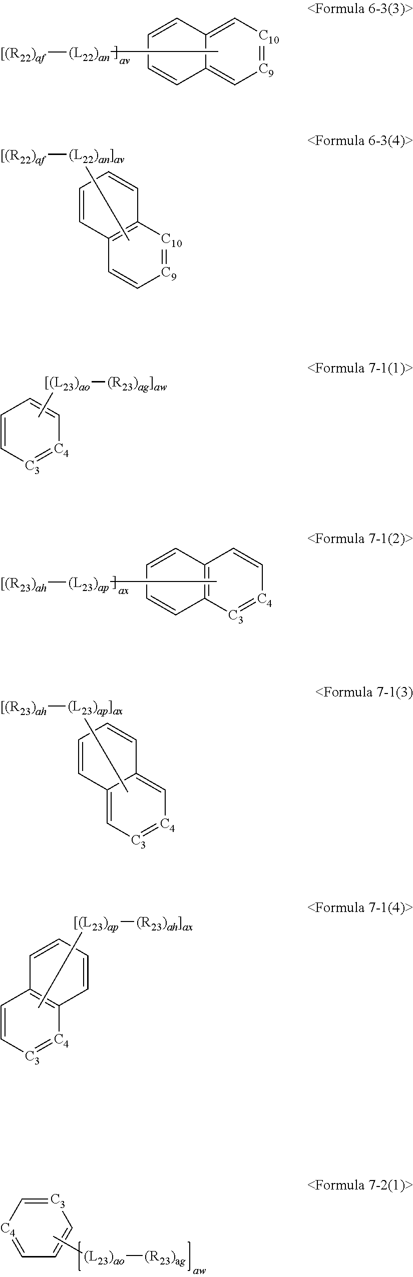

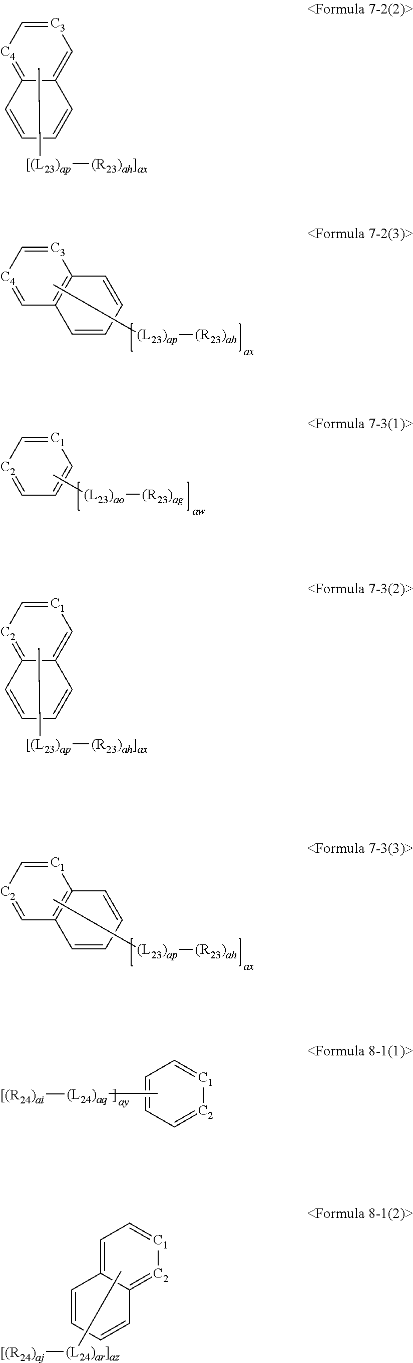

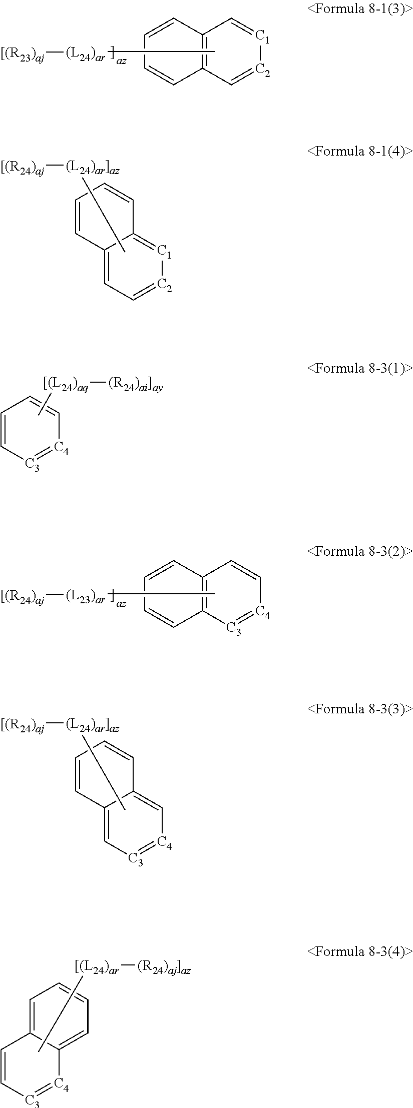

wherein, in Formulae 5-1(1) and 5-1(2), 5-2(1) to 5-2(5), 5-3(1) to 5-3(5), 6-1(1) to 6-1(4), 6-2(1) to 6-2(4), 6-3(1) to 6-3(4), 7-1(1) to 7-1(4), 7-2(1) to 7-2(3), 7-3(1) to 7-3(3), 8-1(1) to 8-1(4), and 8-3(1) to 8-3(4),

L₂₁ to L₂₄ may be defined as described herein in conjunction with L₁;

ak to ar may be each independently selected from 0, 1, 2, and 3;

R₂₁ to R₂₄ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and N(Q₆)(Q₇);

ac to aj may be each independently selected from 0, 1, 2, and 3, at least two R₂₁s may be the same or differ when ac is 2 or greater, at least two R₂₁s may be the same or differ when ad is 2 or greater, at least two R₂₂s may be the same or differ when ae is 2 or greater, at least two R₂₂s may be the same or differ when of is 2 or greater, at least two R₂₃s may be the same or differ when ag is 2 or greater, at least two R₂₃s may be the same or differ when ah is 2 or greater, at least two R₂₄s may be the same or differ when ai is 2 or greater, and at least two R₂₄s may be the same or differ when aj is 2 or greater;

as may be selected from 0, 1, and 2, and two *-[(L₂₁)ₐₖ-(R₂₁)_{ac}]s may be the same or differ when as is 2;

at, au, aw, and ay may be each independently selected from 0, 1, 2, 3, and 4, at least two *-[(L₂₁)_{ad}-(R₂₁)ₐₗ]s may be the same or differ when at is 2 or greater, at least two *-[(L₂₂)ₐₘ-(R₂₂)_{ac}]s may be the same or differ when au is 2 or greater, at least two *-[(L₂₃)ₐₒ-(R₂₃)_{ag}]s may be the same or differ when aw is 2 or greater, and at least two *-[(L₂₄)_{aq}-(R₂₄)ₐᵢ]s may be the same or differ when ay is 2 or greater; and

av, ax, and az may be each independently selected from 0, 1, 2, 3, 4, 5, and 6, at least two *-[(L₂₂)ₐₙ-(R₂₂)_{af}]s may be the same or differ when av is 2 or greater, at least two *-[(L₂₃)ₐₚ-(R₂₃)ₐₕ]s may be the same or differ when ax is 2 or greater, and at least two *-[(L₂₄)ₐᵣ-(R₂₄)ₐⱼ]s may be the same or differ when az is 2 or greater.

In some embodiments, in Formulae 1-1(A), 1-1(B), 1-2(A), 1-2(B), 1-3(A), and 1-3(B), R₁₁, and R₂₁ to R₂₄ may be each independently selected from a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinyl group, a benzoimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group, and

a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinylgroup, a benzoimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group. However, embodiments of the present disclosure are not limited thereto.

For example, in Formulae 1-1(A), 1-1(B), 1-2(A), 1-2(B), 1-3(A), and 1-3(B), R₁₁, and R₂₁ to R₂₄ may be each independently selected from groups represented by Formulae 7-1 to 7-44:

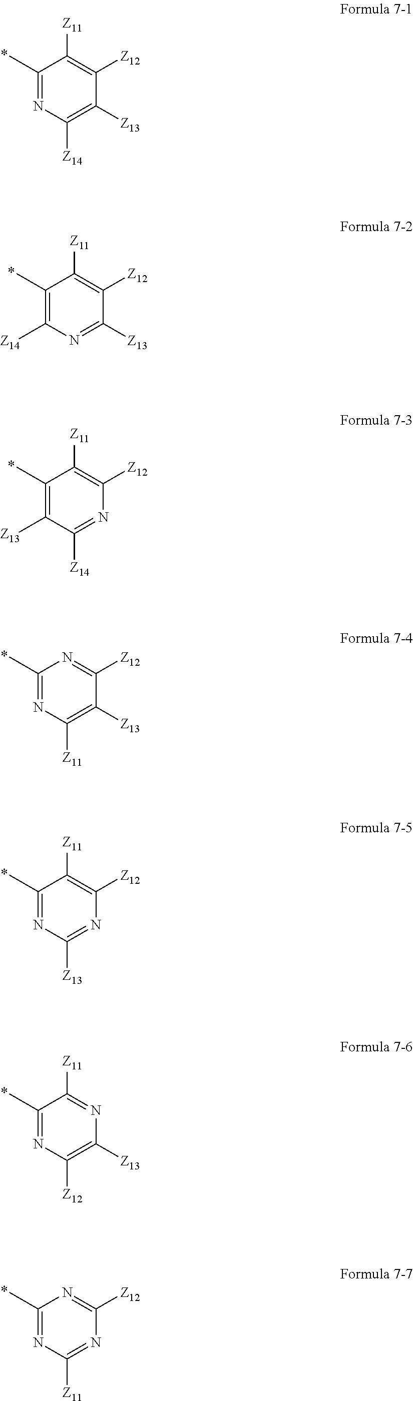

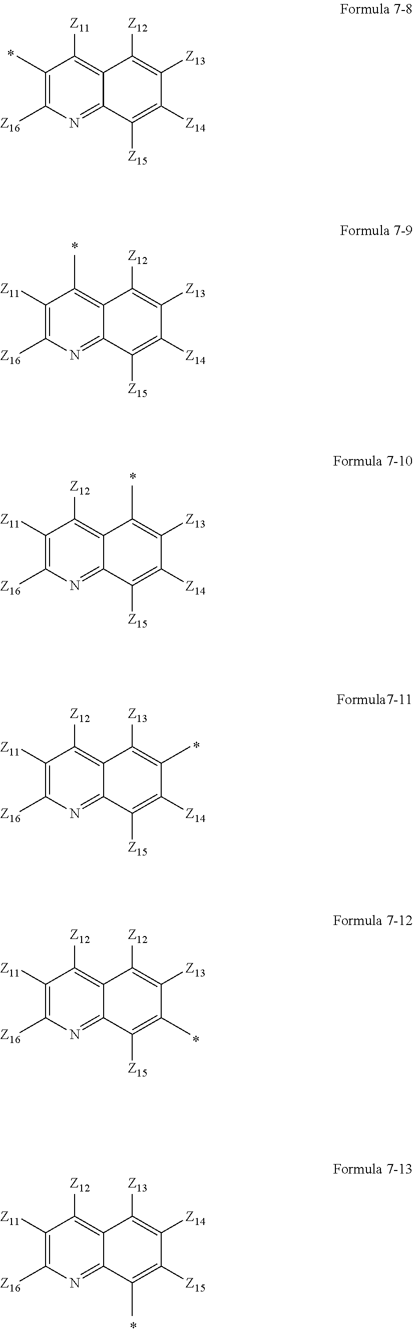

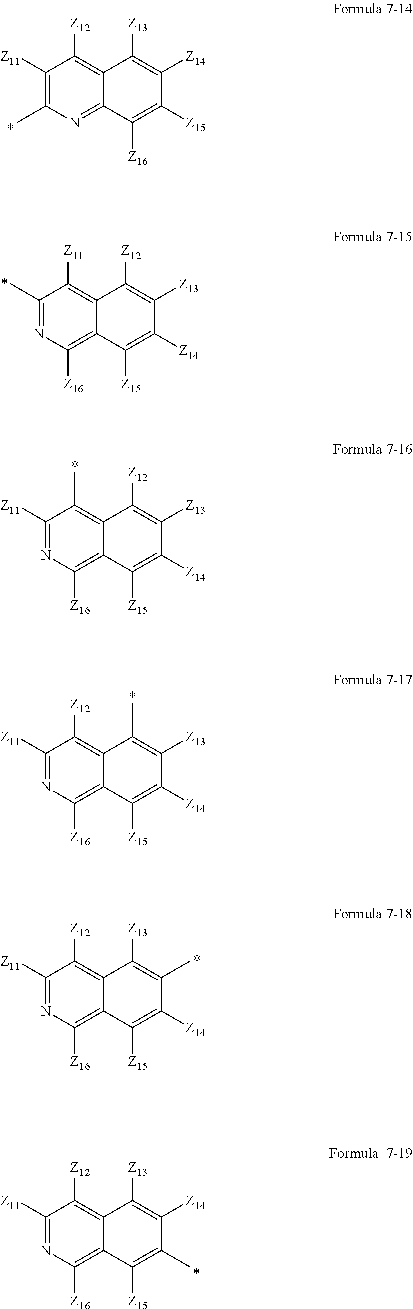

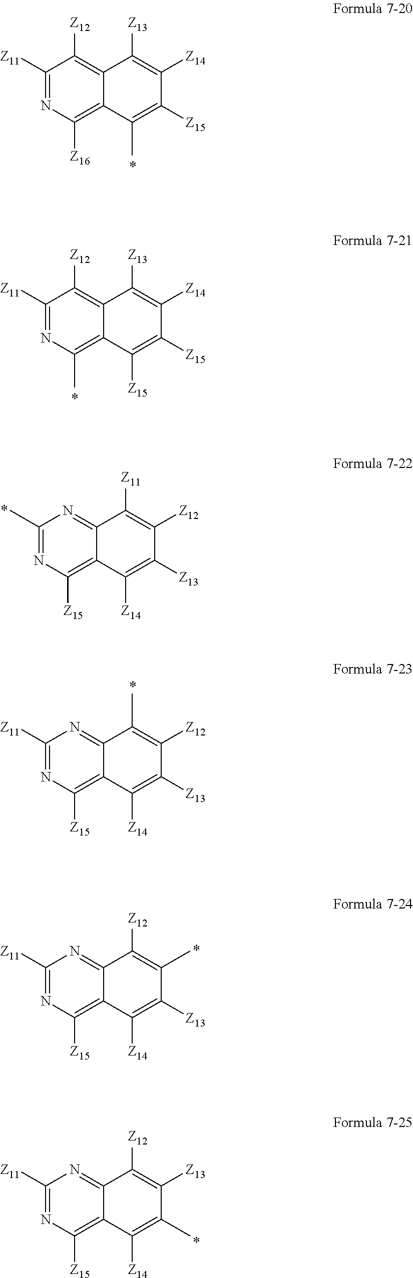

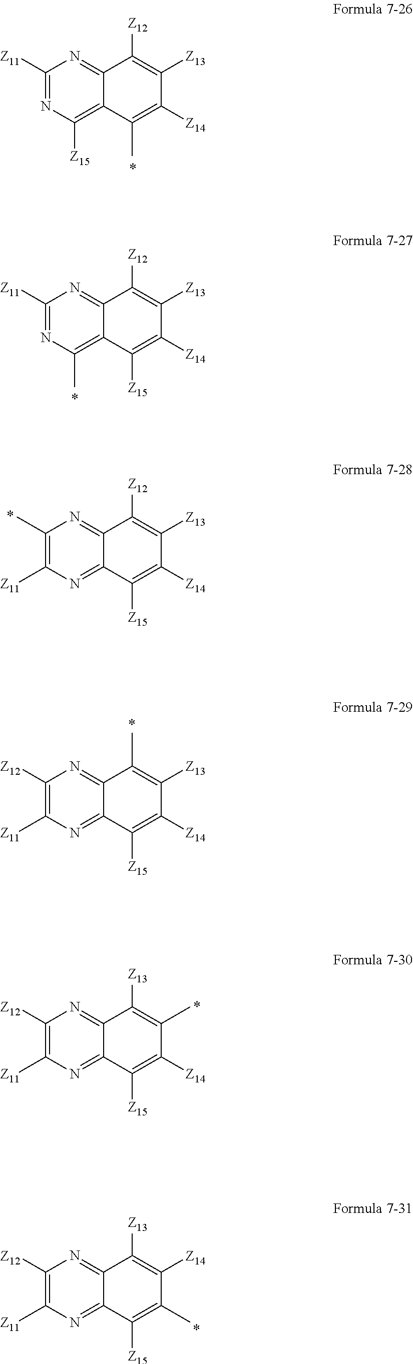

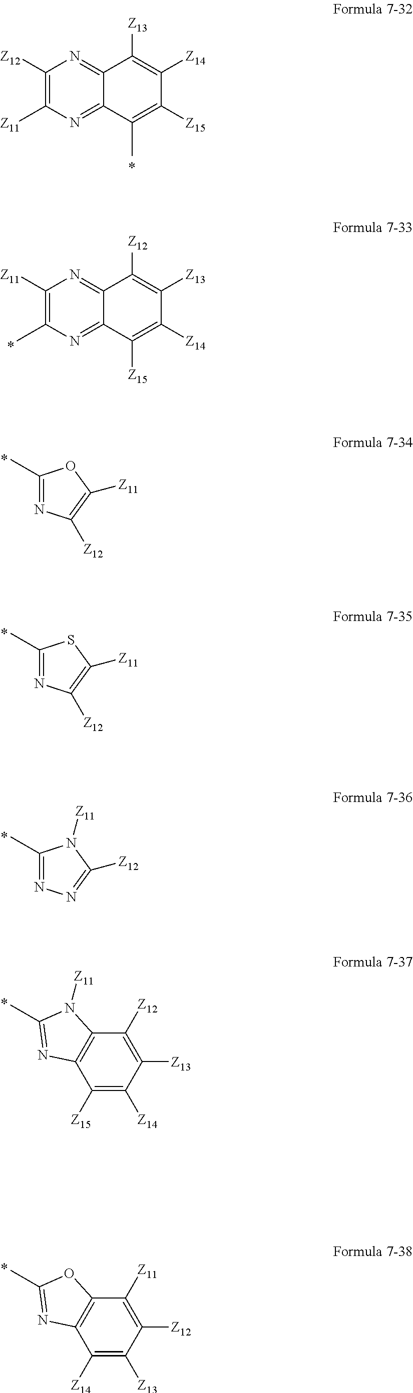

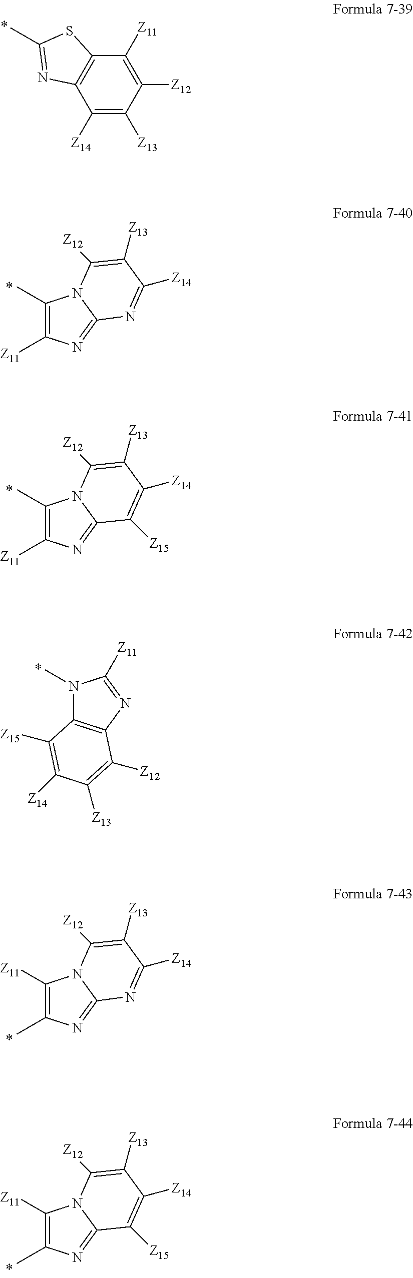

wherein, in Formulae 7-1 to 7-44,

Z₁₁ to Z₁₆ may be each independently selected from a hydrogen, a deuterium, —F, —Cl, —Br, —I, a hydroxyl group, a cyano group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and

* may be a binding site with an adjacent atom.

In some embodiments, when the first compound is represented by one of Formulae 1-1(A), 1-1(B), 1-2(A), 1-2(B), 1-3(A), and 1-3(B), Y₁ in Formula 3 may be N-(L₁)ₐₐ-(R₁₁)_{ab}; L₁ may be represented by one of Formulae 5-1 to 5-16; aa may be 0 or 1; R₁₁ may be represented by one of Formulae 8-1 to 8-11; and ab may be 1:

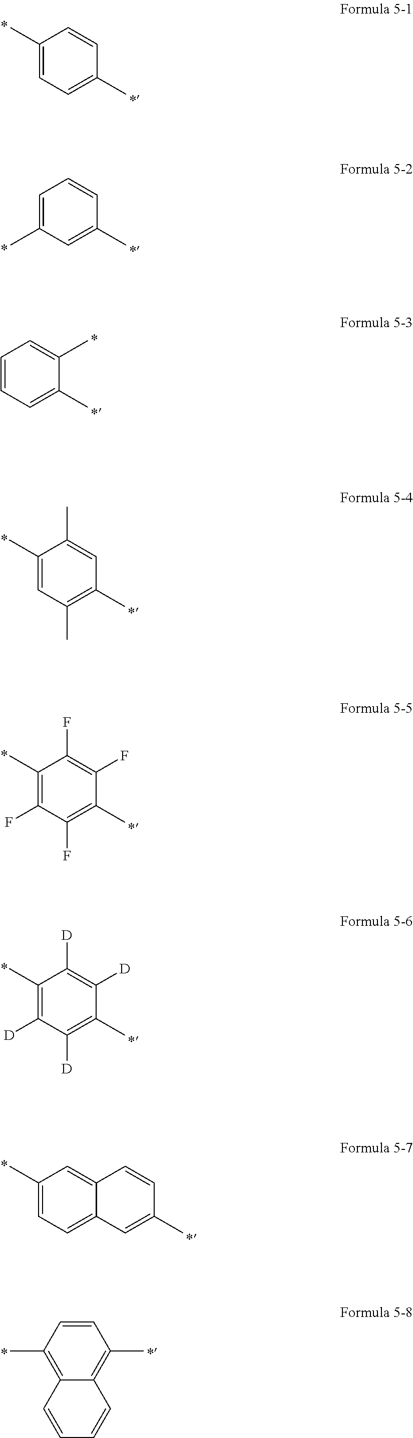

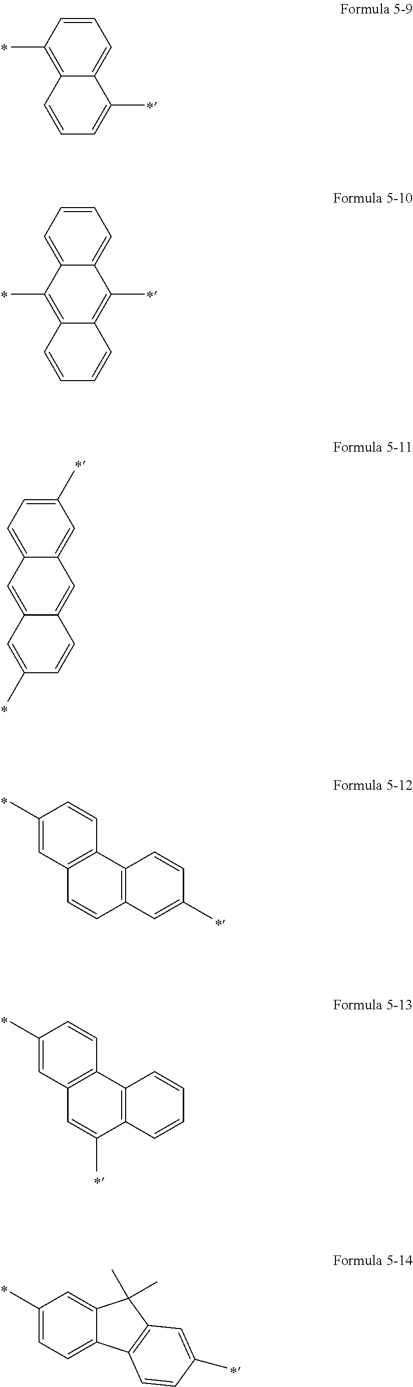

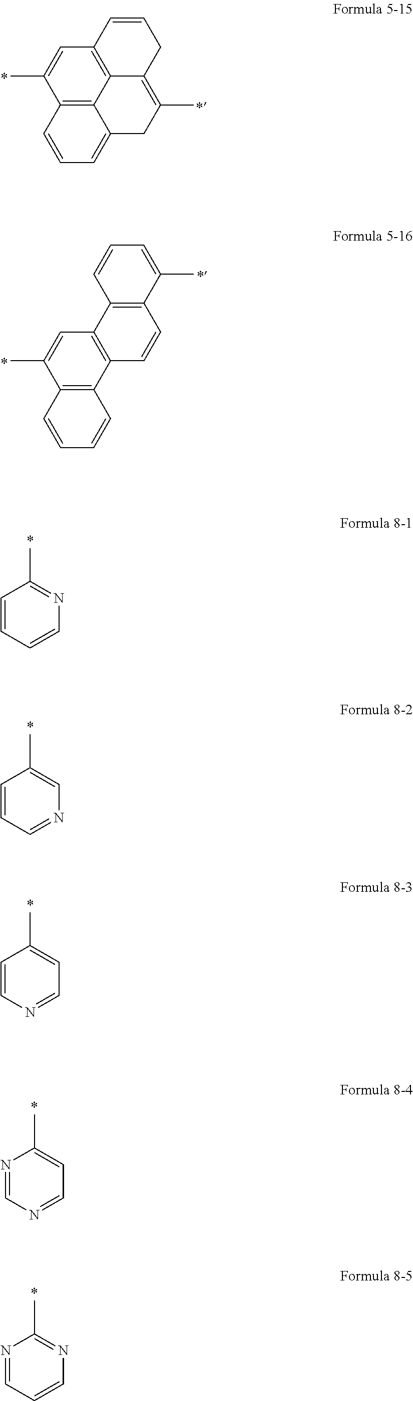

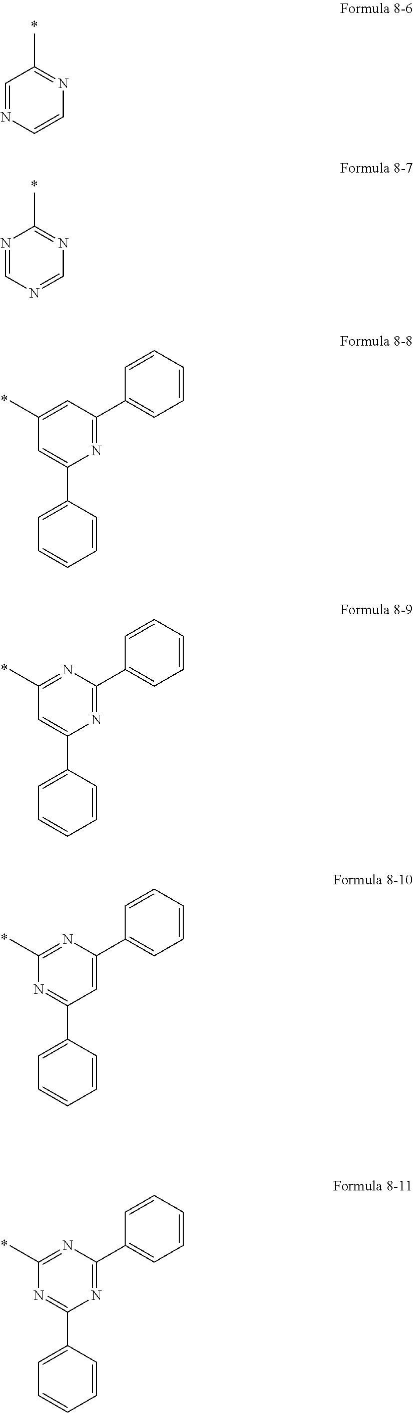

wherein, in Formulae 5-1 to 5-16 and 8-1 to 8-11, * and *′ may be each a binding site with an adjacent atom.

In some embodiments, when the first compound is represented by one of Formulae 1-1(A), 1-1(B), 1-2(A), 1-2(B), 1-3(A), and 1-3(B), Y₁ in Formula 3 may be S or O; A₅ ring and B₅ ring may be each independently represented by one of Formulae 8-1(1) to 8-1(4); and D₅ ring may be represented by one of Formulae 8-3(1) to 8-3(4):

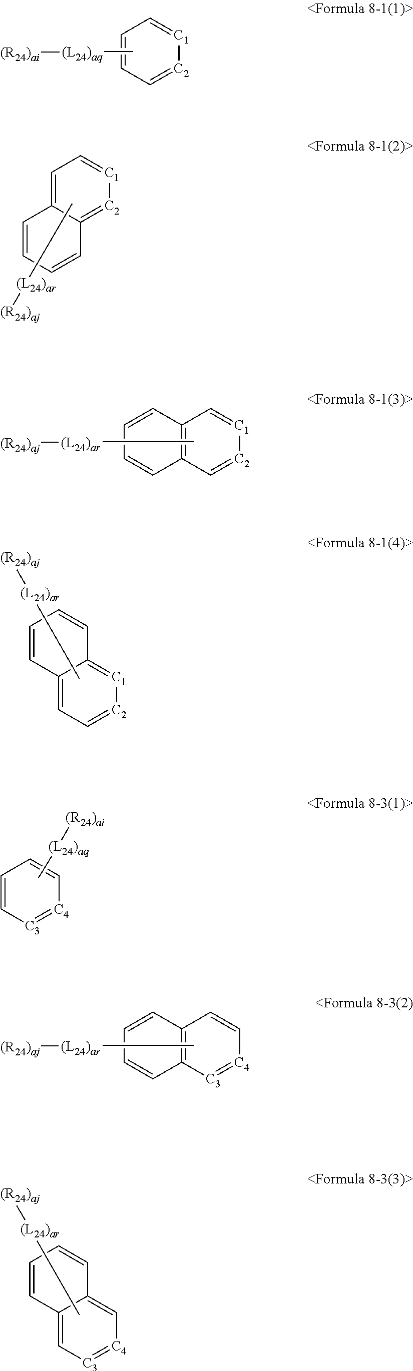

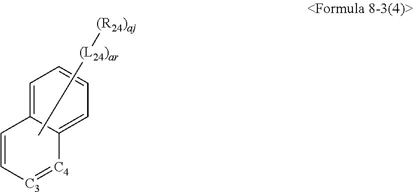

wherein, in Formulae 8-1(1) to 8-1(4) and Formulae 8-3(1) to 8-3(4),

L₂₄ may be represented by one of Formulae 5-1 to 5-16;

aq and ar may be each independently 0 or 1;

R₂₄ may be represented by one of Formulae 8-1 to 8-11; and

ai and aj may be 1:

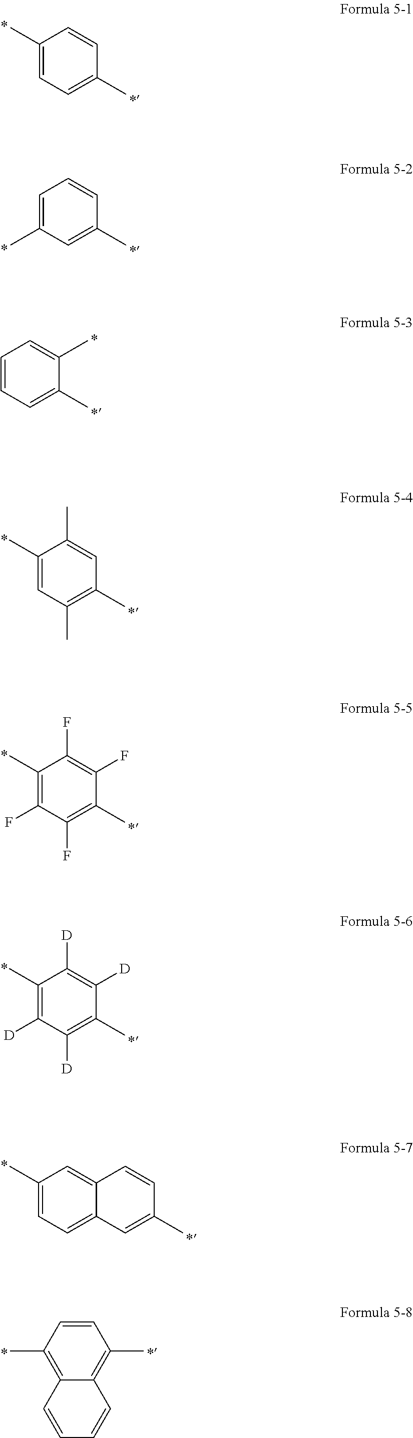

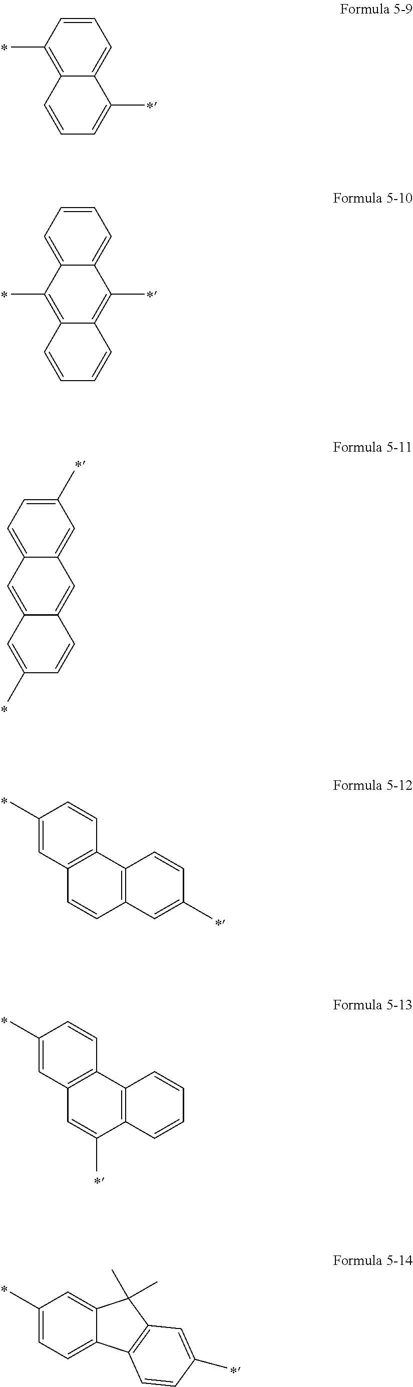

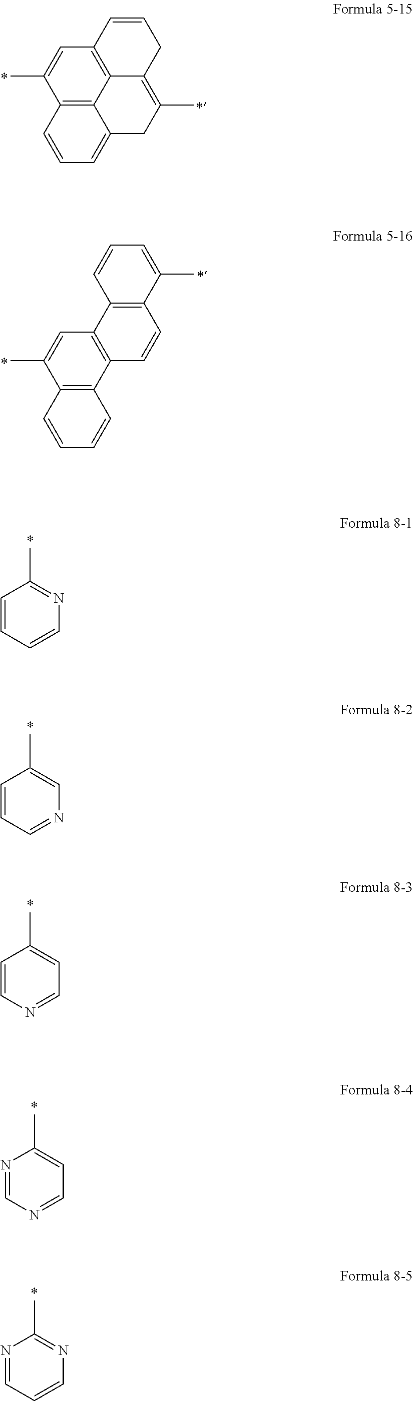

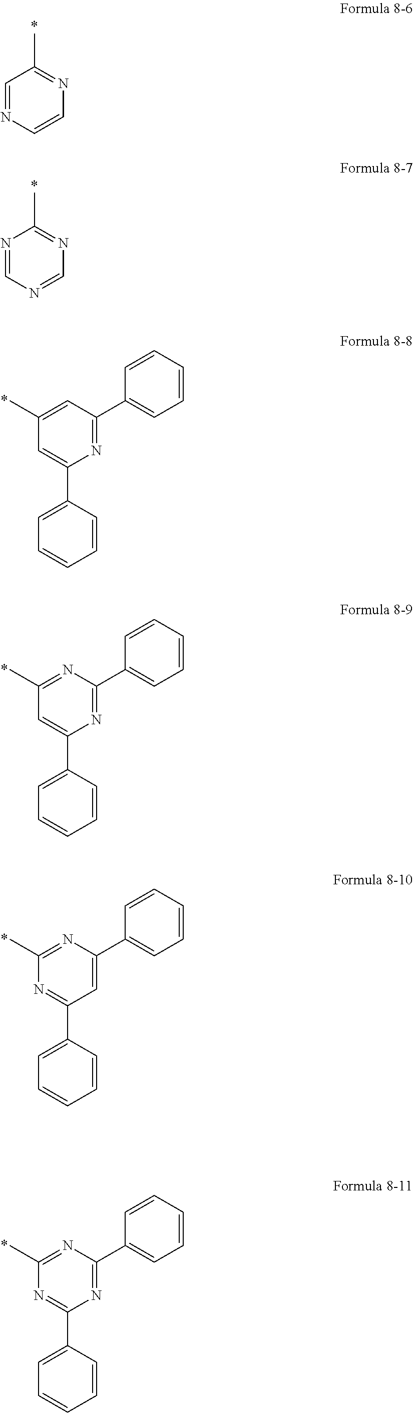

wherein, in Formulae 5-1 to 5-16 and 8-1 to 8-11, * and *′ may be each a binding site with an adjacent atom.

In some embodiments, the first compound may be represented by Formula 1-1(A), 1-2(A), or 1-3(A), wherein, in Formulae 1-1(A), 1-2(A) and 1-3(A), A₁ ring may be represented by one of Formulae 5-1(1) and 5-1(2);

B₁ ring may be represented by one of Formulae 5-2(1) to 5-2(3);

D₁ ring may be represented by one of Formulae 5-3(1) to 5-3(3);

A₃ ring may be represented by one of Formulae 6-1(1) and 6-1(2);

B₃ ring may be represented by one of Formulae 6-2(1) and 6-2(2);

D₃ ring may be represented by one of Formulae 6-3(1) to 6-3(4);

A₄ ring may be represented by one of Formulae 7-1(1) and 7-1(3);

B₄ ring may be represented by one of Formulae 7-2(1) and 7-2(3);

D₄ ring may be represented by one of Formulae 7-3(1) and 7-3(2);

A₅ ring may be represented by one of Formulae 8-1(1) and 8-1(3);

B₅ ring may be represented by one of Formulae 8-2(1) to 8-2(3); and

D₅ ring may be represented by one of Formulae 8-3(1) and 8-3(4).

In some embodiments, in Formula 2,

R₄₁ to R₄₃ and R₅₁ to R₅₃ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₁-C₂₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃) —B(Q₄)(Q₅), and N(Q₆)(Q₇). However, embodiments of the present disclosure are not limited thereto.

For example, R₄₁ to R₄₃ and R₅₁ to R₅₃ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, and an n-octyl group, and, one of groups represented by Formulae 10-1 to 10-17:

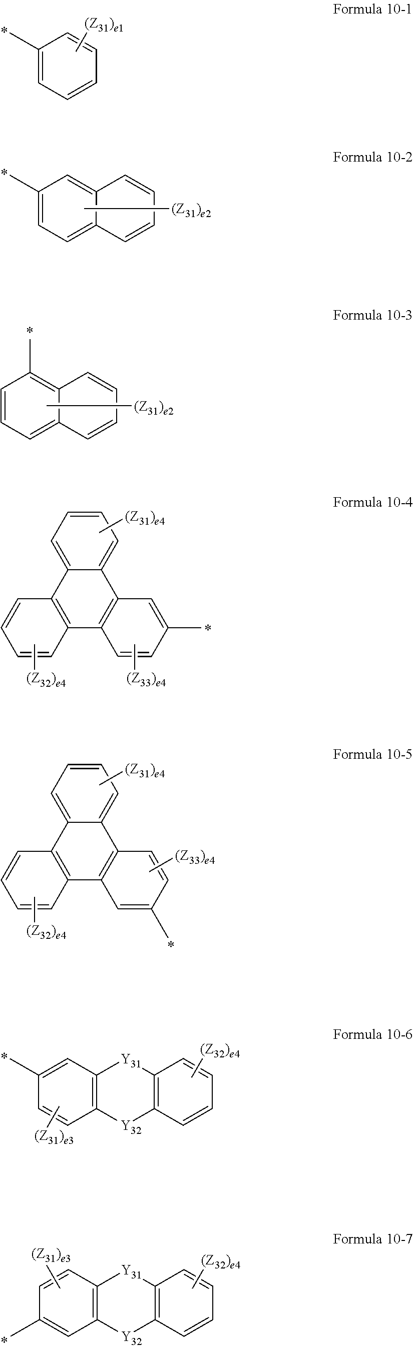

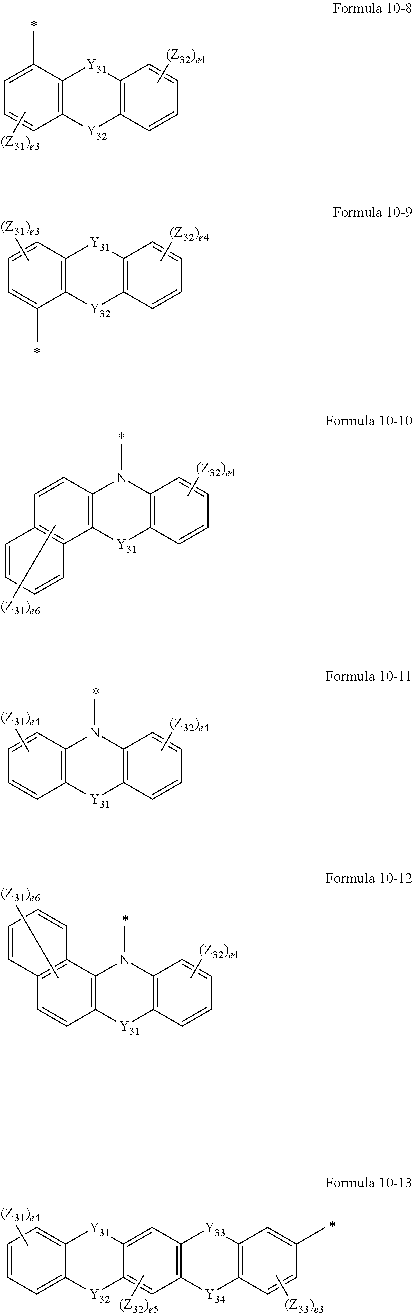

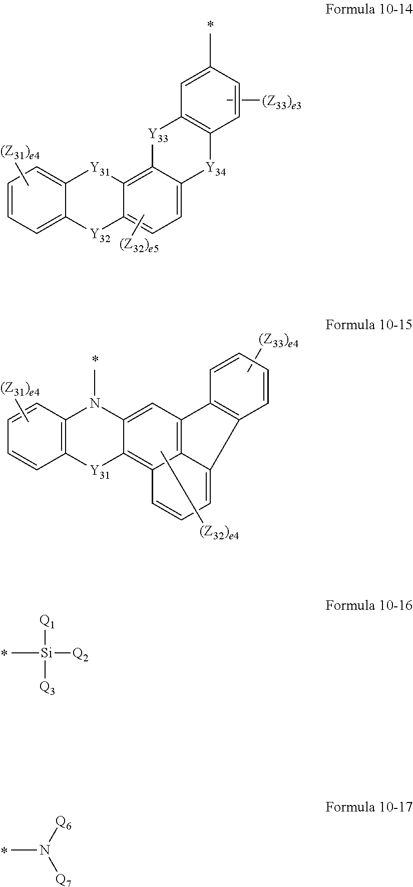

wherein, in Formulae 10-1 to 10-17,

Y₃₁ to Y₃₄ may be each independently a single bond, O, S, C(Z₃₄)(Z₃₅), N(Z₃₆), or Si(Z₃₇)(Z₃₈);

Z₃₁ to Z₃₈ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group,

a C₁-C₂₀ alkyl group and a C₁-C₂₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof,

a C₆-C₂₀ aryl group, a C₁-C₂₀ heteroaryl group, a monovalent non-aromatic condensed polycyclic group, and a monovalent non-aromatic condensed heteropolycyclic group, and

a C₆-C₂₀ aryl group, a C₁-C₂₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group;

Q₁ to Q₃, Q₆ and Q₇ of Formulae 10-16 and 10-17 may each independently be selected from:

a C₆-C₂₀ aryl group, a C₁-C₂₀ heteroaryl group, a monovalent non-aromatic condensed polycyclic group, and a monovalent non-aromatic condensed heteropolycyclic group, and

a C₆-C₂₀ aryl group, a C₁-C₂₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group;

e1 may be an integer selected from 1 to 5;

e2 may be an integer selected from 1 to 7;

e3 may be an integer selected from 1 to 3;

e4 may be an integer selected from 1 to 4;

e5 may be an integer selected from 1 or 2;

e6 may be an integer selected from 1 to 6; and

* may be a binding site with an adjacent atom.

For example, in Formulae 10-1 to 10-17,

Z₃₁ to Z₃₈ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group; and

Q_{1 to} Q₃, Q₆, and Q₇ may be each independently selected from a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group.

For example, in Formula 2, R₄₁ to R₄₃ and R₅₁ to R₅₃ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, and one of groups represented by one of Formulae 12-1 to 12-49:

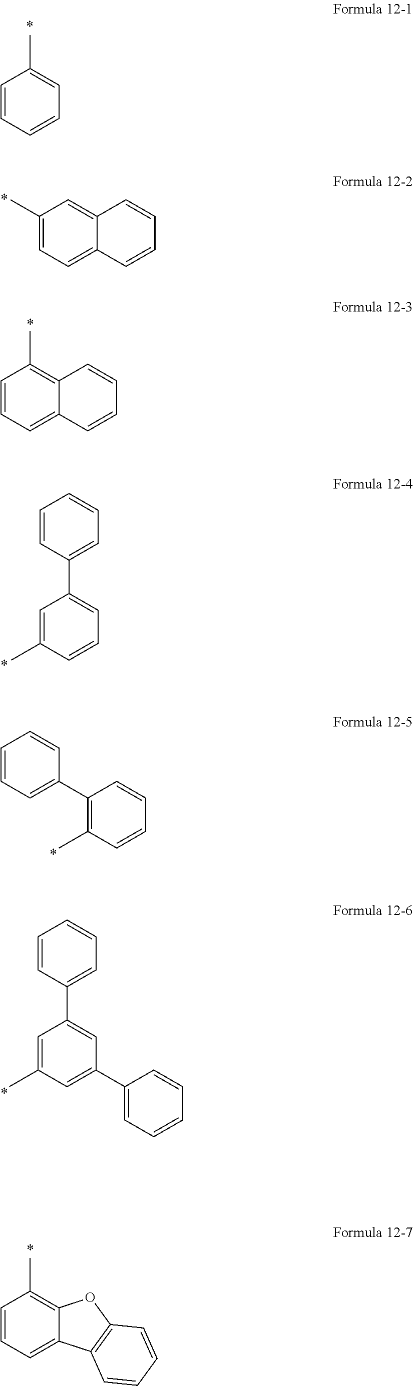

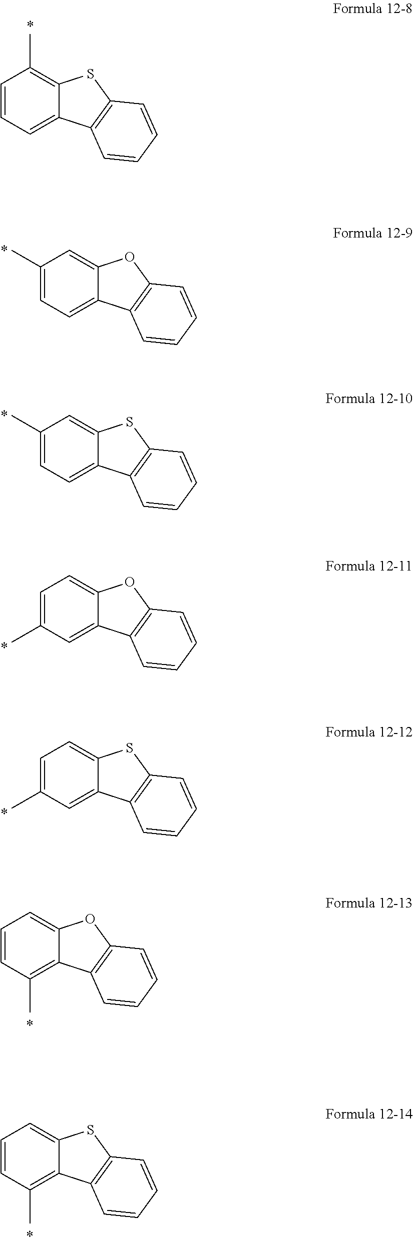

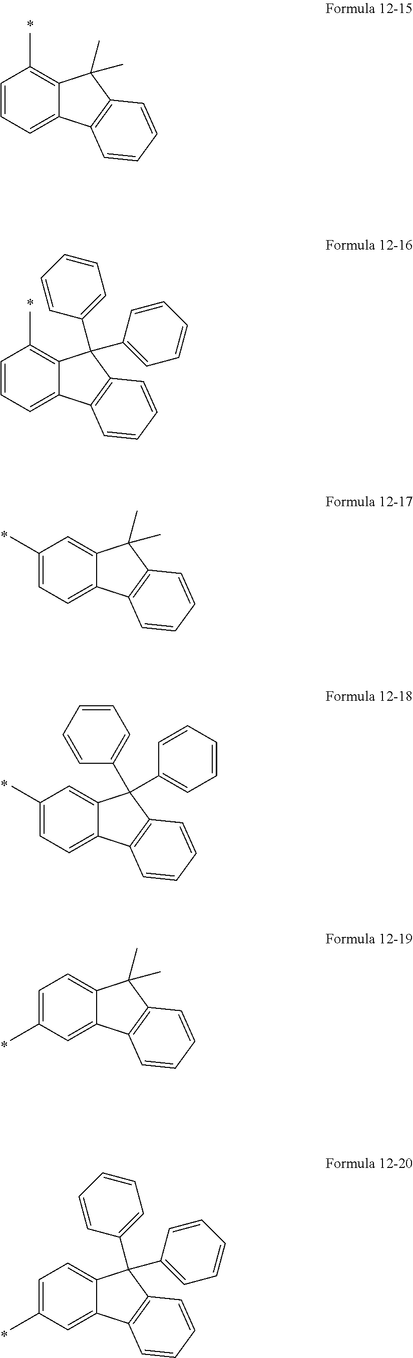

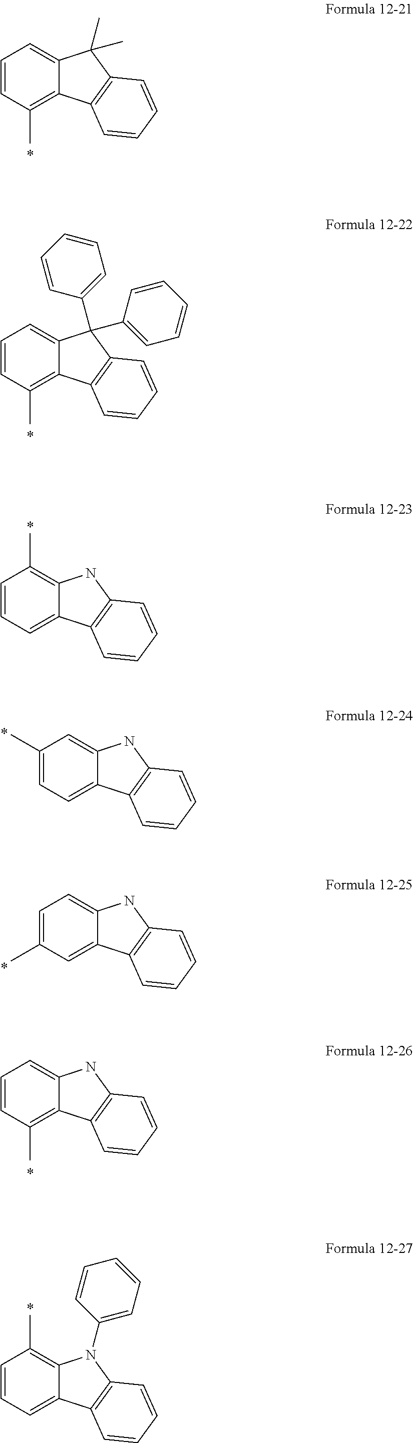

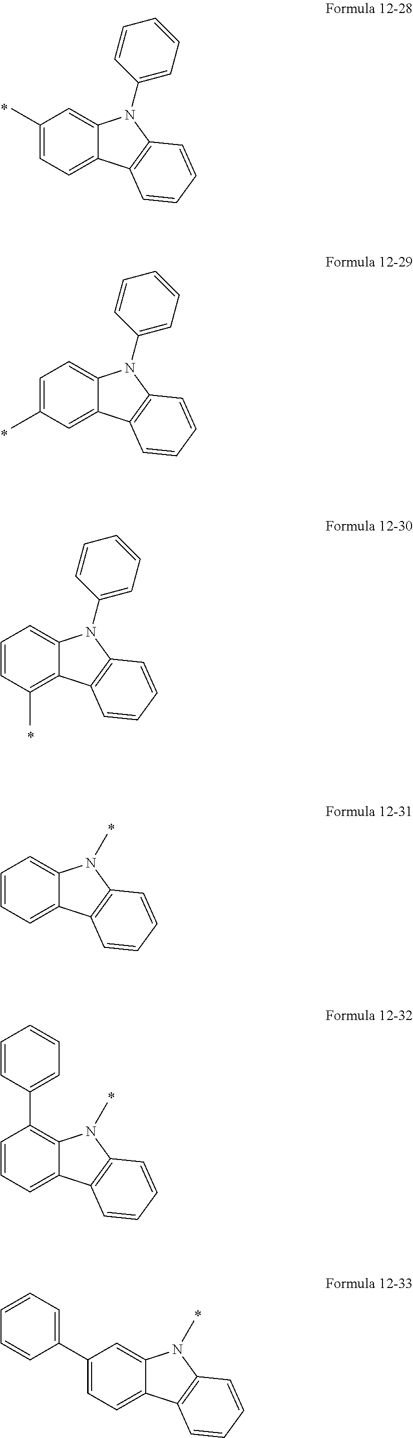

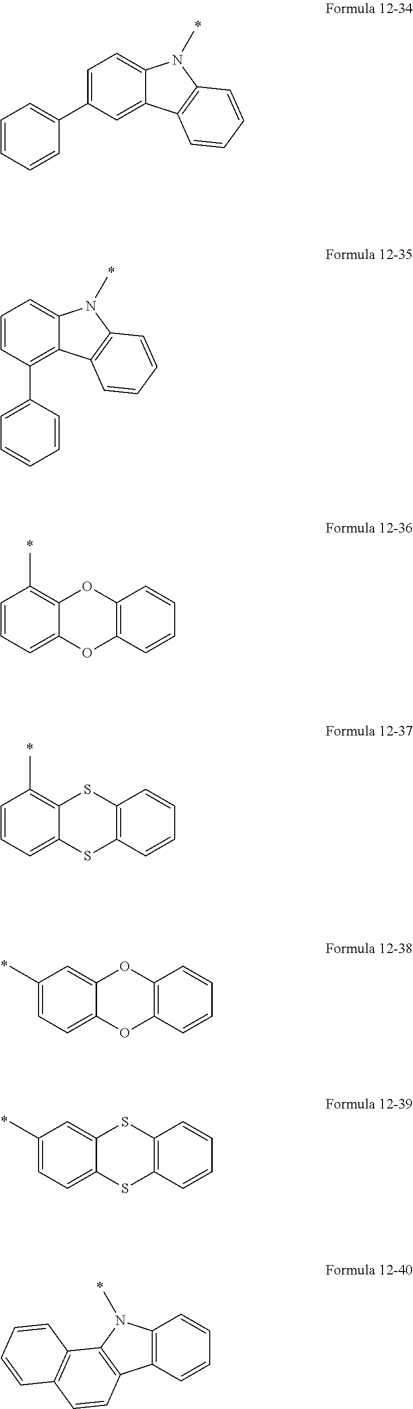

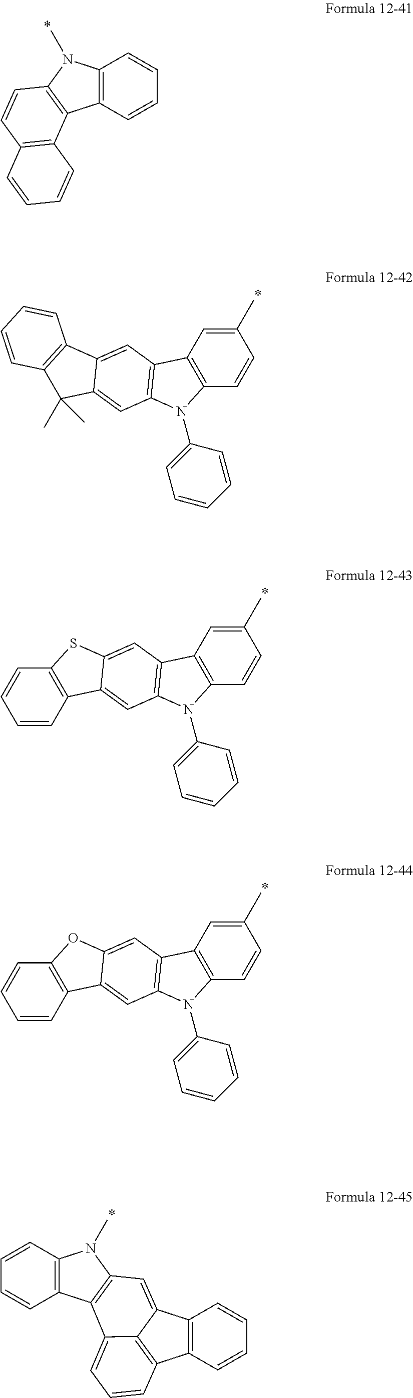

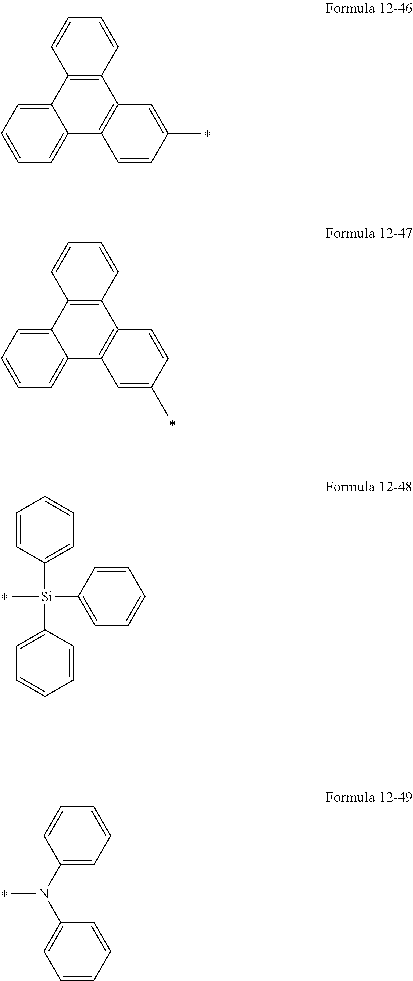

wherein, in Formulae 12-1 to 12-49, * is a binding site with an adjacent atom.

For example, in Formula 2, R₄₁ to R₄₃, and R₅₁ to R₅₃ may be each independently represented by one of Formula 13-1 to Formula 13-6;

bd to bf may be each independently 0 or 1; and

bg+bh+bi may be 1 or 2:

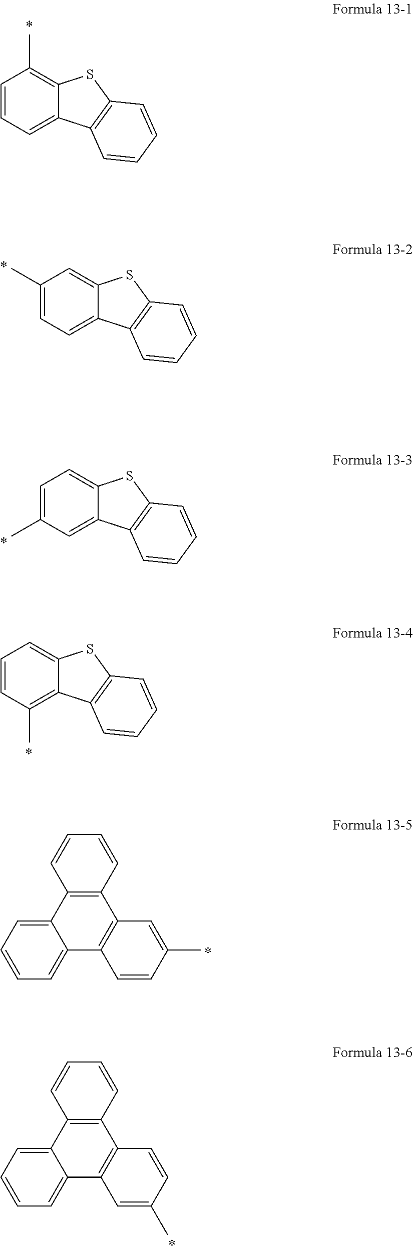

wherein, in Formulae 13-1 to Formula 13-6, * may be a binding site with an adjacent atom.

In some embodiments, the first compound may be represented by one of Formulae 1-1(A-1) to 1-1(A-20), Formulae 1-1(B-1) to 1-1(B-20), Formulae 1-2(A-1) to 1-2(A-27), Formulae 1-2(B-1) to 1-2(B-19), Formulae 1-3(A-1) to 1-3(A-29), and Formulae 1-3(B-1) to 1-3(B-27), and the second compound may be represented by one of Formulae 2(1) and 2(2). However, embodiments of the present disclosure are not limited thereto.

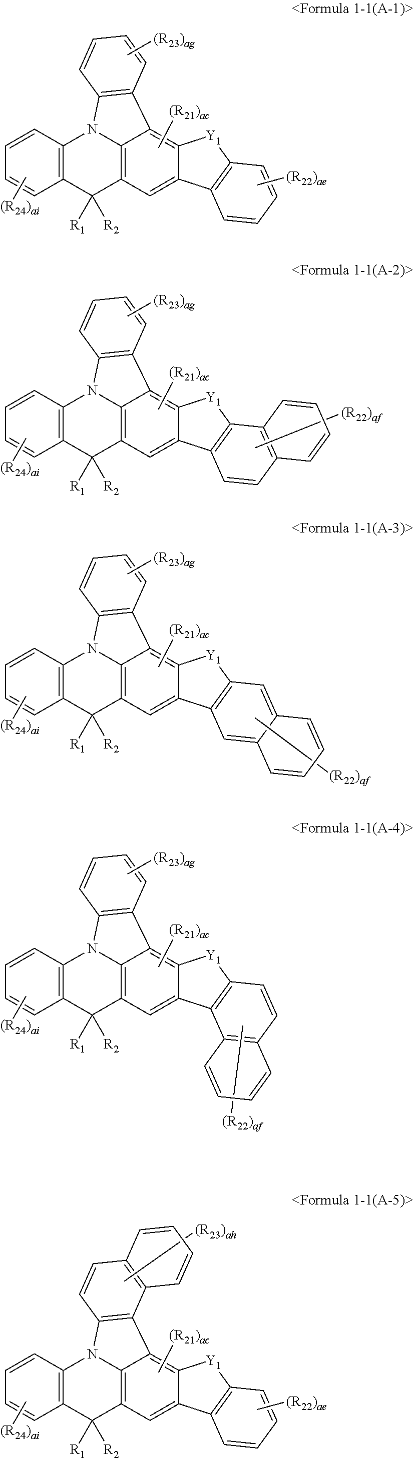

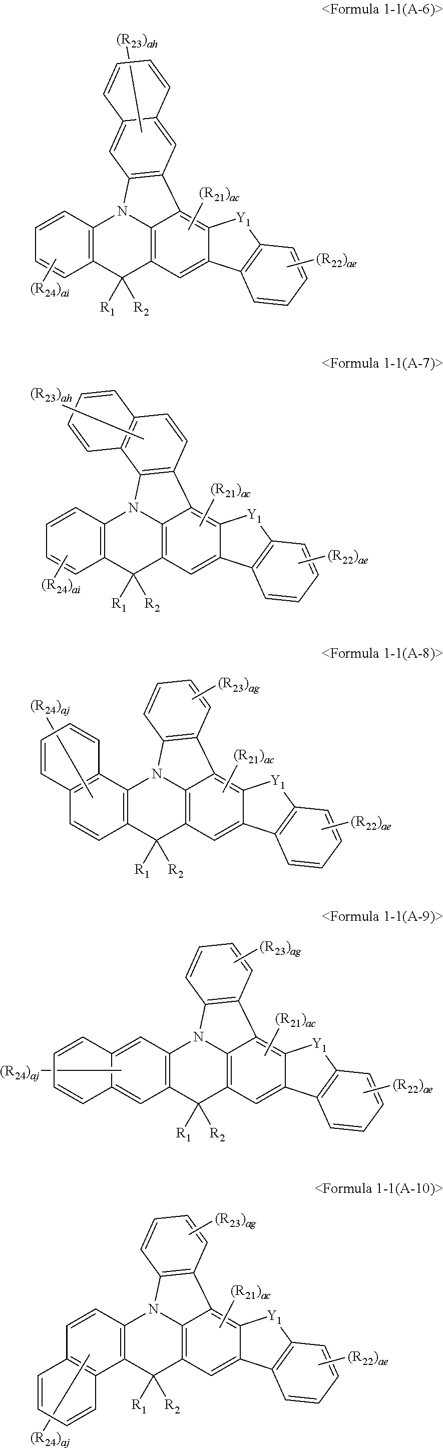

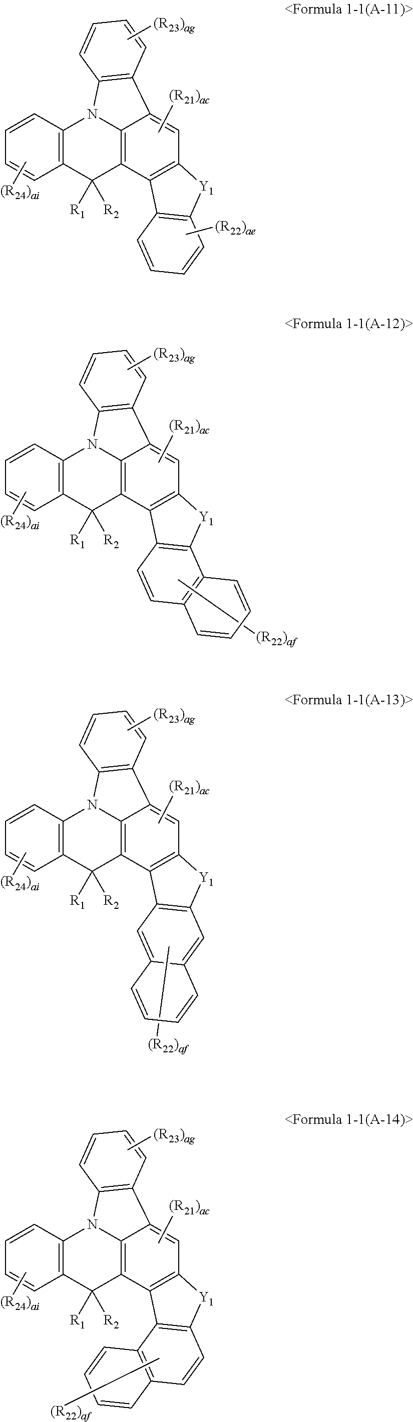

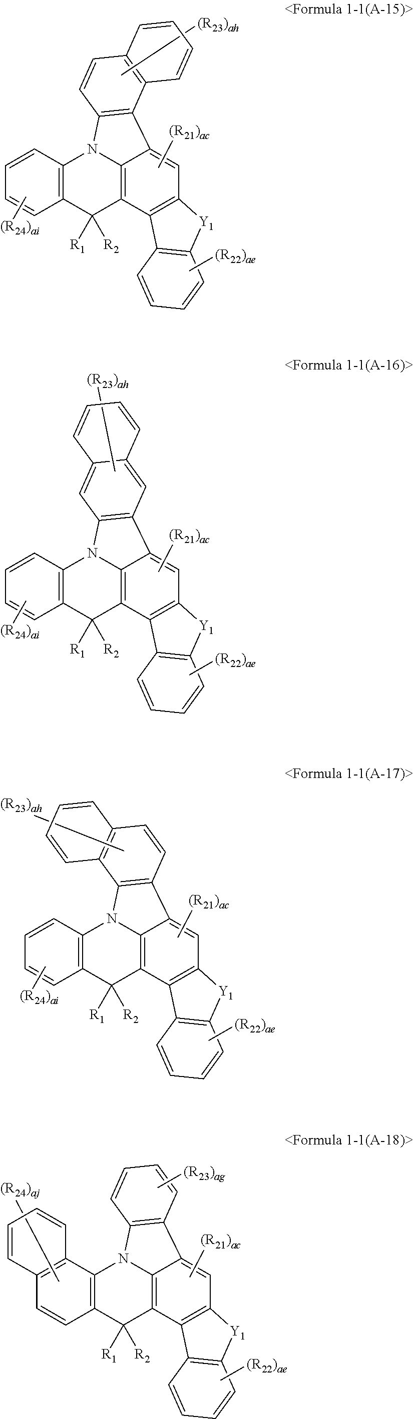

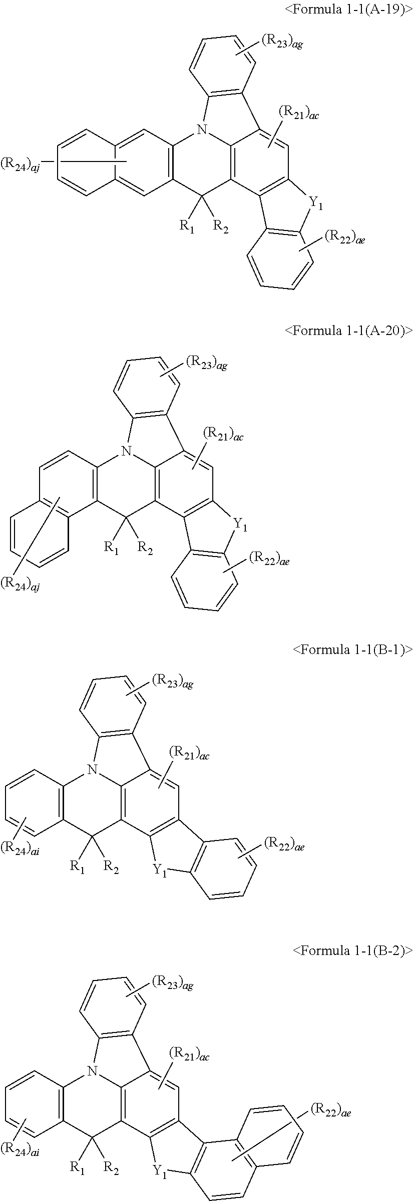

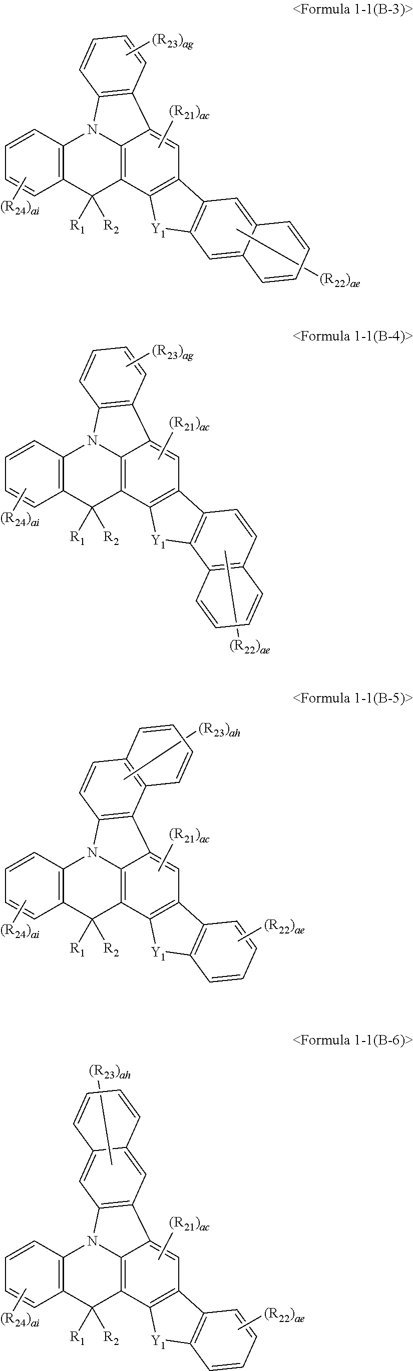

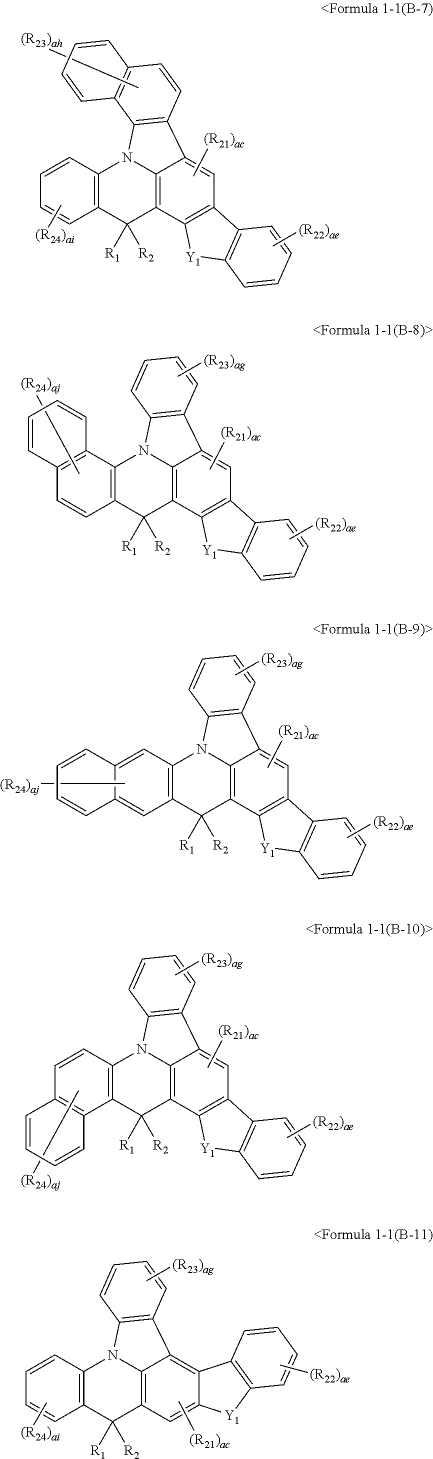

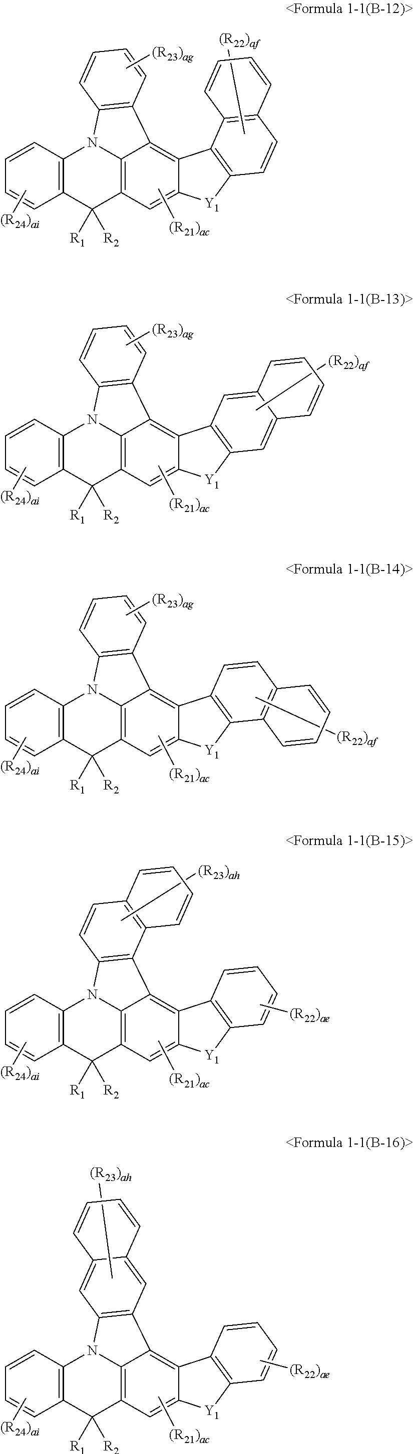

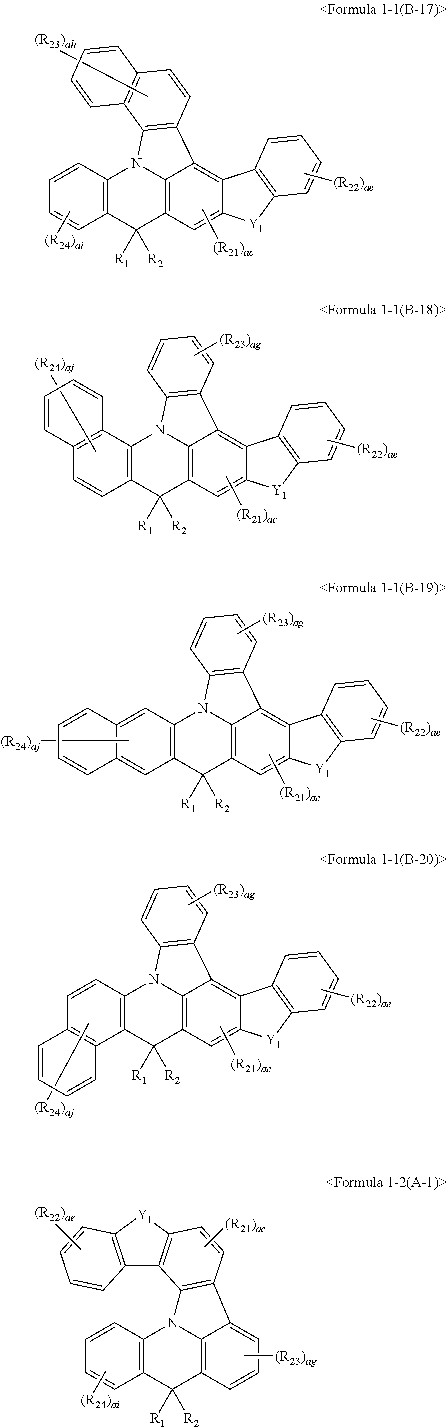

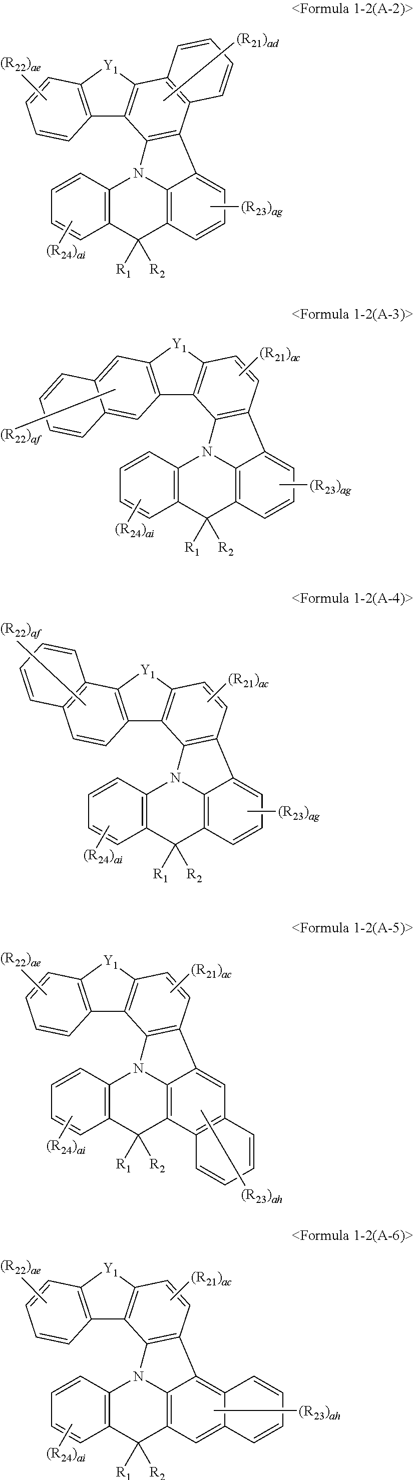

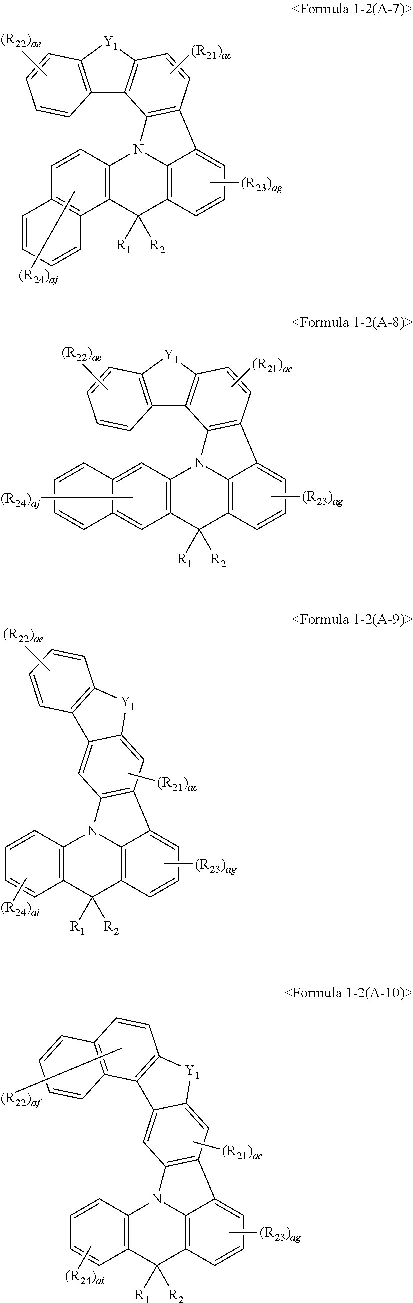

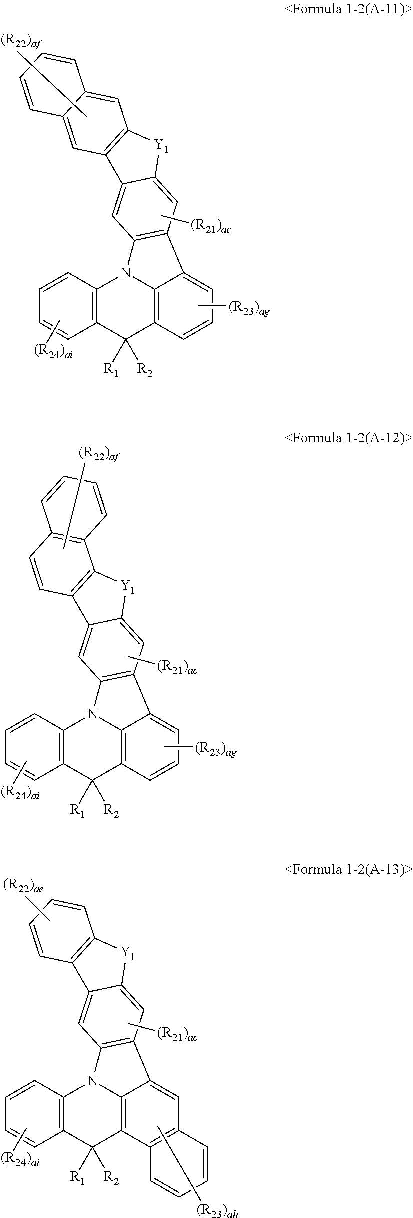

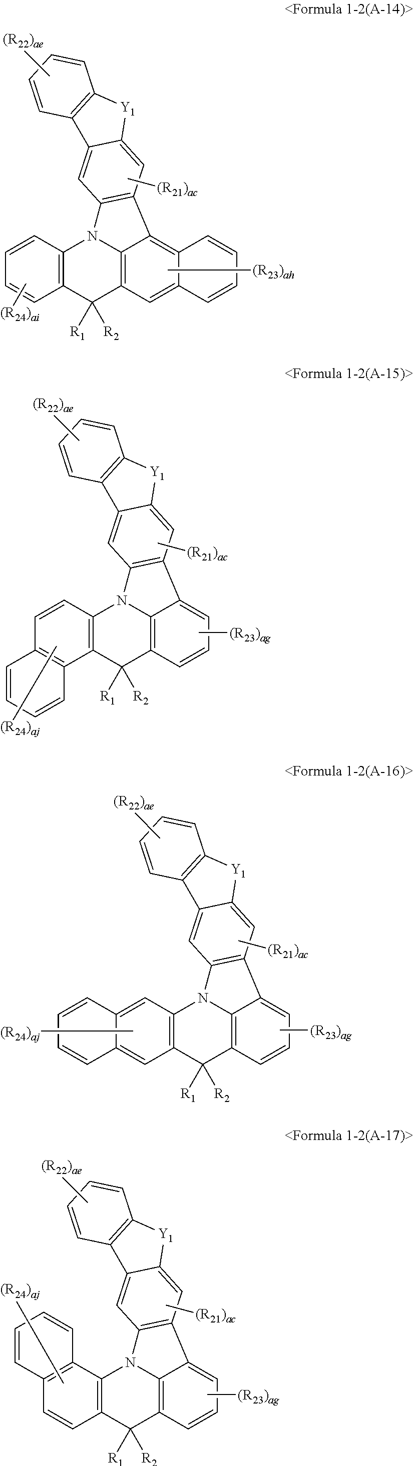

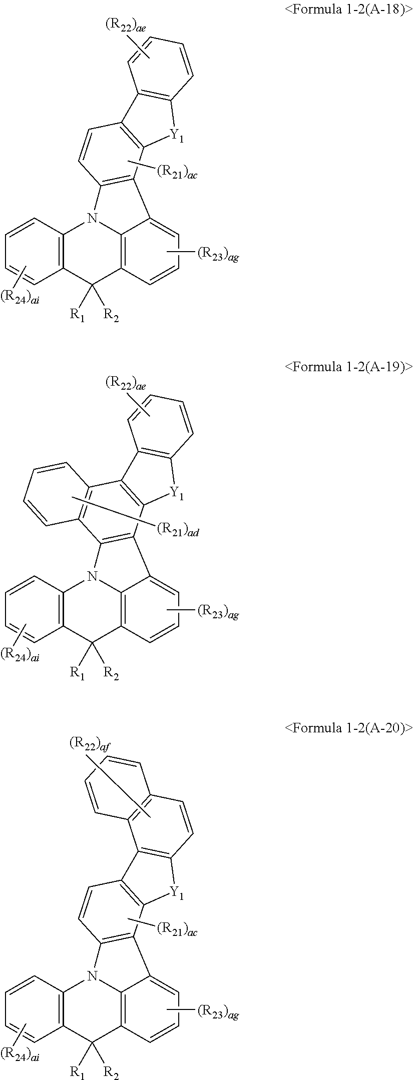

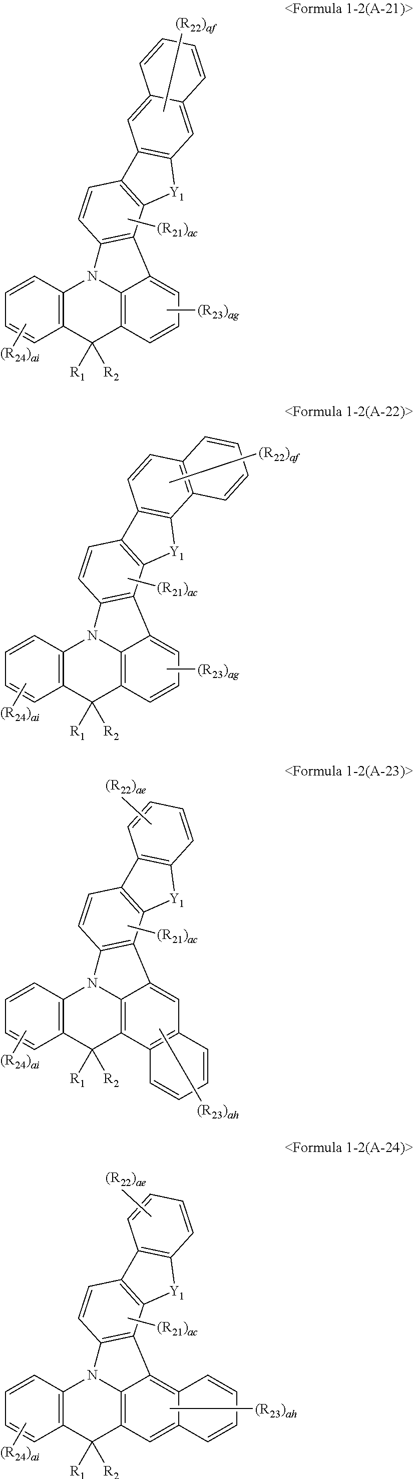

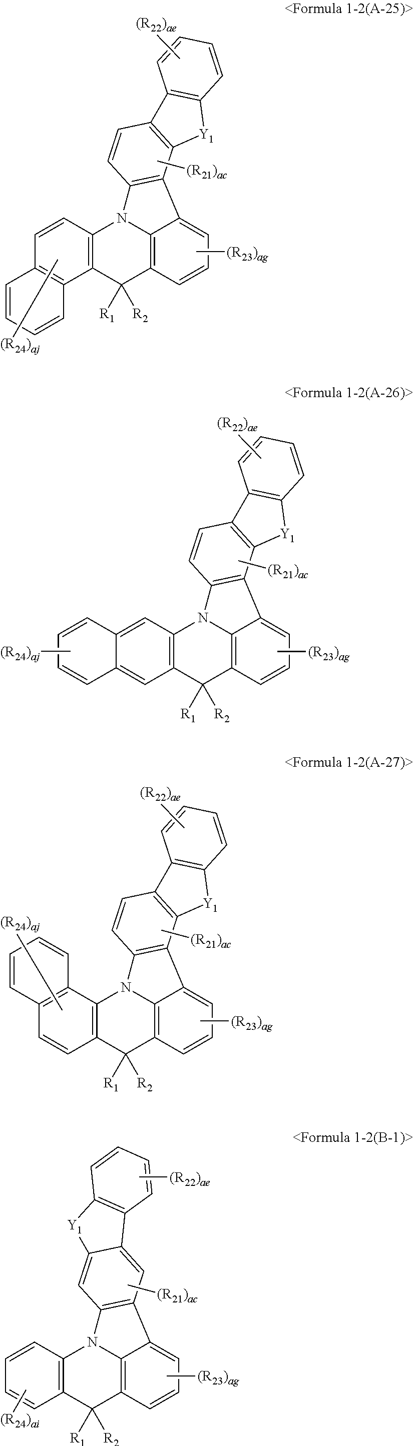

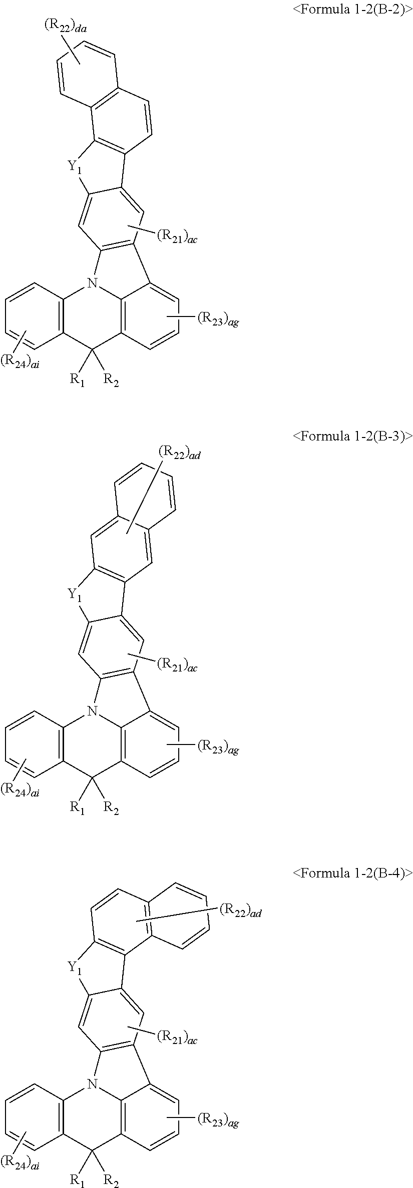

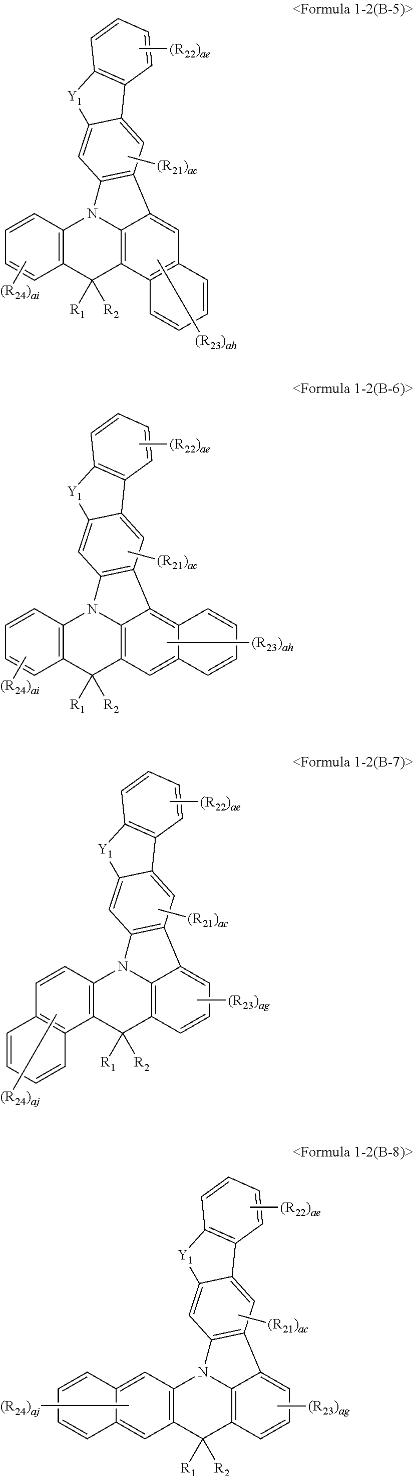

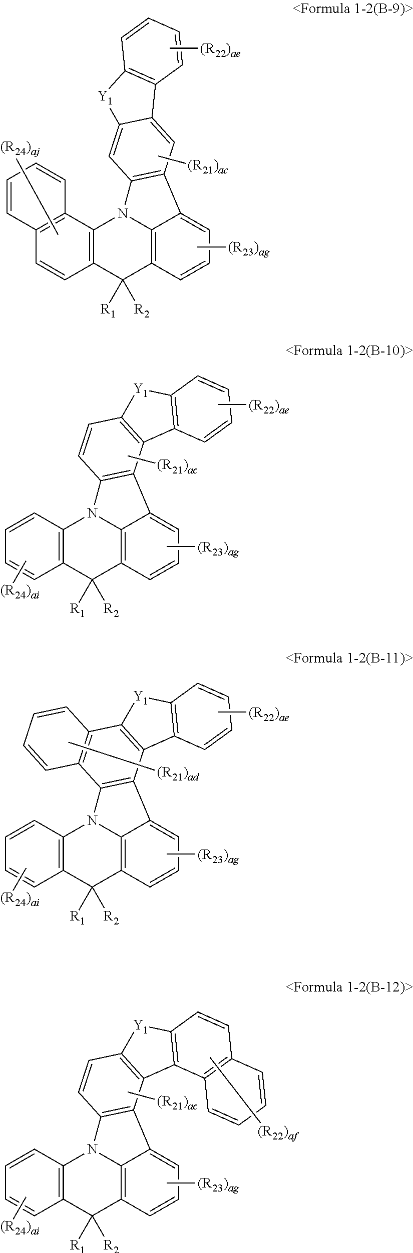

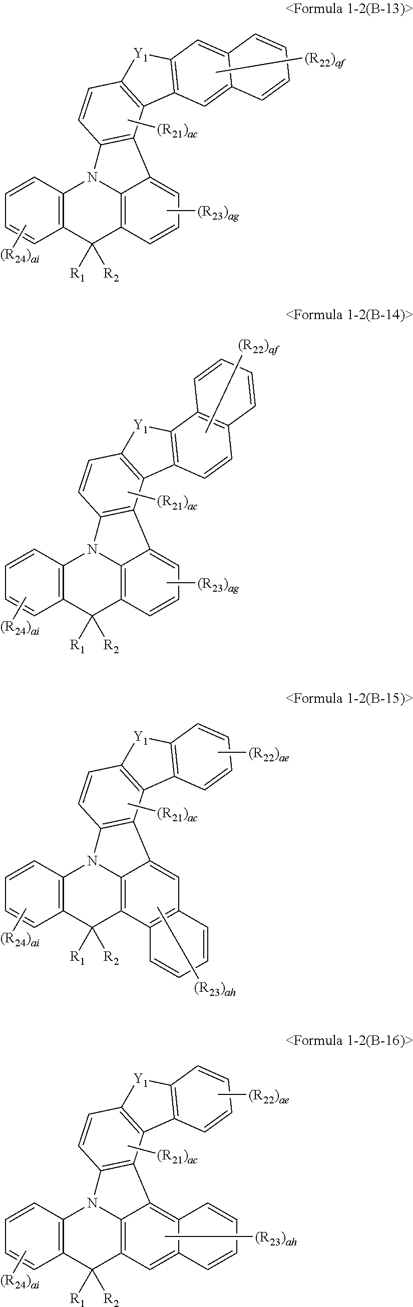

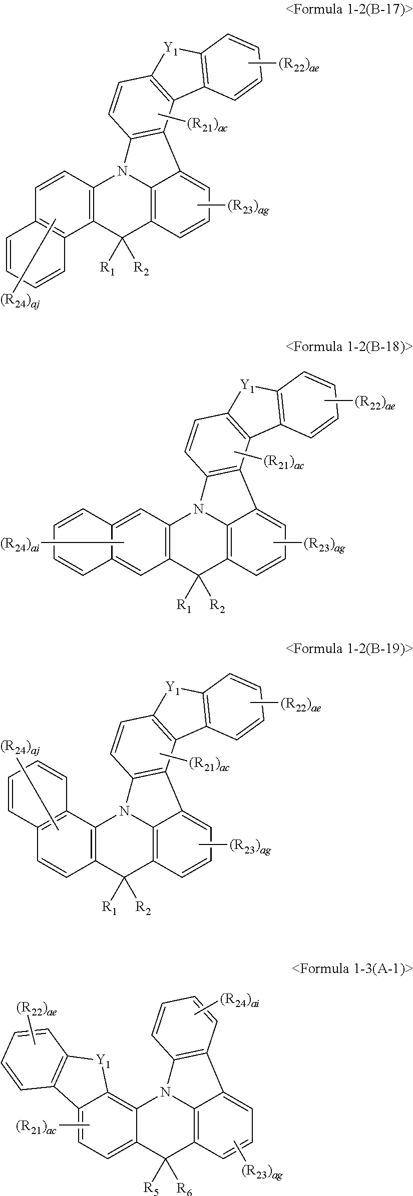

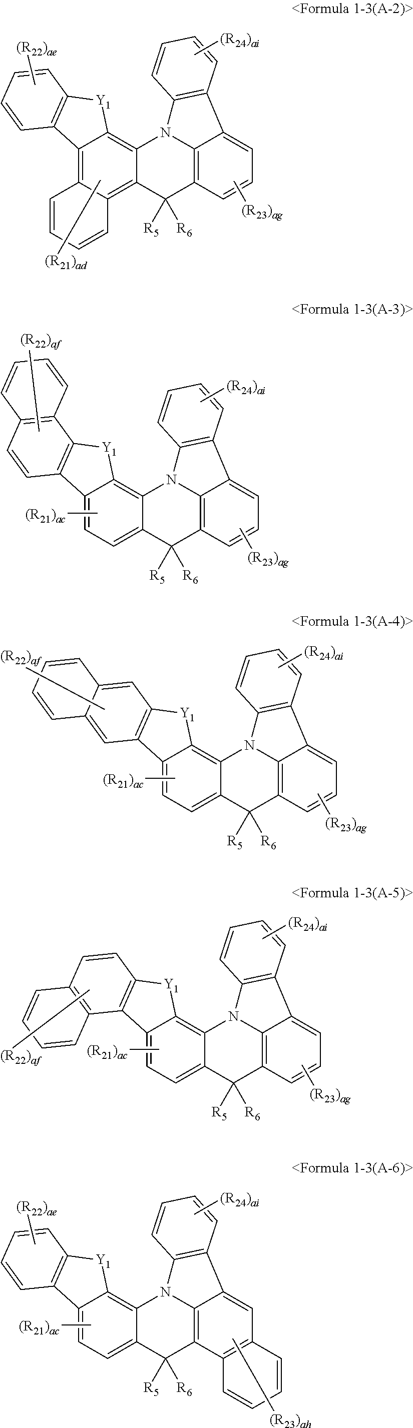

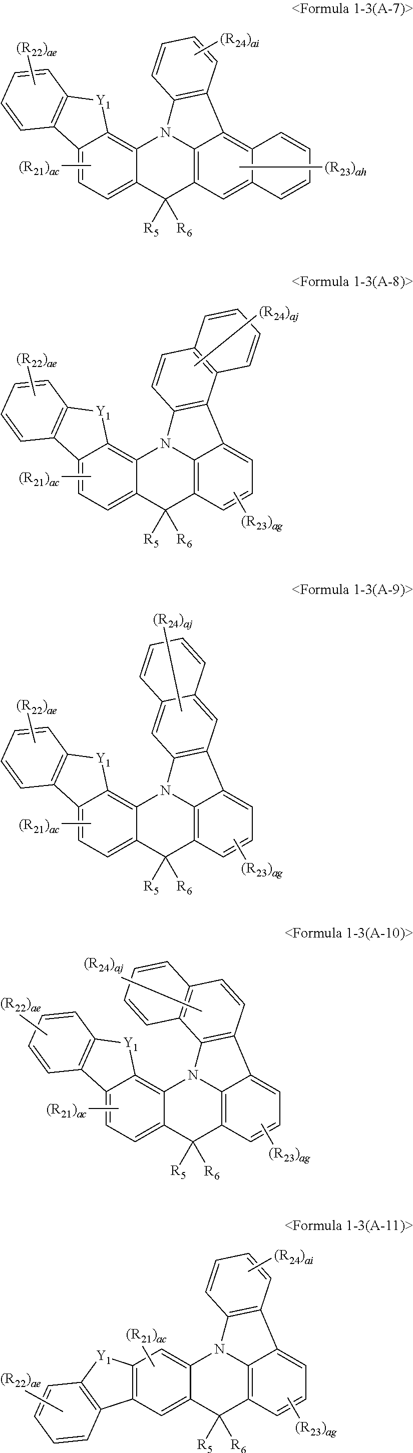

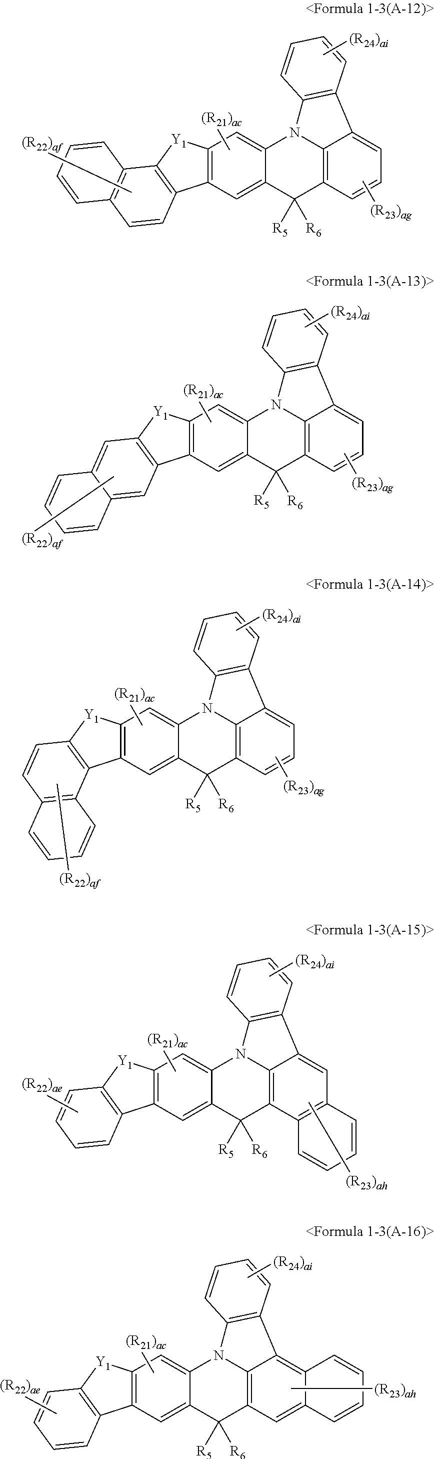

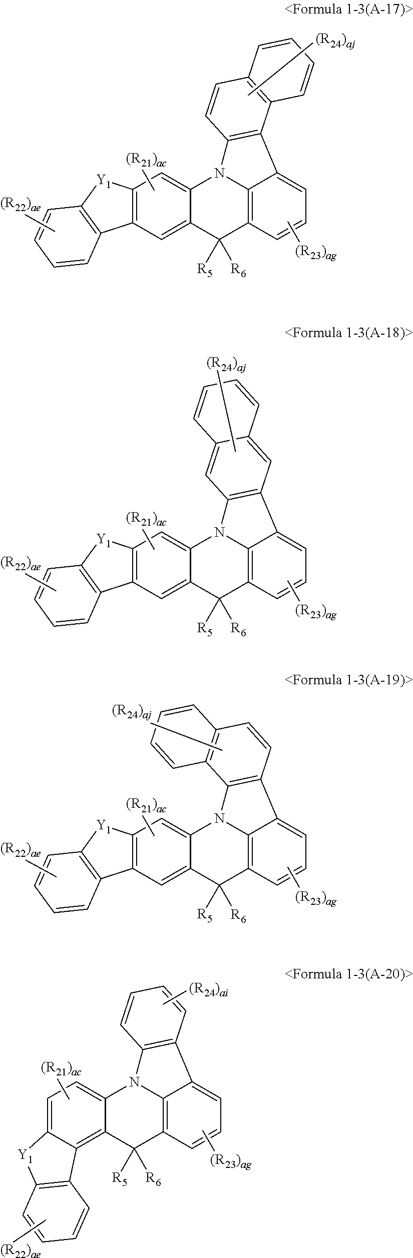

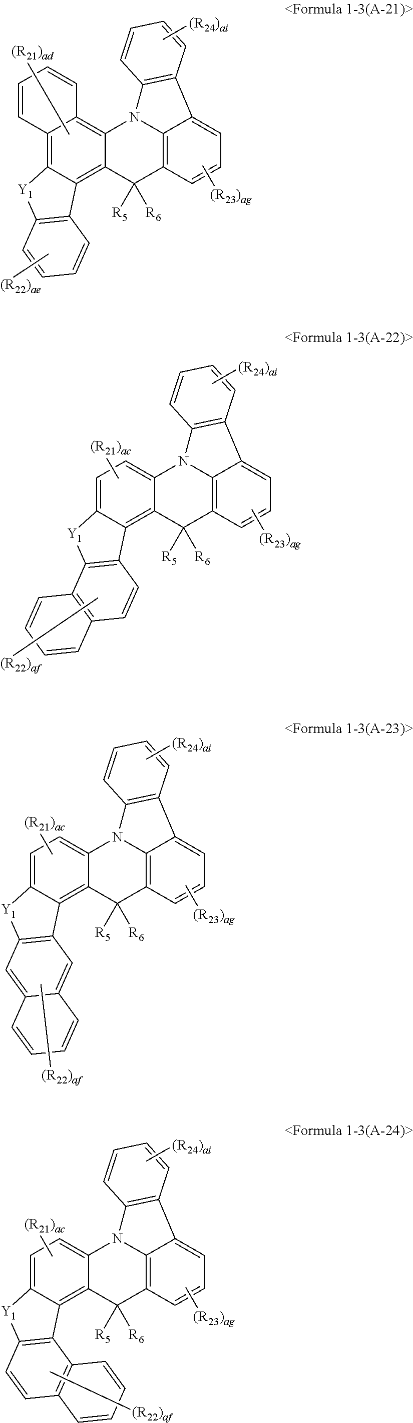

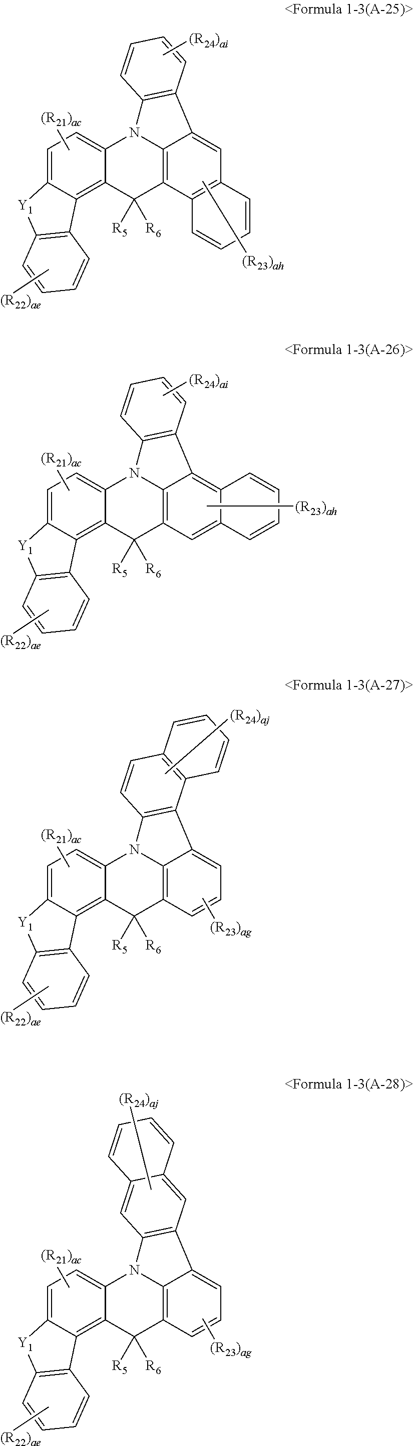

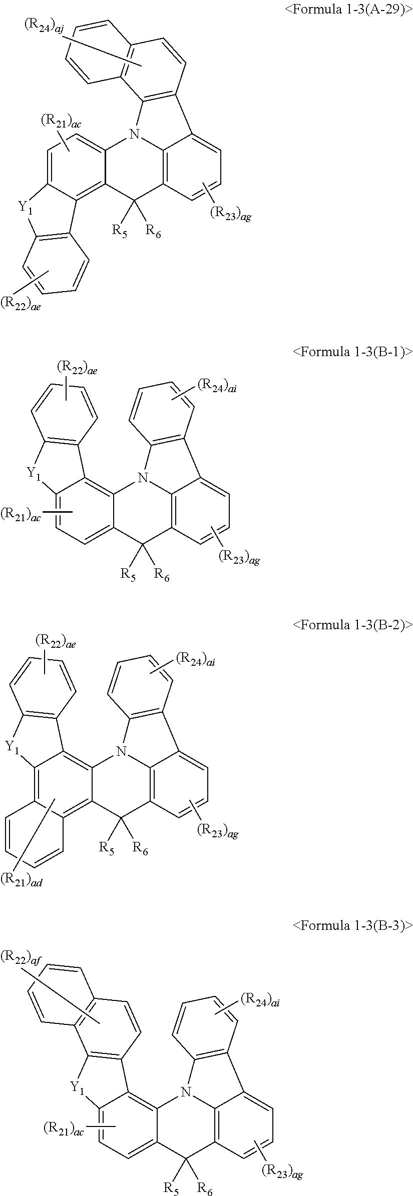

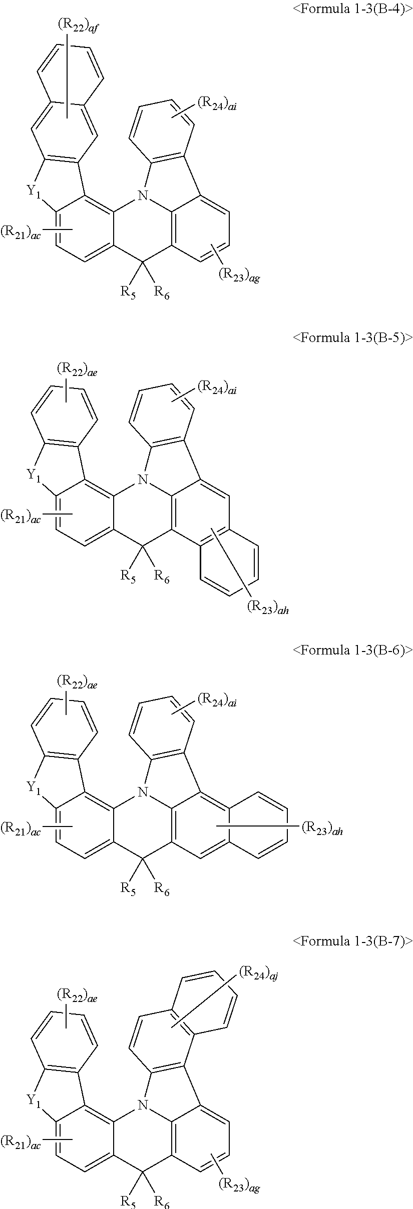

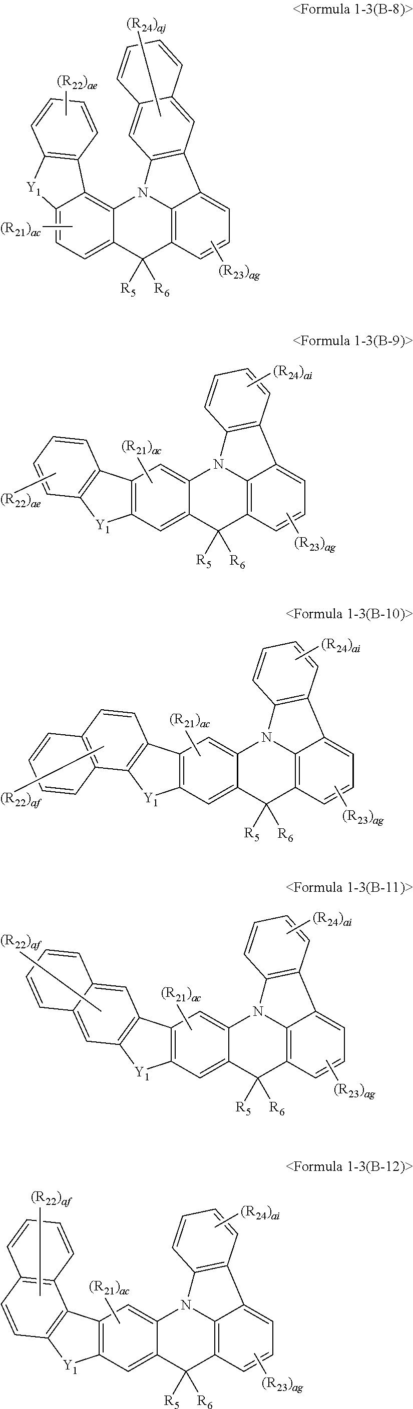

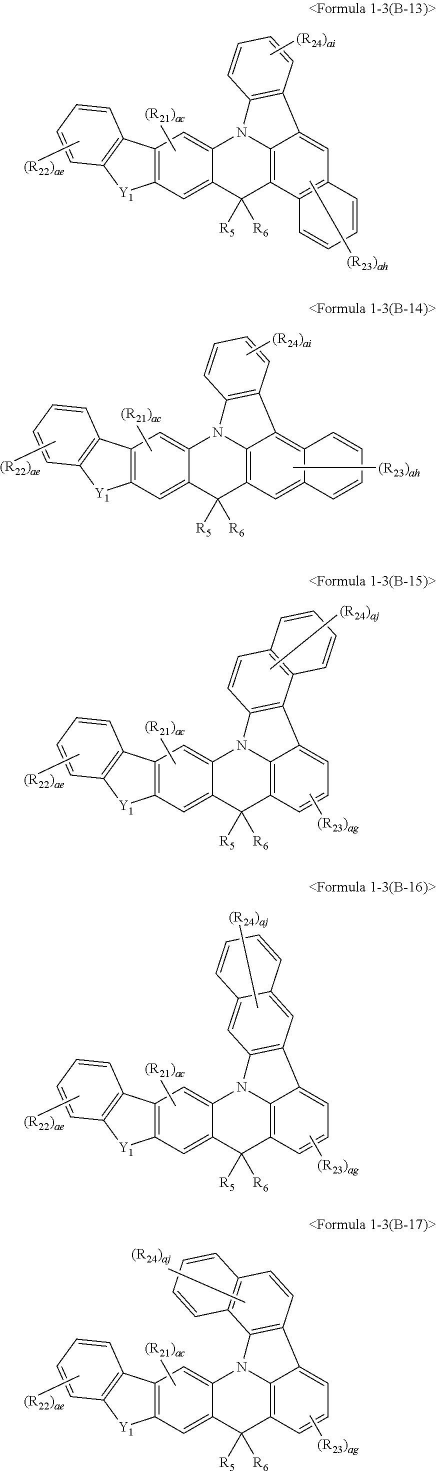

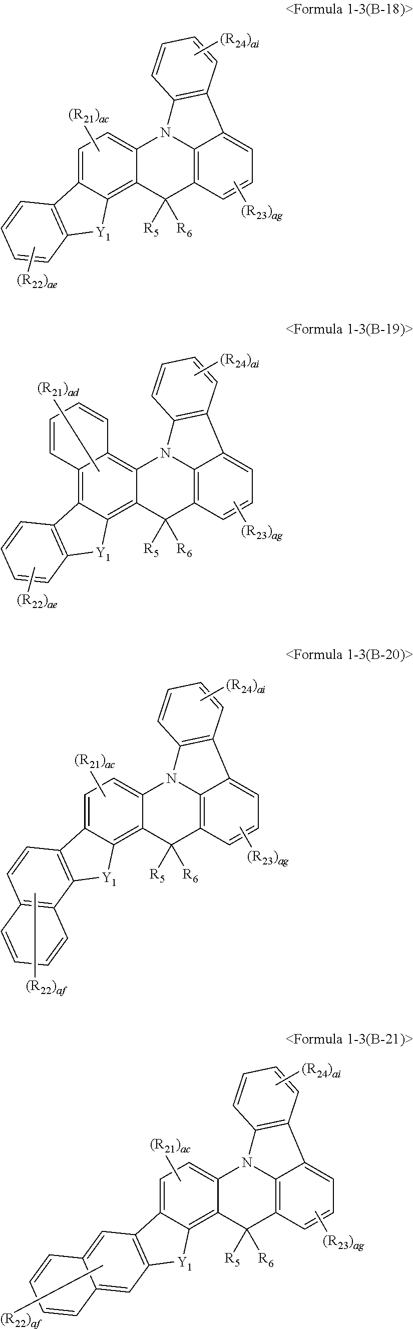

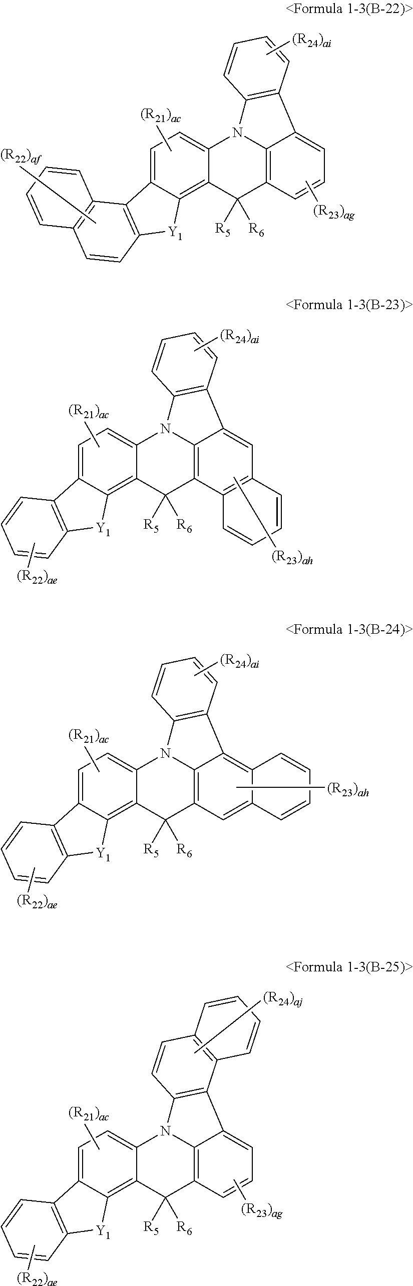

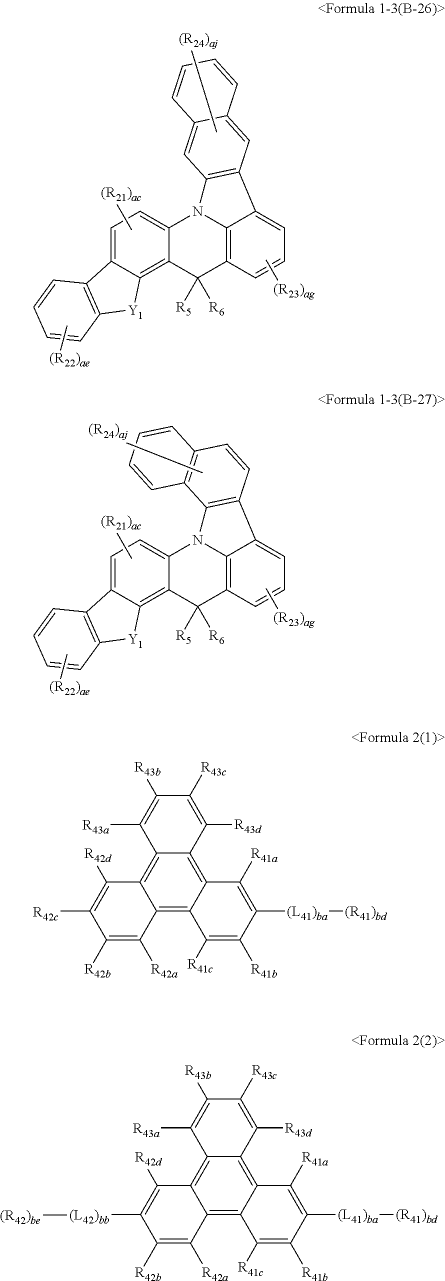

In Formulae 1-1(A-1) to 1-1(A-20), Formulae 1-1(B-1) to 1-1(B-20), Formulae 1-2(A-1) to 1-2(A-27), Formulae 1-2(B-1) to 1-2(B-19), Formulae 1-3(A-1) to 1-3(A-29), and Formulae 1-3(B-1) to 1-3(B-27),

Y₁, R₁ to R₆, and R₂₁ to R₂₄ may be the same as those defined above;

ac may be selected from 0, 1, and 2, and two R₂₁s may be the same or differ when ac is 2;

ad, ae, ag, and ai may be each independently selected from 0, 1, 2, 3, and 4, at least two R₂₁s may be the same or differ when ad is 2 or greater, at least two R₂₂s may be the same or differ when ae is 2 or greater, at least two R₂₃s may be the same or differ when ag is 2 or greater, and at least two R₂₄s may be the same or differ when ai is 2 or greater); and

af, ah, and aj may be each independently selected from 0, 1, 2, 3, 4, 5, and 6, at least two R₂₂s may be the same or differ when af is 2 or greater, at least two R₂₃s may be the same or differ when ah is 2 or greater, and at least two R₂₄s may be the same or differ when aj is 2 or greater, and

in Formulae 2(1) and 2(2),

L₄₁, L₄₂, R₄₁, R₄₂, ba, bb, bd, and be may be the same as those defined above;

R₄₁ₐ to R_{41c} may be the same as defined above in conjunction with R₄₁;

R₄₂ₐ to R_{42d} may be the same as defined above in conjunction with R₄₂; and

R₄₃ₐ to R_{43d} may be the same as defined above in conjunction with R₄₃.

For example, the first compound may be one of Compounds 1 to 37, and the second compound may be one of Compounds 101 to 107. However, embodiments of the present disclosure are not limited thereto.

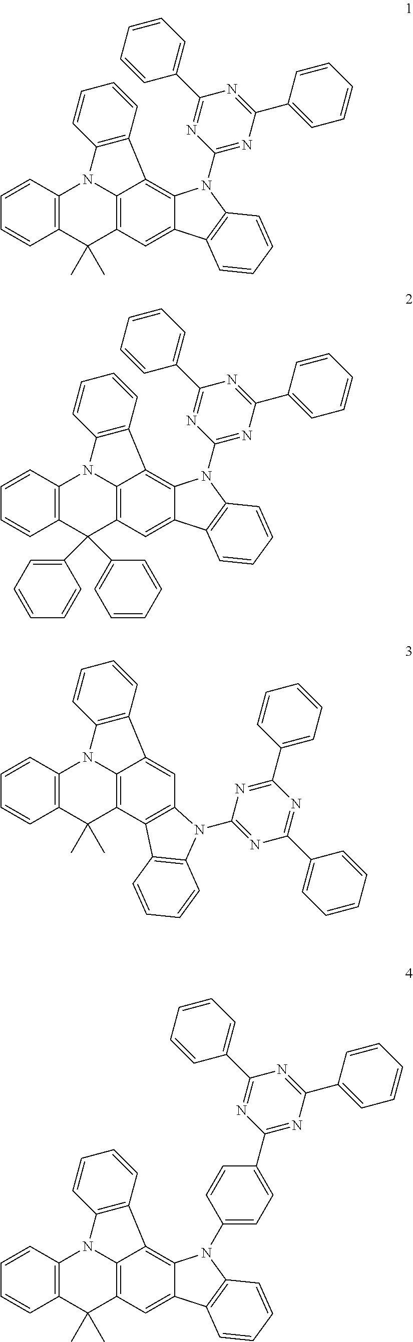

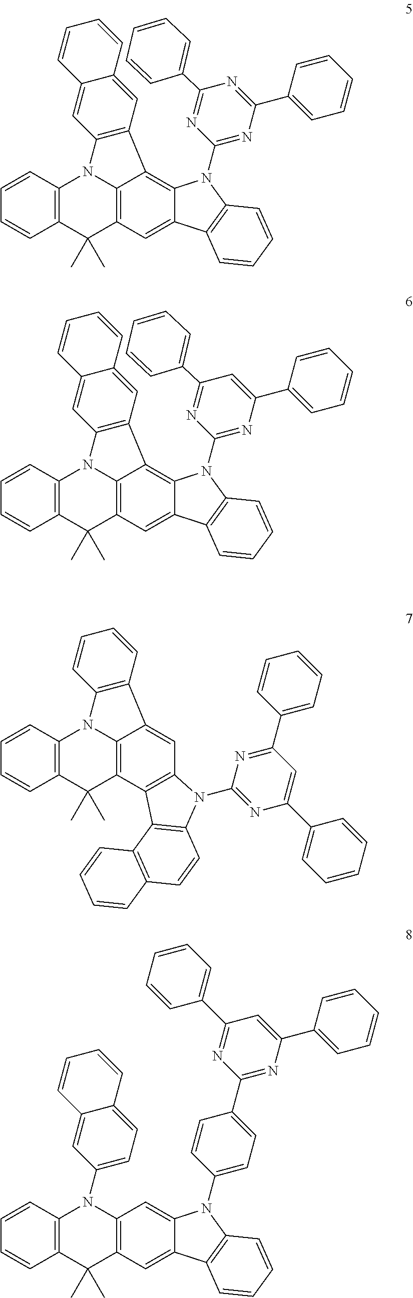

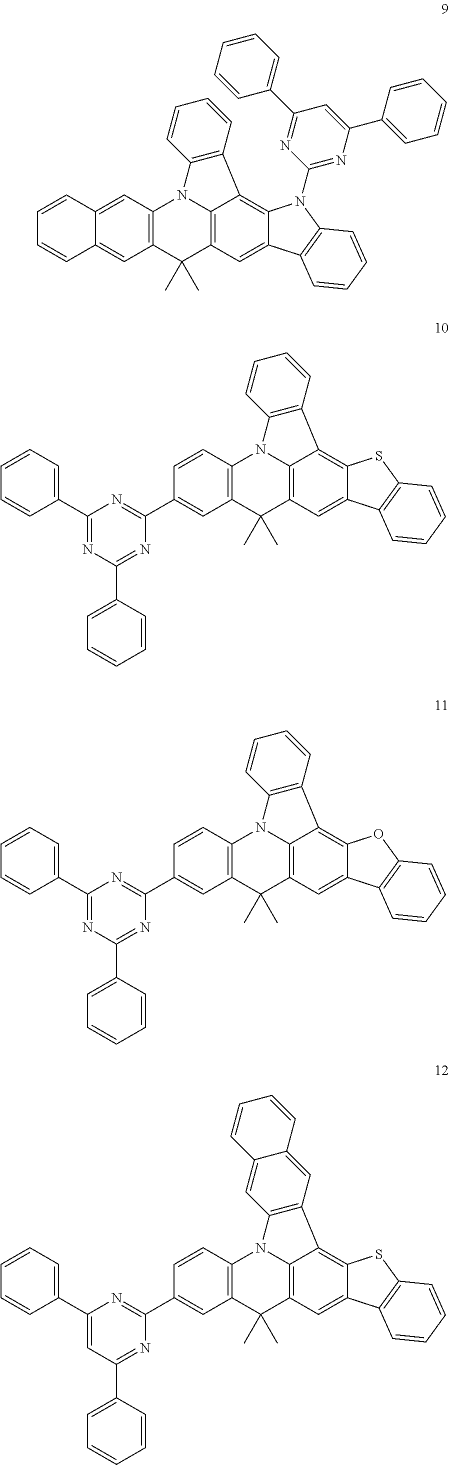 [SMILES: CC1(C)c2cc3ccccc3cc2-n2c3ccccc3c3c2c1cc1c2ccccc2n(-c2nc(-c4ccccc4)cc(-c4ccccc4)n2)c13 ; CC1(C)c2cc(-c3nc(-c4ccccc4)nc(-c4ccccc4)n3)ccc2-n2c3ccccc3c3c4sc5ccccc5c4cc1c32 ; CC1(C)c2cc(-c3nc(-c4ccccc4)nc(-c4ccccc4)n3)ccc2-n2c3ccccc3c3c4oc5ccccc5c4cc1c32 ; CC1(C)c2cc(-c3nc(-c4ccccc4)cc(-c4ccccc4)n3)ccc2-n2c3cc4ccccc4cc3c3c4sc5ccccc5c4cc1c32]

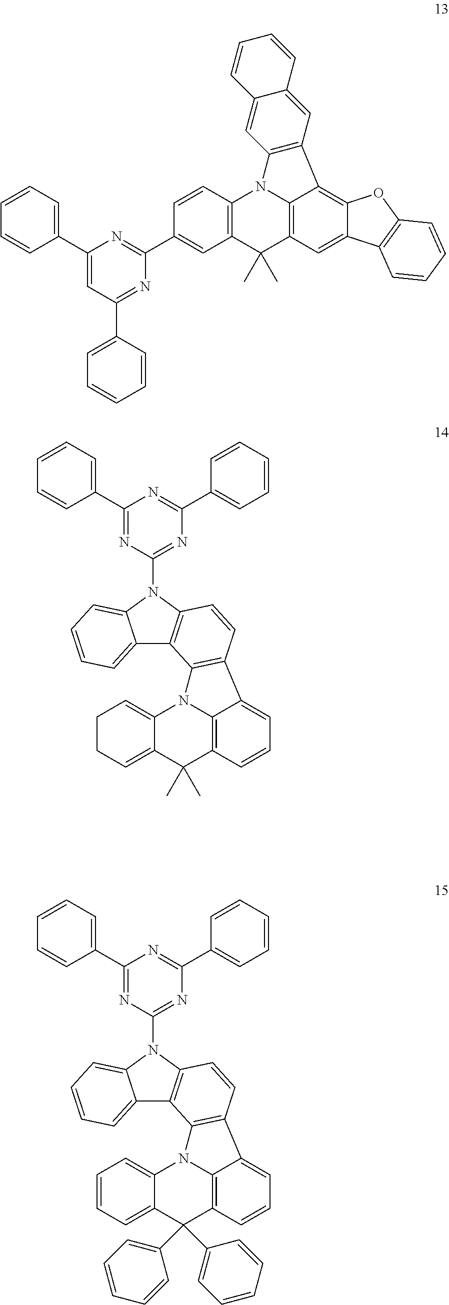 [SMILES: CC1(C)c2cc(-c3nc(-c4ccccc4)cc(-c4ccccc4)n3)ccc2-n2c3cc4ccccc4cc3c3c4oc5ccccc5c4cc1c32 ; CC1(C)C2=CCCC=C2n2c3c1cccc3c1ccc3c(c4ccccc4n3-c3nc(-c4ccccc4)nc(-c4ccccc4)n3)c12 ; c1ccc(-c2nc(-c3ccccc3)nc(-n3c4ccccc4c4c3ccc3c5cccc6c5n(c34)-c3ccccc3C6(c3ccccc3)c3ccccc3)n2)cc1]

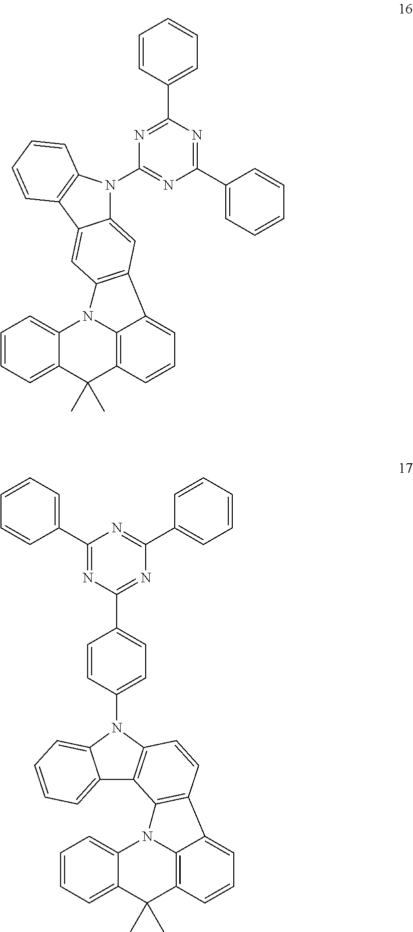 [SMILES: CC1(C)c2ccccc2-n2c3cc4c5ccccc5n(-c5nc(-c6ccccc6)nc(-c6ccccc6)n5)c4cc3c3cccc1c32 ; CC1(C)c2ccccc2-n2c3c1cccc3c1ccc3c(c4ccccc4n3-c3ccc(-c4nc(-c5ccccc5)nc(-c5ccccc5)n4)cc3)c12]

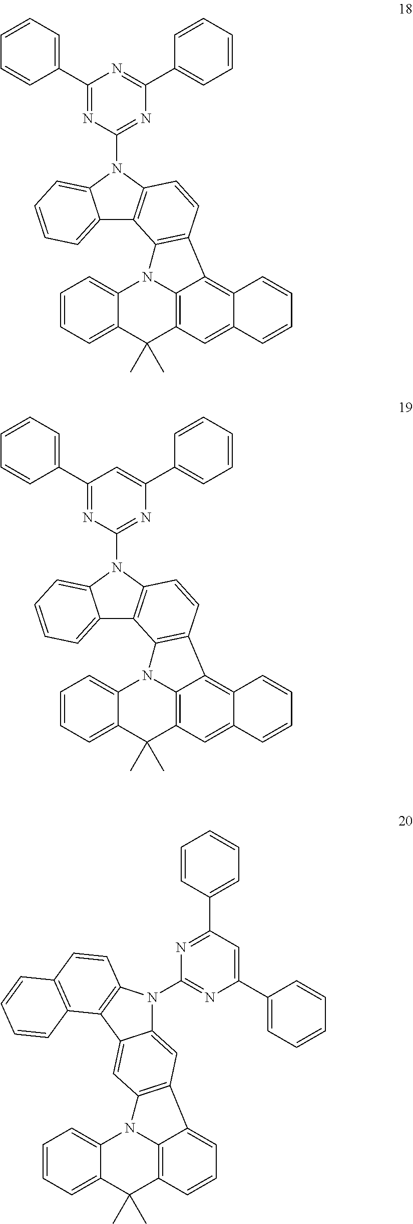 [SMILES: CC1(C)c2ccccc2-n2c3c1cc1ccccc1c3c1ccc3c(c4ccccc4n3-c3nc(-c4ccccc4)nc(-c4ccccc4)n3)c12 ; CC1(C)c2ccccc2-n2c3c1cc1ccccc1c3c1ccc3c(c4ccccc4n3-c3nc(-c4ccccc4)cc(-c4ccccc4)n3)c12 ; CC1(C)c2ccccc2-n2c3cc4c5c6ccccc6ccc5n(-c5nc(-c6ccccc6)cc(-c6ccccc6)n5)c4cc3c3cccc1c32]

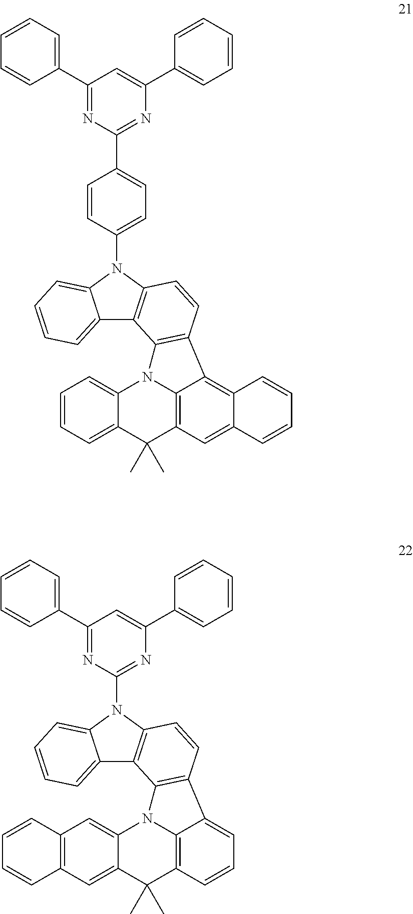 [SMILES: CC1(C)c2ccccc2-n2c3c1cc1ccccc1c3c1ccc3c(c4ccccc4n3-c3ccc(-c4nc(-c5ccccc5)cc(-c5ccccc5)n4)cc3)c12 ; CC1(C)c2cc3ccccc3cc2-n2c3c1cccc3c1ccc3c(c4ccccc4n3-c3nc(-c4ccccc4)cc(-c4ccccc4)n3)c12]

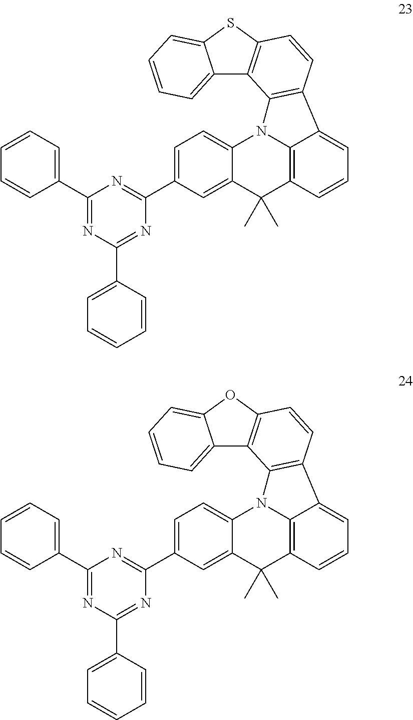 [SMILES: CC1(C)c2cc(-c3nc(-c4ccccc4)nc(-c4ccccc4)n3)ccc2-n2c3c1cccc3c1ccc3sc4ccccc4c3c12 ; CC1(C)c2cc(-c3nc(-c4ccccc4)nc(-c4ccccc4)n3)ccc2-n2c3c1cccc3c1ccc3oc4ccccc4c3c12]

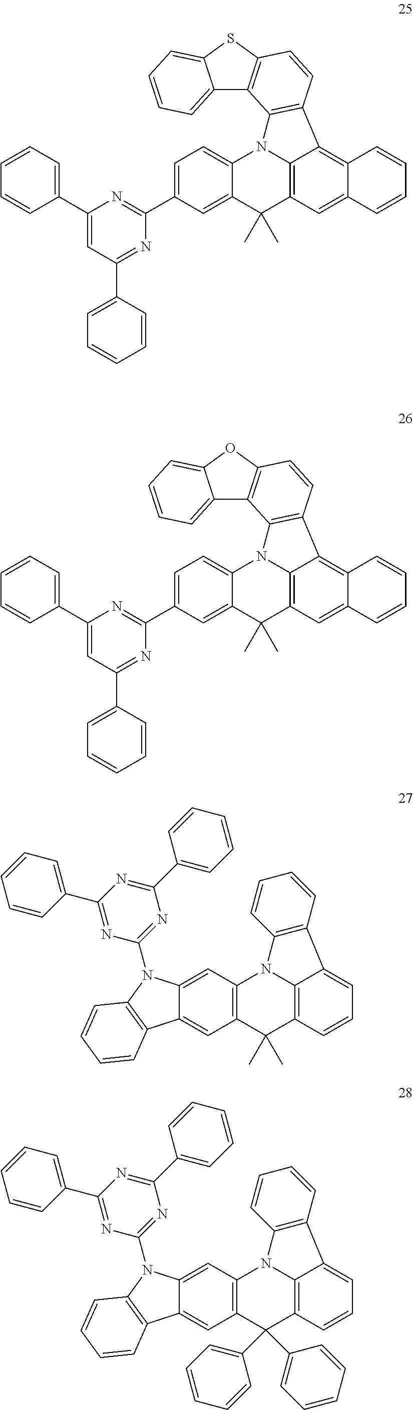 [SMILES: CC1(C)c2cc(-c3nc(-c4ccccc4)cc(-c4ccccc4)n3)ccc2-n2c3c1cc1ccccc1c3c1ccc3sc4ccccc4c3c12 ; CC1(C)c2cc(-c3nc(-c4ccccc4)cc(-c4ccccc4)n3)ccc2-n2c3c1cc1ccccc1c3c1ccc3oc4ccccc4c3c12 ; CC1(C)c2cc3c4ccccc4n(-c4nc(-c5ccccc5)nc(-c5ccccc5)n4)c3cc2-n2c3ccccc3c3cccc1c32 ; c1ccc(-c2nc(-c3ccccc3)nc(-n3c4ccccc4c4cc5c(cc43)-n3c4ccccc4c4cccc(c43)C5(c3ccccc3)c3ccccc3)n2)cc1]

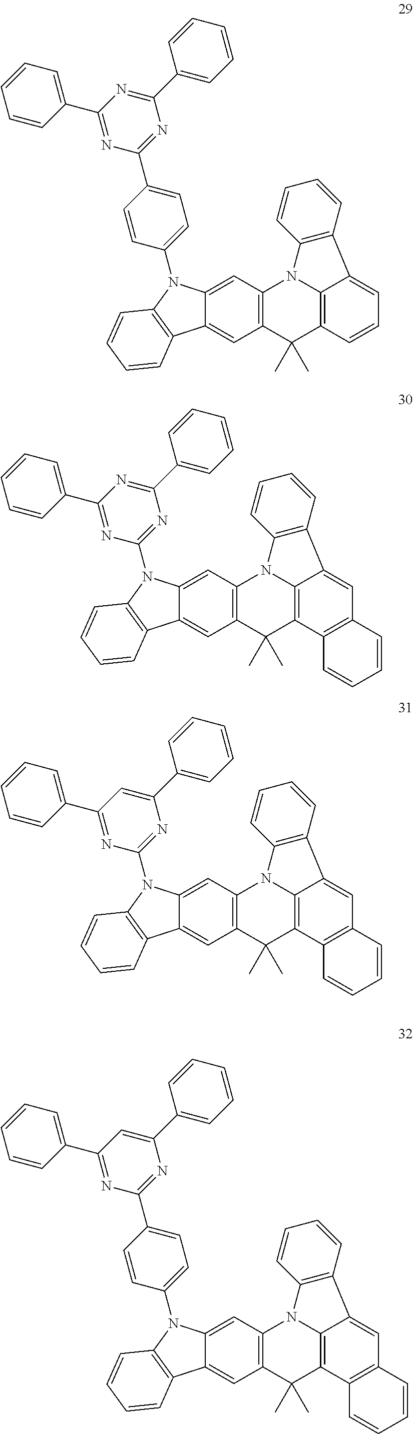 [SMILES: CC1(C)c2cc3c4ccccc4n(-c4ccc(-c5nc(-c6ccccc6)nc(-c6ccccc6)n5)cc4)c3cc2-n2c3ccccc3c3cccc1c32 ; CC1(C)c2cc3c4ccccc4n(-c4nc(-c5ccccc5)nc(-c5ccccc5)n4)c3cc2-n2c3ccccc3c3cc4ccccc4c1c32 ; CC1(C)c2cc3c4ccccc4n(-c4nc(-c5ccccc5)cc(-c5ccccc5)n4)c3cc2-n2c3ccccc3c3cc4ccccc4c1c32 ; CC1(C)c2cc3c4ccccc4n(-c4ccc(-c5nc(-c6ccccc6)cc(-c6ccccc6)n5)cc4)c3cc2-n2c3ccccc3c3cc4ccccc4c1c32]

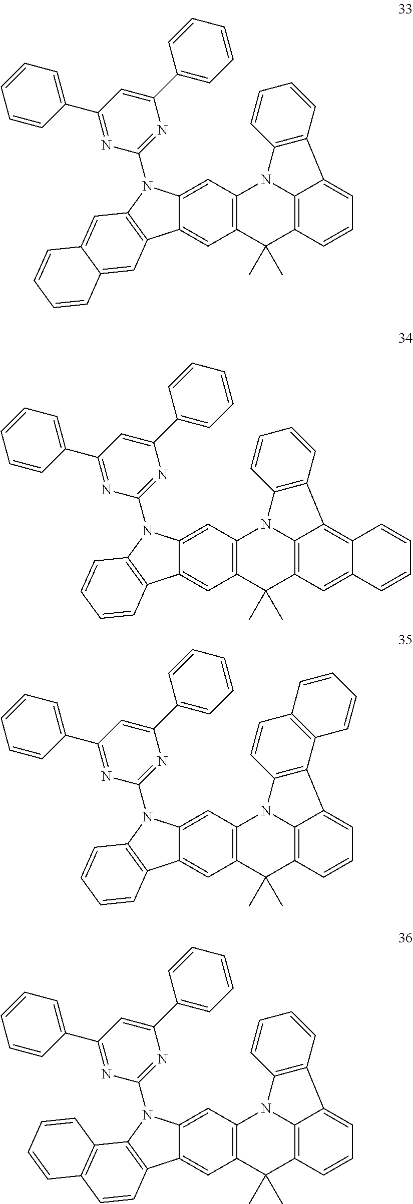

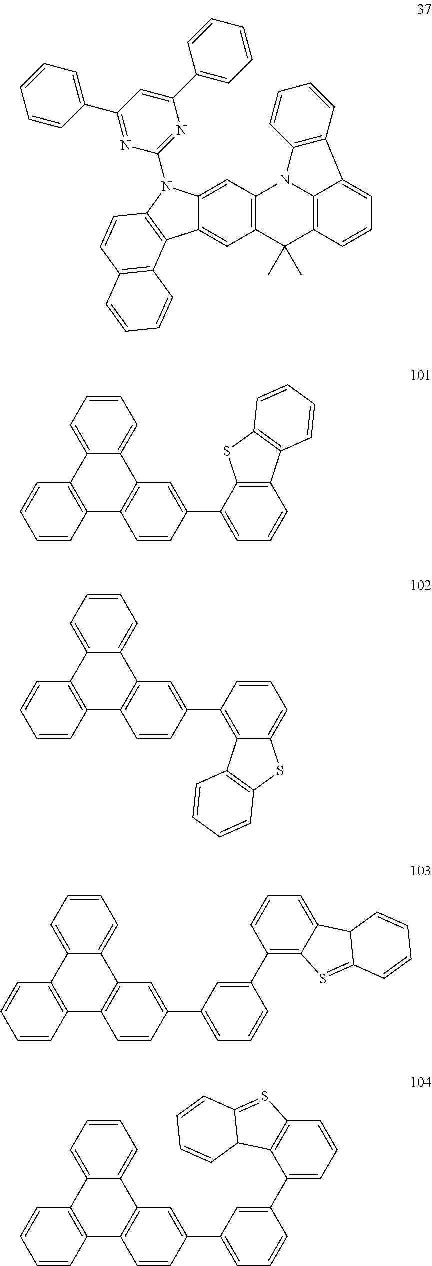

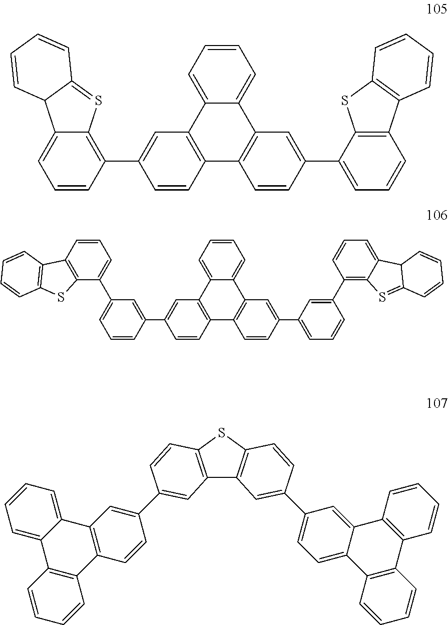

The first compound may include a substituent with high electron mobility and may have good electron transport ability. The second compound may include a substitutent with high hole mobility may have good hole transport ability. When using two separate compounds having electron and hole transport abilities, respectively, e.g., the first and second compounds, electron-hole balance may be improved, compared to when using one compound having both electron and hole transport abilities in molecules. Thus, an electric device, for example, an organic light-emitting device, using the first compound and the second compound may have improved in lifetime and efficiency.

The first compound represented by one of Formulae 1-1 to 1-3 and the second compound represented by Formula 2 may have good thermal stability. Therefore, thermal deformation may not occur when a layer including both the first compound and the second compound is formed. Accordingly, an electric device, e.g., an organic light-emitting device, including the first compound and the second compound may have improved lifetime.

The first compound and the second compound may both be in the emission layer of the organic layer 150. In an implementation, the first compound may be in the emission layer of the organic layer 150, and the second compound may be in the electron transport region between the emission layer and the second electrode. In an implementation, the first compound and the second compound may both be in the emission layer of the organic layer 150, and the second compound may be in the electron transport region between the emission layer and the second electrode. The second compound in the emission layer and the second compound in the electron transport layer may be the same or different.

When the emission layer includes both the first compound and the second compound, a region where holes and electrons combine may be shifted toward an interface between the emission layer and the electron transport region. This may improve the lifetime of the organic light-emitting device.

For example, the emission layer of the organic layer 150 may include a host and a dopant.

The amount of the dopant in the emission layer may be in a range of about 0.01 part to about 15 parts by weight, based on 100 parts by weight of the host.

The emission layer may have a thickness of about 100 Å to about 1,000 Å, e.g., about 200 Å to about 600 Å. When the thickness of the emission layer is within these ranges, mproved emission characteristics may be obtained without a substantial increase in driving voltage.

In an implementation, the host in the emission layer may include the first compound and the second compound, and the dopant in the emission layer may include at least one of a phosphorescent dopant and a fluorescent dopant.

For example, the phosphorescent dopant may include an organometallic compound including at least one of iridium (Ir), platinum (Pt), osmium (Os), titanium (Ti), zirconium (Zr), hafnium (Hf), europium (Eu), terbium (Tb), thulium (Tm), rhodium (Rh), or copper (Cu).

For example, the phosphorescent dopant may include an organometallic complex represented by Formula 401:

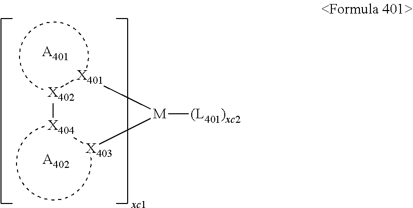

In Formula 401,

M may be selected from iridium (Ir), platinum (Pt), osmium (Os), titanium (Ti), zirconium (Zr), hafnium (Hf), europium (Eu), terbium (Tb), and thulium (TM);

X₄₀₁ to X₄₀₄ may be each independently a nitrogen or a carbon;

A₄₀₁ ring and A₄₀₂ ring may be each independently selected from a substituted or unsubstituted benzene, a substituted or unsubstituted naphthalene, a substituted or unsubstituted fluorene, a substituted or unsubstituted spiro-fluorene, a substituted or unsubstituted indene, a substituted or unsubstituted pyrrole, a substituted or unsubstituted thiophene, a substituted or unsubstituted furan, a substituted or unsubstituted imidazole, a substituted or unsubstituted pyrazole, a substituted or unsubstituted thiazole, a substituted or unsubstituted isothiazole, a substituted or unsubstituted oxazole, a substituted or unsubstituted isoxazole, a substituted or unsubstituted pyridine, a substituted or unsubstituted pyrazine, a substituted or unsubstituted pyrimidine, a substituted or unsubstituted pyridazine, a substituted or unsubstituted quinoline, a substituted or unsubstituted isoquinoline, a substituted or unsubstituted benzoquinoline, a substituted or unsubstituted quinoxaline, a substituted or unsubstituted quinazoline, a substituted or unsubstituted carbazole, a substituted or unsubstituted benzoimidazole, a substituted or unsubstituted benzofuran, a substituted or unsubstituted benzothiophene, a substituted or unsubstituted isobenzothiophene, a substituted or unsubstituted benzoxazole, a substituted or unsubstituted isobenzoxazole, a substituted or unsubstituted triazole, a substituted or unsubstituted an oxadiazole, a substituted or unsubstituted triazine, a substituted or unsubstituted dibenzofuran, and a substituted or unsubstituted dibenzothiophene,

wherein at least one substituent of the substituted benzene, the substituted naphthalene, the substituted fluorene, the substituted spiro-fluorene, the substituted indene, the substituted pyrrole, the substituted thiophene, the substituted furan, the substituted imidazole, the substituted pyrazole, the substituted thiazole, the substituted isothiazole, the substituted oxazole, the substituted isoxazole, the substituted pyridine, the substituted pyrazine, the substituted pyrimidine, the substituted pyridazine, the substituted quinoline, the substituted isoquinoline, the substituted benzoquinoline, the substituted quinoxaline, the substituted quinazoline, the substituted carbazole, the substituted benzoimidazole, the substituted benzofuran, the substituted benzothiophene, the substituted isobenzothiophene, the substituted benzoxazole, the substituted isobenzoxazole, the substituted triazole, the substituted oxadiazole, the substituted triazine, the substituted dibenzofuran, and the substituted dibenzothiophene may be selected from

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group,

a C₁-C₆₀ alkyl group, a C₂-C₆₀ alkenyl group, a C₂-C₆₀ alkynyl group, and a C₁-C₆₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₄₀₁)(Q₄₀₂), —Si(Q₄₀₃)(Q₄₀₄)(Q₄₀₅), and —B(Q₄₀₆)(Q₄₀₇),

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group,

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₄₁₁)(Q₄₁₂), —Si(Q₄₁₃)(Q₄₁₄)(Q₄₁₅), and —B(Q₄₁₆)(Q₄₁₇), and

—N(Q₄₂₁)(Q₄₂₂), —Si(Q₄₂₃)(Q₄₂₄)(Q₄₂₅), and —B(Q₄₂₆)(Q₄₂₇);

L₄₀₁ may be an organic ligand;

xc1 may be 1, 2, or 3; and

xc2 may be 0, 1, 2, or 3,

wherein Q₄₀₁ to Q₄₀₇, Q₄₁₁ to Q₄₁₇, and Q₄₂₁ to Q₄₂₇ may be the same as described herein in conjunction with Q₁.

For example, L₄₀₁ may be a monovalent, divalent, or trivalent organic ligand. For example, L₄₀₁ may be selected from a halogen ligand (for example, a Cl or F), a diketone ligand (for example, acetylacetonate, 1,3-diphenyl-1,3-propanedionate, 2,2,6,6-tetramethyl-3,5-heptanedionate, or hexafluoroacetonate), a carboxylic acid ligand (for example, picolinate, dimethyl-3-pyrazole carboxylate, or benzoate), a carbon monoxide ligand, an isonitrile ligand, a cyano ligand, and a phosphorous ligand (for example, phosphine or phosphaite), but is not limited thereto.

When A₄₀₁ in Formula 401 has at least two substituents, the at least two substituents of A₄₀₁ may be linked to each other to form a saturated or unsaturated ring.

When A₄₀₂ in Formula 401 has at least two substituents, the at least two substituents of A₄₀₂ may be linked to each other to form a saturated or unsaturated ring.

When xc1 in Formula 401 is 2 or greater, the plurality of ligands in Formula 401, represented by

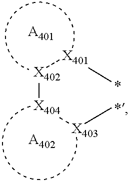

may be identical to or different from each other. When xc1 in Formula 401 is 2 or greater, A₄₀₁ and A₄₀₂ may be linked to A₄₀₁ and A₄₀₂ of another adjacent ligand directly or via a linker (for example, a C₁-C₅ alkylene group, —N(R′)— (where R′ is a C₁-C₁₀ alkyl group or a C₆-C₂₀ aryl group), or —C(═O)—).

In some embodiments, the phosphorescent dopant may include at least one of Compounds PD1 to PD74, but is not limited thereto:

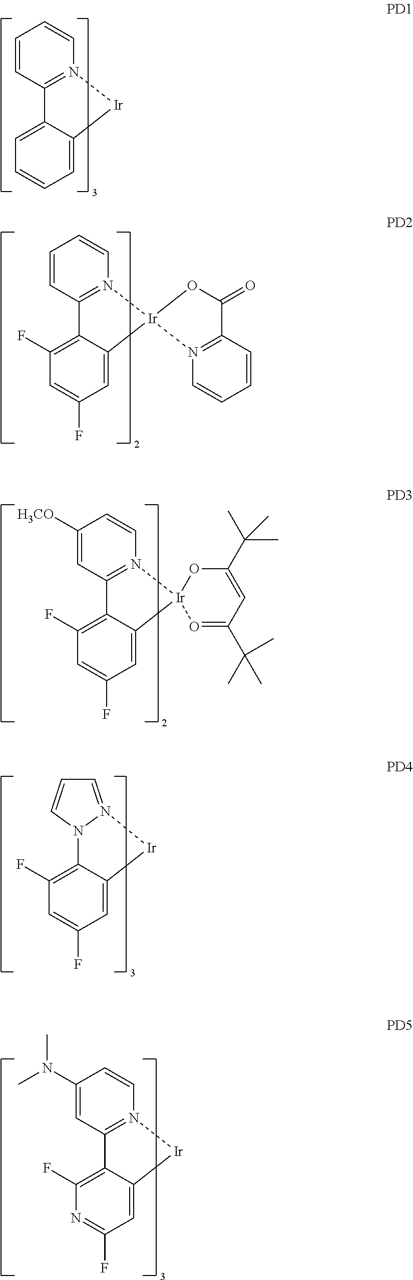

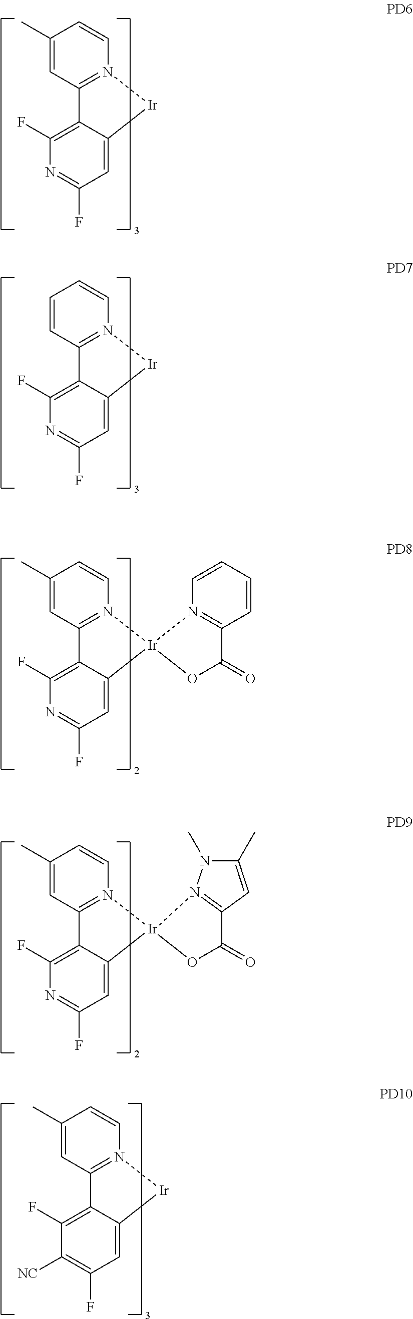

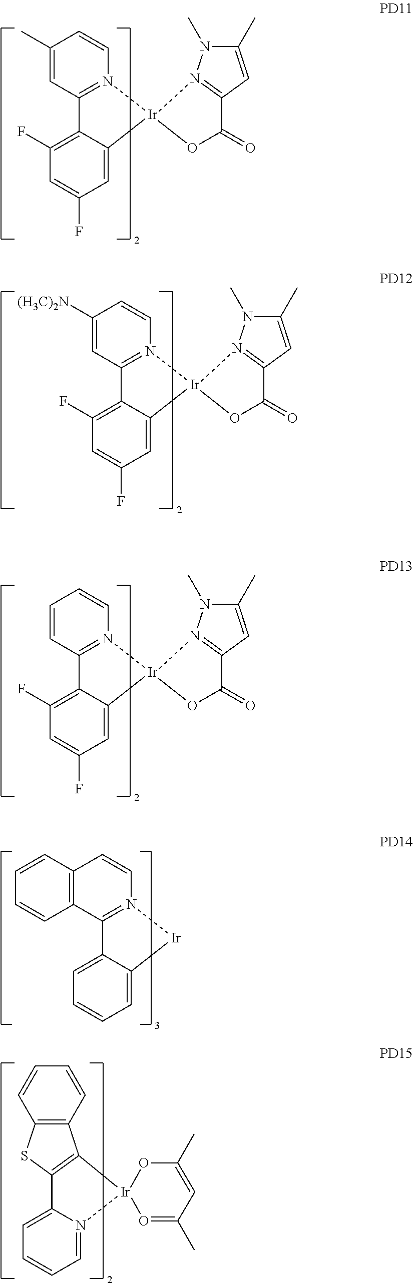

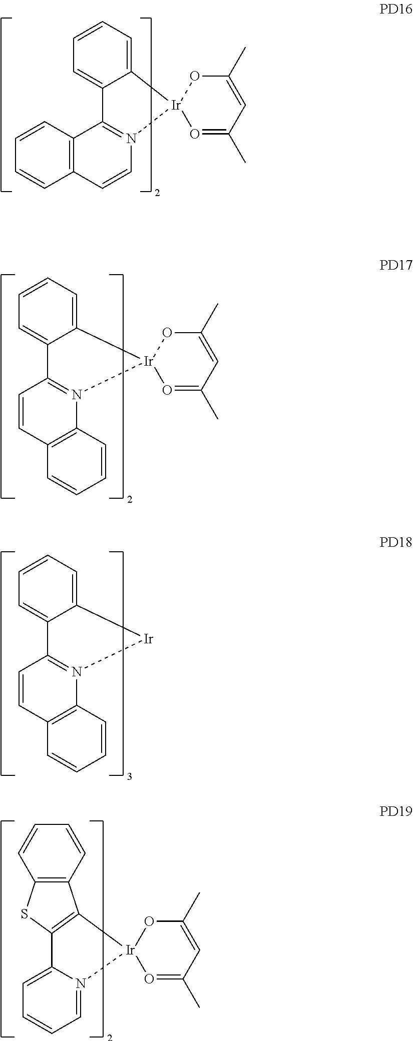

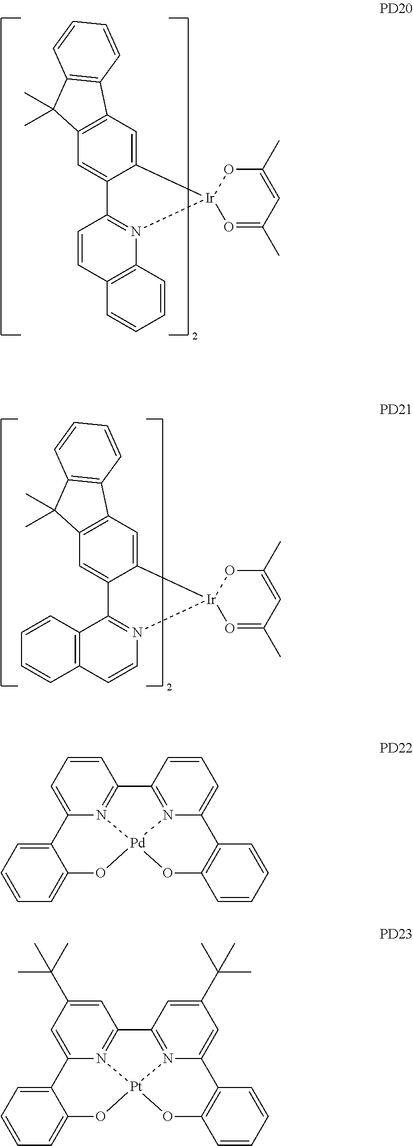

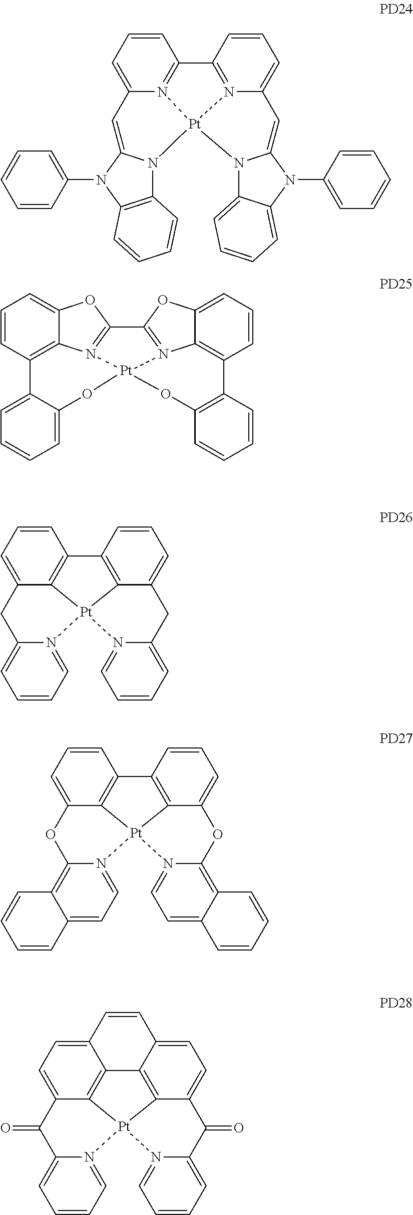

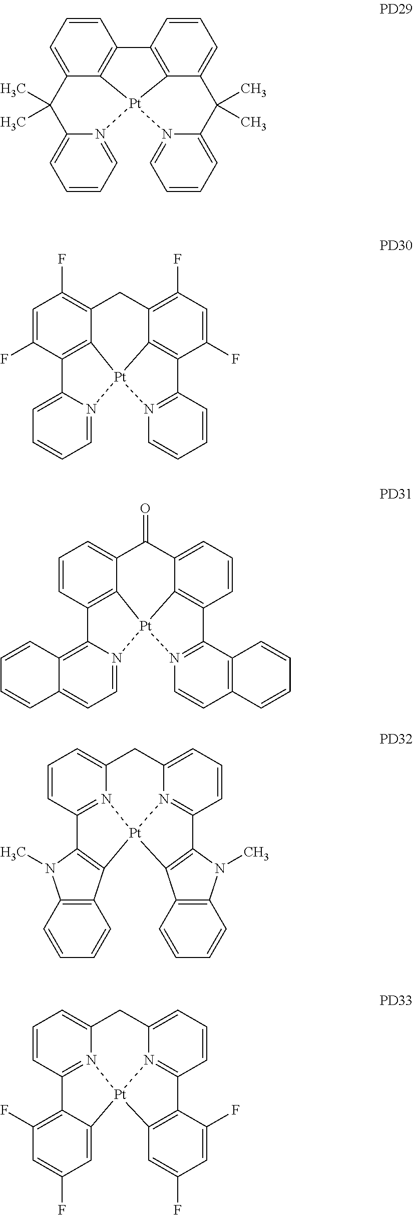

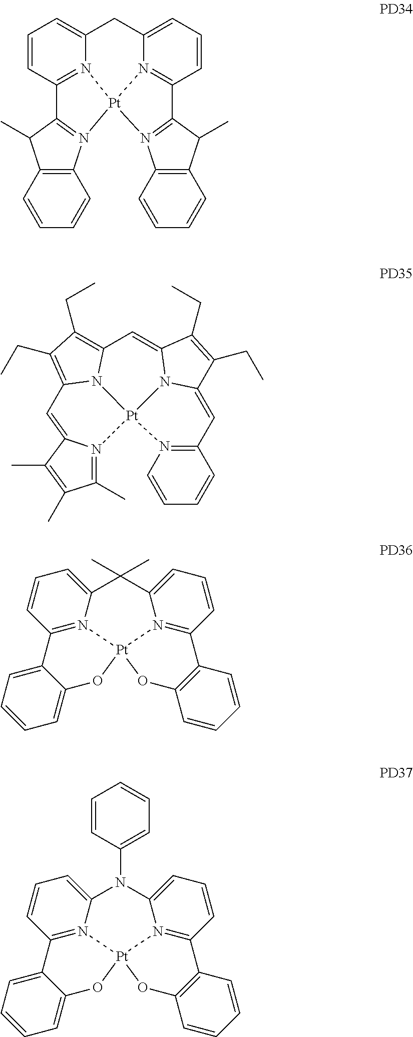

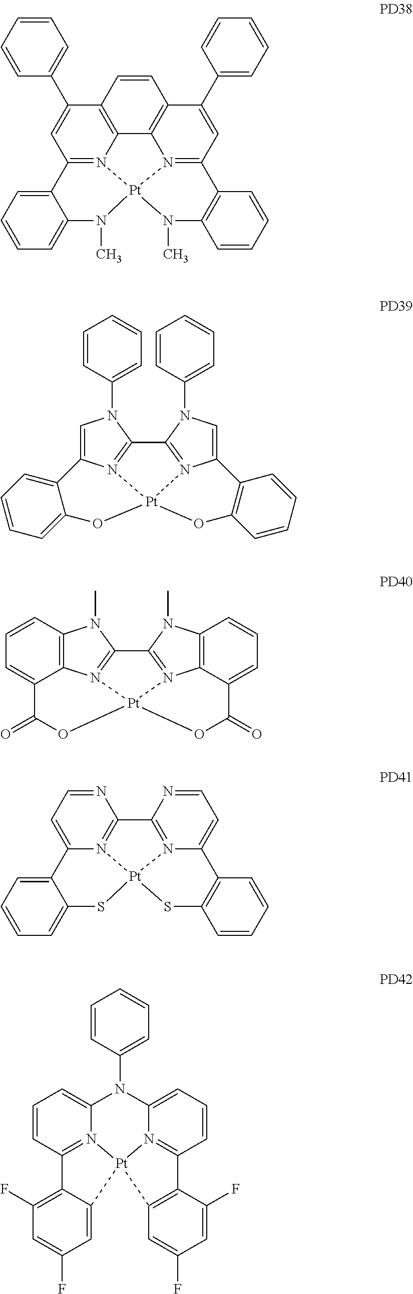

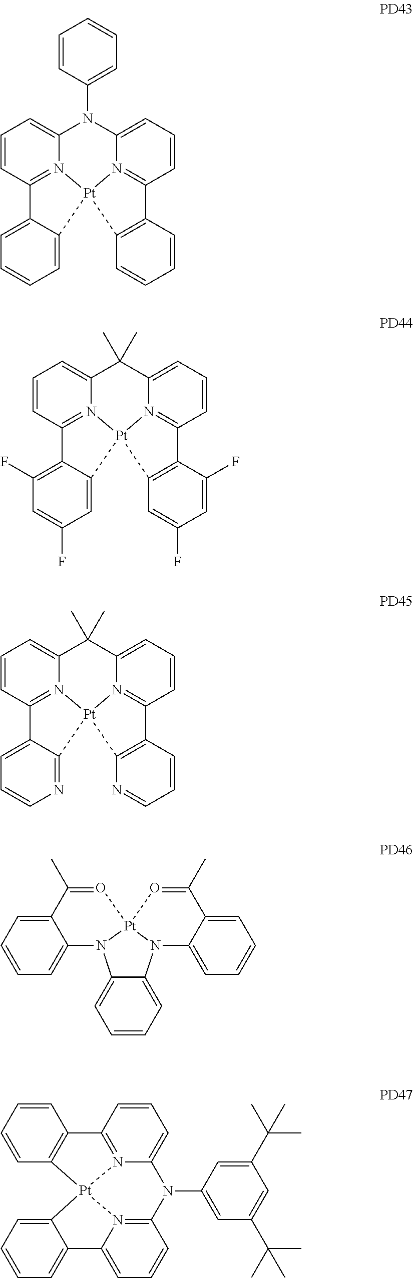

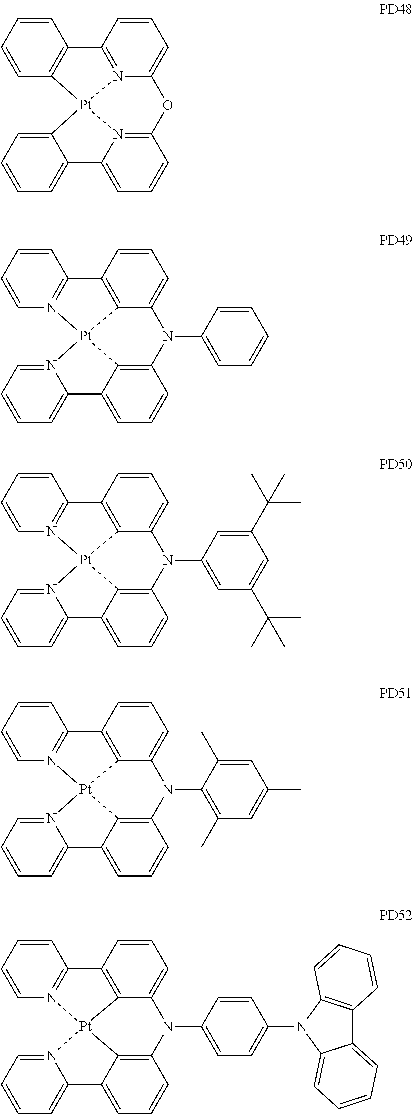

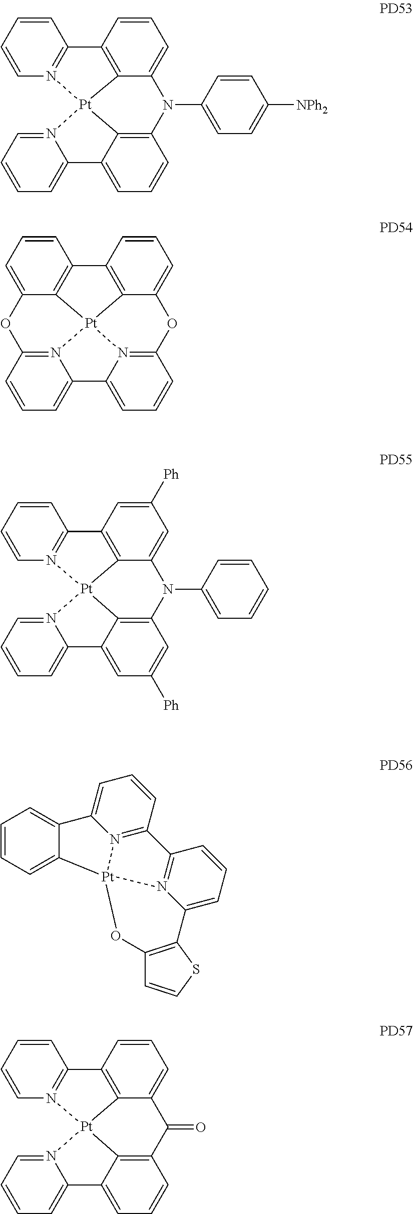

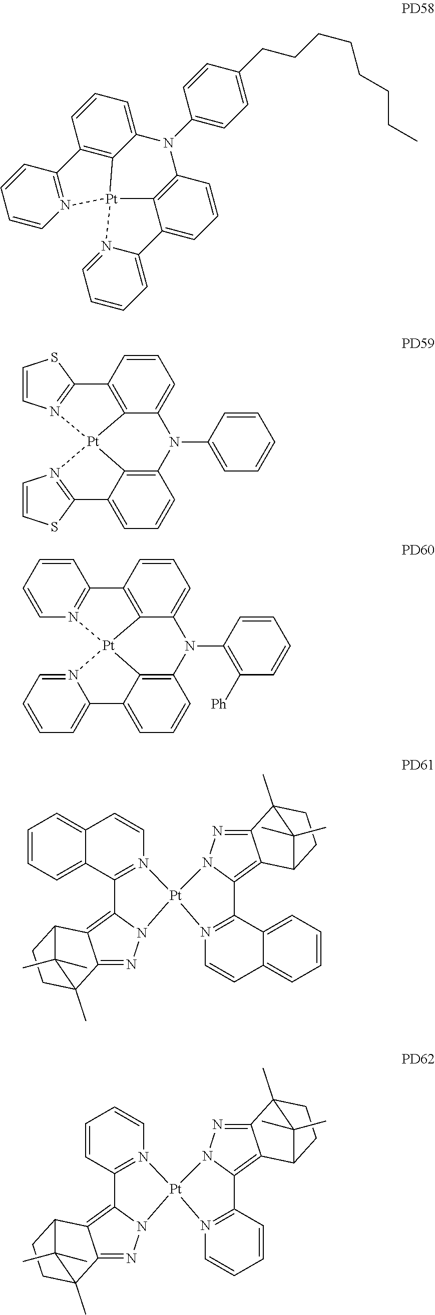

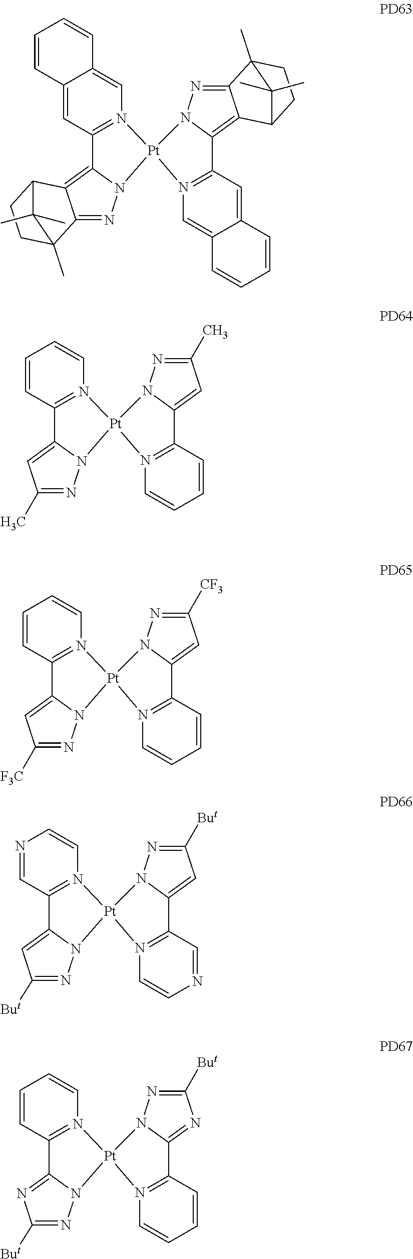

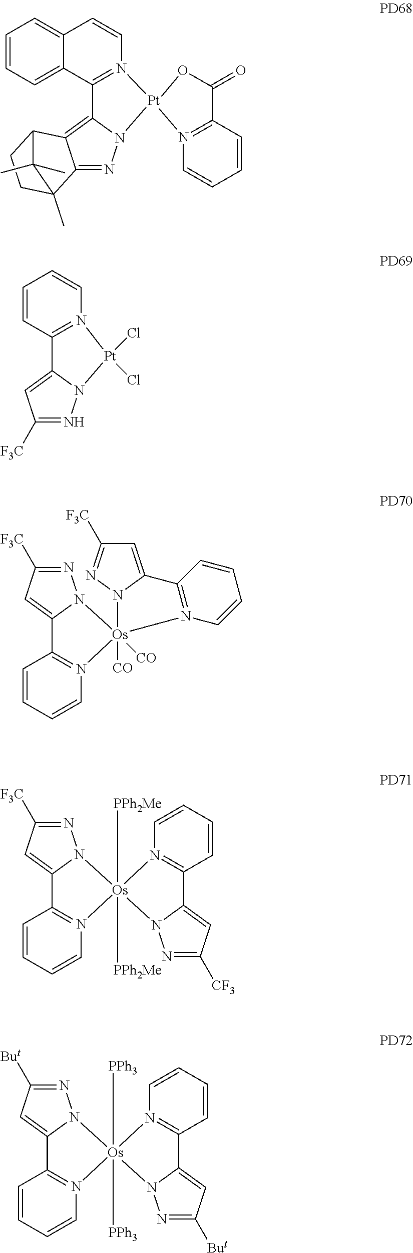

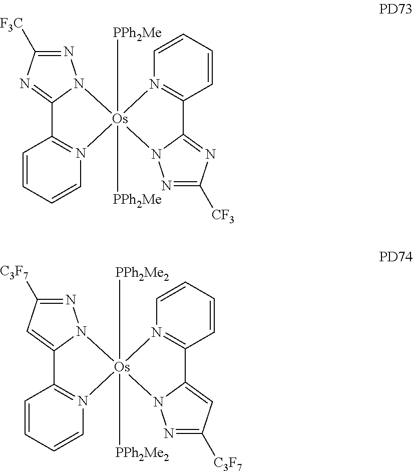

For example, the phosphorescent dopant may include PtOEP:

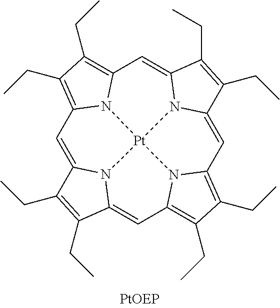

In some embodiments, the phosphorescent dopant may include at least one of DPAVBi, BDAVBi, TBPe, DCM, DCJTB, Coumarin 6, and C545T.

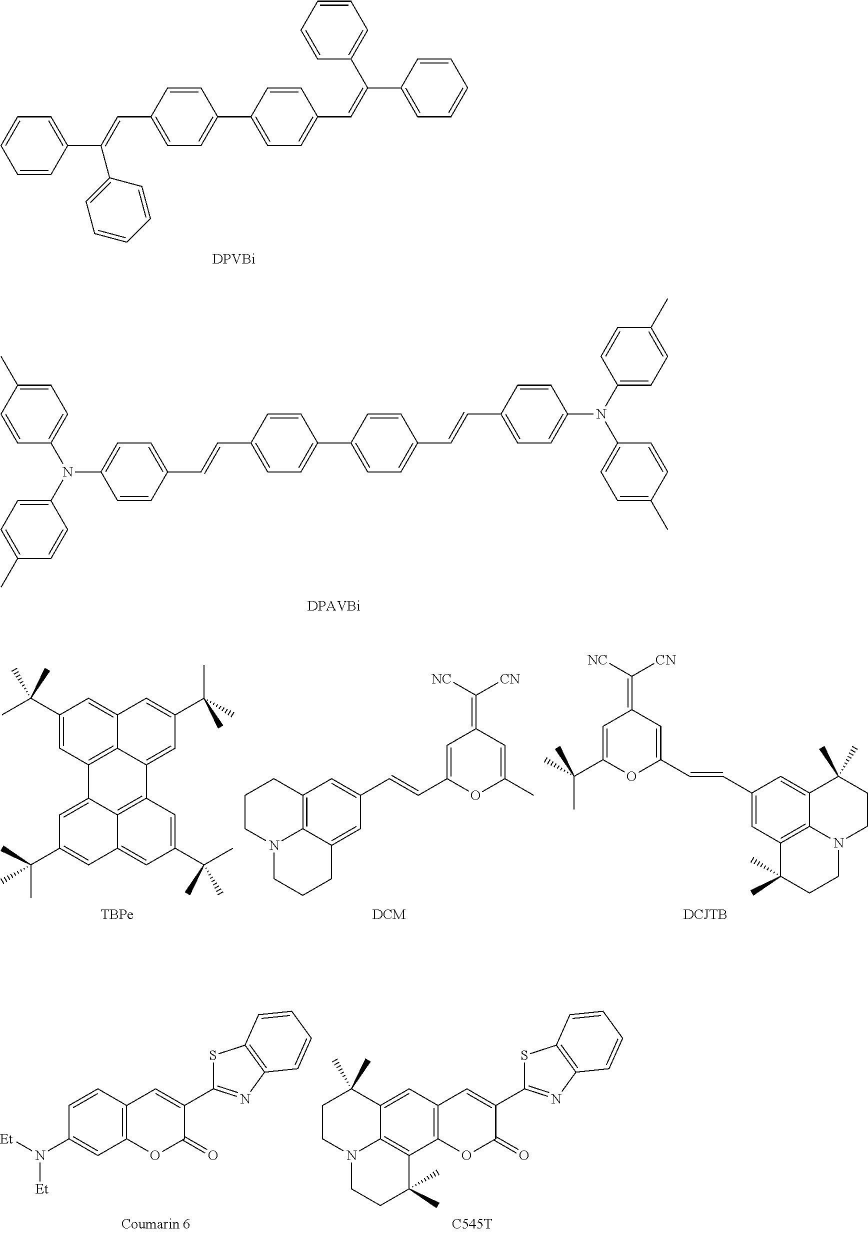

In some embodiments, the phosphorescent dopant may include a compound represented by Formula 501.

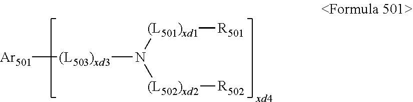

In Formula 501,

Ar₅₀₁ may be a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, or an indenoanthracene, or

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, or an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group and —Si(Q₅₀₁)(Q₅₀₂)(Q₅₀₃), wherein Q₅₀₁ to Q₅₀₃ may be each independently selected from a hydrogen, a C₁-C₆₀ alkyl group, a C₂-C₆₀ alkenyl group, a C₆-C₆₀ aryl group, and a C₁-C₆₀ heteroaryl group;

L₅₀₁ to L₅₀₃ may be the same as described herein in conjunction with L₂₀₁;

R₅₀₁ and R₅₀₂ may be each independently

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, or a dibenzothiophenyl group, or

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, and a dibenzofuranyl group, or a dibenzothiophenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a dibenzofuranyl group, and a dibenzothiophenyl group;

xd1 to xd3 may be each independently selected from 0, 1, 2, and 3; and

xd4 may be selected from 1, 2, 3, and 4.

A weight ratio of the first compound to the second compound may be in a range of about 10:90 to about 90:10, e.g., about 80:20, about 70:30, about 60:40, about 50:50, about 40:60, about 30:70, or about 20:80. For example, a weight ratio of the first compound to the second compound may be about 5:5. When the weight ratio of the first compound to the second compound is within these ranges, the electron-hole mobility balance in the emission layer may be effectively achieved.

For example, the hole transport region may include at least one of a hole injection layer (HIL), a hole transport layer (HTL), a buffer layer, and an electron blocking layer (EBL). For example, the electron transport layer may include at least one of a hole blocking layer (HBL), an electron transport layer (ETL), and an electron injection layer (EIL). However, embodiments of the present disclosure are not limited thereto.

The hole transport region may have a single-layered structure including a single material, a single-layered structure including a plurality of materials, or a multi-layered structure including a plurality of layers including different materials.

In some embodiments, the electron transport region may have a single-layered structure including a plurality of materials, or a multi-layered structure of HIL/HTL, HIL/HTL/buffer layer, HIL/buffer layer, HTL/buffer layer, or HIL/HTL/EBL, wherein these layers forming a multi-layered structure are sequentially disposed on the first electrode 110 in the order stated above. However, embodiments of the present disclosure are not limited thereto.

When the hole transport region includes a HIL, the HIL may be formed on the first electrode 110 by using any of a variety of methods, for example, by using vacuum deposition, spin coating, casting, Langmuir-Blodgett (LB) deposition, inkjet printing, laser printing, laser induced thermal imaging (LITI), or the like.

When the HIL is formed using vacuum deposition, the deposition conditions may vary depending on the material that is used to form the HIL and the structure of the HIL. For example, the deposition conditions may be selected from the following conditions: a deposition temperature of about 100° C. to about 500° C., a degree of vacuum of about 10⁻⁸ to about 10⁻³ torr, and a deposition rate of about 0.01 to 100 Å/sec.

When the HIL is formed using spin coating, the coating conditions may vary depending on the material that is used to form the HIL and the structure of the HIL. For example, the coating conditions may be selected from the following conditions: a coating rate of about 2,000 rpm to about 5,000 rpm and a heat treatment temperature of about 800° C. to about 200° C.

When the hole transport region includes a HTL, the HTL may be formed on the first electrode 110 or the HIL by using any of a variety of methods, for example, by using vacuum deposition, spin coating, casting, Langmuir-Blodgett (LB) deposition, inkjet printing, laser printing, laser induced thermal imaging (LITI), or the like. When the HTL is formed using vacuum deposition or spin coating, the conditions for deposition and coating may be similar to the above-described deposition and coating conditions for forming the HIL, and accordingly will not be described in detail.

In some embodiments, the hole transport region may include at least one of m-MTDATA, TDATA, 2-TNATA, NPB, β-NPB, TPD, Spiro-TPD, Spiro-NPB, methylated-NPB, TAPC, HMTPD, 4,4′,4″-tris(N-carbazolyl)triphenylamine (TCTA). polyaniline/dodecylbenzene sulfonic acid (Pani/DBSA), poly(3,4-ethylenedioxythiophene)/poly(4-styrenesulfonate)(PEDOT/PSS), polyaniline/camphor sulfonic acid (Pani/CSA), polyaniline/poly(4-styrenesulfonate) (PANI/PSS), a compound represented by Formula 201, and a compound represented by Formula 202.

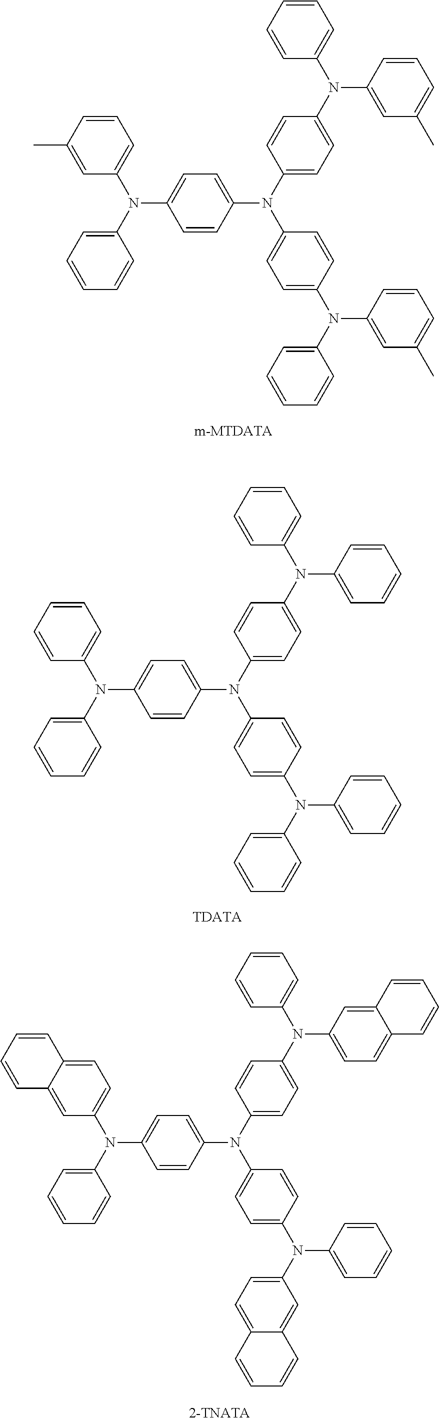

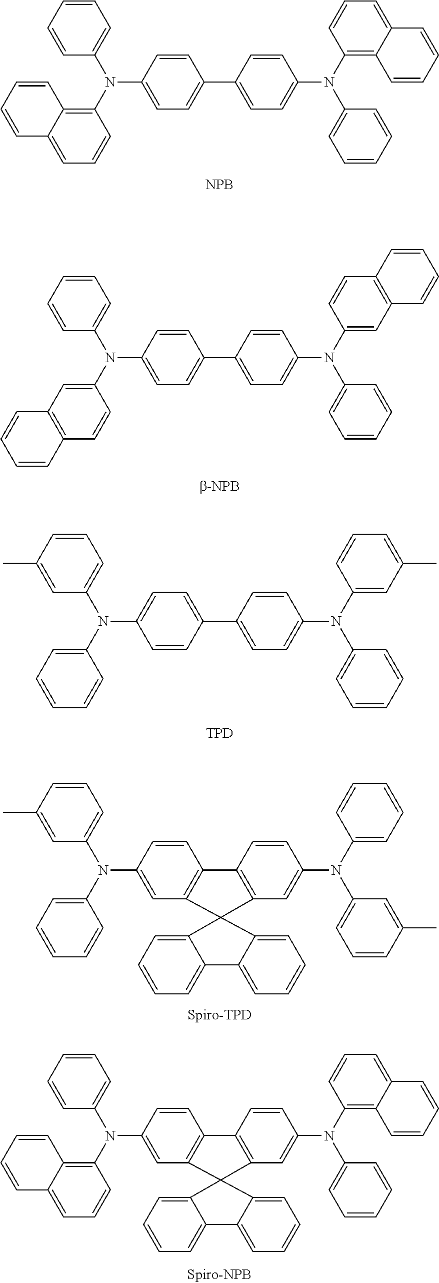

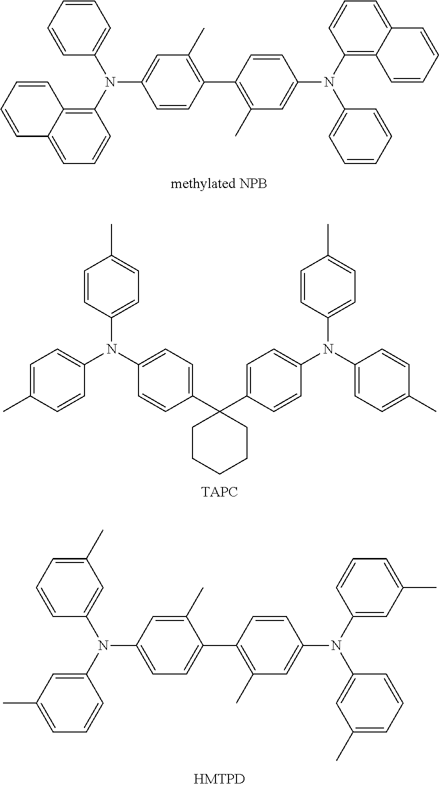

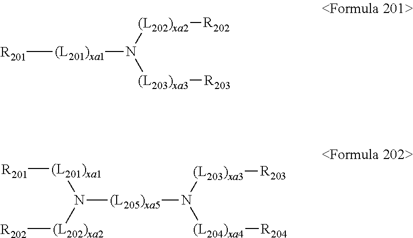

In Formulae 201 and 202,

L₂₀₁ to L₂₀₅ may be defined as described above herein in conjunction with L₁ to L₃;

xa1 to xa4 may be each independently selected from 0, 1, 2, and 3;

xa5 may be selected from 1, 2, 3, 4, and 5; and

R₂₀₁ to R₂₀₄ may be each independently selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

For example, in Formulae 201 and 202,

L₂₀₁ to L₂₀₅ may be each independently selected from

a phenylene group, a naphthylene group, a fluorenylene group, a spiro-fluorenylene group, a benzofluorene group, a dibenzofluorene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, an isoindolyl group, a quinolinyl group, an isoquinolinyl group, a quinoxalinyl group, a quinazolinyl group, a carbazolyl group, and a triazinyl group;

xa1 to xa4 may be each independently 0, 1, or 2;

xa5 may be 1, 2, or 3; and

R₂₀₁ to R₂₀₄ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an azulenyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group. However, embodiments of the present disclosure are not limited thereto.

For example, the compound of Formula 201 may be a compound represented by Formula 201A.

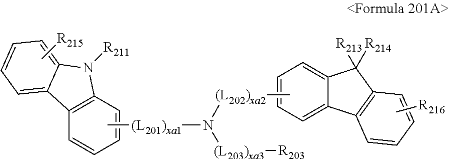

For example, the compound of Formula 201 may be a compound represented by Formula 201A-1, but is not limited thereto.

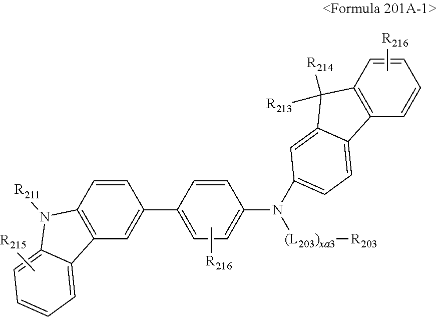

The compound of Formula 202 may be a compound represented by Formula 202A, but is not limited thereto.

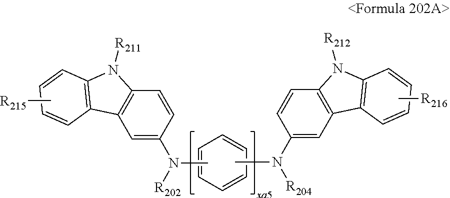

In Formulae 201A, 201A-1, and 202A,

L₂₀₁ to L₂₀₃, xa1 to xa3, xa5, and R₂₀₂ to R₂₀₄ may be the same as those described above herein;

R₂₁₁ and R₂₁₂ may be defined as described above herein in conjunction with R₂₀₃; and

R₂₁₃ to R₂₁₆ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, C₆-C₆₀ arylthio group, C₁-C₆₀ heteroaryl group, a monovalent non-aromatic condensed polycyclic group, and a monovalent non-aromatic condensed heteropolycyclic group.

For example, in Formulae 201A, 201A-1, and 202A,

L₂₀₁ to L₂₀₃ may be each independently selected from

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xa1 to xa3 may be each independently 0 or 1;

R₂₀₃, R₂₀₄, R₂₁₁ and R₂₁₂ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, carboxylic acid a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₃ and R₂₁₄ may be each independently selected from

a C₁-C₂₀ alkyl group and a C₁-C₂₀ alkoxy group,

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₅ and R₂₁₆ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group,

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, and a triazinyl group, and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

xa5 may be 1 or 2.

In Formulae 201A and 201A-1, R₂₁₃ and R₂₁₄ may be linked to each other to form a saturated or unsaturated ring.

The compound of Formula 201 and the compound of Formula 202 may each independently be selected from Compounds HT1 to HT20, but are not limited thereto.

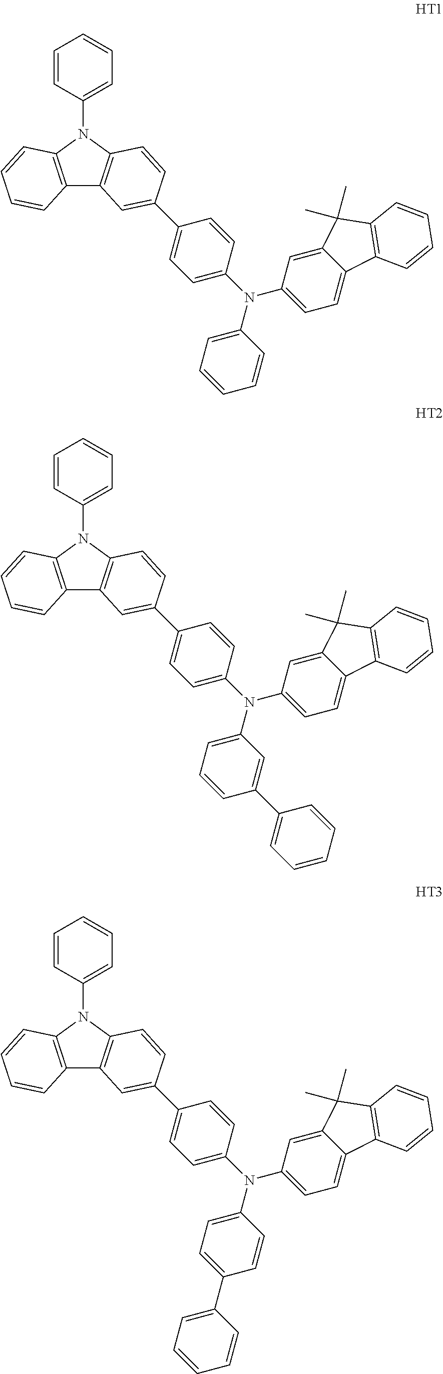 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

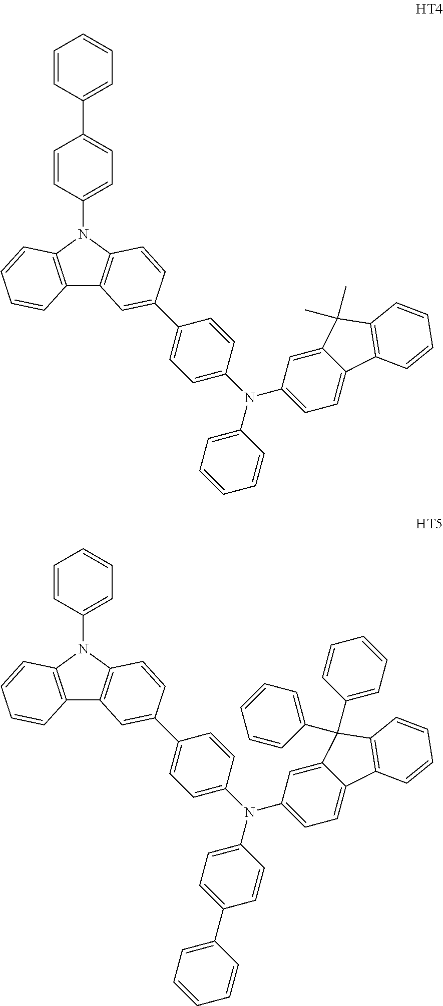 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

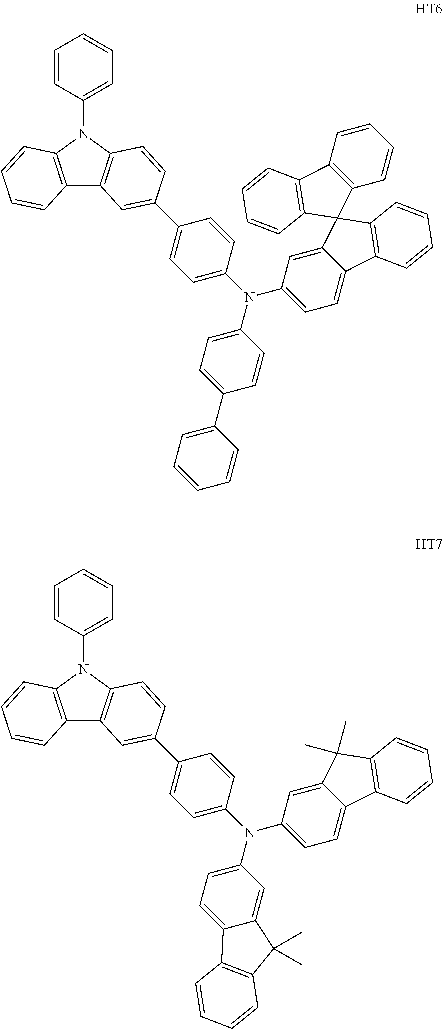 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

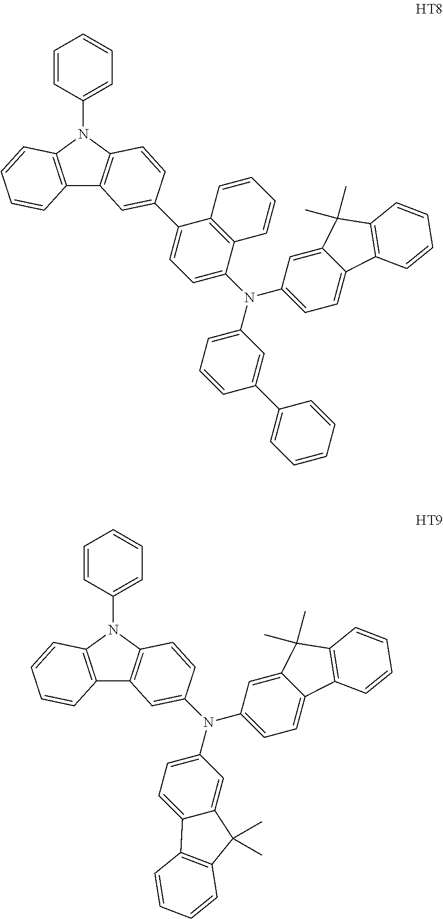 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

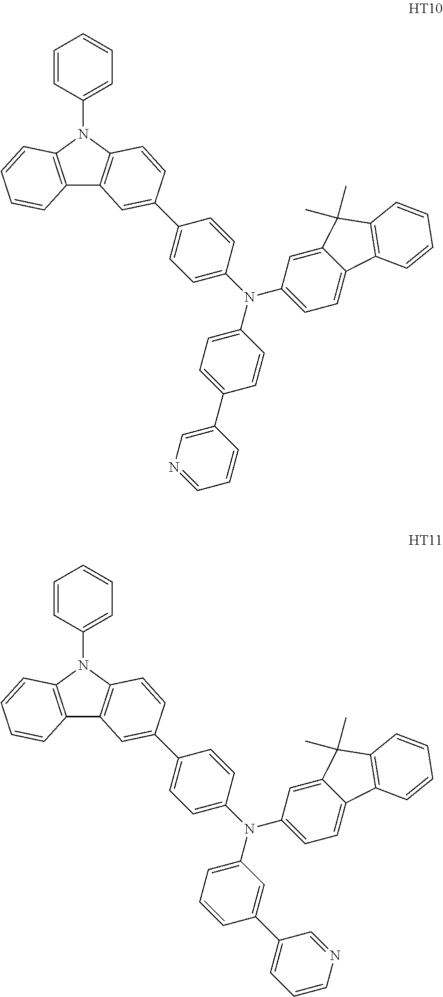 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

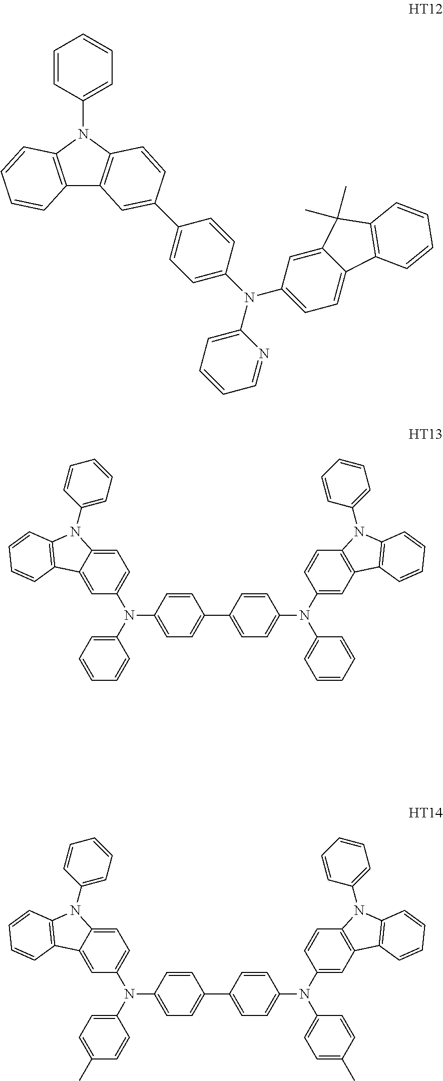 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1]

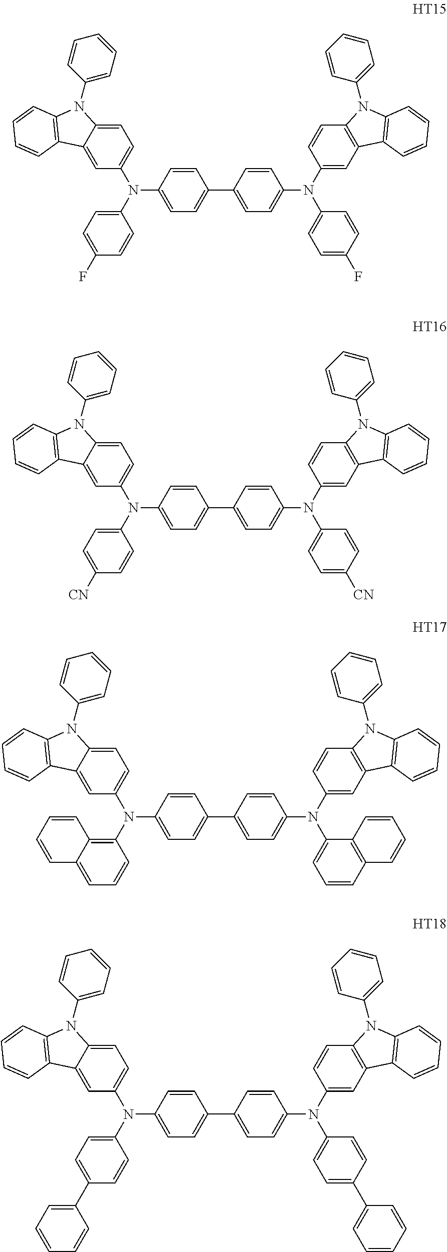

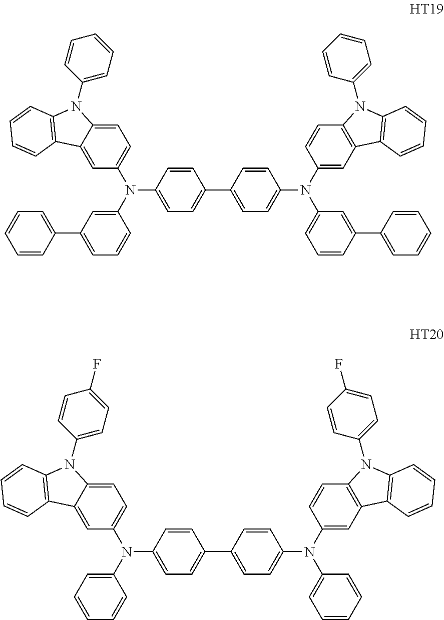 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be from about 100 Å to about 10000 Å, and in some embodiments, from about 100 Å to about 1000 Å. When the hole transport region includes a HIL and a HTL, a thickness of the HIL may be from about 100 Å to about 10,000 Å, and in some embodiments, from about 100 Å to about 1,000 Å, and a thickness of the HTL may be from about 50 Å to about 2,000 Å, and in some embodiments, from about 100 Å to about 1,500 Å. When the thicknesses of the hole transport region, the HIL, and the HTL are within these ranges, satisfactory hole transport characteristics may be obtained without a substantial increase in driving voltage.

The hole transport region may further include a charge-generating material to improve conductivity, in addition to the materials as described above. The charge-generating material may be homogeneously or inhomogeneously dispersed in the hole transport region.

The charge-generating material may be, for example, a p-dopant. The p-dopant may be one of quinine derivatives, metal oxides, and cyano group-containing compounds, but is not limited thereto. Non-limiting examples of the p-dopant are quinone derivatives such as tetracyanoquinonedimethane (TCNQ), 2,3,5,6-tetrafluoro-tetracyano-1,4-benzoquinonedimethane (F4-TCNQ), and the like; metal oxides such as tungsten oxide, molybdenum oxide, and the like; and a Compound HT-D1.

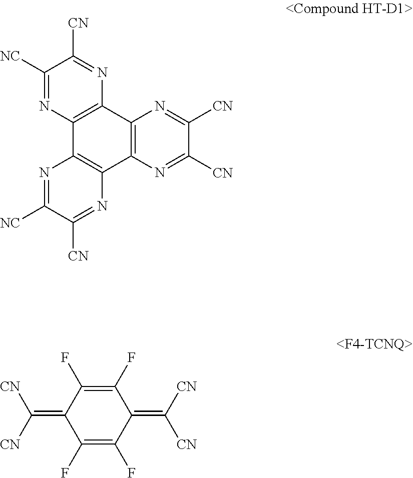

The hole transport region may further include at least one of a buffer layer and an EBL, in addition to the HIL and HTL described above. The buffer layer may compensate for an optical resonance distance of light according to a wavelength of the light emitted from the EML, and thus may improve light-emission efficiency. A material included in the buffer layer may be any material used in the hole transport region. The EBL may block migration of electrons from the electron transport region into EML.

For example, a material for the EBL may be mCP, but is not limited thereto.

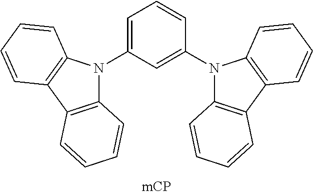 [SMILES: c1cc(-n2c3ccccc3c3ccccc32)cc(-n2c3ccccc3c3ccccc32)c1]

The electron transport region may include at least one of a HBL, an ETL, and an EIL. However, embodiments of the present disclosure are not limited thereto.

In some embodiments, the electron transport region may have a structure including an ETL/EIL or a HBL/ETL/EIL, wherein the layers forming a structure of the electron transport region may be sequentially stacked on the EML in the order stated above. However, embodiments of the present disclosure are not limited thereto.

The electron transport region may include a HBL. When the EML includes a phosphorescent dopant, the HBL may prevent diffusion of triplet exitons or holes into the ETL from the EML.

When the electron transport region includes a HBL, the HBL may be formed on the EML by using any of a variety of methods, for example, by using vacuum deposition, spin coating, casting, Langmuir-Blodgett (LB) deposition, inkjet printing, laser printing, laser induced thermal imaging (LITI), or the like. When the HBL is formed using vacuum deposition or spin coating, the deposition and coating conditions for forming the HBL may be similar to the above-described deposition and coating conditions for forming the HIL, and accordingly will not be described in detail.

For example, the HBL may include at least one of BCP and Bphen. However, embodiments of the present disclosure are not limited thereto.

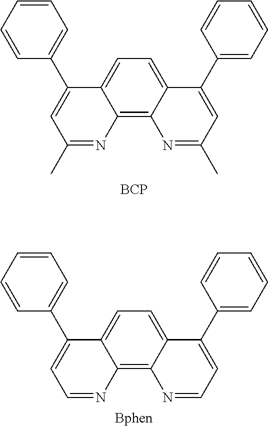

A thickness of the HBL may be from about 20 Å to about 1,000 Å, and in some embodiments, from about 30 Å to about 300 Å. When the thickness of the HBL is within these ranges, the HBL may have improved hole blocking ability without a substantial increase in driving voltage.

The electron transport region may include an ETL. The ETL may be formed on the EML or the HBL by using any of a variety of methods, for example, by using vacuum deposition, spin coating, casting, Langmuir-Blodgett (LB) deposition, inkjet printing, laser printing, laser induced thermal imaging (LITI), or the like. When the ETL is formed using vacuum deposition or spin coating, the deposition and coating conditions for forming the ETL may be similar to the above-described deposition and coating conditions for forming the HIL, and accordingly will not be described in detail.

The ETL may further include at least one of BCP, Bphen, Alq₃, Balq, TAZ, and NTAZ.

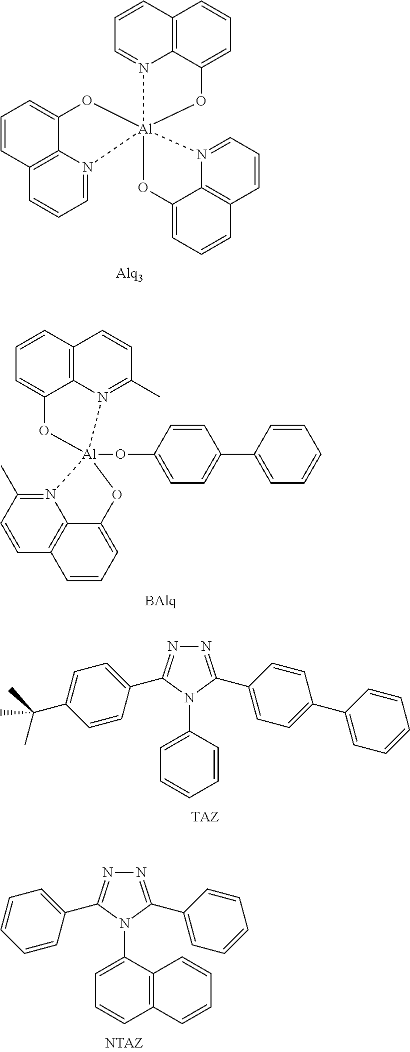

In some embodiments, the ETL may include at least one of compounds represented by Formulae 601 and 602.

Ar₆₀₁-[(L₆₀₁)ₓₑ₁-E₆₀₁]ₓₑ₂ <Formula 601>

In Formula 601,

Ar₆₀₁ may be selected from

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, and an indenoanthracene, and

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, and an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₃₀₁)(Q₃₀₂)(Q₃₀₃), wherein Q₃₀₁ to Q₃₀₃ may be each independently selected from a hydrogen, a C₁-C₆₀ alkyl group, a C₂-C₆₀ alkenyl group, a C₆-C₆₀ aryl group, and a C₁-C₆₀ heteroaryl group;

L₆₀₁ may be defined as described herein in conjunction with L₂₀₁;

E₆₀₁ may be selected from

a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group,

a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group;

xe1 may be selected from 0, 1, 2, and 3; and

xe2 may be selected from 1, 2, 3, and 4.

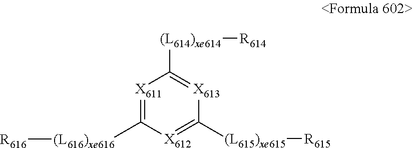

In Formula 602,

X₆₁₁ may be N or C-(L₆₁₁)ₓₑ₆₁₁-R₆₁₁, X₆₁₂ may be N or C-(L₆₁₂)ₓₑ₆₁₂-R₆₁₂; X₆₁₃ may be N or C-(L₆₁₃)ₓₑ₆₁₃-R₆₁₃, at least one of X₆₁₁ to X₆₁₃ may be N;

L₆₁₁ to L₆₁₆ may be defined as described above in conjunction L₂₀₁;

R₆₁₁ to R₆₁₆ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

xe611 to xe616 may be each independently selected from, 0, 1, 2, and 3.

The compound of Formula 601 and the compound of Formula 602 may be each independently selected from Compounds ET1 to ET15.

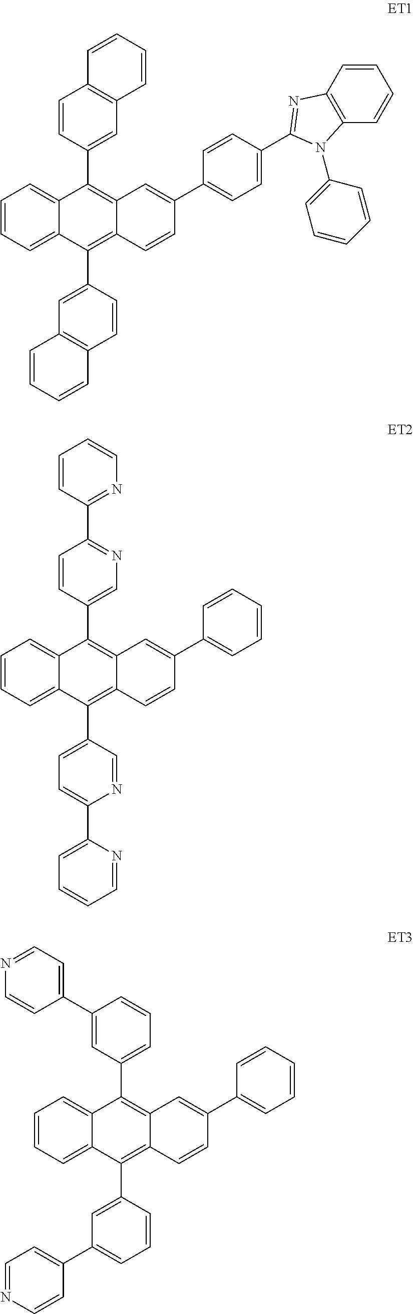 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

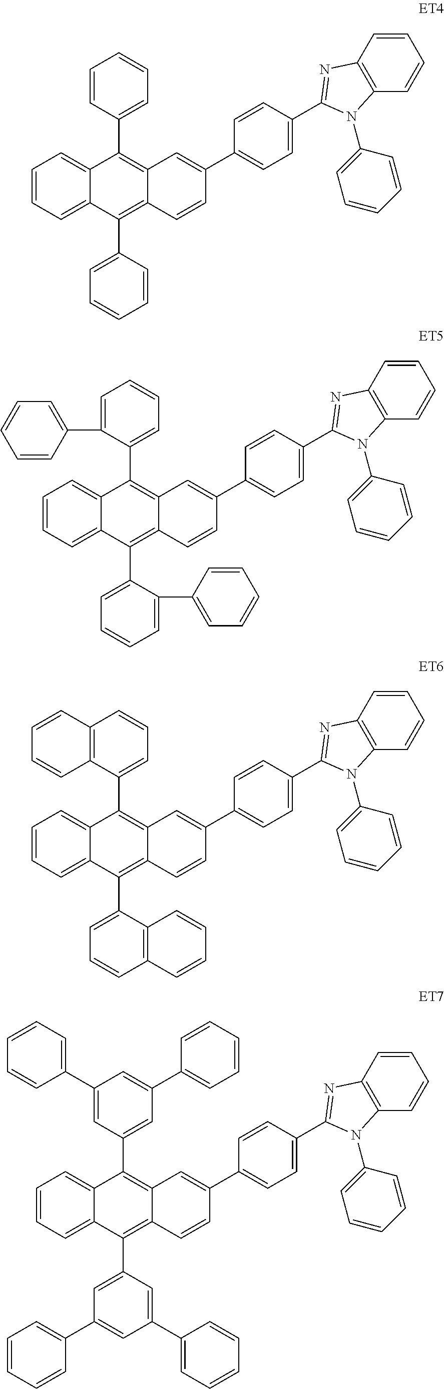 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

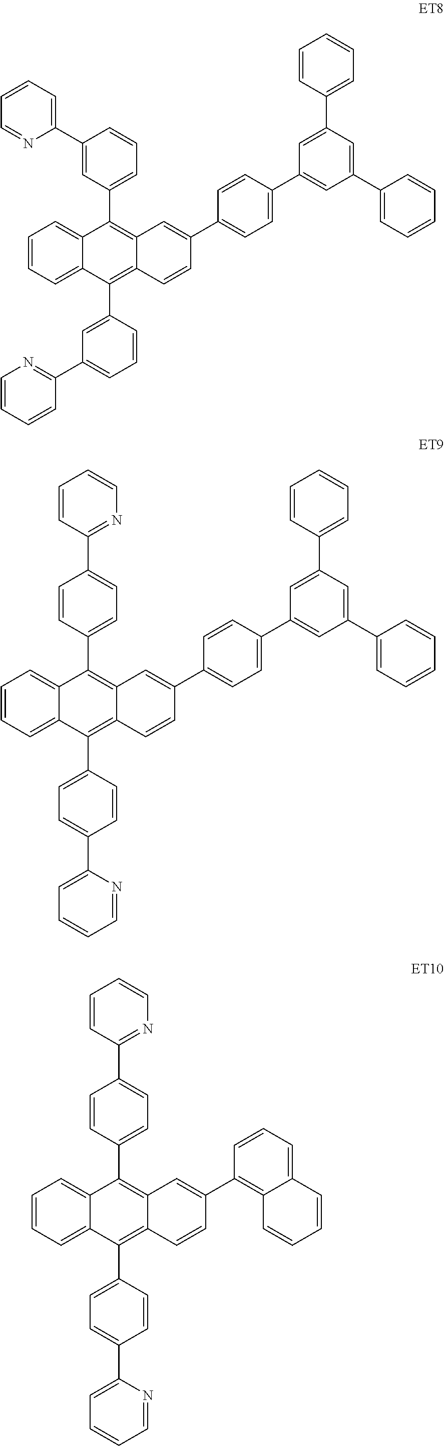 [SMILES: c1ccc(-c2cc(-c3ccccc3)cc(-c3ccc(-c4ccc5c(-c6cccc(-c7ccccn7)c6)c6ccccc6c(-c6cccc(-c7ccccn7)c6)c5c4)cc3)c2)cc1 ; c1ccc(-c2cc(-c3ccccc3)cc(-c3ccc(-c4ccc5c(-c6ccc(-c7ccccn7)cc6)c6ccccc6c(-c6ccc(-c7ccccn7)cc6)c5c4)cc3)c2)cc1 ; c1ccc(-c2ccc(-c3c4ccccc4c(-c4ccc(-c5ccccn5)cc4)c4cc(-c5cccc6ccccc56)ccc34)cc2)nc1]

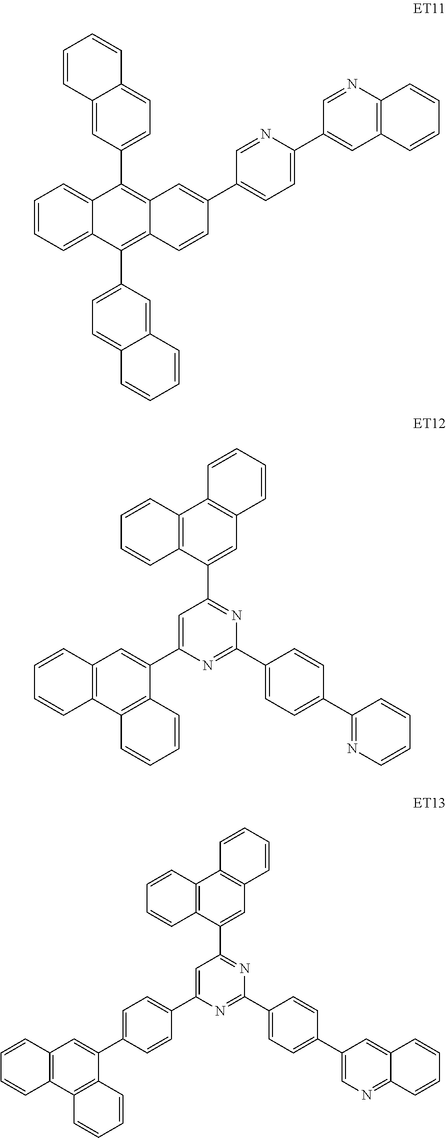 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1]

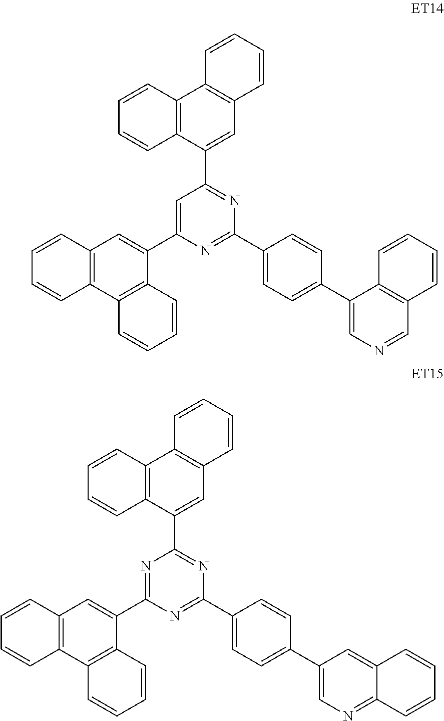 [SMILES: c1ccc2c(-c3ccc(-c4nc(-c5cc6ccccc6c6ccccc56)cc(-c5cc6ccccc6c6ccccc56)n4)cc3)cncc2c1 ; c1ccc2ncc(-c3ccc(-c4nc(-c5cc6ccccc6c6ccccc56)nc(-c5cc6ccccc6c6ccccc56)n4)cc3)cc2c1]

A thickness of the ETL may be from about 100 Å to about 1,000 Å, and in some embodiments, from about 150 Å to about 500 Å. When the thickness of the ETL is within these ranges, the ETL may have satisfactory electron transporting ability without a substantial increase in driving voltage.

In some embodiments the ETL may further include a metal-containing material, in addition to the above-described materials.

The metal-containing material may include a lithium (Li) complex. Non-limiting examples of the Li complex are Compound ET-D1 (lithium quinolate (LiQ)), and Compound ET-D2.

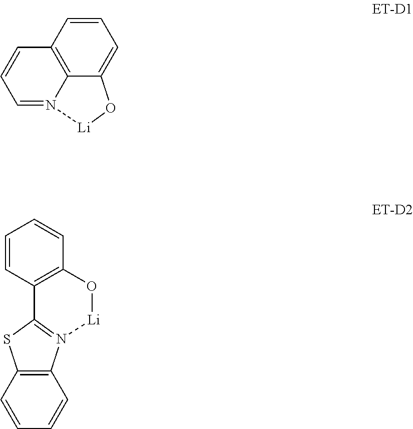

The electron transport region may include an EIL that may facilitate injection of electrons from the second electrode 190.

The EIL may be formed on the ETL by using any of a variety of methods, for example, by using vacuum deposition, spin coating, casting, Langmuir-Blodgett (LB) deposition, inkjet printing, laser printing, laser induced thermal imaging (LITI), or the like. When the EIL is formed using vacuum deposition or spin coating, the deposition and coating conditions for forming the EIL may be similar to the above-described deposition and coating conditions for forming the HIL, and accordingly will not be described in detail.

The EIL may include at least one selected from LiF, NaCl, CsF, Li₂O, BaO, and LiQ.

A thickness of the EIL may be from about 1 Å to about 100 Å, and in some embodiments, from about 3 Å to about 90 Å. When the thickness of the EIL is within these ranges, the EIL may have satisfactory electron injection ability without a substantial increase in driving voltage.

The second electrode 190 may be disposed on the organic layer 150, as described above. The second electrode 190 may be a cathode as an electron injecting electrode. A material for forming the second electrode 190 may be a metal, an alloy, an electrically conductive compound, which have a low-work function, or a mixture thereof. Non-limiting examples of materials for forming the second electrode 190 are lithium (Li), magnesium (Mg), aluminum (Al), aluminum-lithium (Al—Li), calcium (Ca), magnesium-indium (Mg—In), and magnesium-silver (Mg—Ag). In some embodiments, a material for forming the second electrode 190 may be ITO or IZO. The second electrode 190 may be a reflective electrode, a semi-transmissive electrode, or a transmissive electrode.

Although the organic light-emitting device of FIG. 1 is described above, embodiments of the present disclosure are not limited thereto.

As used herein, a C₁-C₆₀ alkyl group refers to a linear or branched aliphatic hydrocarbon monovalent group having 1 to 60 carbon atoms. Non-limiting examples of the C₁-C₆₀ alkyl group, a methyl group, a ethyl group, a propyl group, an isobutyl group, a sec-butyl group, a tert-butyl group, a pentyl group, an iso-amyl group, and a hexyl group. A C₁-C₆₀ alkylene group refers to a divalent group having the same structure as the C₁-C₆₀ alkyl.

As used herein, a C₁-C₆₀ alkoxy group refers to a monovalent group represented by —OA₁₀₁ (where A₁₀₁ is a C₁-C₆₀ alkyl group, as described above). Non-limiting examples of the C₁-C₆₀ alkoxy group are a methoxy group, an ethoxy group, and an isopropyloxy group.

As used herein, a C₂-C₆₀ alkenyl group refers to a hydrocarbon group including at least one carbon double bond in the middle or terminal of the C₂-C₆₀ alkyl group. Non-limiting examples of the C₂-C₆₀ alkenyl group are an ethenyl group, a prophenyl group, and a butenyl group. A C₂-C₆₀ alkylene group refers to a divalent group having the same structure as the C₂-C₆₀ alkenyl group.

As used herein, a C₂-C₆₀ alkynyl group refers to a hydrocarbon group including at least one carbon triple bond in the middle or terminal of the C₂-C₆₀ alkyl group. Non-limiting examples of the C₂-C₆₀ alkynyl group are an ethynyl group, and a propynyl group. A C₂-C₆₀ alkynylene group used herein refers to a divalent group having the same structure as the C₂-C₆₀ alkynyl group.

As used herein, a C₃-C₁₀ cycloalkyl group refers to a monovalent, monocyclic hydrocarbon group having 3 to 10 carbon atoms. Non-limiting examples of the C₃-C₁₀ cycloalkyl group, are a cyclopropyl group, a cyclobutyl group, a cyclopentyl group, a cyclohexyl group, and a cycloheptyl group. A C₃-C₁₀ cycloalkylene group refers to a divalent group having the same structure as the C₃-C₁₀ cycloalkyl group.

As used herein, a C₁-C₁₀ heterocycloalkyl group refers to a monovalent monocyclic group having 1 to 10 carbon atoms in which at least one hetero atom selected from N, O, P, and S is included as a ring-forming atom. Non-limiting examples of the C₁-C₁₀ heterocycloalkyl group are a tetrahydrofuranyl group, and a tetrahydrothiophenyl group. A C₁-C₁₀ heterocycloalkylene group refers to a divalent group having the same structure as the C₁-C₁₀ heterocycloalkyl group.

As used herein, a C₃-C₁₀ cycloalkenyl group refers to a monovalent monocyclic group having 3 to 10 carbon atoms that includes at least one double bond in the ring but does not have aromaticity. Non-limiting examples of the C₃-C₁₀ cycloalkenyl group, are a cyclopentenyl group, a cyclohexenyl group, and a cycloheptenyl group. A C₃-C₁₀ cycloalkenylene group refers to a divalent group having the same structure as the C₃-C₁₀ cycloalkenyl group.

As used herein, a C₁-C₁₀ heterocycloalkenyl group used herein refers to a monovalent monocyclic group having 1 to 10 carbon atoms that includes at least one double bond in the ring and in which at least one hetero atom selected from N, O, P, and S is included as a ring-forming atom. Non-limiting examples of the C₁-C₁₀ heterocycloalkenyl group are a 2,3-dihydrofuranyl group, and a 2,3-dihydrothiophenyl group. A C₁-C₁₀ heterocycloalkenylene group used herein refers to a divalent group having the same structure as the C₁-C₁₀ heterocycloalkenyl group.

As used herein, a C₆-C₆₀ aryl group refers to a monovalent, aromatic carbocyclic aromatic group having 6 to 60 carbon atoms, and a C₆-C₆₀ arylene group refers to a divalent, aromatic carbocyclic group having 6 to 60 carbon atoms. Non-limiting examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀arylene group include at least two rings, the rings may be fused to each other.

As used herein, a C₁-C₆₀ heteroaryl group refers to a monovalent, aromatic carbocyclic aromatic group having 1 to 60 carbon atoms in which at least one hetero atom selected from N, O, P, and S is included as a ring-forming atom, and 2 to 60 carbon atoms. A C₁-C₆₀ heteroarylene group refers to a divalent, aromatic carbocyclic group having 1 to 60 carbon atoms in which at least one hetero atom selected from N, O, P, and S is included as a ring-forming atom. Non-limiting examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl and the C₁-C₆₀ heteroarylene include at least two rings, the rings may be fused to each other.

As used herein, a C₆-C₆₀ aryloxy group indicates —OA₁₀₂ (where A₁₀₂ is a C₆-C₆₀ aryl group, as described above), and a C₆-C₆₀ arylthio group indicates —SA₁₀₃ (where A₁₀₃ is a C₆-C₆₀ aryl group, as described above).

As used herein, the monovalent non-aromatic condensed polycyclic group refers to a monovalent group that includes at least two rings condensed to each other and includes only carbon atoms (for example, 8 to 60 carbon atoms) as ring-forming atoms and that represents non-aromaticity as a whole. An example of the monovalent non-aromatic condensed polycyclic group is a fluorenyl group. As used herein, a divalent non-aromatic condensed polycyclic group refers to a divalent group with the same structure as the monovalent non-aromatic condensed polycyclic group.

As used herein, the monovalent non-aromatic condensed heteropolycyclic group refers to a monovalent group that includes at least two rings condensed to each other and include carbon (for example, 1 to 60 carbon atoms) and hetero atoms selected from N,O, P and S as ring-forming atoms and that represents non-aromaticity as a whole. An example of the monovalent non-aromatic condensed heteropolycyclic group is a carbazolyl group. As used herein, a divalent non-aromatic condensed heteropolycyclic group refers to a divalent group with the same structure as the monovalent non-aromatic condensed polycyclic group.

As used herein, at least one substituent of the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from

a C₁-C₆₀ alkyl group, a C₂-C₆₀ alkenyl group, a C₂-C₆₀ alkynyl group, and a C₁-C₆₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇),

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group,

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇), and

—Si(Q₃₁)(Q₃₂)(Q₃₃), —B(Q₃₄)(Q₃₅), and —N(Q₃₆)(Q₃₇),

wherein Q₁ to Q₇, Q₁₁ to Q₁₇, Q₂₁ to Q₂₇, and Q₃₁ to Q₃₇ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

For example, at least one substituent of the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group,

a C₁-C₆₀ alkyl group, a C₂-C₆₀ alkenyl group, a C₂-C₆₀ alkynyl group, and a C₁-C₆₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₁₁)(Q₁₂), —B(Q₁₃)(Q₁₄), and —Si(Q₁₅)(Q₁₆)(Q₁₇),

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a Spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group,

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₂₁)(Q₂₂), —B(Q₂₃)(Q₂₄), and —Si(Q₂₅)(Q₂₆)(Q₂₇), and

—N(Q₃₁)(Q₃₂), —B(Q₃₃)(Q₃₄), and —Si(Q₃₅)(Q₃₆)(Q₃₇),

wherein Q₁ to Q₇, Q₁₁ to Q₁₇, Q₂₁ to Q₂₇, and Q₃₁ to Q₃₇ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group. However, embodiments of the present disclosure are not limited thereto.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Example 1

### Synthesis of Compound 1

Compound 1 was synthesized according to Reaction Scheme 1:

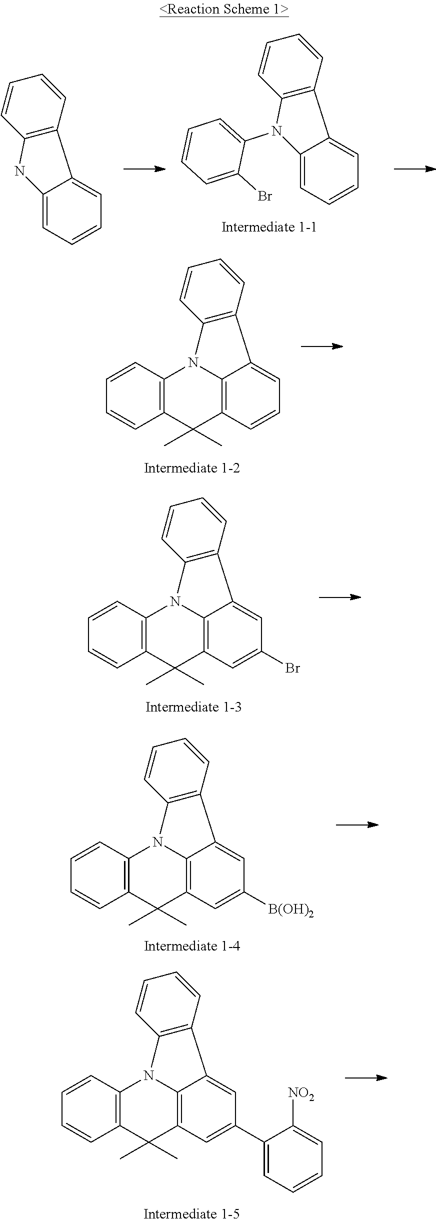 [SMILES: c1ccc2c(c1)[nH]c1ccccc12 ; Brc1ccccc1-n1c2ccccc2c2ccccc21 ; CC1(C)c2ccccc2-n2c3ccccc3c3cccc1c32 ; CC1(C)c2ccccc2-n2c3ccccc3c3cc(Br)cc1c32 ; CC1(C)c2ccccc2-n2c3ccccc3c3cc(B(O)O)cc1c32 ; CC1(C)c2ccccc2-n2c3ccccc3c3cc(-c4ccccc4[N+](=O)[O-])cc1c32]

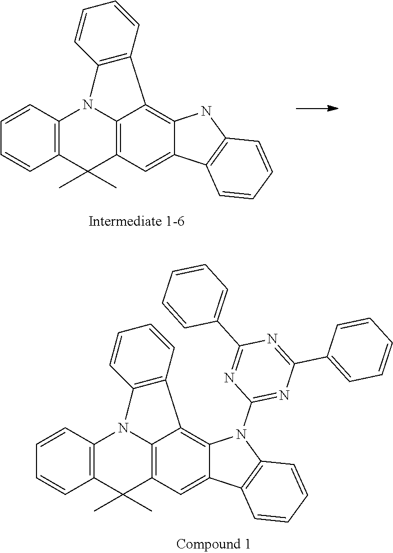 [SMILES: CC1(C)c2ccccc2-n2c3ccccc3c3c4[nH]c5ccccc5c4cc1c32 ; CC1(C)c2ccccc2-n2c3ccccc3c3c2c1cc1c2ccccc2n(-c2nc(-c4ccccc4)nc(-c4ccccc4)n2)c13]

### Synthesis of Intermediate 1-1

20 g (119.61 mmol) of carbazole, 67.68 g (239.22 mmol) of 2-bromoiodobenzene, 11.40 g (59.81 mmol) of copper iodide, and 33.06 g (239.22 mmol) of potassium carbonate were dissolved in xylene under nitrogen atmosphere, and stirred under reflux. After about 12 hours, the temperature was cooled down to ambient temperature, followed by adding distilled water, extraction with methylene chloride (MC), drying using magnesium sulfate, and then distillation under a reduced pressure. A resulting product was separated by column chromatography to obtain 32.64 g (101.67 mmol, Yield: 85%) of Intermediate 1-1.

### Synthesis of Intermediate 1-2

20 g (62.30 mmol) of Intermediate 1-1 was dissolved in 100 mL of tetrahydrofuran (THF), and 24.91 mL (62.30 mmol, 2.5M in hexane) of n-buLi was slowly added thereto at about −78° C. After stirring for about 2 hours, 4.70 mL (80.99 mmol) of acetone was added thereto, and the temperature was slowly increased to ambient temperature, followed by adding an aqueous NaHCO₃ solution and extraction with methylene chloride (MC). A result product was dried using magnesium sulfate, followed by distillation under a reduced pressure, and then mixing with 100 mL of acetic acid in a 2-necked flask. A catalytic amount of an aqueous HCl solution (5 mol %, 12N) was added thereto, stirred under reflux for about 12 hours, and then cooled down to ambient temperature. Subsequently, distilled water was added thereto, followed by extraction with MC, drying using magnesium sulfate, and distillation under a reduced pressure. A resulting product was separated by column chromatography to obtain 11.47 g (40.50 mmol, Yield: 65%) of Intermediate 1-2.

### Synthesis of Intermediate 1-3

20 g (70.64 mmol) of Intermediate 1-2 was dissolved in 200 mL of dimethylformamide (DMF), and then 13.83 g (77.70 mmol) of N-bromosuccinimide (NBS) was added thereto. After stirring at ambient temperature for about 10 hours, the organic solvents were distilled under a reduced pressure, followed by adding distilled water and extraction with ethyl acetate (EA). A resulting product was dried using magnesium sulfate, followed by distillsation under a reduced pressure and separation by column chromatography to obtain 22.19 g (61.45 mmol, Yield: 87%) of Intermediate 1-3.

### Synthesis of Intermediate 1-4

20 g (55.39 mmol) of Intermediate 1-3 was dissolved in 200 mL of tetrahydrofuran (THF), and 22.15 mL (55.39 mmol, 2.5M in hexane) of n-buLi was slowly added thereto at about −78° C. After stirring for about 1 hour, 8.02 mL (72.01 mmol) of trimethyl borate was added thereto, and the temperature was slowly increased to ambient temperature, followed by stirring for about 12 hours. After distilled water was added thereto, followed by extraction with EA, drying using magnesium sulfate, and then distillation under a reduced pressure. A resulting product was separated by column chromatography to obtain 10.87 g (33.24 mmol, Yield: 60%) of Intermediate 1-4.

### Synthesis of Intermediate 1-5

20 g (61.14 mmol) of Intermediate 1-4, 14.81 g (73.36 mmol) of bromo-2-nitrobenzene, 1.78 g (1.53 mmol) of tetrakis(triphenylphosphine)palladium(0) (Pd(PPh₃)₄), 49.98 mL (101.89 mmol) of a 2M aqueous K₂CO₃ solution, 160 mL of toluene, and 60 mL of ethanol were mixed and stirred under reflux. After about 4 hours, the temperature was cooled down to ambient temperature, followed by adding distilled water, extraction with EA, drying using magnesium sulfate, and distillation under a reduced pressure. A resulting product was separated by column chromatography to obtain 18.78 g (46.46 mmol, Yield: 76%) of Intermediate 1-5.

### Synthesis of Intermediate 1-6

10 g (24.74 mmol) of Intermediate 1-5 was mixed with 100 mL of triethylphosphite and stirred at about 180° C. After about 10 hours, the temperature was cooled down to ambient temperature, and the organic solvent was distilled under a reduced pressure. Subsequently, distilled water was added thereto, followed by extraction with EA, drying using magnesium sulfate, and distillation under a reduced pressure. A resulting product was separated by column chromatography to obtain 5.51 g (14.85 mmol, Yield: 60%) of Intermediate 1-6.

### Synthesis of Compound 1

10 g (26.92 mmol) of Intermediate 1-6 was dissolved in 100 mL of dimethylformamide (DMF) to obtain a solution, which was then put into a reaction vessel in which 1.62 g (40.38 mmol, a 60% dispersion in mineral oil) of NaH was dissolved in 100 mL of DMF. After about 1 hour, a solution of 8.65 g (32.31 mmol) of 2-chloro-4,6-diphenyltriazine dissolved in 100 mL of DMF was added thereto and stirred for about 12 hours. Subsequently, distilled water was added thereto, and a resulting solid was filtered under a reduced pressure, followed by recrystallization with EA and DMF to obtain 8.77 g (14.54 mmol, Yield: 54%) of Compound 1.

MS: m/z 603.24 [M]⁺

¹H NMR (CDCl₃) δ 8.55 (1H), 8.32 (1H), 8.28 (4H), 8.12 (1H), 7.94 (1H), 7.63 (1H), 7.51 (4H), 7.50 (1H), 7.41 (2H), 7.40 (1H), 7.37 (1H), 7.33 (1H), 7.30 (1H), 7.29 (1H), 7.26 (1H), 7.25 (1H), 1.72 (6H)

### Synthesis Example 2

### Synthesis of Compound 2

Compound 2 (Yield: 52%) was synthesized in the same manner as in Synthesis Example 1, except that benzophenone was used instead of acetone to synthesize Intermediate 1-2.

MS: m/z 727.27 [M]⁺

¹H NMR (CDCl₃) δ 8.55 (1H), 8.28 (4H), 8.25 (1H), 8.12 (1H), 7.94 (1H), 7.63 (1H), 7.51 (4H), 7.50 (1H), 7.41 (2H), 7.39 (1H), 7.33 (6H), 7.29 (1H), 7.26 (2H), 7.25 (1H), 7.23 (1H), 7.22 (1H), 7.11 (4H)

### Synthesis Example 3

### Synthesis of Compound 3

Compound 3 was synthesized according to Reaction Scheme 2:

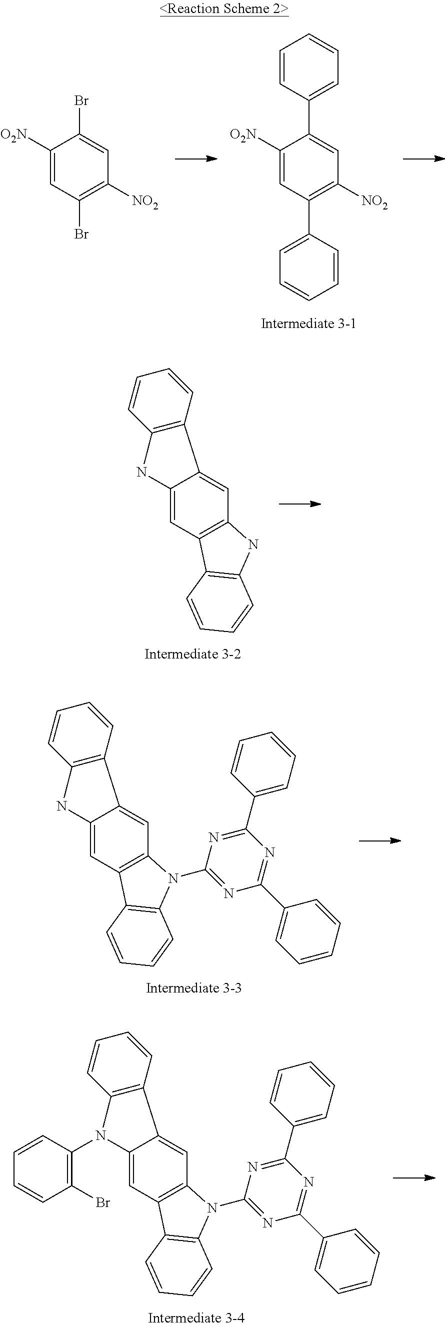 [SMILES: O=[N+]([O-])c1cc(Br)c([N+](=O)[O-])cc1Br ; O=[N+]([O-])c1cc(-c2ccccc2)c([N+](=O)[O-])cc1-c1ccccc1 ; c1ccc2c(c1)[nH]c1cc3c(cc12)[nH]c1ccccc13 ; c1ccc(-c2nc(-c3ccccc3)nc(-n3c4ccccc4c4cc5[nH]c6ccccc6c5cc43)n2)cc1 ; Brc1ccccc1-n1c2ccccc2c2cc3c(cc21)c1ccccc1n3-c1nc(-c2ccccc2)nc(-c2ccccc2)n1]

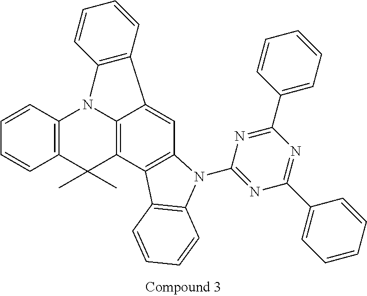 [SMILES: CC1(C)c2ccccc2-n2c3ccccc3c3cc4c(c1c32)c1ccccc1n4-c1nc(-c2ccccc2)nc(-c2ccccc2)n1]

### Synthesis of Intermediate 3-1

20 g (61.76 mmol) of 1,4-dibromo-2,5-dinitrobenzene, 18.83 g (154.40 mmol) of 1-phenylboronic acid, 4.32 g (3.71 mmol) of Pd(PPh₃)₄, 90.88 mL (185.28 mmol) of a 2M aqueous K₂CO₃ solution, 200 mL of toluene, and 100 mL of ethanol were mixed and stirred under reflux. After about 10 hours, the temperature was cooled down to ambient temperature, followed by adding distilled water, extraction with EA, drying using magnesium sulfate, and distillation under a reduced pressure. A resulting product was separated by column chromatography to obtain 17.79 g (55.58 mmol, Yield: 90%) of Intermediate 3-1.

### Synthesis of Intermediate 3-2

Intermediate 3-2 was synthesized in the same manner as in the synthesis of Intermediate 1-6 in Synthesis Example 1, except that Intermediate 3-1 instead of Intermediate 1-5 was used.

### Synthesis of Intermediate 3-3

Intermediate 3-3 was synthesized in the same manner as in the synthesis of Compound 1 in Synthesis Example 1, except that Intermediate 3-2 instead of Intermediate 1-6 was used.

### Synthesis of Intermediate 3-4

Intermediate 3-4 was synthesized in the same manner as in the synthesis of Intermediate 1-1 in Synthesis Example 1, except that Intermediate 3-3 instead of carbazole was used.

### Synthesis of Compound 3

Compound 3 (Yield: 56%) was synthesized in the same manner as in the synthesis of Intermediate 1-2 in Synthesis Example 1, except that Intermediate 3-4 instead of Intermediate 1-1 was used.

MS: m/z 603.24 [M]⁺

¹H NMR (CDCl₃) δ 8.55 (1H), 8.28 (4H), 8.12 (1H), 7.94 (1H), 7.63 (1H), 7.51 (4H), 7.50 (1H), 7.41 (2H), 7.40 (1H), 7.37 (2H), 7.33 (1H), 7.30 (1H), 7.29 (1H), 7.26 (1H), 7.25 (1H), 1.72 (6H)

### Synthesis Example 4

### Synthesis of Compound 4

Compound 4 (Yield: 60%) was synthesized in the same manner as in Synthesis Example 1, except that 2-(4-chlorophenyl)-4,6-diphenyltriazine was used instead of 2-chloro-4,6-diphenyltriazine.

MS: m/z 679.27 [M]⁺

¹H NMR (CDCl₃) δ 8.55 (1H), 8.32 (1H), 8.28 (4H), 8.12 (1H), 7.94 (1H), 7.79 (2H), 7.68 (2H), 7.63 (1H), 7.51 (4H), 7.50 (1H), 7.41 (2H), 7.40 (1H), 7.37 (1H), 7.33 (1H), 7.30 (1H), 7.29 (1H), 7.26 (1H), 7.25 (1H), 1.72 (6H)

### Synthesis Example 5

### Synthesis of Compound 10

Compound 10 was synthesized according to Reaction Scheme 3:

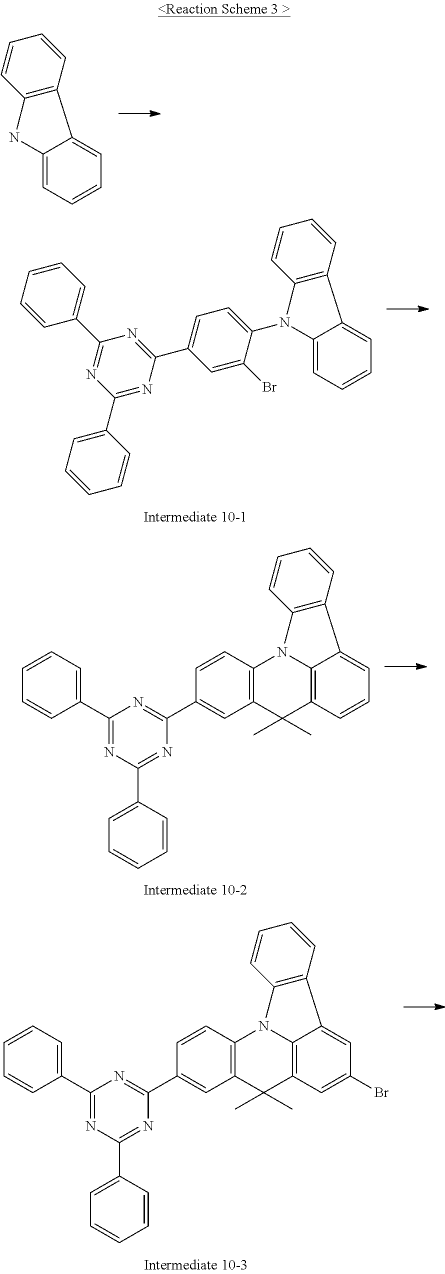 [SMILES: c1ccc2c(c1)[nH]c1ccccc12 ; Brc1cc(-c2nc(-c3ccccc3)nc(-c3ccccc3)n2)ccc1-n1c2ccccc2c2ccccc21 ; CC1(C)c2cc(-c3nc(-c4ccccc4)nc(-c4ccccc4)n3)ccc2-n2c3ccccc3c3cccc1c32 ; CC1(C)c2cc(-c3nc(-c4ccccc4)nc(-c4ccccc4)n3)ccc2-n2c3ccccc3c3cc(Br)cc1c32]

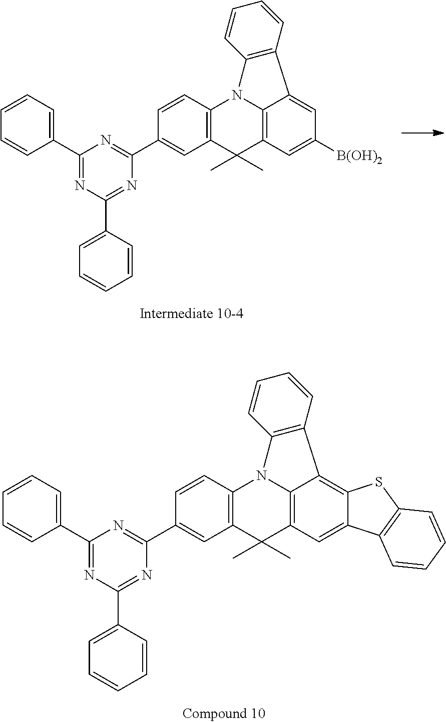 [SMILES: CC1(C)c2cc(-c3nc(-c4ccccc4)nc(-c4ccccc4)n3)ccc2-n2c3ccccc3c3cc(B(O)O)cc1c32 ; CC1(C)c2cc(-c3nc(-c4ccccc4)nc(-c4ccccc4)n3)ccc2-n2c3ccccc3c3c4sc5ccccc5c4cc1c32]

### Synthesis of Intermediate 10-1

Intermediate 10-1 was synthesized in the same manner as in the synthesis of Intermediate 1-1 in Synthesis Example 1, except that 2-(3-bromo-4-iodophenyl)-4,6-diphenyl-1,3-,5-triazine, instead of 2-bromoiodobenzene used to synthesize Intermediate 1-1, was used.

### Synthesis of Intermediates 10-2, 10-3, and 10-4

Intermediates 10-2, 10-3, and 10-4 were synthezied in the same manner as in the synthesis of Intermediate 1-2, 1-3, and 1-4, respectively, in Synthesis Example 1, except that Intermediate 10-1 was used intead of Intermediate 1-1.

### Synthesis of Compound 10

Compound 10 (Yield: 48%) was synthezied in the same manner as in the synthesis of Intermediate 1-5 in Synthesis Example 1, except that Intermediate 10-4 and 2-bromobenzenethiol were instead of Intermediate 1-4 and bromo-2-nitrobenzene, respectively.

MS: m/z 620.20 [M]⁺

¹H NMR (CDCl₃) δ 8.45 (1H), 8.28 (4H), 8.12 (1H), 7.98 (1H), 7.86 (1H), 7.68 (1H), 7.63 (1H), 7.61 (1H), 7.60 (1H), 7.52 (1H), 7.51 (4H), 7.50 (2H), 7.41 (2H), 7.29 (1H), 1.72 (6H)

### Synthesis Example 6

### Synthesis of Compound 11

Compound 11 (Yield: 50%) was synthesized in the same manner as in Synthesis Example 10, except that 2-bromophenol, instead of 2-bromobenzene thiol used to synthesize Compound 1, was used.

MS: m/z 604.23 [M]⁺

¹H NMR (CDCl₃) δ 8.28 (4H), 8.12 (1H), 7.89 (1H), 7.86 (1H), 7.66 (1H), 7.63 (1H), 7.61 (1H), 7.60 (1H), 7.51 (4H), 7.50 (1H), 7.41 (2H), 7.38 (1H), 7.36 (1H), 7.32 (1H), 7.29 (1H), 1.72 (6H)

### Synthesis Example 7

### Synthesis of Compound 14

Compound 14 was synthesized according to Reaction Scheme 4:

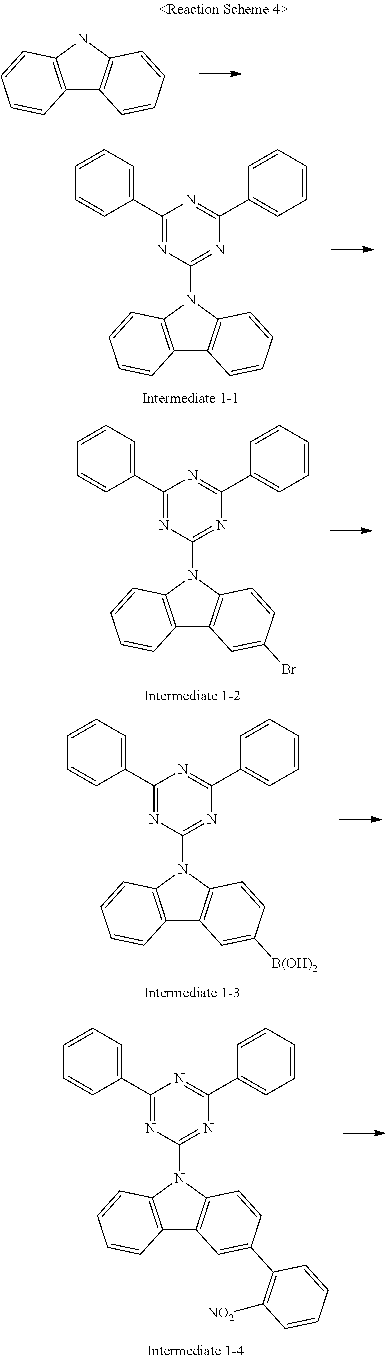

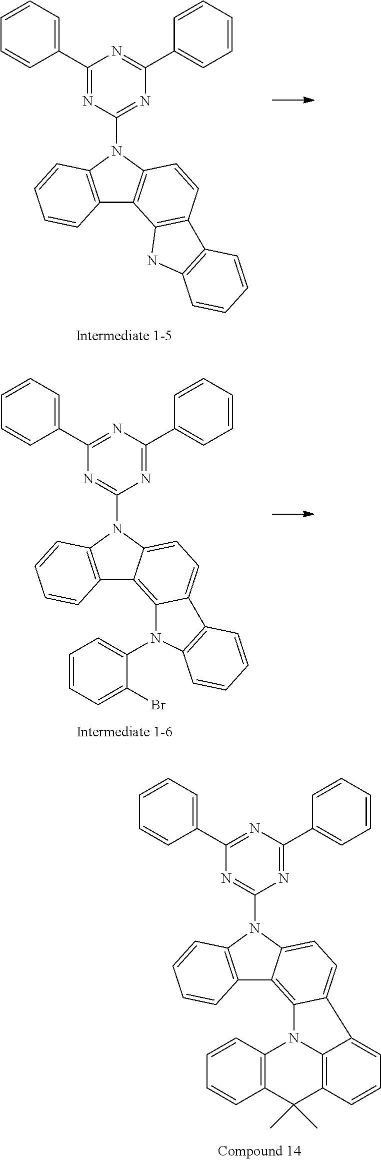 [SMILES: c1ccc(-c2nc(-c3ccccc3)nc(-n3c4ccccc4c4c5[nH]c6ccccc6c5ccc43)n2)cc1 ; Brc1ccccc1-n1c2ccccc2c2ccc3c(c4ccccc4n3-c3nc(-c4ccccc4)nc(-c4ccccc4)n3)c21 ; CC1(C)c2ccccc2-n2c3c1cccc3c1ccc3c(c4ccccc4n3-c3nc(-c4ccccc4)nc(-c4ccccc4)n3)c12]

### Synthesis of Intermediate 1-1

20 g (119.61 mmol) of carbazole was dissolved in 100 mL of DMF to obtain a solution, which was then put into a reaction vessel in which 7.07 g (179.42 mmol, 60% dispersion in mineral oil) of NaH was dissolved in 100 mL of DMF. After about 1 hour, 38.42 g (143.53 mmol) of 2-chloro-4,6-diphenyltriazine dissolved in 100 mL of DMA was added thereto and stirred for about 12 hours. Subsequently, distilled water was added thereto, and a resulting solid was filtered under a reduced pressure, followed by recrystallization with EA and DMF to obtain 25.74 g (64.59 mmol, Yield: 54%) of Intermediate 1-1.

### Synthesis of Intermediate 1-2

20 g (50.19 mmol) of Intermediate 1-1 was dissolved in 200 mL of DMF, and 9.83 g (55.21 mmol) of N-bromosuccinimide (NBS) was added thereto. After stirring at room temperature for about 10 hours, the organic solvent was distilled under a reduced pressure. Subsequently, distilled water was added thereto, followed by extraction with EA, drying using magnesium sulfate, and distillation under a reduced pressure. A resulting product was separated by column chromatography to obtain 22.04 g (41.90 mmol, Yield: 92%) of Intermediate 1-2.

### Synthesis of Intermediate 1-3

20 g (41.90 mmol) of Intermediate 1-2 was dissolved in 200 mL of tetrahydrofuran (THF), and 16.76 mL (41.90 mmol, 2.5M in hexane) of n-buLi was slowly added thereto at about −78° C. After stirring for about 1 hour, 6.07 mL (54.47 mmol) of trimethyl borate was added thereto, and the temperature was slowly increased to ambient temperature, followed by stirring for about 12 hours. After distilled water was added thereto, followed by extraction with EA, drying using magnesium sulfate, and then distillation under a reduced pressure. A resulting product was separated by column chromatography to obtain 7.41 g (16.67 mmol, Yield: 40%) of Intermediate 1-3.

### Synthesis of Intermediate 1-4

10 g (22.61 mmol) of Intermediate 1-3, 5.48 g (27.13 mmol) of bromo-2-nitrobenzene, 0.79 g (0.68 mmol) of tetrakis(triphenylphosphine)palladium(0) (Pd(PPh₃)₄), 22.18 mL (45.22 mmol) of a 2M aqueous K₂CO₃ solution, 80 mL of toluene, and 30 mL of ethanol were mixed and stirred under reflux. After about 4 hours, the temperature was cooled down to ambient temperature, followed by adding distilled water, extraction with EA, drying using magnesium sulfate, and distillation under a reduced pressure. A resulting product was separated by column chromatography to obtain 8.69 g (16.73 mmol, Yield: 74%) of Intermediate 1-4.

### Synthesis of Intermediate 1-5

10 g (19.25 mmol) of Intermediate 1-4 was mixed with 100 mL of triethylphosphite and stirred at about 180° C. After about 10 hours, the temperature was cooled down to ambient temperature, and the organic solvent was distilled under a reduced pressure. Subsequently, distilled water was added thereto, followed by extraction with EA, drying using magnesium sulfate, and distillation under a reduced pressure. A resulting product was separated by column chromatography to obtain 5.62 g (11.55 mmol, Yield: 60%) of Intermediate 1-5.

### Synthesis of Intermediate 1-6

10 g (20.55 mmol) of Intermediate 1-5, 11.63 g (41.11 mmol) of 2-bromoiodobenzene, 1.96 g (10.28 mmol) of copper iodide, and 5.68 g (41.11 mmol) of potassium carbonate were dissolved in xylene under nitrogen atmosphere, and stirred under reflux. After about 12 hours, the temperature was cooled down to room temperature, followed by adding distilled water, extraction with MC, drying using magnesium sulfate, and then distillation under a reduced pressure. A resulting product was separated by column chromatography to obtain 5.55 g (8.63 mmol, Yield: 42%) of Intermediate 1-6.

### Synthesis of Compound 14

10 g (15.56 mmol) of Intermediate 1-6 was dissolved in 100 mL of THF, and 6.22 mL (15.56 mmol, 2.5M in hexane) of n-buLi was slowly added thereto at about −78° C. After stirring for aout 2 hours, 1.20 mL (20.23 mmol) of acetone was added thereto, and the temperature was slowly increased to ambient temperature, followed by adding an aqueous NaHCO₃ solution and extraction with MC. A result product was dried using magnesium sulfate, followed by distillation under a reduced pressure, and then mixing with 100 mL of acetic acid in a 2-necked flask. A catalytic amount of an aqueous HCl solution (5 mol %, 12N) was added thereto, stirred under reflux for about 12 hours, and then cooled down to ambient temperature. Subsequently, distilled water was added thereto, followed by extraction with MC, drying using magnesium sulfate, and distillation under a reduced pressure. A resulting product was separated by column chromatography to obtain 5.45 g (9.03 mmol, Yield: 58%) of Compound 14.

MS: m/z 603.24 [M]⁺

¹H NMR (CDCl₃) δ 7.55 (2H), 7.48 (4H), 7.40 (1H), 7.37 (1H), 7.32 (4H), 7.22 (2H), 7.20 (2H), 7.10 (2H), 7.08 (1H), 7.00 (2H), 6.95 (1H), 6.92 (1H), 1.67 (6H)

### Synthesis Example 8

### Synthesis of Compound 15

10 g (15.56 mmol) of Intermediate 1-6, synthesized in the same manner as in Synthesis Example 7, was mixed with 100 mL of THF, and 6.22 mL (15.56 mmol, 2.5M in hexane) of n-buLi was slowly added thereto at about −78° C. After stirring for about 2 hours, 3.69 g (20.23 mmol) of benzophenone dissolved in 50 mL of THF was added thereto, and the temperature was slowly increased to ambient temperature, followed by adding an aqueous NaHCO₃ solution and extraction with MC. A catalytic amount of an aqueous HCl solution (5 mol %, 12N) was added thereto, stirred under reflux for about 12 hours, and then cooled down to room temperature. Subsequently, distilled water was added thereto, followed by extraction with MC, drying using magnesium sulfate, and distillation under a reduced pressure. A resulting product was separated by column chromatography to obtain 6.12 g (8.40 mmol, Yield: 54%) of Compound 15.

MS: m/z 727.27 [M]⁺

¹H NMR (CDCl₃) δ 7.55 (2H), 7.48 (4H), 7.40 (1H), 7.36 (1H), 7.32 (4H), 7.22 (2H), 7.14 (4H), 7.10 (4H), 7.08 (1H), 7.07 (2H), 7.06 (4H), 7.00 (2H), 6.88 (2H)

### Synthesis Example 9

### Synthesis of Compound 16

Compound 16 was synthesized according to Reaction Scheme 5:

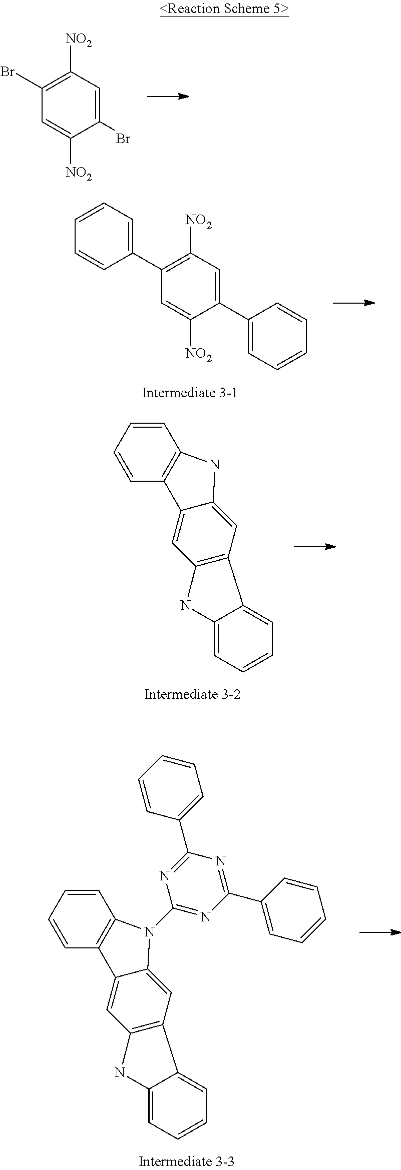

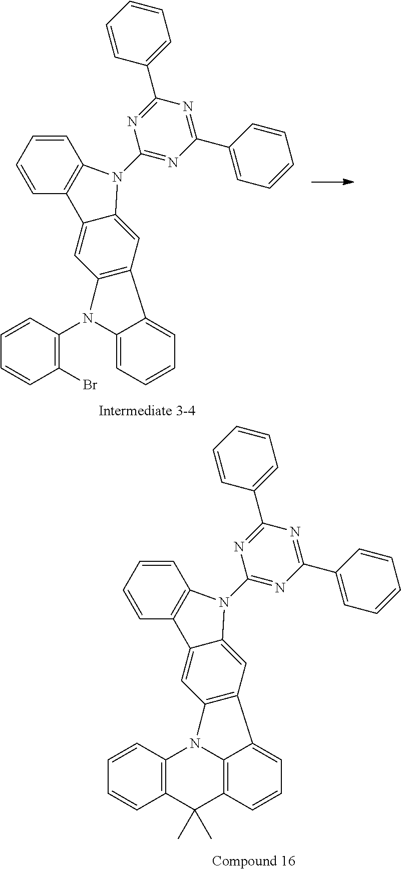 [SMILES: Brc1ccccc1-n1c2ccccc2c2cc3c(cc21)c1ccccc1n3-c1nc(-c2ccccc2)nc(-c2ccccc2)n1 ; CC1(C)c2ccccc2-n2c3cc4c5ccccc5n(-c5nc(-c6ccccc6)nc(-c6ccccc6)n5)c4cc3c3cccc1c32]

### Synthesis of Intermediate 3-1

20 g (61.36 mmol) of 1,4-dibromo-2,5-dinitrobenzene, 18.7 g (153.40 mmol) of 1-phenylboronic acid, 4.30 g (3.68 mmol) of Pd(PPh₃)₄, 90.29 mL (184.08 mmol) of a 2M aqueous K₂CO₃ solution, 200 mL of toluene, and 100 mL of ethanol were mixed and stirred under reflux. After about 10 hours, the temperature was cooled down to ambient temperature, followed by adding distilled water, extraction with EA, drying using magnesium sulfate, and distillation under a reduced pressure. A resulting product was separated by column chromatography to obtain 16.99 g (53.38 mmol, Yield: 87%) of Intermediate 3-2.

### Synthesis of Intermediate 3-2

9.27 g (36.44 mmol, Yield: 58%) of Intermediate 3-2 was synthesized in the same manner as in the synthesis of Intermediate 1-5 in Synthesis Example 7, except that 20 g (62.83 mmol) of Intermediate 3-1 and 200 mL of triethylphosphite, instead of 10 g of Intermediate 1-4 and 100 mL of triethylphosphite in Synthesis Example 7, respectively, were used.

### Synthesis of Intermediate 3-3

20 g (78.65 mmol) of Intermediate 3-2 was dissolved in 100 mL of DMF to obtain a solution, which was then put into a reaction vessel in which 4.65 g (117.98 mmol, a 60% dispersion in mineral oil) of NaH was dissolved in 100 mL of DMF. After about 1 hour, 37.90 g (141.57 mmol) of 2-chloro-4,6-diphenyltriazine dissolved in 100 mL of DMF was added thereto and stirred for about 12 hours. Subsequently, distilled water was added thereto, and a resulting solid was filtered under a reduced pressure, followed by recrystallization with EA and DMF to obtain 10.71 g (22.02 mmol, Yield: 28%) of Intermediate 3-3.

### Synthesis of Intermediate 3-4

5.28 g (8.22 mmol, Yield: 40%) of Intermediate 3-4 was synthesized in the same manner as in the synthesis of Intermediate 1-6 in Synthesis Example 7, except that Intermediate 3-3, instead of Intermediate 1-5 in Synthesis Example 7, was used.

### Synthesis of Compound 16

5.07 g (8.40 mmol, Yield: 54%) of Compound 16 was synthesized in the same manner as in the synthesis of Compound 14 in Synthesis Example 7, except that Intermediate 3-4, instead of Intermediate 1-6 in Synthesis Example 7, was used.

MS: m/z 603.24 [M]⁺

¹H NMR (CDCl₃) δ 7.55 (2H), 7.48 (4H), 7.40 (2H), 7.37 (1H), 7.32 (4H), 7.22 (2H), 7.20 (2H), 7.10 (2H), 7.08 (1H), 7.00 (1H), 6.95 (1H), 6.92 (1H), 1.67 (6H)

### Synthesis Example 10

### Synthesis of Compound 17

Compound 17 was synthesized according to Reaction Scheme 6:

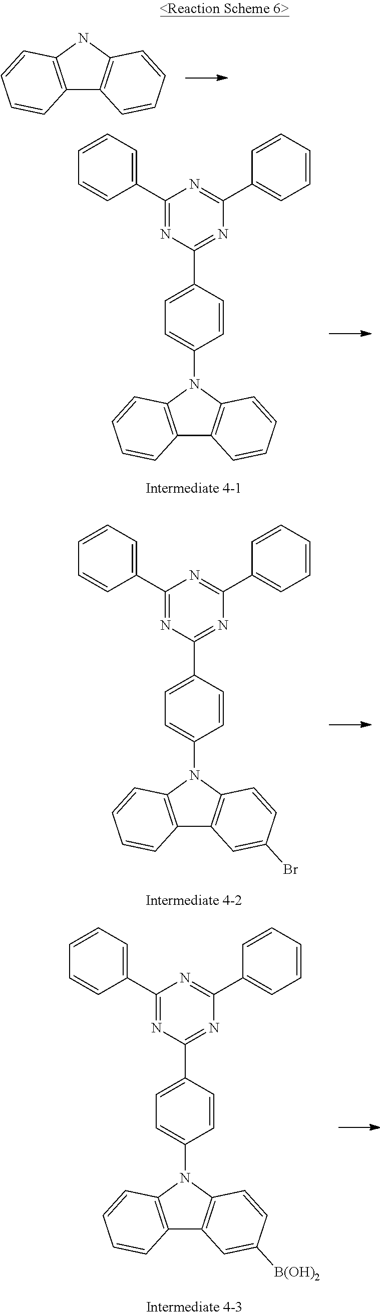

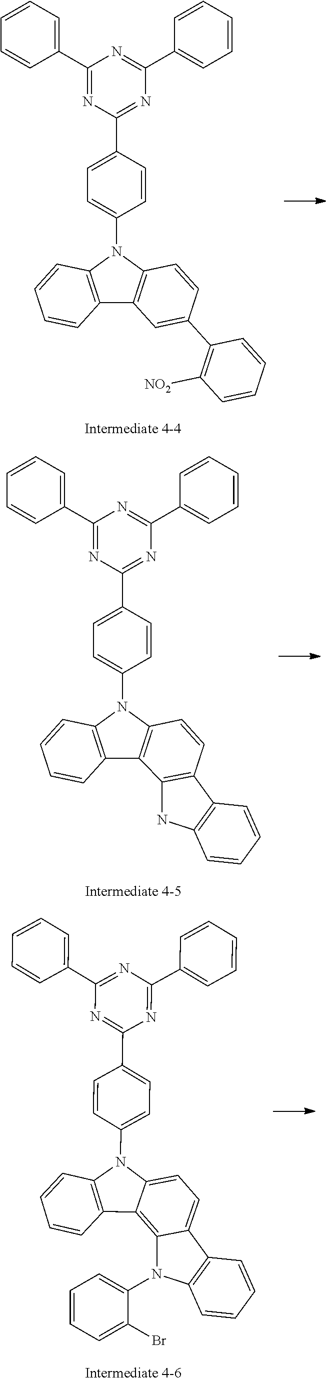 [SMILES: O=[N+]([O-])c1ccccc1-c1ccc2c(c1)c1ccccc1n2-c1ccc(-c2nc(-c3ccccc3)nc(-c3ccccc3)n2)cc1 ; c1ccc(-c2nc(-c3ccccc3)nc(-c3ccc(-n4c5ccccc5c5c6[nH]c7ccccc7c6ccc54)cc3)n2)cc1 ; Brc1ccccc1-n1c2ccccc2c2ccc3c(c4ccccc4n3-c3ccc(-c4nc(-c5ccccc5)nc(-c5ccccc5)n4)cc3)c21]

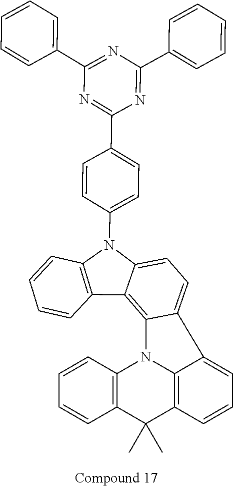 [SMILES: CC1(C)c2ccccc2-n2c3c1cccc3c1ccc3c(c4ccccc4n3-c3ccc(-c4nc(-c5ccccc5)nc(-c5ccccc5)n4)cc3)c12]

### Synthesis of Intermediate 4-1

31.79 g (66.98 mmol, Yield: 56%) of Intermediate 4-1 was synthesized in the same manner as in the synthesis of intermediate 1-1 in Synthesis Example 7, except that 49.35 g (143.53 mmol) of 2-(4-chlorophenyl)-4,6-diphenyltriazine, instead of 2-chloro-4,6-diphenyltriazine, was used.

### Synthesis of Intermediate 4-2

20.99 g (37.93 mmol, Yield: 90%) of Intermediate 4-2 was synthesized in the same manner as in the synthesis of Intermediate 1-2 in Synthesis Example 7, except that 20 g (42.14 mmol) of Intermediate 4-1, instead of Intermediate 1-1 in Synthesis Example 7, was used, and the amount of NBS was adjusted to 9.00 g (50.57 mmol).

### Synthesis of Intermediate 4-3

20 g (36.14 mmol) of Intermediate 4-2 was dissolved in 200 mL of tetrahydrofuran (THF), and 14.45 mL (41.90 mmol, 2.5M in hexane) of n-buLi was slowly added thereto at about −78° C. After stirring for about 1 hour, 5.23 mL (46.98 mmol) of trimethyl borate was added thereto, and the temperature was slowly increased to ambient temperature, followed by stirring for about 12 hours. After distilled water was added thereto, followed by extraction with EA, drying using magnesium sulfate, and then distillation under a reduced pressure. A resulting product was separated by column chromatography to obtain 7.49 g (14.45 mmol, Yield: 40%) of Intermediate 4-3.

### Synthesis of Intermediate 4-4

10 g (19.29 mmol) of Intermediate 4-3, 4.67 g (23.15 mmol) of bromo-2-nitrobenzene, 0.68 g (0.58 mmol) of Pd(PPh₃)₄, 18.92 mL (38.58 mmol) of a 2M aqueous K₂CO₃ solution, 80 mL of toluene, and 30 mL of ethanol were mixed and stirred under reflux. After about 4 hours, the temperature was cooled down to ambient temperature, followed by adding distilled water, extraction with EA, drying using magnesium sulfate, and distillation under a reduced pressure. A resulting product was column-separated to obtain 8.27 g (13.89 mmol, Yield: 72%) of Intermediate 4-4.

### Synthesis of Intermediate 4-5

5.67 g (10.07 mmol, Yield: 60%) of Intermediate 4-5 was synthesized in the same manner as in the synthesis of Intermediate 1-5 in Synthesis Example 7, except that 10 g (16.79 mmol) of Intermediate 4-4, instead of Intermediate 1-4 in Synthesis Example 7, was used.

### Synthesis of Intermediate 4-6

10 g (17.77 mmol) of Intermediate 4-5, 10.06 g (35.55 mmol) of 2-bromoiodobenzene, 1.69 g (8.89 mmol) of copper iodide, and 4.91 g (35.55 mmol) of potassium carbonate were dissolved in xylene under nitrogen atmosphere, and stirred under reflux. After about 12 hours, the temperature was cooled down to ambient temperature, followed by adding distilled water, extraction with MC, drying using magnesium sulfate, and then distillation under a reduced pressure. A resulting product was separated by column chromatography to obtain 5.11 g (7.11 mmol, Yield: 40%) of Intermediate 4-6.

### Synthesis of Compound 17

10 g (13.91 mmol) of Intermediate 4-6 was dissolved in 100 mL of THF, and 5.56 mL (13.91 mmol, 2.5M in hexane) of n-buLi was slowly added thereto at about −78° C. After stirring for about 2 hours, 1.05 mL (18.09 mmol) of acetone was added thereto, and the temperature was slowly increased to ambient temperature, followed by adding an aqueous NaHCO₃ solution and extraction with MC. A resulting product was dried using magnesium sulfate, followed by distillation under a reduced pressure, and then mixing with 100 mL of acetic acid in a 2-necked flask. A catalytic amount of an aqueous HCl solution (5 mol %, 12N) was added thereto, stirred under reflux for about 12 hours, and then cooled down to ambient temperature. Subsequently, distilled water was added thereto, followed by extraction with MC, drying using magnesium sulfate, and distillation under a reduced pressure. A resulting product was separated by column chromatography to obtain 5.68 g (8.35 mmol, Yield: 60%) of Compound 17.

MS: m/z 679.27 [M]⁺

¹H NMR (CDCl₃) δ 7.55 (2H), 7.50 (2H), 7.48 (4H), 7.40 (1H), 7.37 (1H), 7.32 (4H), 7.30 (2H), 7.22 (2H), 7.20 (2H), 7.10 (2H), 7.08 (1H), 7.00 (2H), 6.95 (1H), 6.92 (1H), 1.67 (6H)

### Synthesis Example 11

### Synthesis of Compound 23

Compound 23 was synthesized according to Reaction Scheme 7:

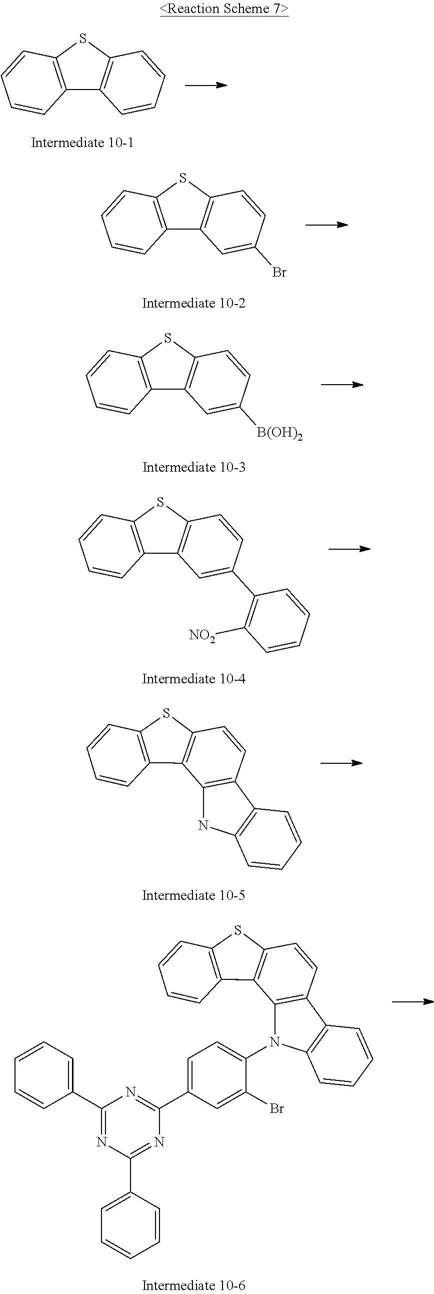 [SMILES: c1ccc2c(c1)sc1ccccc12 ; Brc1ccc2sc3ccccc3c2c1 ; OB(O)c1ccc2sc3ccccc3c2c1 ; O=[N+]([O-])c1ccccc1-c1ccc2sc3ccccc3c2c1 ; c1ccc2c(c1)[nH]c1c2ccc2sc3ccccc3c21 ; Brc1cc(-c2nc(-c3ccccc3)nc(-c3ccccc3)n2)ccc1-n1c2ccccc2c2ccc3sc4ccccc4c3c21]

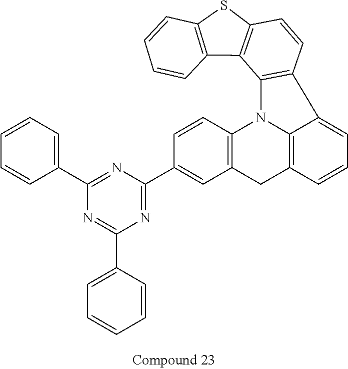 [SMILES: c1ccc(-c2nc(-c3ccccc3)nc(-c3ccc4c(c3)Cc3cccc5c6ccc7sc8ccccc8c7c6n-4c35)n2)cc1]

### Synthesis of Intermediate 10-2

Intermediate 10-2 was synthesized in the same manner as in the synthesis of Intermediate 1-2 in Synthesis Example 7, except that Intermediate 10-1, instead of Intermediate 1-1 in Synthesis Example 7, was used.

### Synthesis of Intermediate 10-3

Intermediate 10-3 was synthesized in the same manner as in the synthesis of Intermediate 1-3 in Synthesis Example 7, except that Intermediate 10-2, instead of Intermediate 1-2 in Synthesis Example 7, was used.

### Synthesis of Intermediate 10-4

Intermediate 10-4 was synthesized in the same manner as in the synthesis of Intermediate 1-4 in Synthesis Example 7, except that Intermediate 10-3, instead of Intermediate 1-3 in Synthesis Example 7, was used.

### Synthesis of Intermediate 10-5

Intermediate 10-5 was synthesized in the same manner as in the synthesis of Intermediate 1-5 in Synthesis Example 7, except that Intermediate 10-4, instead of Intermediate 1-4 in Synthesis Example 7, was used.

### Synthesis of Intermediate 10-6

Intermediate 10-6 was synthesized in the same manner as in the synthesis of Intermediate 1-6 in Synthesis Example 7, except that Intermediate 10-5 and 2-(4-bromo-3-iodo-phenyl)-4,6-diphenyl-triazine, instead of Intermediate 1-5 and 2-bromoiodobenzene in Synthesis Example 7, respectively, were used.

### Synthesis of Compound 23

Compound 23 (Yield: 52%) was synthesized in the same manner as in the synthesis of Compound 14 in Synthesis Example 7, except that Intermediate 10-6, instead of Intermediate 1-6 in Synthesis Example 7, was used.

MS: m/z 620.20 [M]⁺

¹H NMR (CDCl₃) δ 7.86 (2H), 7.78 (1H), 7.48 (4H), 7.37 (1H), 7.33 (1H), 7.32 (4H), 7.30 (2H), 7.22 (2H), 7.20 (1H), 6.95 (1H), 6.92 (1H), 1.67 (6H)

### Synthesis Example 12

### Synthesis of Compound 24

Compound 24 (Yield: 54%) was synthesized in the same manner as in Synthesis Example 11, except that Intermediate 11-1, instead of Intermediate 10-1 in Synthesis Example 7, was used.

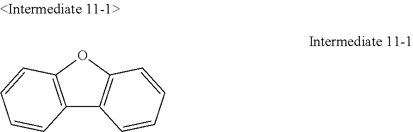 [SMILES: c1ccc2c(c1)oc1ccccc12]

MS: m/z 604.23 [M]⁺

¹H NMR (CDCl₃) δ 7.49 (1H), 7.48 (4H), 7.42 (2H), 7.37 (1H), 7.32 (4H), 7.30 (2H), 7.22 (2H), 7.20 (1H), 7.19 (2H), 7.13 (1H), 6.95 (1H), 6.92 (1H), 1.67 (6H)

### Synthesis Example 13

### Synthesis of Compound 27

Compound 27 was synthesized according to Reaction Scheme 13:

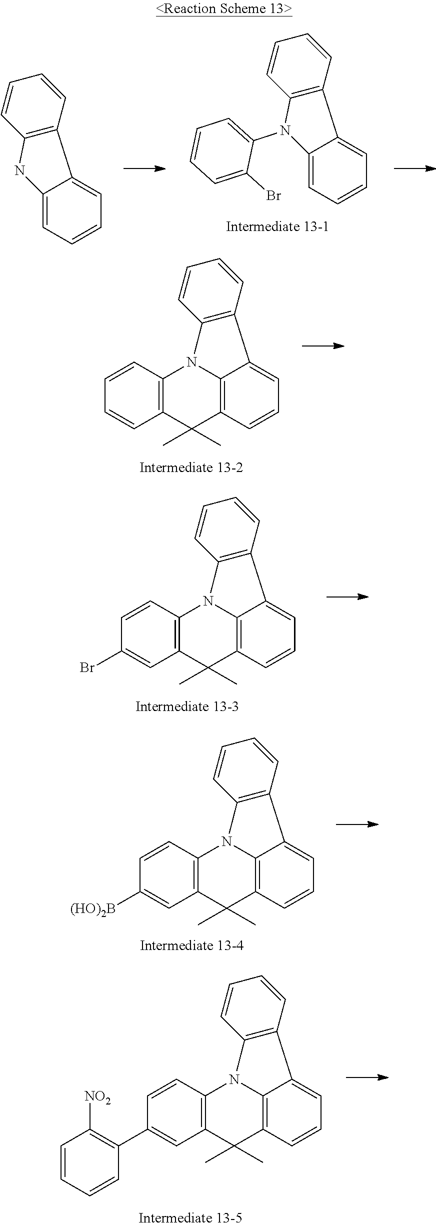 [SMILES: c1ccc2c(c1)[nH]c1ccccc12 ; Brc1ccccc1-n1c2ccccc2c2ccccc21 ; CC1(C)c2ccccc2-n2c3ccccc3c3cccc1c32 ; CC1(C)c2cc(Br)ccc2-n2c3ccccc3c3cccc1c32 ; CC1(C)c2cc(B(O)O)ccc2-n2c3ccccc3c3cccc1c32 ; CC1(C)c2cc(-c3ccccc3[N+](=O)[O-])ccc2-n2c3ccccc3c3cccc1c32]

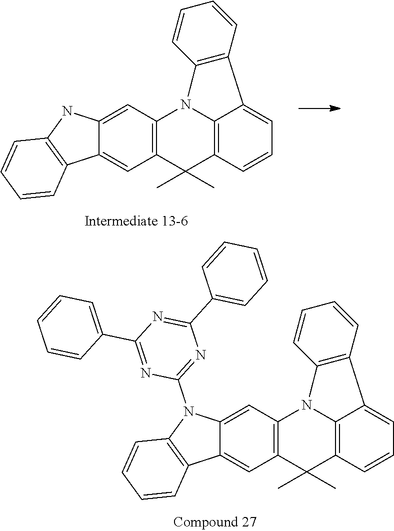 [SMILES: CC1(C)c2cc3c(cc2-n2c4ccccc4c4cccc1c42)[nH]c1ccccc13 ; CC1(C)c2cc3c4ccccc4n(-c4nc(-c5ccccc5)nc(-c5ccccc5)n4)c3cc2-n2c3ccccc3c3cccc1c32]

### Synthesis of Intermediate 13-2

Intermediate 13-2 was synthesized in the same manner as in the synthesis of Intermediate 1-2 in Synthesis Example 1, except that Intermediate 13-1, instead of Intermediate 1-1 in Synthesis Example 1, was used.

### Synthesis of Intermediate 13-3

Intermediate 13-3 was synthesized in the same manner as in the synthesis of Intermediate 1-3 in Synthesis Example 1, except that Intermediate 13-2, instead of Intermediate 1-2 in Synthesis Example 1, was used.

### Synthesis of Intermediate 13-4

Intermediate 13-4 was synthesized in the same manner as in the synthesis of Intermediate 1-4 in Synthesis Example 1, except that Intermediate 13-3, instead of Intermediate 1-3 in Synthesis Example 1, was used.

### Synthesis of Intermediate 13-5

Intermediate 13-5 was synthesized in the same manner as in the synthesis of Intermediate 1-5 in Synthesis Example 1, except that Intermediate 13-4, instead of Intermediate 1-4 in Synthesis Example 1, was used.

### Synthesis of Intermediate 13-6

Intermediate 13-6 was synthesized in the same manner as in the synthesis of Intermediate 1-6 in Synthesis Example 1, except that Intermediate 13-5, instead of Intermediate 1-5 in Synthesis Example 1, was used.

### Synthesis of Compound 27

Compound 27 (Yield: 48%) was synthesized in the same manner as in the synthesis of Compound 1 in Synthesis Example 1, except that Intermediate 13-6, instead of Intermediate 1-6 in Synthesis Example 1, was used.

MS: m/z 603.24 [M]⁺

¹H NMR (CDCl₃) δ 8.96 (1H), 8.45 (1H), 8.36 (4H), 8.19 (2H), 7.58 (2H), 7.51 (1H), 7.50 (8H), 7.24 (1H), 7.20 (2H), 6.98 (1H), 1.69 (6H)

### Synthesis Example 14

### Synthesis of Compound 103

Compound 103 was synthesized according to Reaction Scheme 14:

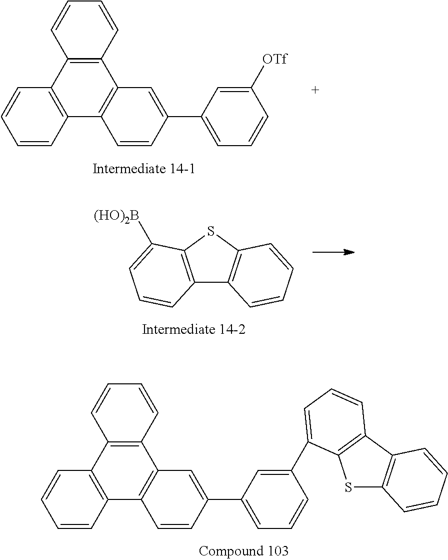 [SMILES: O=S(=O)(Oc1cccc(-c2ccc3c4ccccc4c4ccccc4c3c2)c1)C(F)(F)F ; OB(O)c1cccc2c1sc1ccccc12 ; c1cc(-c2ccc3c4ccccc4c4ccccc4c3c2)cc(-c2cccc3c2sc2ccccc23)c1]

4.52 g (10.0 mmol) of Intermediate 14-1 (4-(3-a triphenylene-2-yl)phenyl trifluoromethanesulfonate), 3.0 g (13.0 mmol) of Intermediate 14-2 (4-dibenzothiophene boronic acid), 0.46 g (0.5 mmol) of bis(dibenzylideneacetone)palladium(0), 0.82 g (2.0 mmol) of 2-dicyclohexylphosphino-2′,6′-dimethoxybiphenyl, and 12.7 g (60.0 mmol) of K₃PO₄ were mixed with 150 mL of toluene and 15 mL of water in a 250-mL round-bottomed flask, stirred under reflux in nitrogen atmosphere for about 24 hours, and then cooled down to ambient temperature. A resulting product was separated by column chromatography to obtain 4.3 g (Yield: 88%) of Compound 103.

### Example 1

A 15 Ω/cm²ITO glass substrate (having a thickness of 1,200 Å, available from Corning) was cut to a size of 50 mm×50 mm×0.5 mm and then sonicated in isopropyl alcohol and pure water each for 10 minutes, and then washed by irradiation of ultraviolet rays for 30 minutes and exposure to ozone. The resulting glass substrate with an ITO anode was mounted into a vacuum deposition device.

2-TNATA was vacuum-deposited on the ITO anode of the glass substrate to form an HIL having a thickness of 600 Å, and then NPB was deposited on the HIL to form a HTL having a thickness of about 200 Å. Subsequently, Compound 1 and Compound 103 as hosts (in a weight ratio of about 1:1) and PD1 as a dopant (8 wt %) were co-deposited on the HTL to form an EML having a thickness of about 300 Å.

ET1 was deposited on the EML to form an ETL having a thickness of about 200 Å, and then ET-D1 was deposited on the ETL to form an EIL having a thickness of about 10 Å. Next, Al was deposited on the EIL to form a cathode having a thickness of about 1,000 Å, thereby completing the manufacture of an organic light-emitting device.

### Example 2

An organic light-emitting device was manufactured in the same manner as in Example 1, except that Compound 2, instead of Compound 1, was used as a host to form the EML.

### Example 3

An organic light-emitting device was manufactured in the same manner as in Example 1, except that Compound 3, instead of Compound 1, was used as a host to form the EML.

### Example 4

An organic light-emitting device was manufactured in the same manner as in Example 1, except that Compound 4, instead of Compound 1, was used as a host to form the EML.

### Example 5

An organic light-emitting device was manufactured in the same manner as in Example 1, except that Compound 10, instead of Compound 1, was used as a host to form the EML.

### Example 6

An organic light-emitting device was manufactured in the same manner as in Example 1, except that Compound 11, instead of Compound 1, was used as a host to form the EML.

### Example 7

An organic light-emitting device was manufactured in the same manner as in Example 1, except that Compound 14, instead of Compound 1, was used as a host to form the EML.

### Example 8

An organic light-emitting device was manufactured in the same manner as in Example 1, except that Compound 15, instead of Compound 1, was used as a host to form the EML.

### Example 9

An organic light-emitting device was manufactured in the same manner as in Example 1, except that Compound 16, instead of Compound 1, was used as a host to form the EML.

### Example 10

An organic light-emitting device was manufactured in the same manner as in Example 1, except that Compound 17, instead of Compound 1, was used as a host to form the EML.

### Example 11

An organic light-emitting device was manufactured in the same manner as in Example 1, except that Compound 23, instead of Compound 1, was used as a host to form the EML.

### Example 12

An organic light-emitting device was manufactured in the same manner as in Example 1, except that Compound 24, instead of Compound 1, was used as a host to form the EML.

### Example 13

An organic light-emitting device was manufactured in the same manner as in Example 1, except that Compound 27, instead of Compound 1, was used as a host to form the EML.

### Comparative Example 1

An organic light-emitting device was manufactured in the same manner as in Example 1, except that CPB, instead of Compound 1 and Compound 103, was used as a host to form the EML.

### Comparative Example 2

An organic light-emitting device was manufactured in the same manner as in Example 1, except that Compound 1 and CPB, instead of Compound 1 and Compound 103, were used as a host to form the EML.

### Comparative Example 3

An organic light-emitting device was manufactured in the same manner as in Example 9, except that Compound 16 and CPB, instead of Compound 16 and Compound 103, were used as a host to form the EML.

### Comparative Example 4

An organic light-emitting device was manufactured in the same manner as in Example 1, except that Compound A and Compound 103, instead of Compound 1 and Compound 103, were used as a host to form the EML.

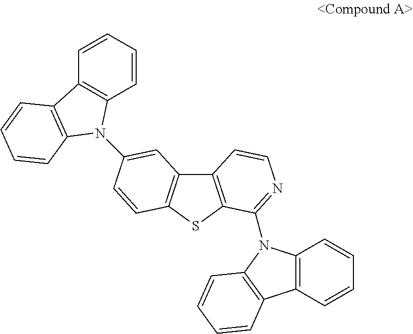 [SMILES: c1ccc2c(c1)c1ccccc1n2-c1ccc2sc3c(-n4c5ccccc5c5ccccc54)nccc3c2c1]

### Comparative Example 5

An organic light-emitting device was manufactured in the same manner as in Example 1, except that Compound B and Compound 103, instead of Compound 1 and Compound 103, were used as a host to form the EML.

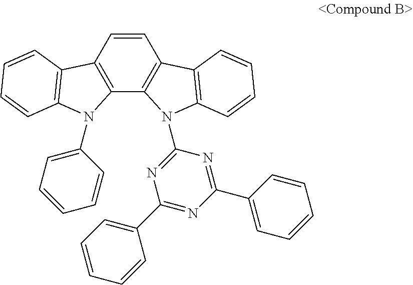 [SMILES: c1ccc(-c2nc(-c3ccccc3)nc(-n3c4ccccc4c4ccc5c6ccccc6n(-c6ccccc6)c5c43)n2)cc1]

### Evaluation Example 1

Driving voltages, efficiencies, and color coordinates of the organic light-emitting devices of Examples 1 to 13 and Comparative Examples 1 to 5 were evaluated by supplying power with a voltage and current meter (Kethley Source-Measure Unit (SMU) 236) and using a luminance meter (PR650 Spectroscan, available from Photo Research, Inc.). The results are shown in Table 1. Lifetime T95 was measured as the time (hour) taken until a measured initial luminance (assumed as 100% @10 mA/cm²) is reduced to 95%.

TABLE 1

| | | | Driving | | Color | | |
|---|---|---|---|---|---|---|---|
| | EML | | voltage | Efficiency | coordinate | | Lifetime |
| Example | host 1 | host 2 | (V) | (cd/A) | CIEx | CIEy | T95 (hr) |
| Example 1 | Compound 1 | Compound 103 | 5.0 | 28.1 | 0.311 | 0.603 | 190 |
| Example 2 | Compound 2 | Compound 103 | 4.2 | 30.1 | 0.312 | 0.602 | 240 |
| Example 3 | Compound 3 | Compound 103 | 4.5 | 29.3 | 0.312 | 0.604 | 250 |
| Example 4 | Compound 4 | Compound 103 | 4.9 | 25.4 | 0.314 | 0.605 | 200 |
| Example 5 | Compound 10 | Compound 103 | 5.3 | 26.2 | 0.312 | 0.602 | 180 |
| Example 6 | Compound 11 | Compound 103 | 5.1 | 27.2 | 0.313 | 0.605 | 200 |
| Example 7 | Compound 14 | Compound 103 | 4.8 | 25.5 | 0.312 | 0.605 | 190 |
| Example 8 | Compound 15 | Compound 103 | 5.0 | 28.4 | 0.311 | 0.604 | 240 |
| Example 9 | Compound 16 | Compound 103 | 4.5 | 26.2 | 0.312 | 0.604 | 280 |
| Example 10 | Compound 17 | Compound 103 | 4.9 | 28.7 | 0.312 | 0.603 | 190 |
| Example 11 | Compound 23 | Compound 103 | 5.1 | 26.2 | 0.313 | 0.607 | 200 |
| Example 12 | Compound 24 | Compound 103 | 4.9 | 26.3 | 0.312 | 0.605 | 220 |
| Example 13 | Compound 27 | Compound 103 | 4.8 | 27.5 | 0.311 | 0.604 | 160 |
| Comparative | CBP | | 5.5 | 25.2 | 0.312 | 0.605 | 80 |
| Example 1 | | | | | | | |
| Comparative | Compound 1 | CBP | 4.9 | 24.8 | 0.311 | 0.604 | 70 |
| Example 2 | | | | | | | |
| Comparative | Compound 16 | CBP | 5.0 | 25.7 | 0.310 | 0.607 | 80 |
| Example 3 | | | | | | | |
| Comparative | Compound A | Compound | 5.8 | 21.5 | 0.310 | 0.605 | 50 |
| Example 4 | | 103 | | | | | |
| Comparative | Compound B | Compound | 4.7 | 23.9 | 0.312 | 0.605 | 140 |
| Example 5 | | 103 | | | | | |

Referring to Table 1, the organic light-emitting devices of Examples 1 to 13 were found to be improved in driving voltage, luminance, efficiency, and lifetime T95, compared to the organic light-emitting devices of Comparative Examples 1 to 5.

As described above, according to the one or more of the above embodiments, an organic light-emitting device including a first compound represented by one of Formulae 1-1 to 1-3 and a second compound represented by Formula 2 in an organic layer may have a high efficiency and long lifetime.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode opposite to the first electrode; and
an organic layer between the first electrode and the second electrode, the organic layer including an emission layer,
wherein the organic layer includes a first compound and a second compound, the first compound being represented by one of the following Formulae 1-1 to 1-3, and the second compound being represented by the following Formula 2: 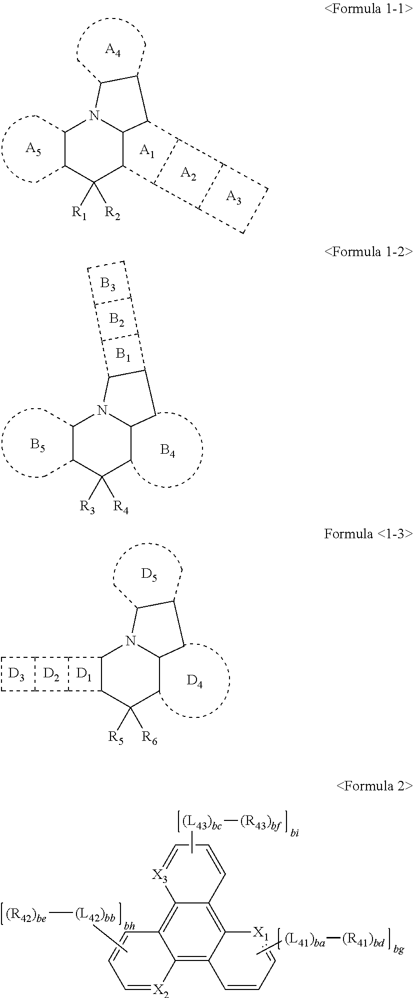
wherein, in Formulae 1-1 to 1-3 and Formula 2,
ring A₁, ring A₂, and ring A₃ are condensed together, ring B₁, ring B₂, and ring B₃ are condensed together, and ring D₁, ring D₂, and ring D₃ are condensed together;
ring A₂, ring B₂, and ring D₂ are each independently represented by the following Formula 3, in which Y₁ in Formula 3 is O, S, or N-(L₁)ₐₐ-(R₁₁)_{ab}; 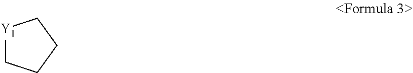
ring A₁, ring A₃ to A₅, ring B₁, ring B₃ to ring B₅, ring D₁, and ring D₃ to D₅ are each independently a substituted or unsubstituted benzene ring or a substituted or unsubstituted naphthalene ring;
R₁ to R₆ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein R₁ and R₂, R₃ and R₄, and R₅ and R₆ are non-ring forming substituents which are not linked to each other and do not form a ring;
X₁ is N or C(R₅₁), X₂ is N or C(R₅₂), X₃ is N or C(R₅₃);
L₁, and L₄₁ to L₄₃ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group;
aa, ba, bb, and be are each independently selected from 0, 1, 2, and 3, *-(L₁)ₐₐ-*′ is a single bond when aa is 0, *-(L₄₁)_{ba}-*′ is a single bond when ba is 0, *-(L₄₂)_{bb}-*′ is a single bond when bb is 0, *-(L₄₃)_{bc}-*′ is a single bond when be is 0, at least two L₁s are the same or different when aa is 2 or greater, at least two L₄₁s are the same or different when ba is 2 or greater, at least two L₄₂s are the same or different when bb is 2 or greater, and at least two L₄₃s are the same or different when be is 2 or greater;
R₁₁, R₄₁ to R₄₃, and R₅₁ to R₅₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and N(Q₆)(Q₇);
ab, bd, be, and bf are each independently selected from 1, 2, and 3, at least two R₁₁s are the same or different when ab is 2 or greater, at least two R₄₁s are the same or different when bd is 2 or greater, at least two R₄₂s are the same or different when be is 2 or greater, and at least two R₄₃s are the same or different when bf is 2 or greater;
bg, bh, and bi are each independently selected from 0, 1, 2, and 3, provided that bg, bh, and bi are not all 0; and
at least one substituent of the substituted benzene ring, the substituted naphthalene ring, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is selected from:
a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group,
a C₁-C₆₀ alkyl group, a C₂-C₆₀ alkenyl group, a C₂-C₆₀ alkynyl group, and a C₁-C₆₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇),
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇), and
—Si(Q₃₁)(Q₃₂)(Q₃₃), —B(Q₃₄)(Q₃₅), and —N(Q₃₆)(Q₃₇),
wherein Q₁ to Q₇, Q₁₁ to Q₁₇, Q₂₁ to Q₂₇, and Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

2. The organic light-emitting device as claimed in claim 1, wherein the first compound is represented by one of the following Formulae 1-1(A), 1-1(B), 1-2(A), 1-2(B), 1-3(A), and 1-3(B): 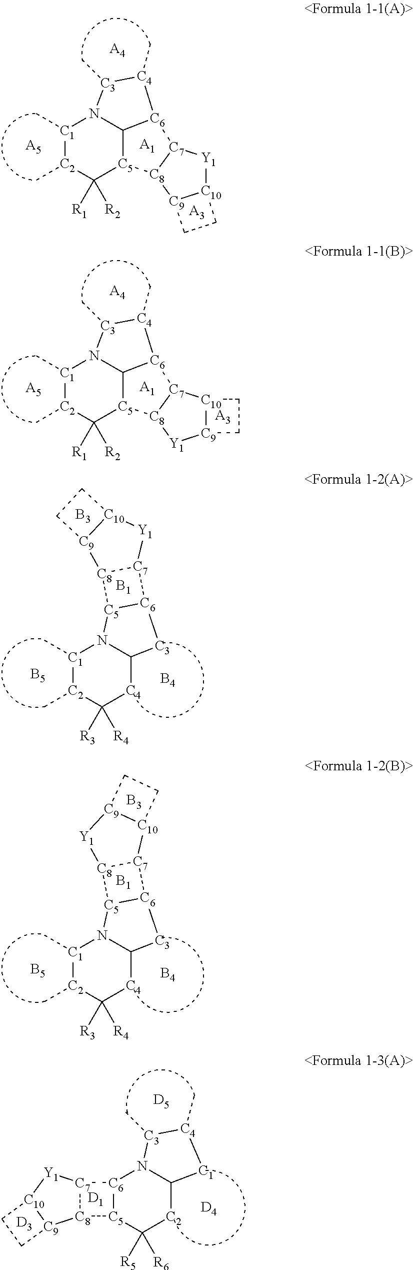 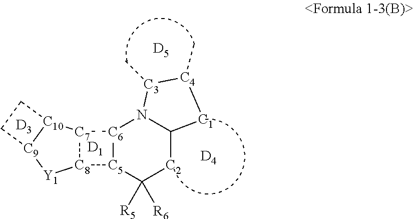
wherein, in Formulae 1-1(A), 1-1(B), 1-2(A), 1-2(B), 1-3(A), and 1-3(B),
C₁ to C₁₀ are numbered to indicate chemically distinct carbon atoms;
ring A₁ is represented by one of the following Formulae 5-1(1) and 5-1(2);
ring B₁ is represented by one of the following Formulae 5-2(1) to 5-2(5);
ring D₁ is represented by one of the following Formulae 5-3(1) to 5-3(5);
ring A₃ is represented by one of the following Formulae 6-1(1) to 6-1(4);
ring B₃ is represented by one of the following Formulae 6-2(1) to 6-2(4);
ring D₃ is represented by one of the following Formulae 6-3(1) to 6-3(4);
ring A₄ is represented by one of the following Formulae 7-1(1) to 7-1(4);
ring B₄ is represented by one of the following Formulae 7-2(1) to 7-2(3);
ring D₄ is represented by one of the following Formulae 7-3(1) to 7-3(3);
ring A₅ and ring B₅ are each independently represented by one of the following Formulae 8-1(1) to 8-1(4); and
ring D₅ is represented by one of the following Formulae 8-3(1) to 8-3(4): 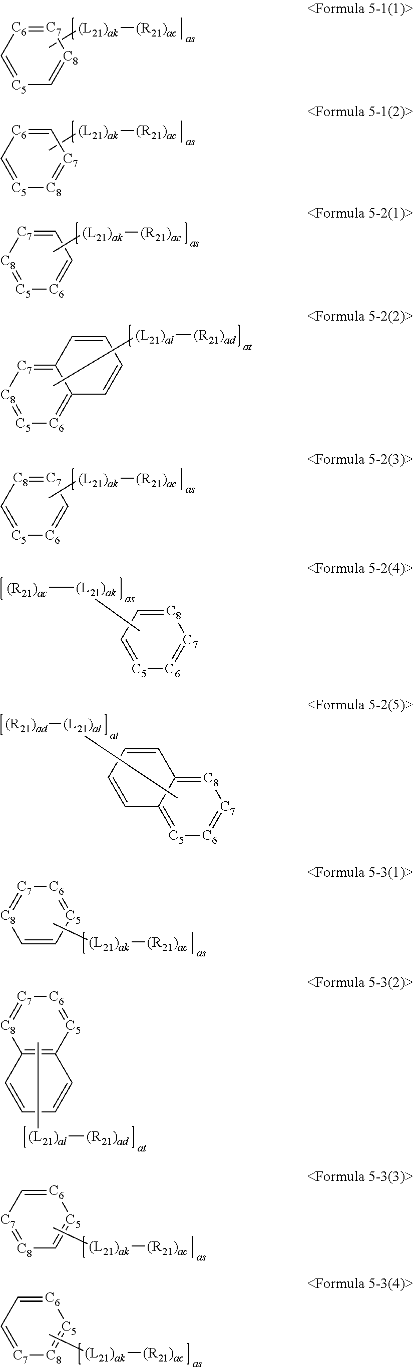 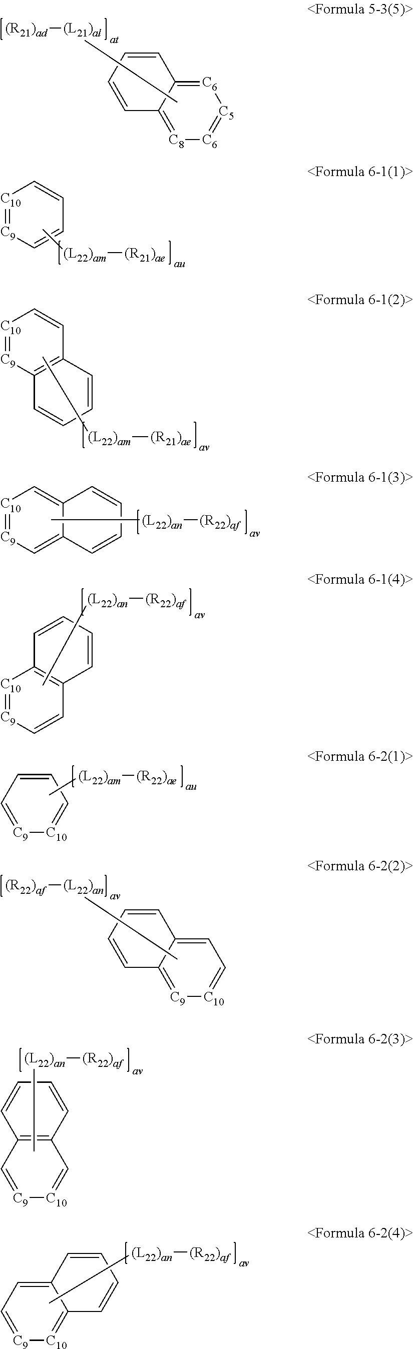 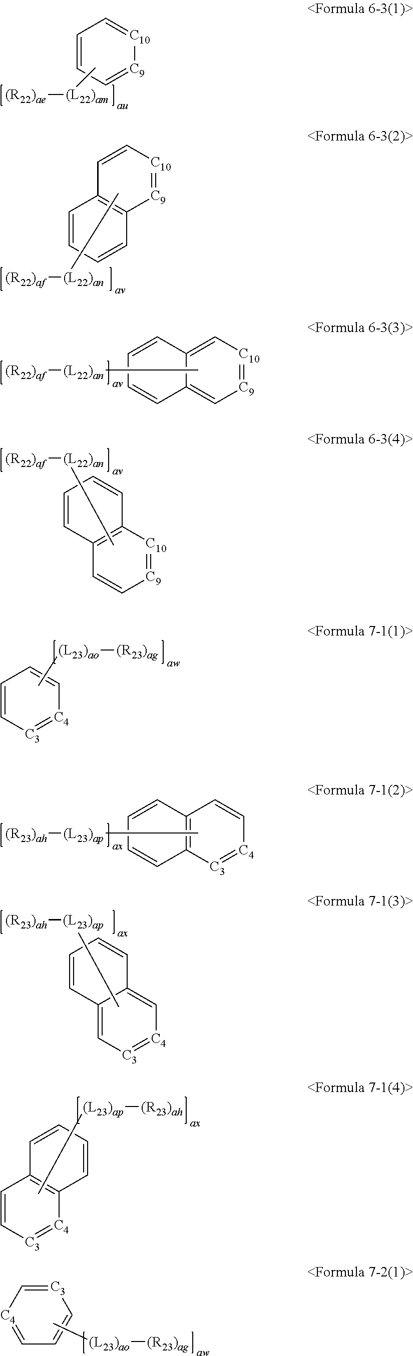 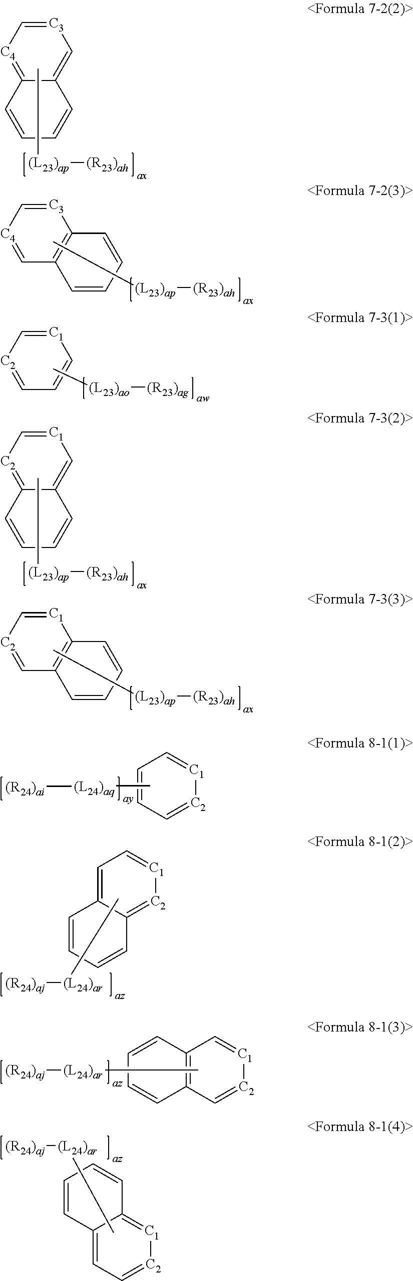 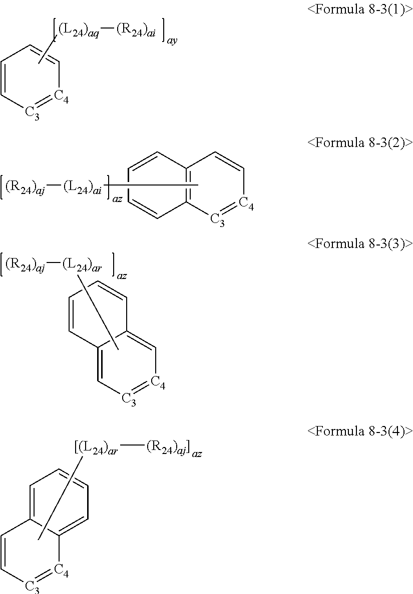
wherein, in Formulae 5-1(1) and 5-1(2), 5-2(1) to 5-2(5), 5-3(1) to 5-3(5), 6-1(1) to 6-1(4), 6-2(1) to 6-2(4), 6-3(1) to 6-3(4), 7-1(1) to 7-1(4), 7-2(1) to 7-2(3), 7-3(1) to 7-3(3), 8-1(1) to 8-1(4), and 8-3(1) to 8-3(4),
L₂₁ to L₂₄ are defined the same as L₁ of Formula 3;
ak, al, am, an, ao, ap, aq, and ar are each independently selected from 0, 1, 2, and 3;
R₂₁ to R₂₄ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and —N(Q₆)(Q₇);
ac, ad, ae, af, ag, ah, ai, and aj are each independently selected from 0, 1, 2, and 3, at least two R₂₁s are the same or different when ac is 2 or greater, at least two R₂₁s are the same or different when ad is 2 or greater, at least two R₂₂s are the same or different when ae is 2 or greater, at least two R₂₂s are the same or different when af is 2 or greater, at least two R₂₃s are the same or different when ag is 2 or greater, at least two R₂₃s are the same or different when ah is 2 or greater, at least two R₂₄s are the same or different when ai is 2 or greater, and at least two R₂₄s are the same or different when aj is 2 or greater;
as is selected from 0, 1, and 2, and two *-[(L₂₁)ₐₖ-(R₂₁)_{ac}] are the same or different when as is 2;
at, au, aw, and ay are each independently selected from 0, 1, 2, 3, and 4, at least two *-[(L₂₁)_{ad}-(R₂₁)ₐₗ] are the same or different when at is 2 or greater, at least two *-[(L₂₂)ₐₘ-(R₂₂)ₐₑ] are the same or different when au is 2 or greater, at least two *-[(L₂₃)ₐₒ-(R₂₃)_{ag}] are the same or different when aw is 2 or greater, and at least two *-[(L₂₄)_{aq}-(R₂₄)ₐᵢ] are the same or different when ay is 2 or greater;
av, ax, and az are each independently selected from 0, 1, 2, 3, 4, 5, and 6, at least two *-[(L₂₂)ₐₙ-(R₂₂)_{af}] are the same or different when av is 2 or greater, at least two *-[(L₂₃)ₐₚ-(R₂₃)ₐₕ] are the same or different when ax is 2 or greater, and at least two *-[(L₂₄)ₐᵣ-(R₂₄)ₐⱼ] are the same or different when az is 2 or greater; and
substituents of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group, and
Q₁ to Q₇ are defined the same as Q₁ to Q₇ of Formulae 1-1 to 1-3 and Formula 2.

3. The organic light-emitting device as claimed in claim 2, wherein the first compound is represented by one of Formula 1-1(A), 1-2(A), or 1-3(A), in which:
ring A₁ is represented by one of Formulae 5-1(1) and 5-1(2);
ring B₁ is represented by one of Formulae 5-2(1) to 5-2(3);
ring D₁ is represented by one of Formulae 5-3(1) to 5-3(3);
ring A₃ is represented by one of Formulae 6-1(1) and 6-1(2);
ring B₃ is represented by one of Formulae 6-2(1) and 6-2(2);
ring D₃ is represented by one of Formulae 6-3(1) to 6-3(4);
ring A₄ is represented by one of Formulae 7-1(1) and 7-1(3);
ring B₄ is represented by one of Formulae 7-2(1) and 7-2(3);
ring D₄ is represented by one of Formulae 7-3(1) and 7-3(2);
ring A₅ is represented by one of Formulae 8-1(1) and 8-1(3);
ring B₅ is represented by one of Formulae 8-2(1) to 8-2(3); and
ring D₅ is represented by one of Formulae 8-3(1) and 8-3(4).

4. The organic light-emitting device as claimed in claim 1, wherein, in Formulae 1-1 to 1-3, R₁ to R₆ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group,
a C₁-C₂₀ alkyl group and a C₁-C₂₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, and a naphthyl group,
a phenyl group, a naphthyl group, a fluorenyl group, a phenanthrenyl group, an anthracenyl group, a fluoranthenyl group, a triphenylenyl group, a pyrenyl group, and a chrysenyl group, and
a phenyl group, a naphthyl group, a fluorenyl group, a phenanthrenyl group, an anthracenyl group, a fluoranthenyl group, a triphenylenyl group, a pyrenyl group, and a chrysenyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, and a chrysenyl group.

5. The organic light-emitting device as claimed in claim 1, wherein, in Formulae 1-1 to 1-3 and 2, L₁ and L₄₁ to L₄₃ are each independently selected from:
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, and
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group.

6. The organic light-emitting device as claimed in claim 1, wherein, in Formulae 1-1 to 1-3, and Formula 2, L₁ and L₄₁ to L₄₃ are each independently selected from:
a phenylene group, a naphthylene group, a fluorenylene group, a phenanthrenylene group, an anthracenylene group, a triphenylenylene group, a pyrenylene group, and a chrysenylene group, and
a phenylene group, a naphthylene group, a fluorenylene group, a phenanthrenylene group, an anthracenylene group, a triphenylenylene group, a pyrenylene group, and a chrysenylene group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a triphenylenyl group, a pyrenyl group, and a chrysenyl group.

7. The organic light-emitting device as claimed in claim 1, wherein, in Formulae 1-1 to 1-3, and Formula 2, L₁ and L₄₁ to L₄₃ are each independently a group represented by one of the following Formulae 5-1 to 5-26; and
aa, ba, and be are each independently 0 or 1: 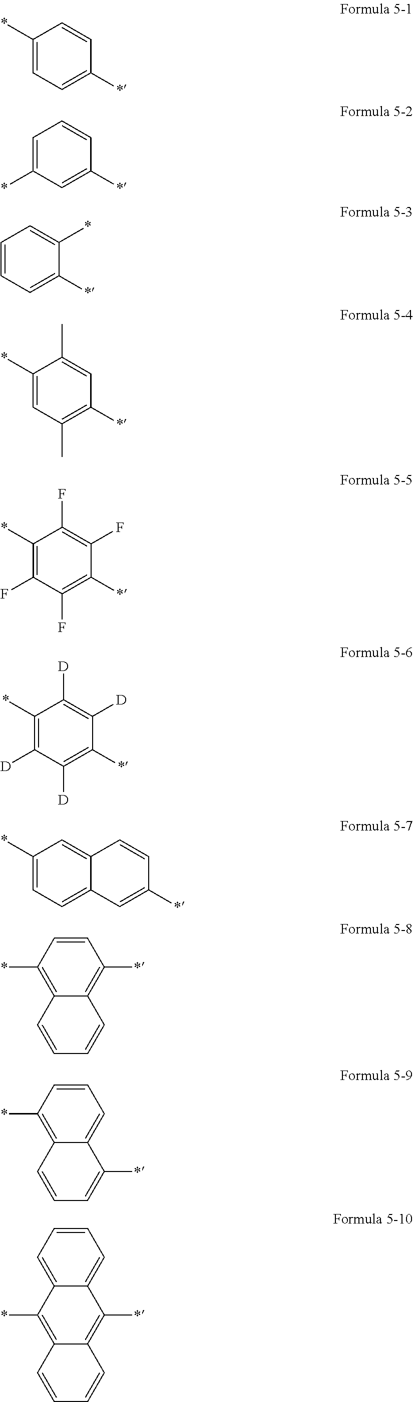 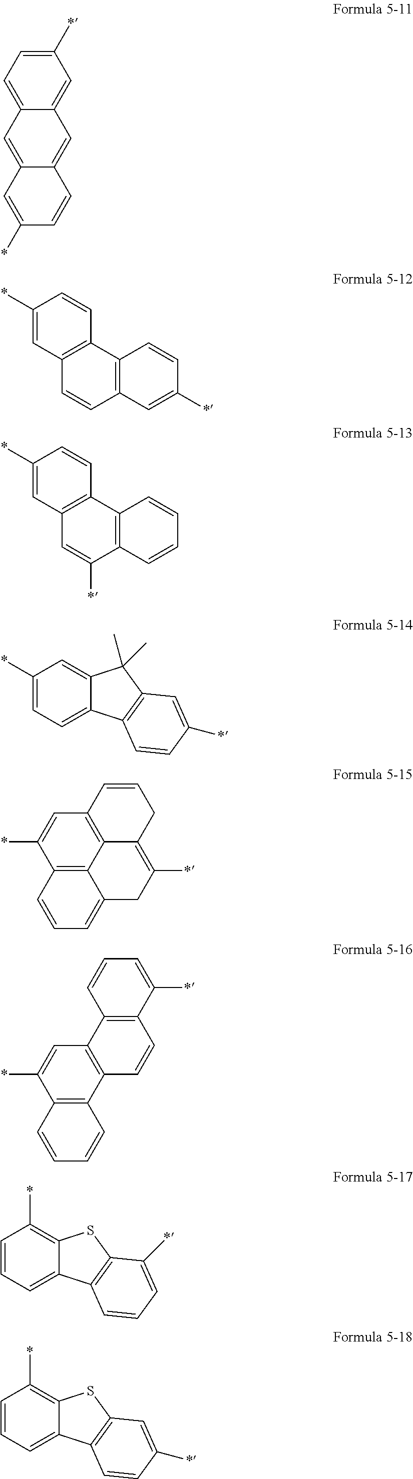 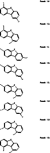
wherein, in Formulae 5-1 to 5-26, * and *′ are each a binding site with an adjacent atom.

8. The organic light-emitting device as claimed in claim 2, wherein R₁₁ and R₂₁ to R₂₄ are each independently selected from:
a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinyl group, a benzoimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group, and
a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinyl group, a benzoimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group.

9. The organic light-emitting device as claimed in claim 2, wherein R₁₁ and R₂₁ to R₂₄ are each independently a group represented by one of the following Formulae 7-1 to 7-44: 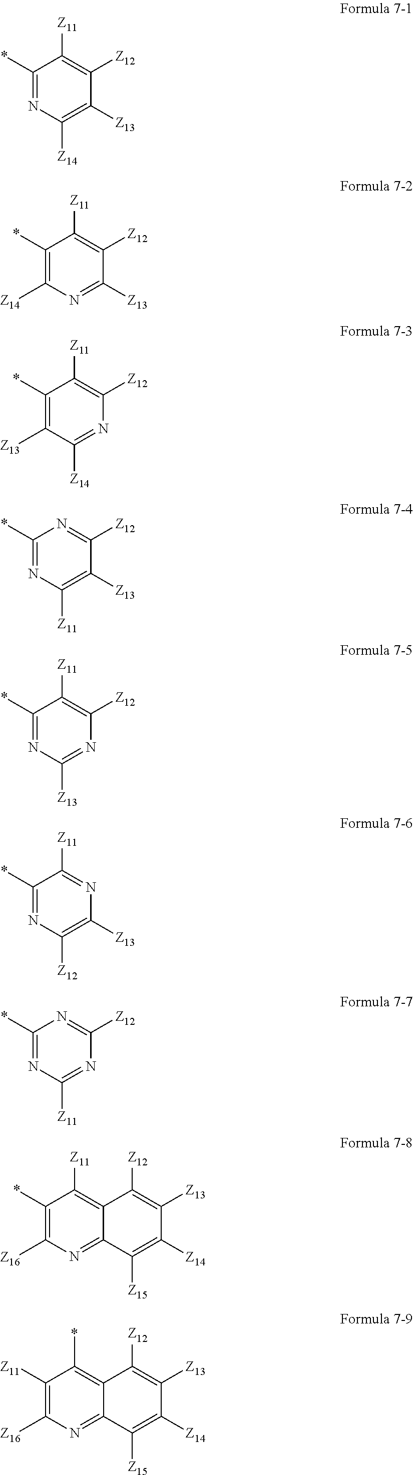 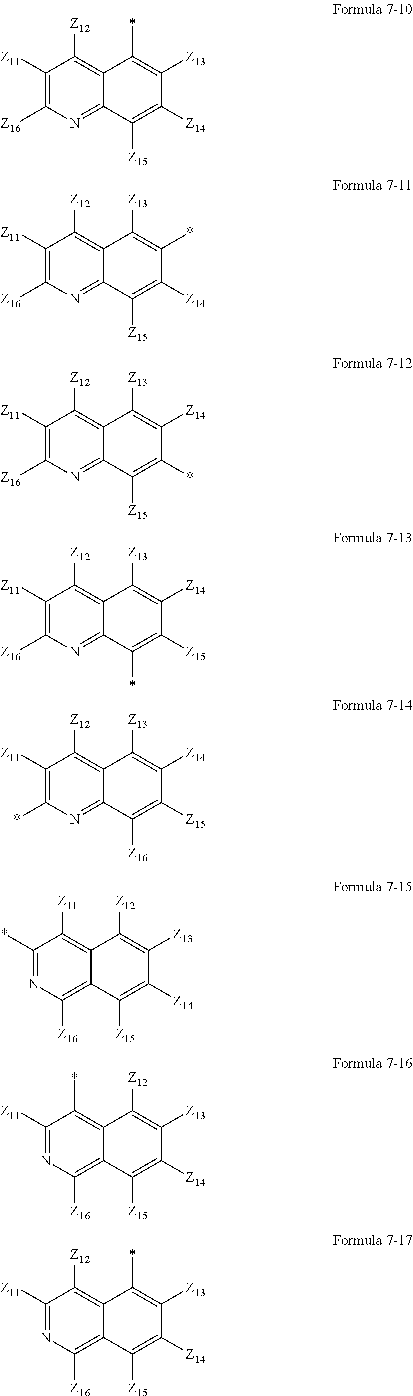 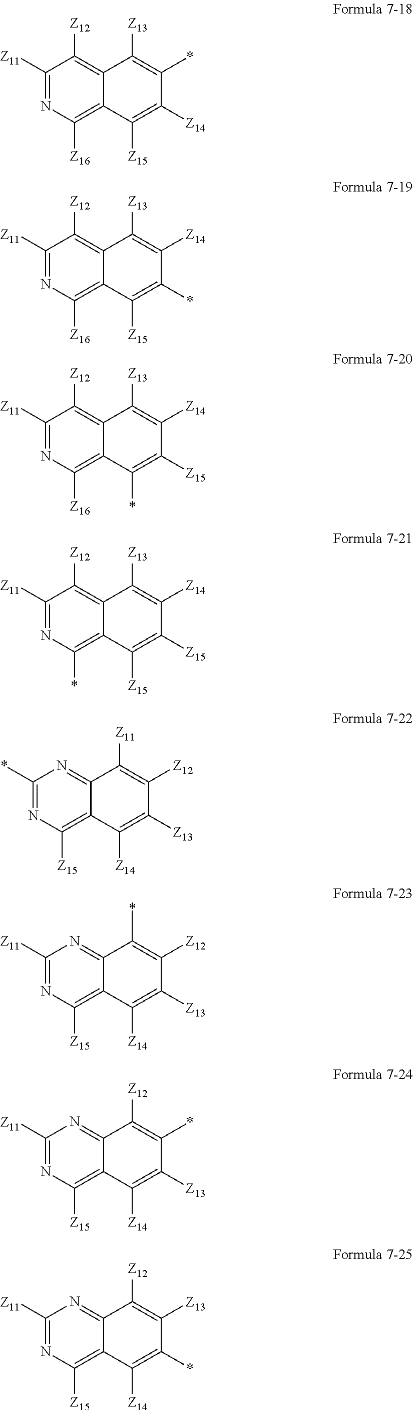 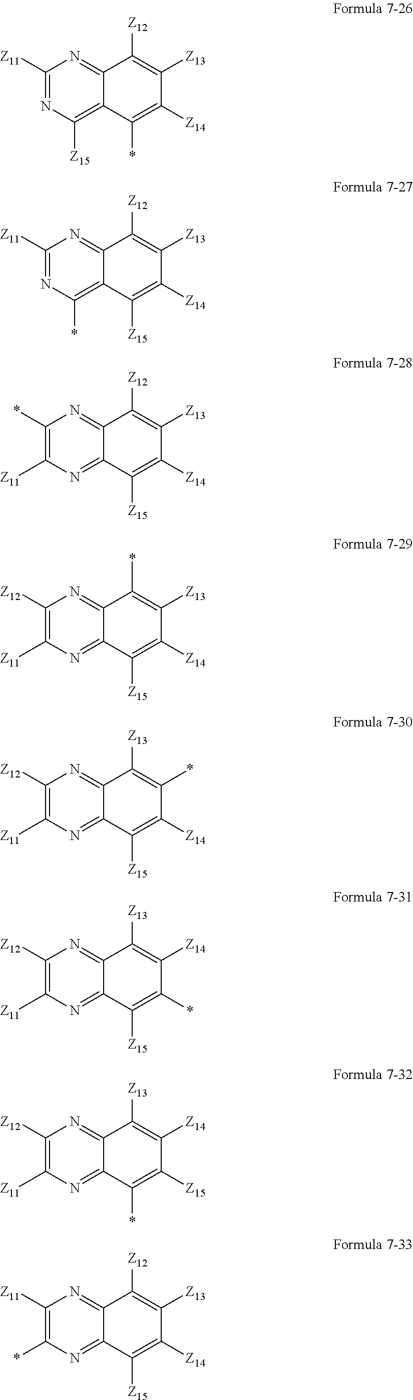 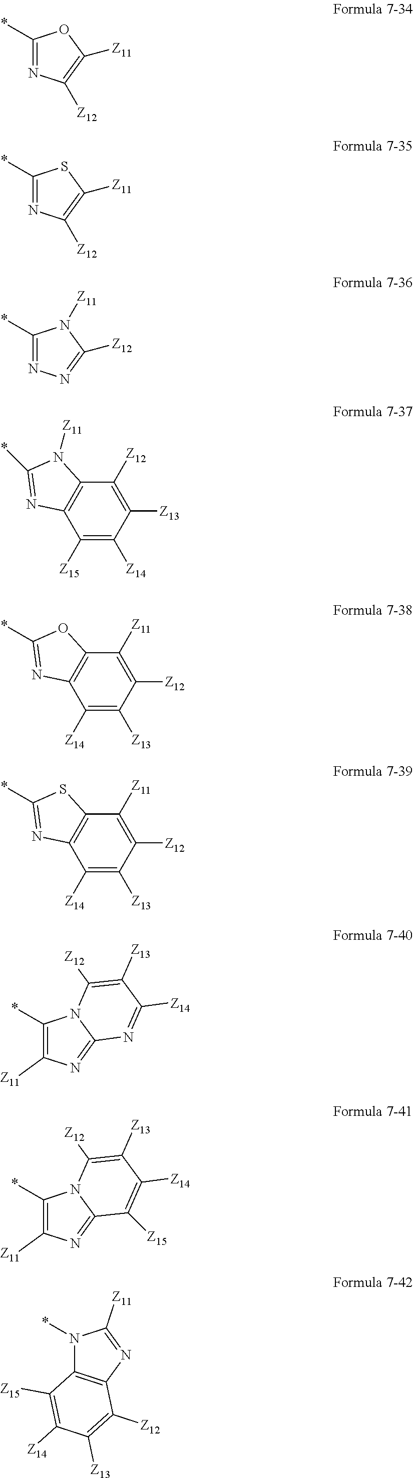 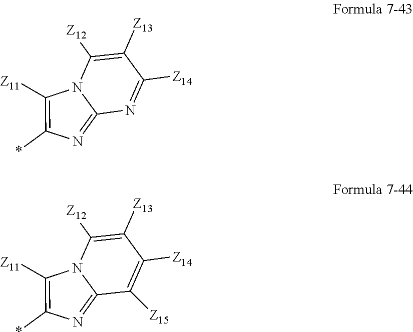
wherein, in Formulae 7-1 to 7-44,
Z₁₁ to Z₁₆ are each independently selected from a hydrogen, a deuterium, —F, —Cl, —Br, —I, a hydroxyl group, a cyano group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and
* is a binding site with an adjacent atom.

10. The organic light-emitting device as claimed in claim 2, wherein, in Formula 3,
Y₁ is N-(L₁)ₐₐ-(R₁)_{ab};
L₁ is a group represented by one of the following Formulae 5-1 to 5-16;
aa is 0 or 1;
R₁₁ is a group represented by one of the following Formulae 8-1 to 8-11; and
ab is 1: 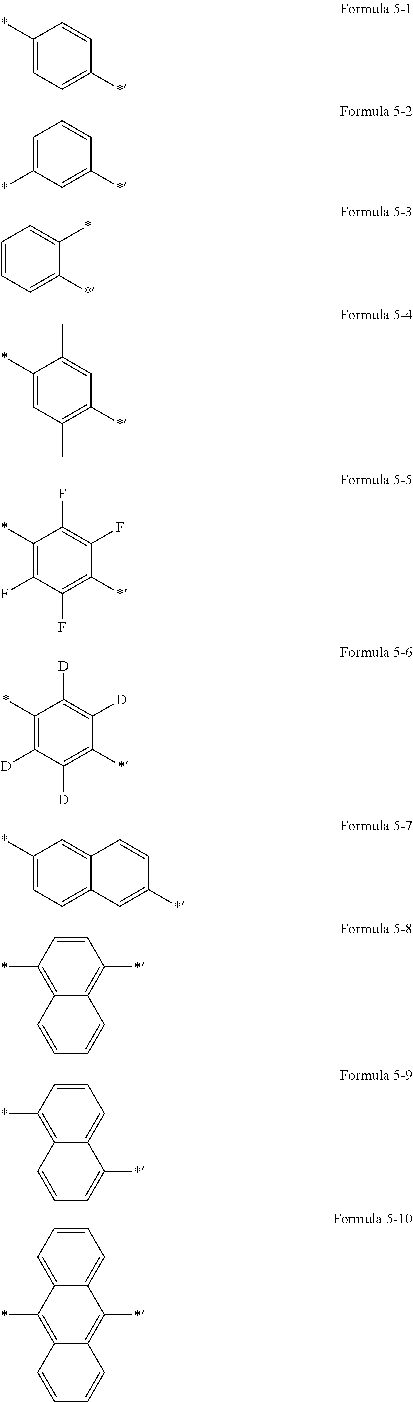 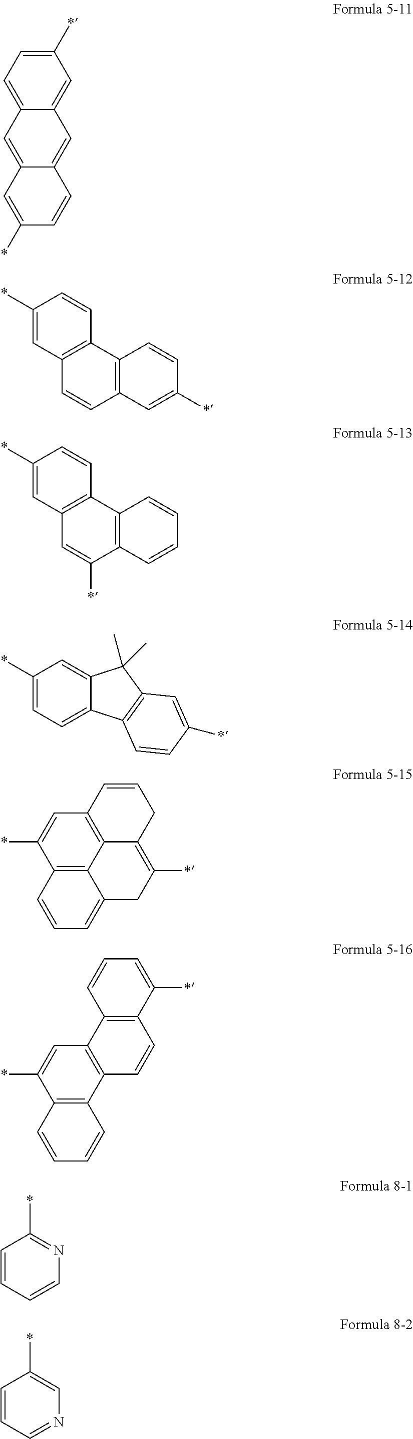 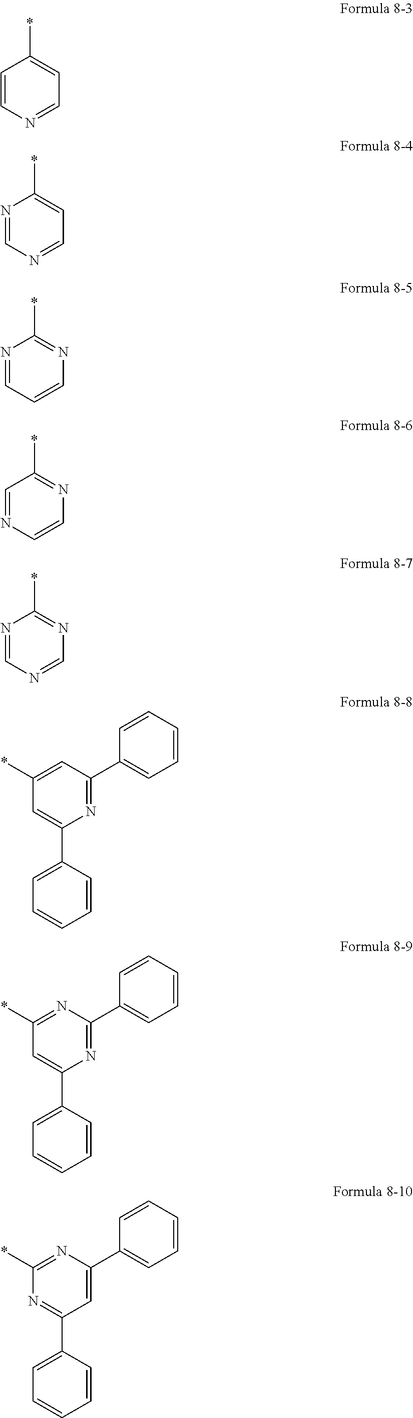 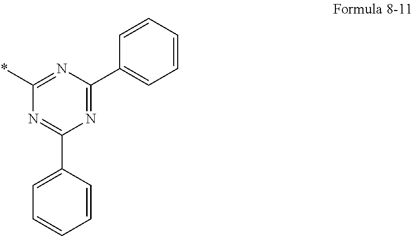
wherein, in Formulae 5-1 to 5-16 and 8-1 to 8-11, * and *′ are each a binding site with an adjacent atom.

11. The organic light-emitting device as claimed in claim 2, wherein:
in Formula 3, Y₁ is S or O;
ring A₅ and ring B₅ are each independently represented by one of the following Formulae 8-1(1) to 8-1(4); and
ring D₅ is represented by one of the following Formulae 8-3(1) to 8-3(4): 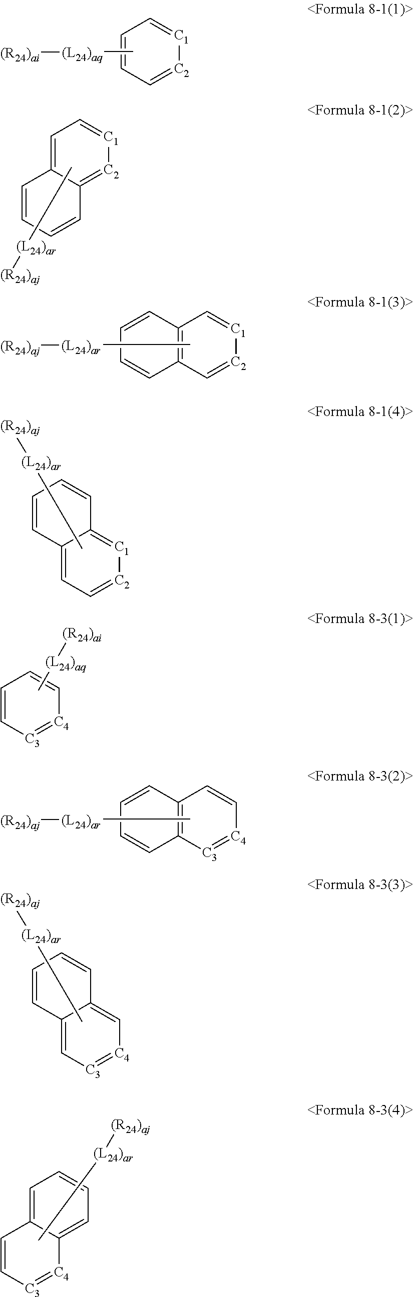
wherein, in Formulae 8-1(1) to 8-1(4) and Formulae 8-3(1) to 8-3(4), L₂₄ is a group represented by one of the following Formulae 5-1 to 5-16;
aq and ar are each independently 0 or 1;
R₂₄ is a group represented by one of the following Formulae 8-1 to 8-11; and
ai and aj are 1: 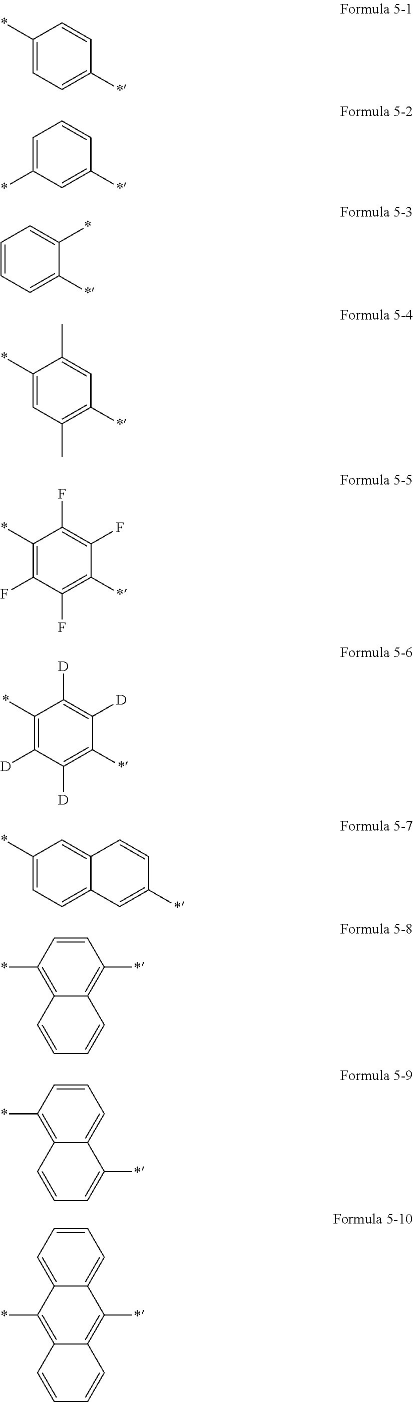 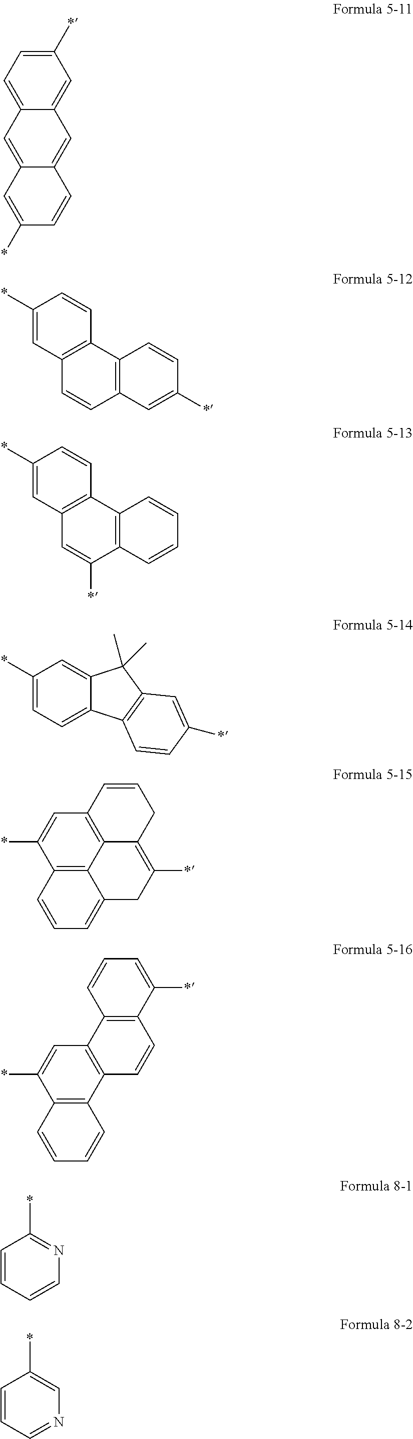 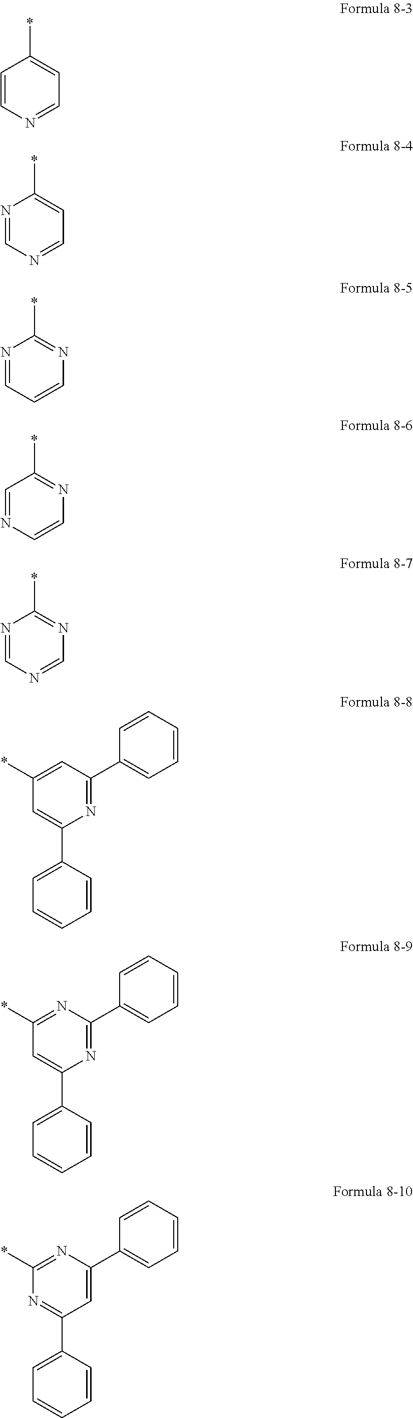 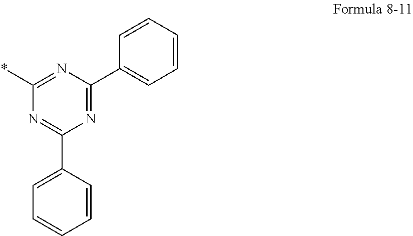
wherein, in Formulae 5-1 to 5-16 and Formulae 8-1 to 8-11, * and *′ are each a binding site with an adjacent atom.

12. The organic light-emitting device as claimed in claim 1, wherein, in Formula 2, R₄₁ to R₄₃ and R₅₁ to R₅₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₁-C₂₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and —N(Q₆)(Q₇).

13. The organic light-emitting device as claimed in claim 1, wherein R₄₁ to R₄₃ and R₅₁ to R₅₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, and a group represented by one of the following Formulae 10-1 to 10-17: 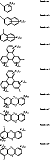 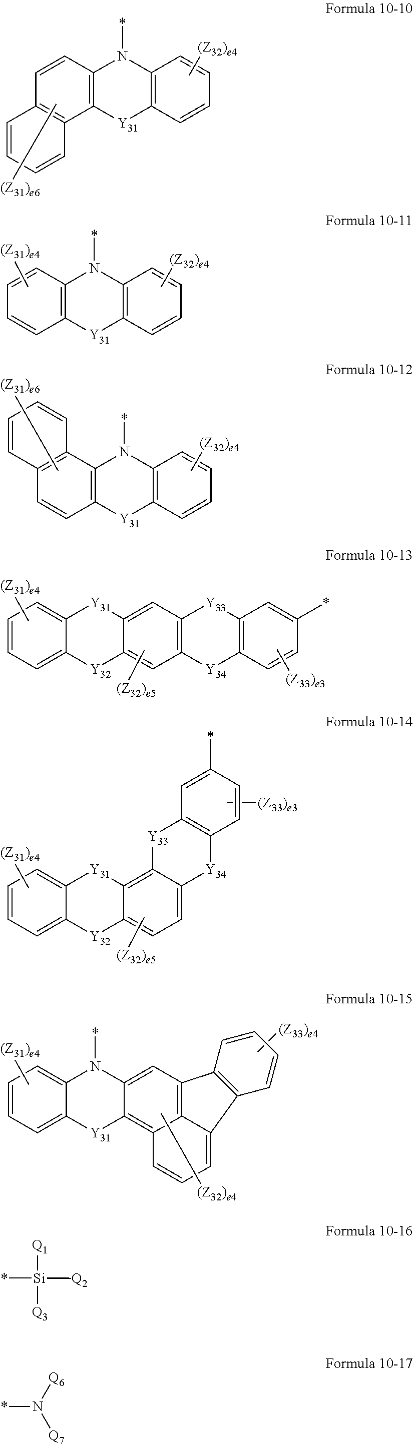
wherein, in Formulae 10-1 to 10-17,
Y₃₁ to Y₃₄ are each independently a single bond, O, S, C(Z₃₄)(Z₃₅), N(Z₃₆), or Si(Z₃₇)(Z₃₈);
Z₃₁ to Z₃₈ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group,
a C₁-C₂₀ alkyl group and a C₁-C₂₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof,
a C₆-C₂₀ aryl group, a C₁-C₂₀ heteroaryl group, a monovalent non-aromatic condensed polycyclic group, and a monovalent non-aromatic condensed heteropolycyclic group, and
a C₆-C₂₀ aryl group, a C₁-C₂₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group;
Q₁ to Q₃, Q₆, and Q₇ of Formulae 10-16 and 10-17 are each independently selected from:
a C₆-C₂₀ aryl group, a C₁-C₂₀ heteroaryl group, a monovalent non-aromatic condensed polycyclic group, and a monovalent non-aromatic condensed heteropolycyclic group, and
a C₆-C₂₀ aryl group, a C₁-C₂₀ heteroaryl group, a monovalent non-aromatic condensed polycyclic group, and a monovalent non-aromatic condensed heteropolycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group;
e1 is an integer selected from 1 to 5;
e2 is an integer selected from 1 to 7;
e3 is an integer selected from 1 to 3;
e4 is an integer selected from 1 to 4;
e5 is an integer selected from 1 or 2;
e6 is an integer selected from 1 to 6; and
* is a binding site with an adjacent atom.

14. The organic light-emitting device as claimed in claim 1, wherein, in Formula 2, R₄₁ to R₄₃ and R₅₁ to R₅₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, and a group represented by one of the following Formulae 12-1 to 12-49: 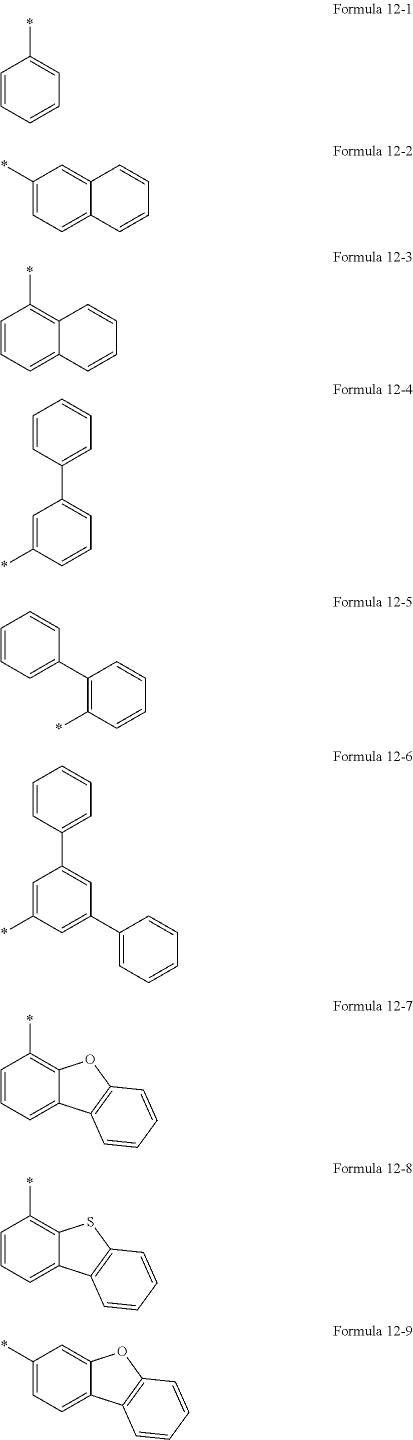 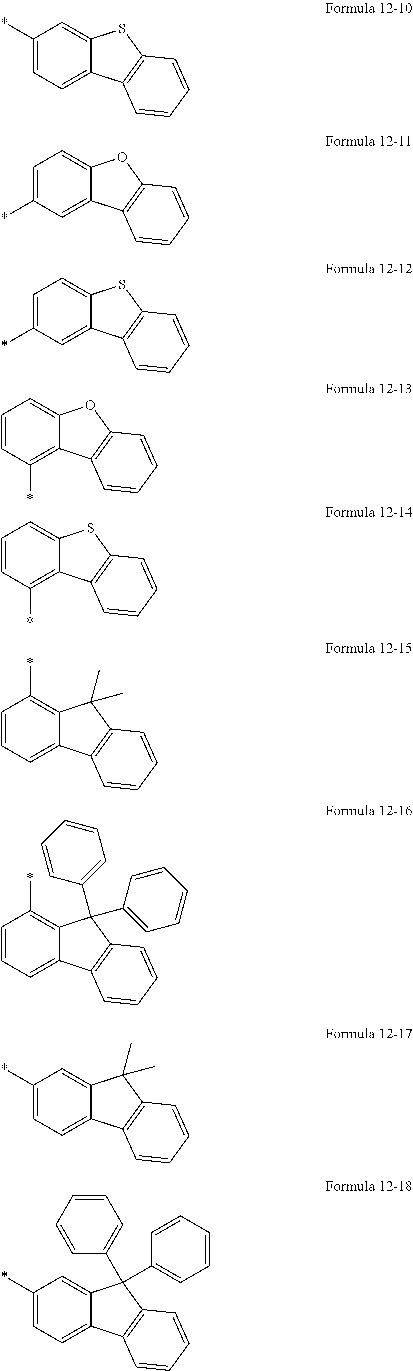 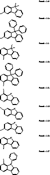 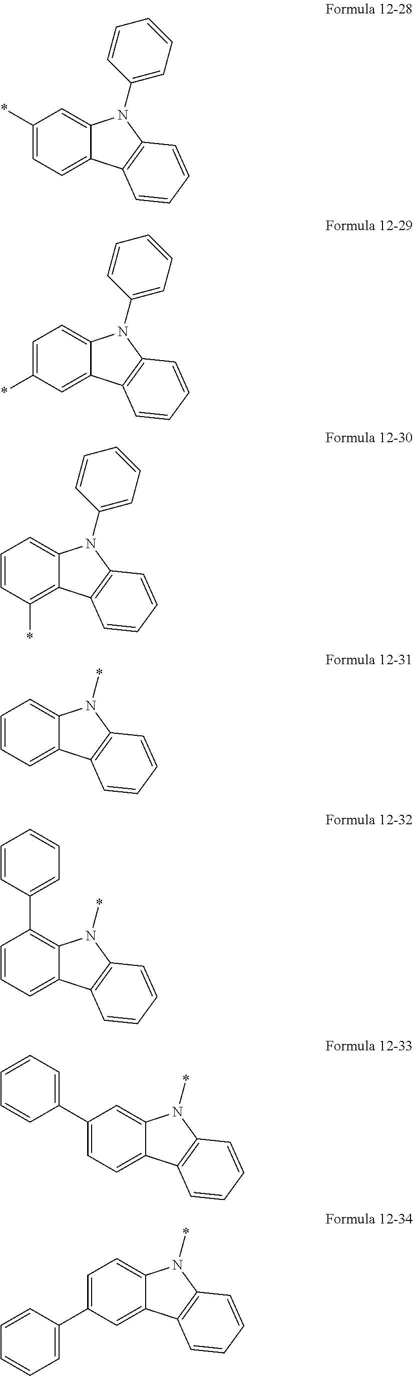 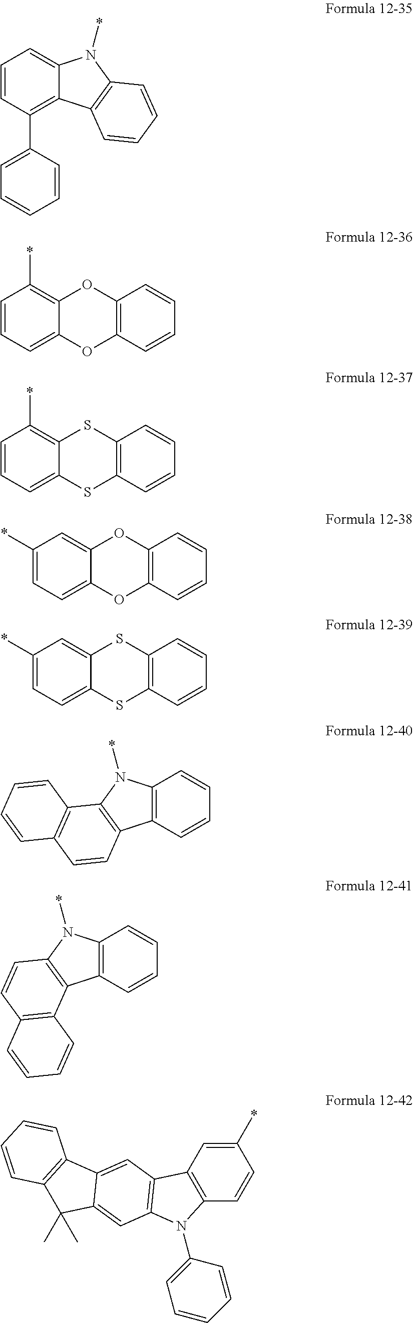 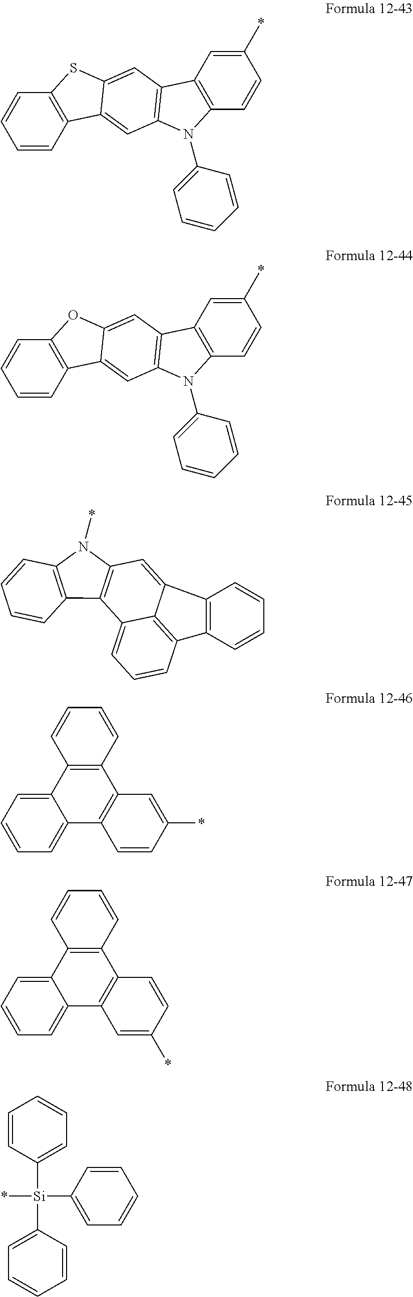 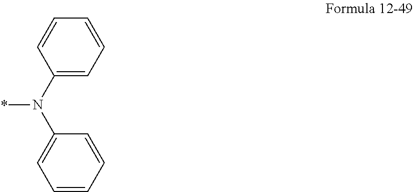
wherein, in Formulae 12-1 to 12-49, * is a binding site with an adjacent atom.

15. The organic light-emitting device as claimed in claim 1, wherein:
the first compound is represented by one of the following Formulae 1-1(A-1) to 1-1(A-20), Formulae 1-1(B-1) to 1-1(B-20), Formulae 1-2(A-1) to 1-2(A-27), Formulae 1-2(B-1) to 1-2(B-19), Formulae 1-3(A-1) to 1-3(A-29), and Formulae 1-3(B-1) to 1-3(B-27), and
the second compound is represented by one of the following Formulae 2(1) and 2(2): 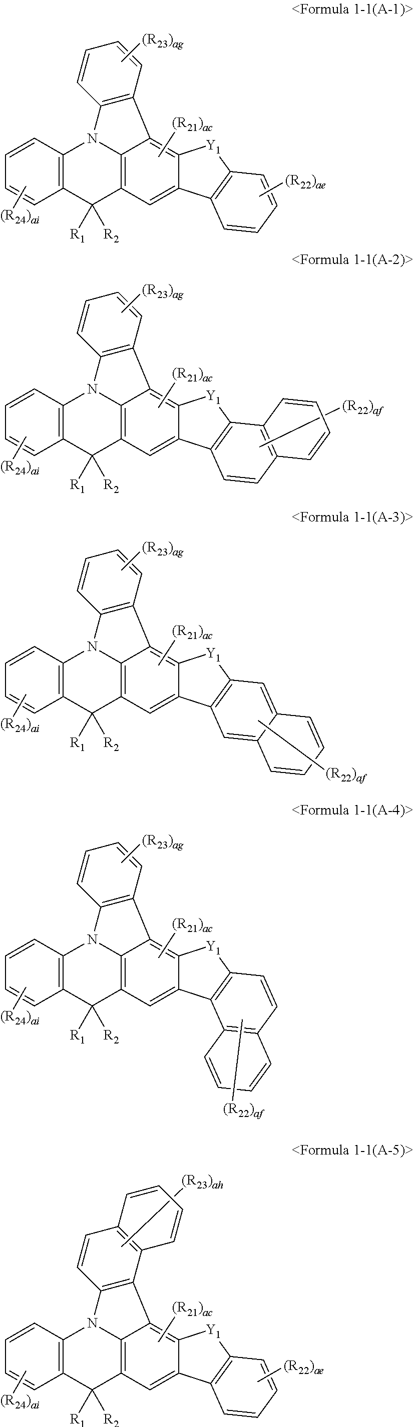 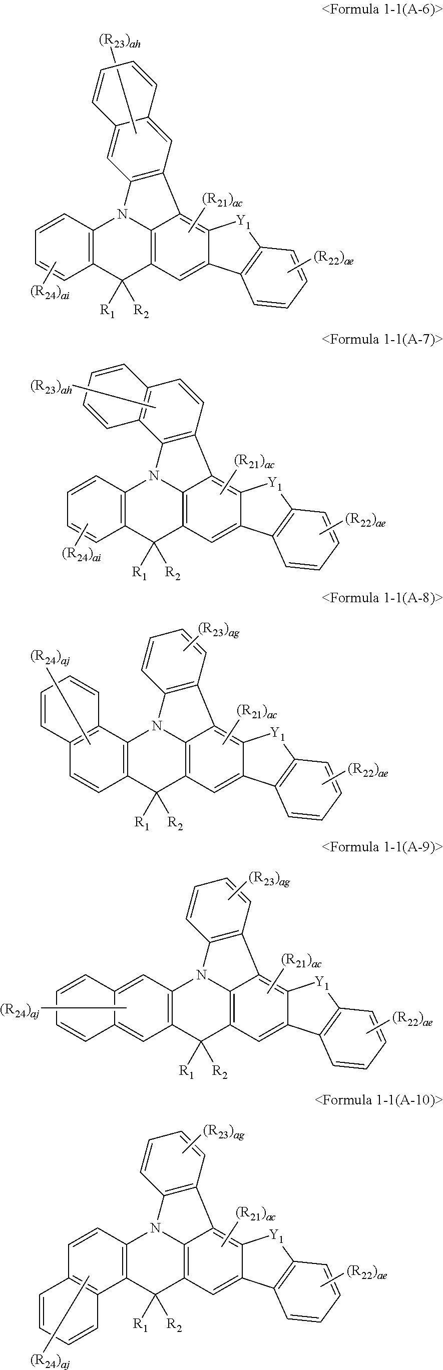 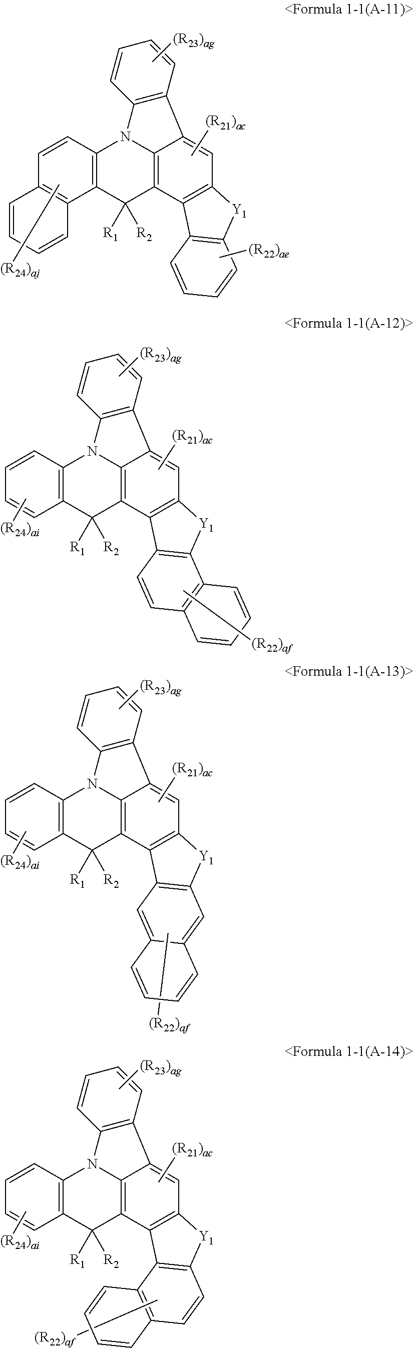 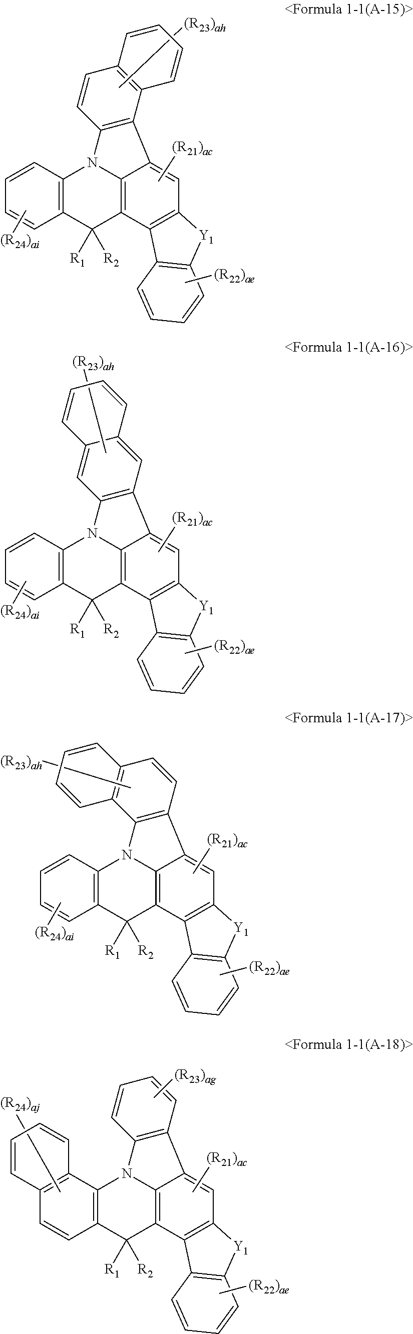 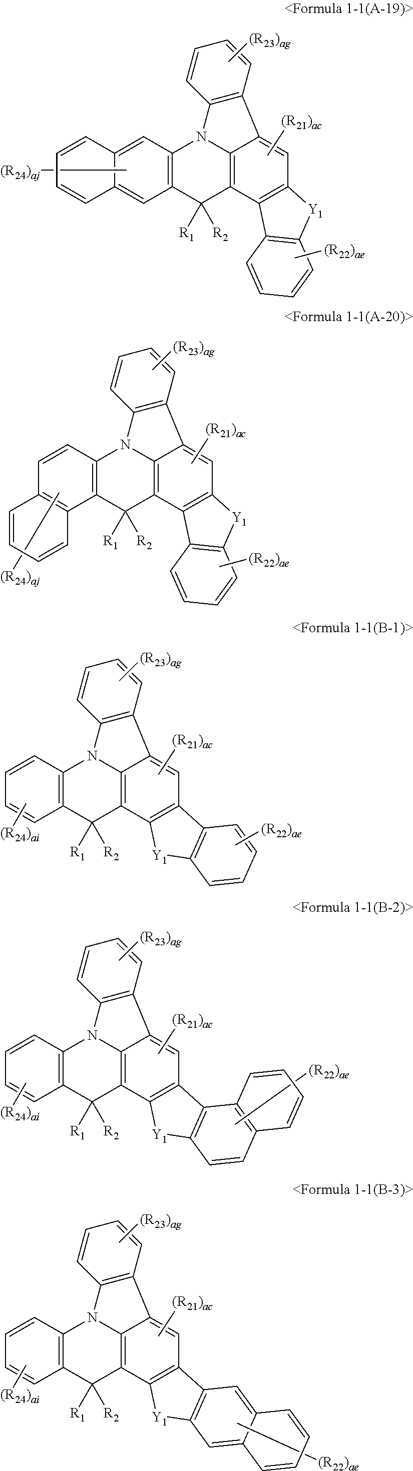 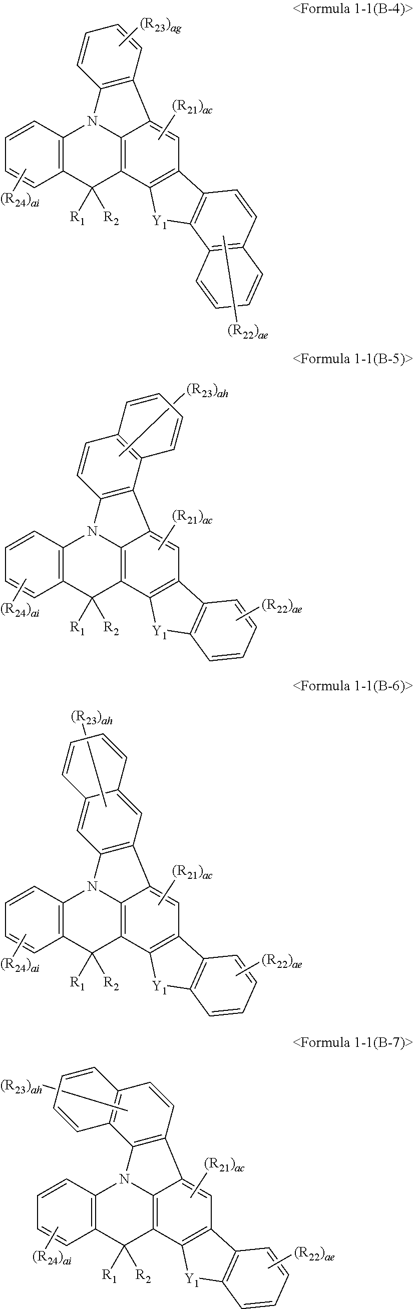 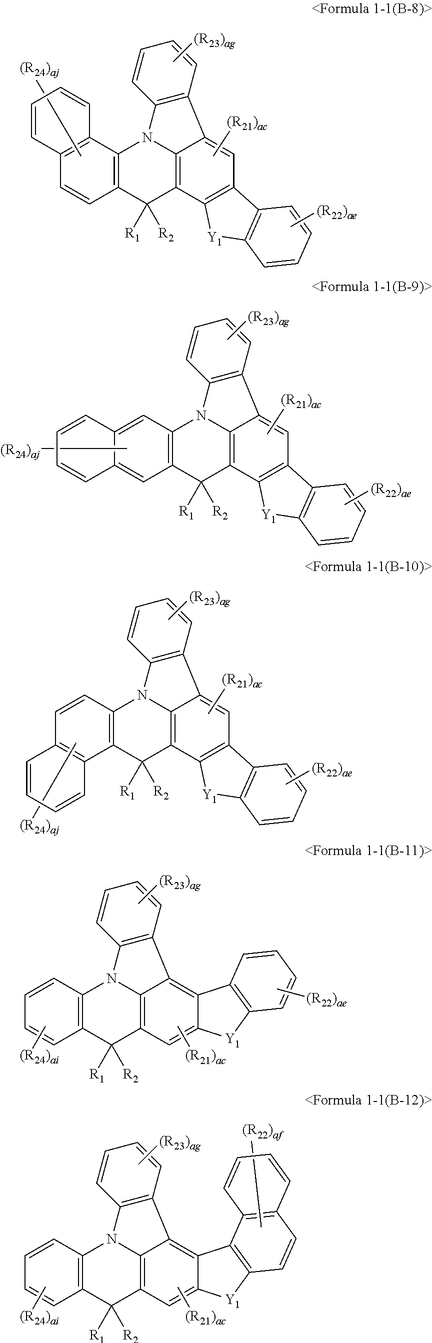 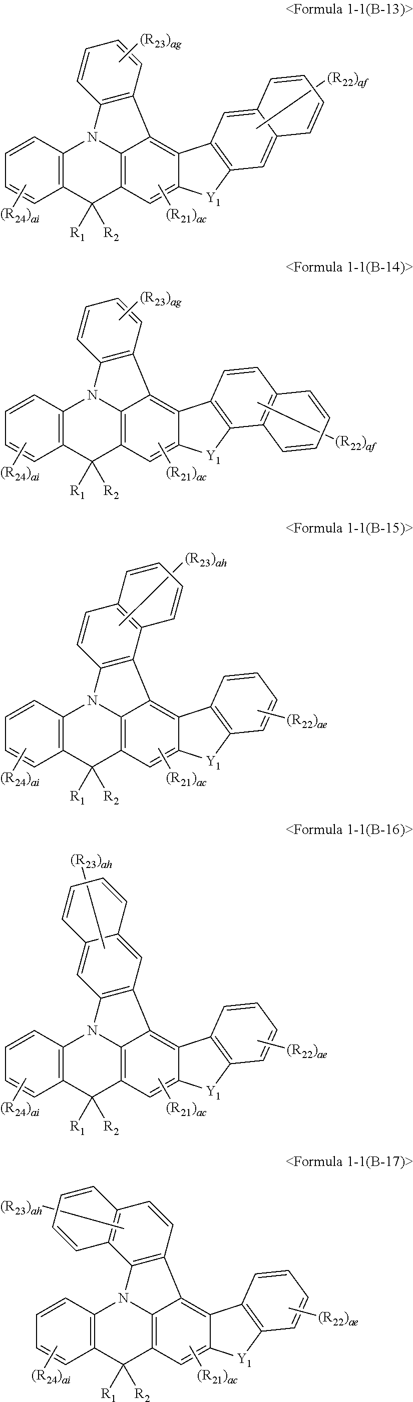 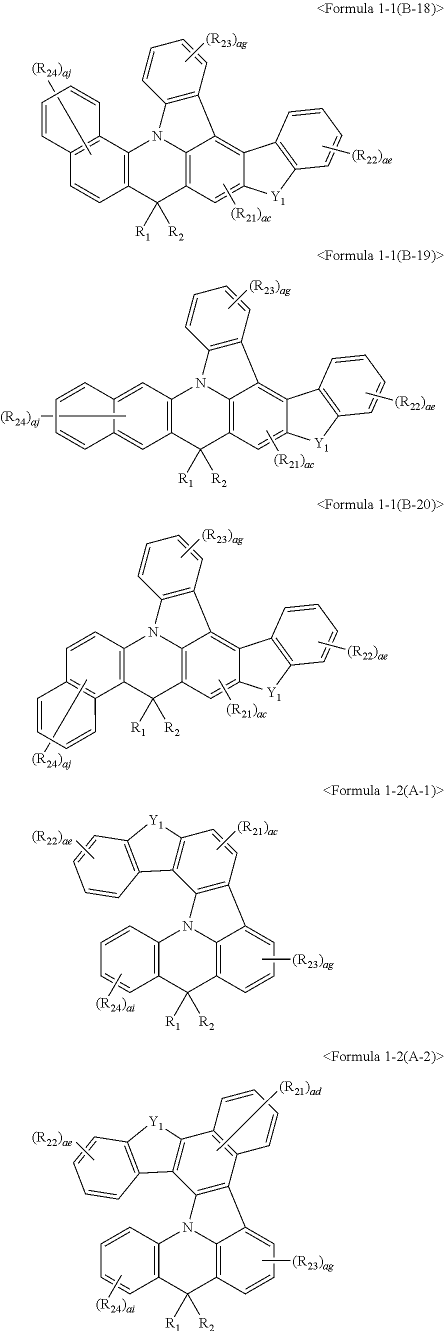 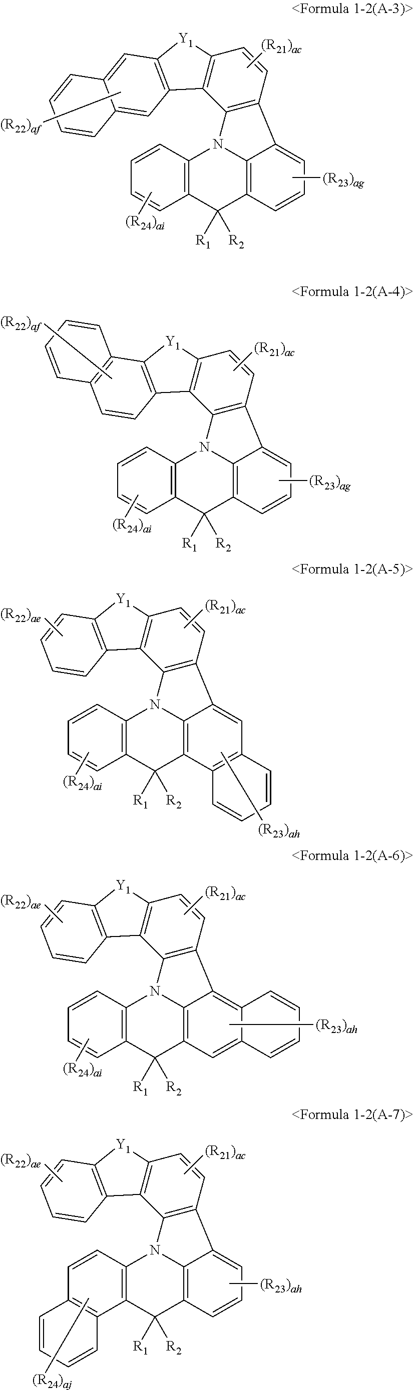 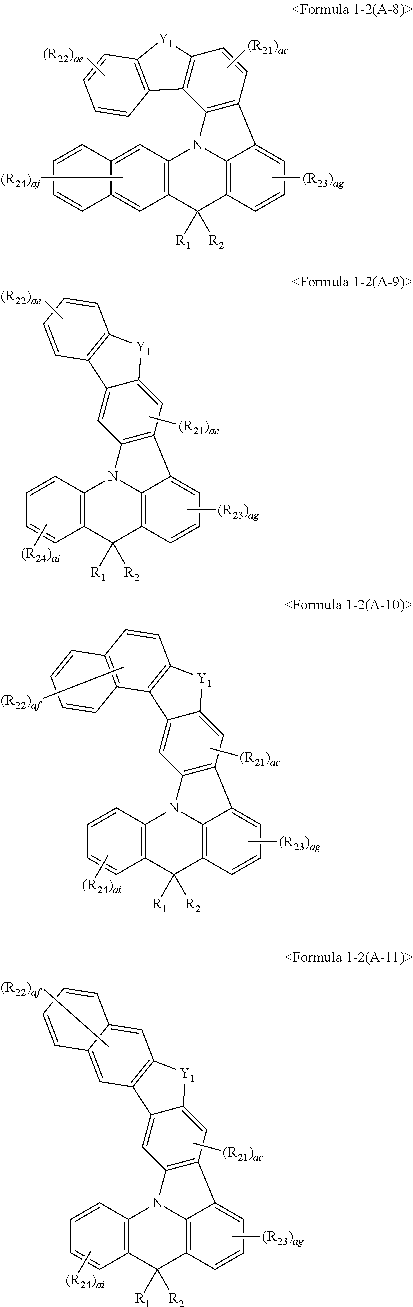 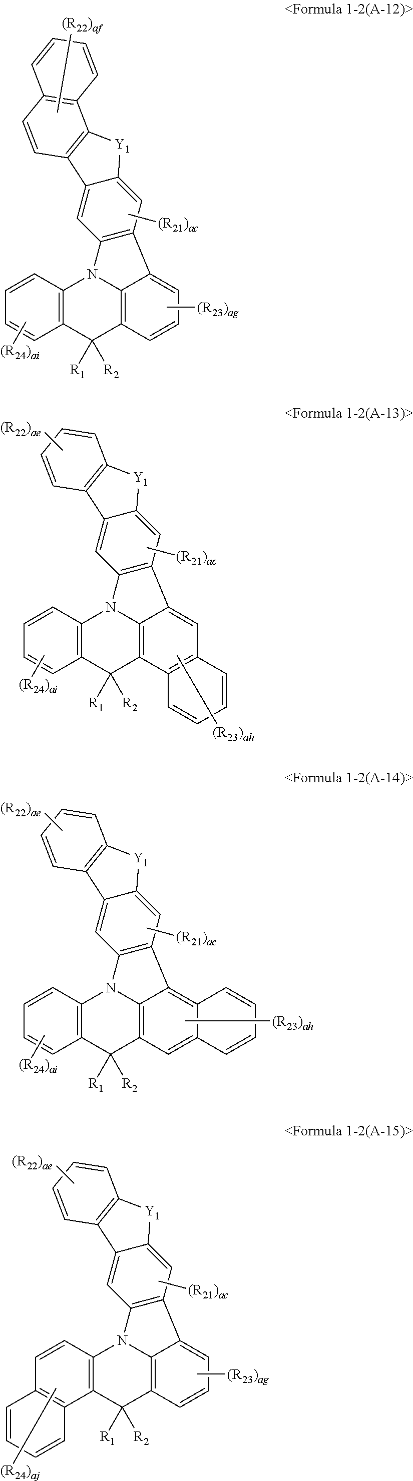 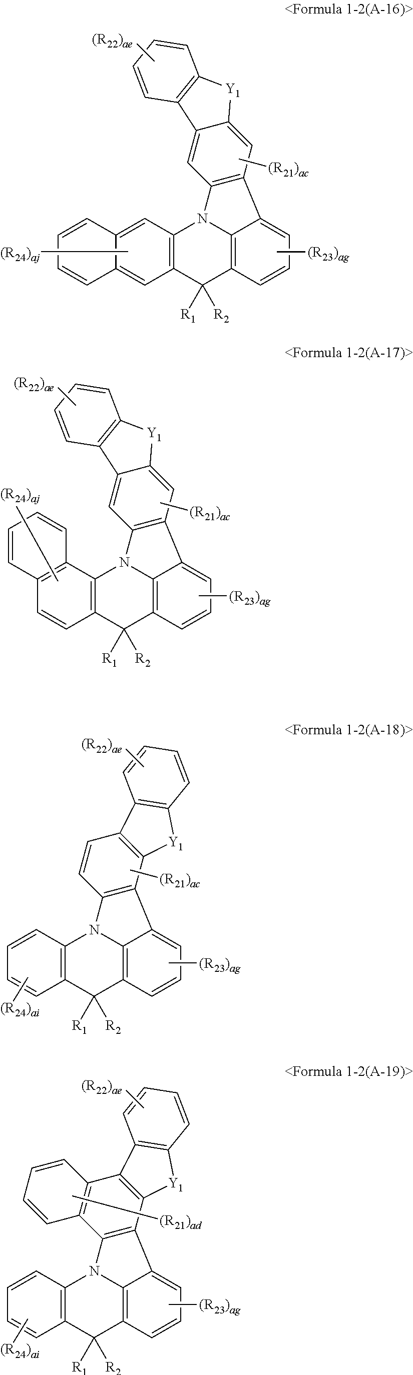 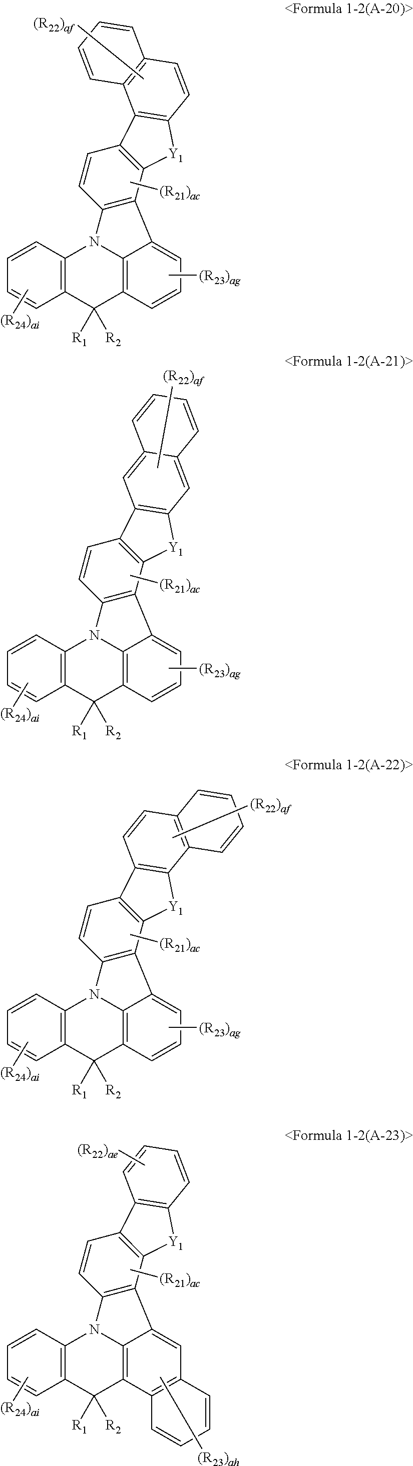 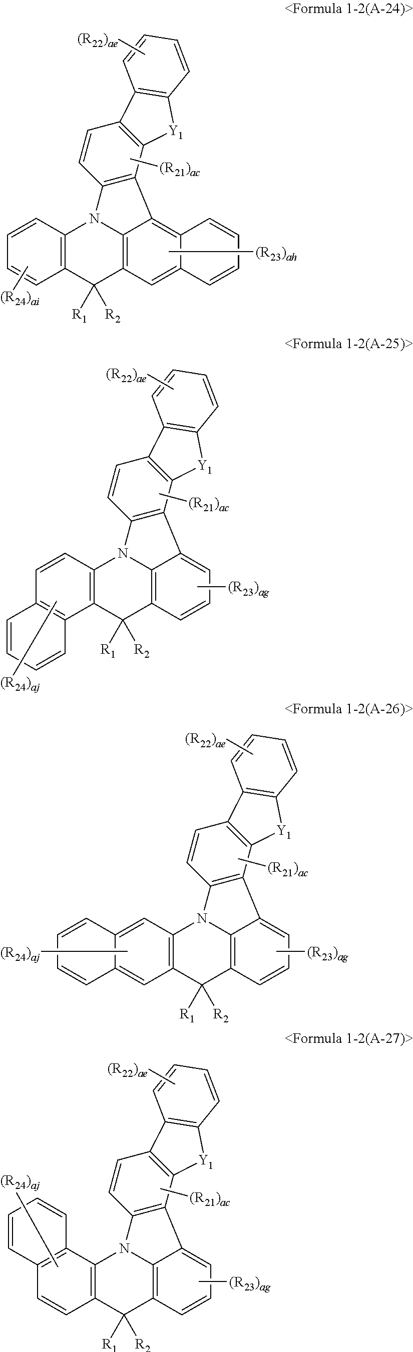 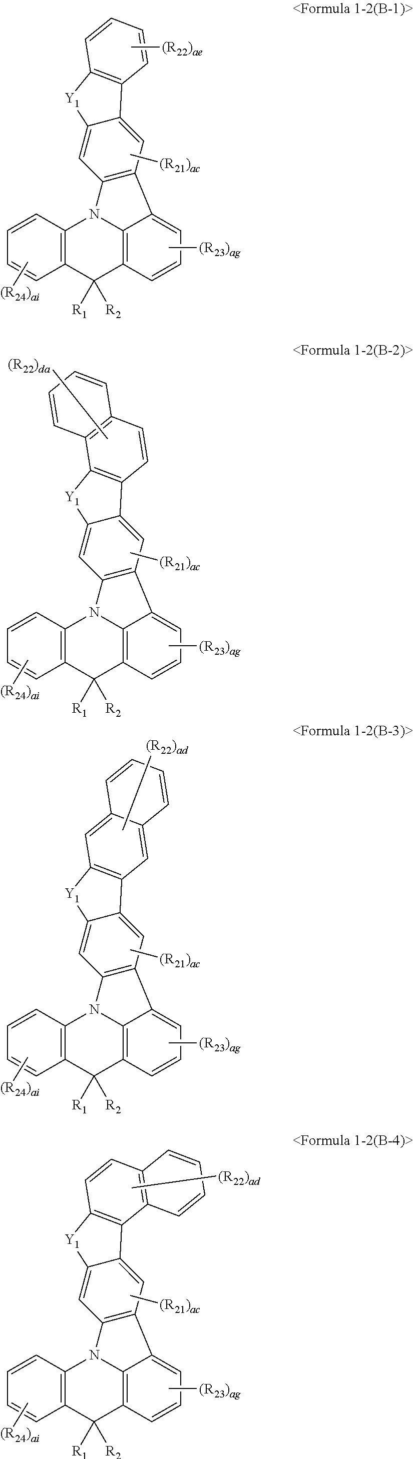 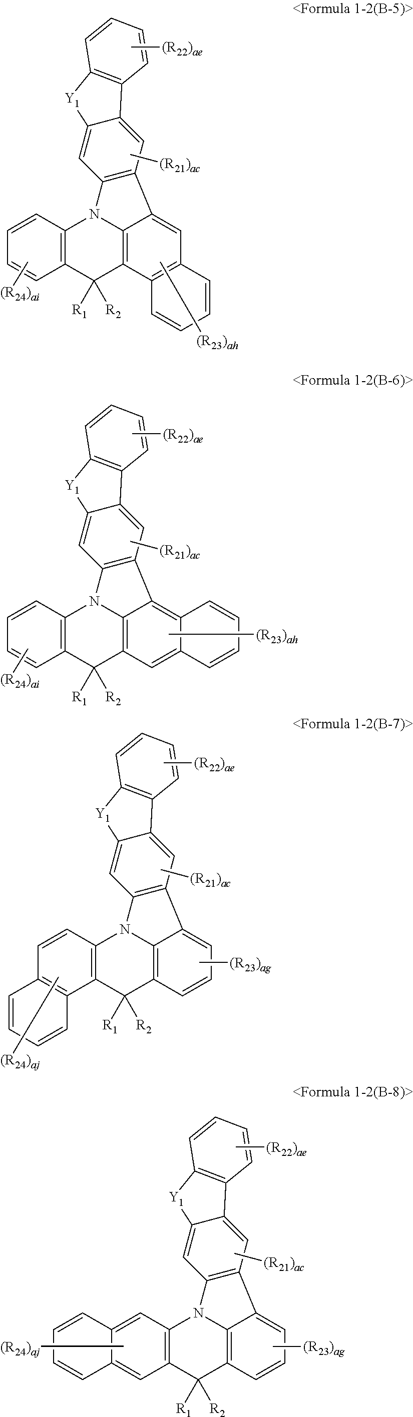 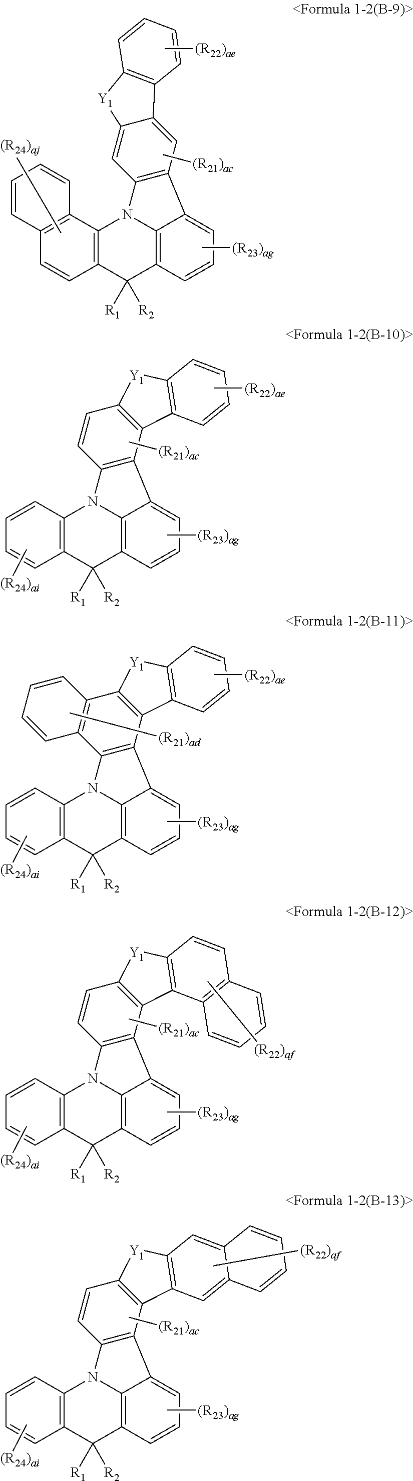 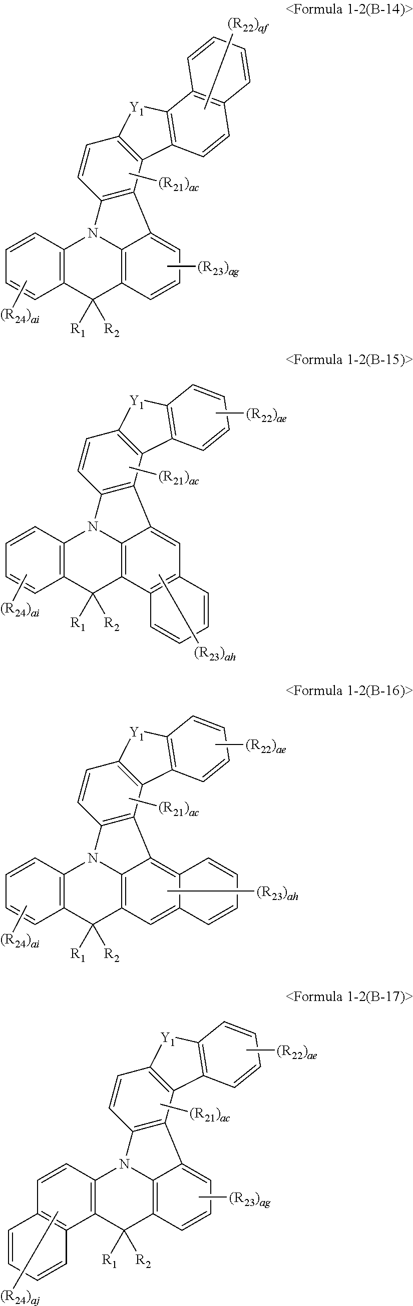 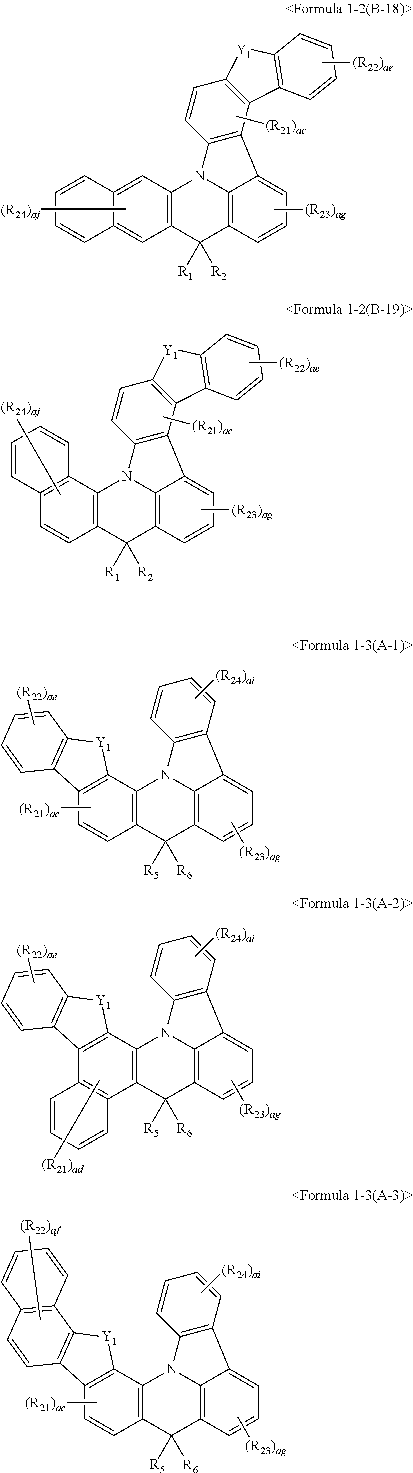 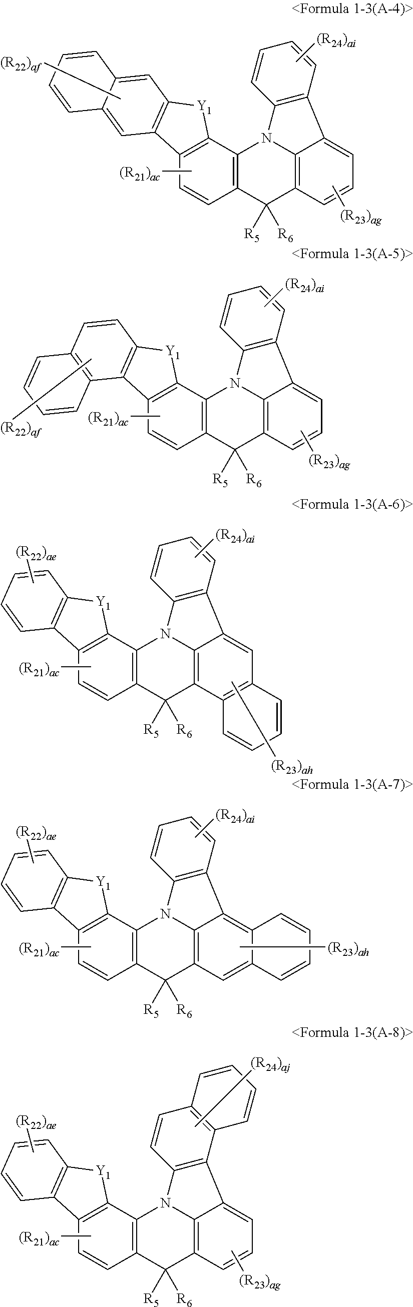 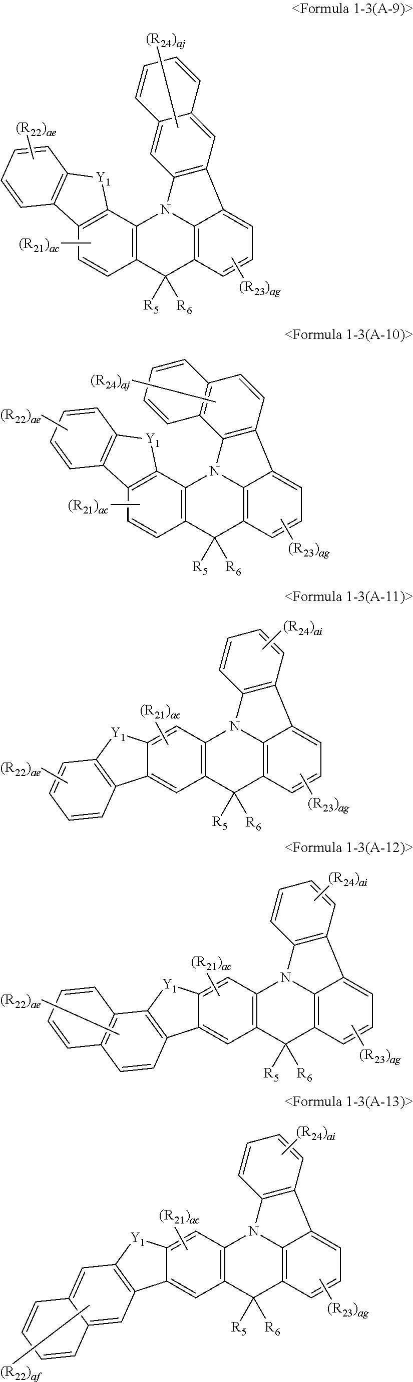 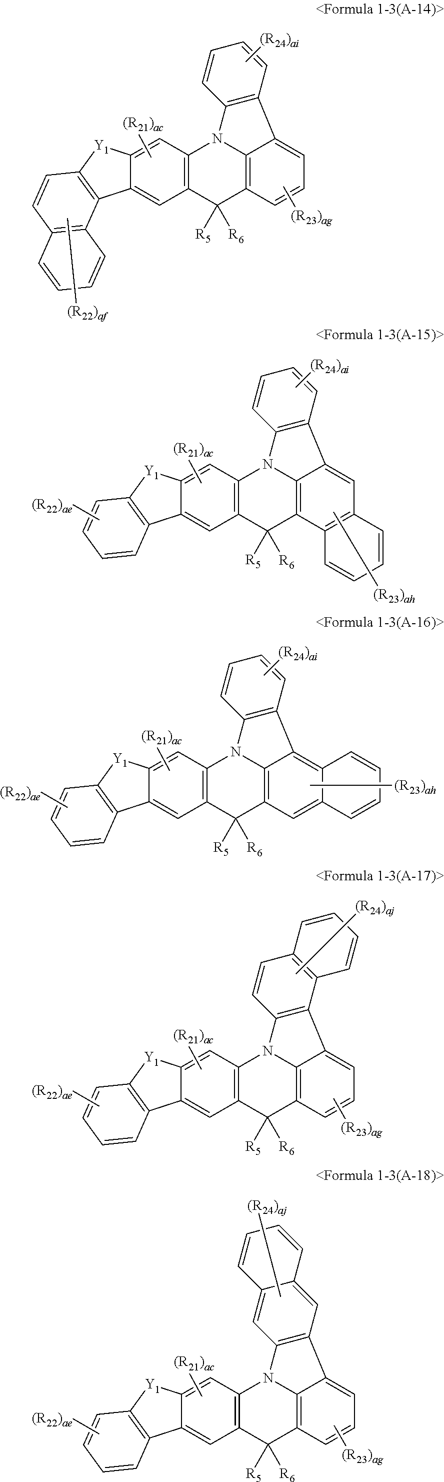 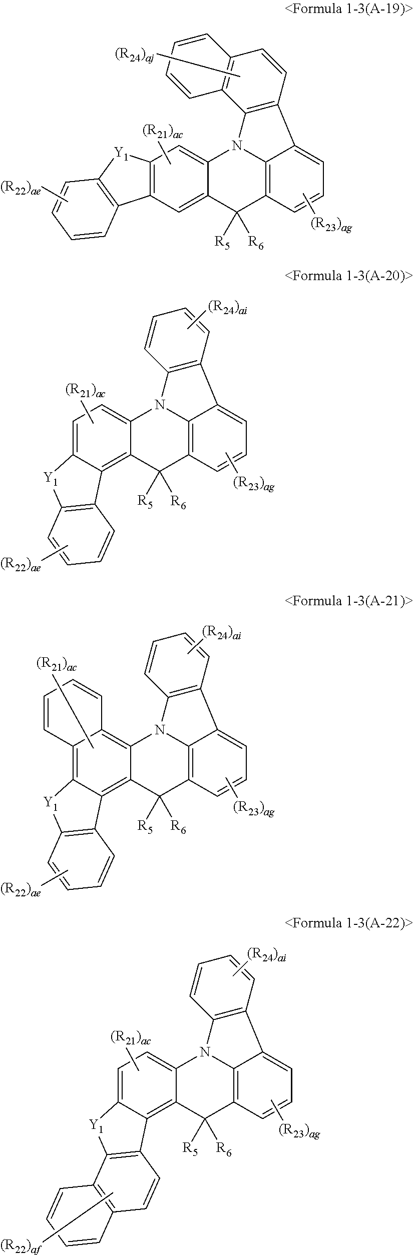 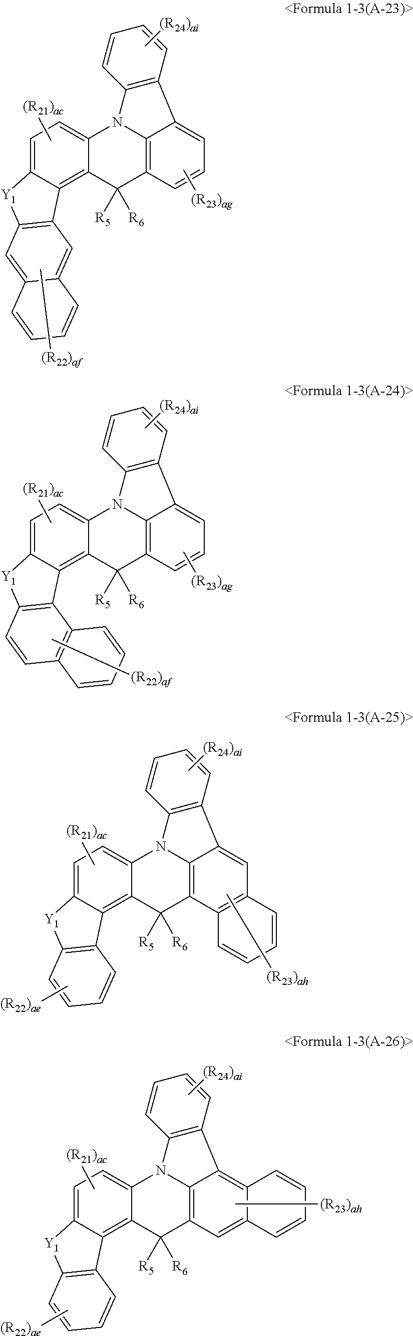 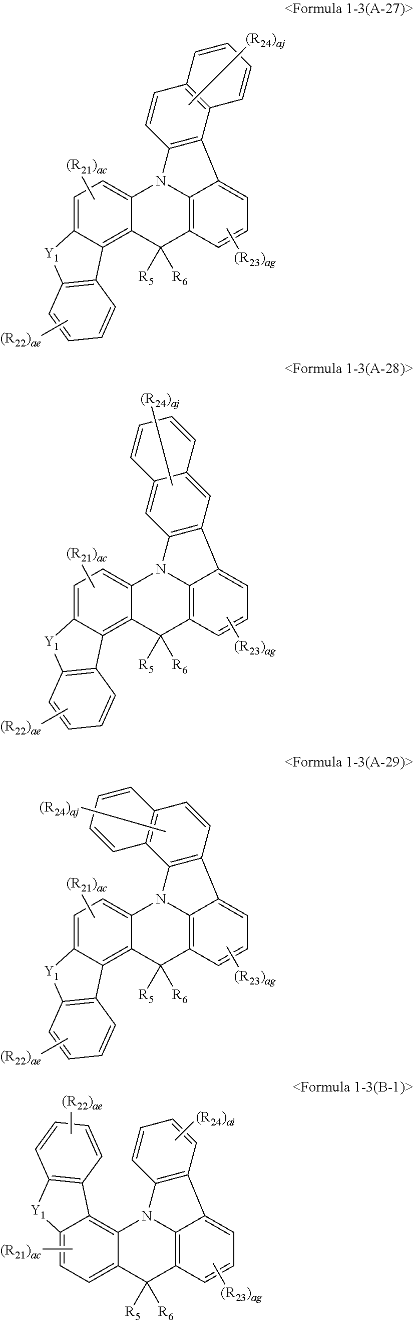 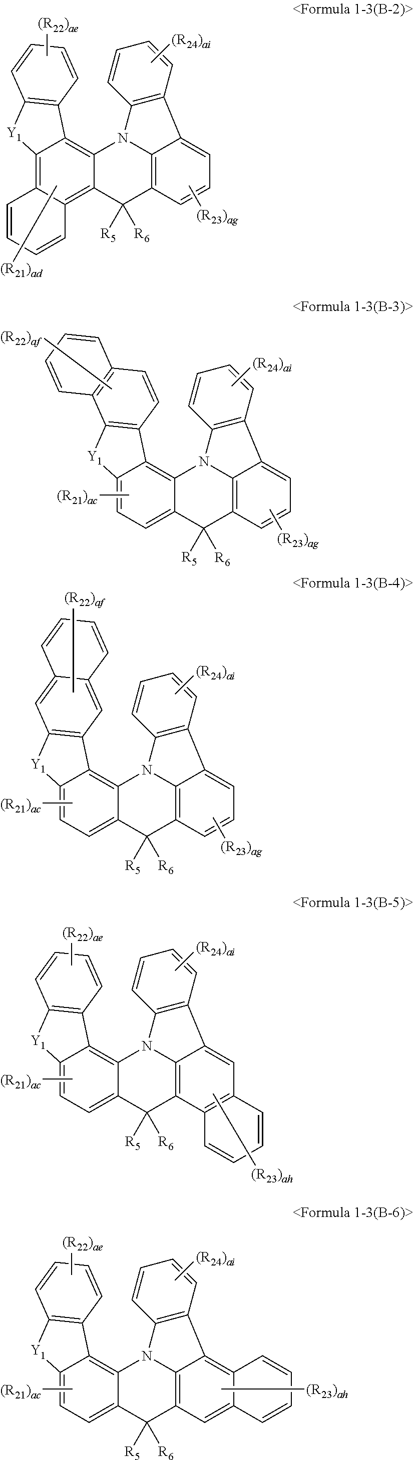 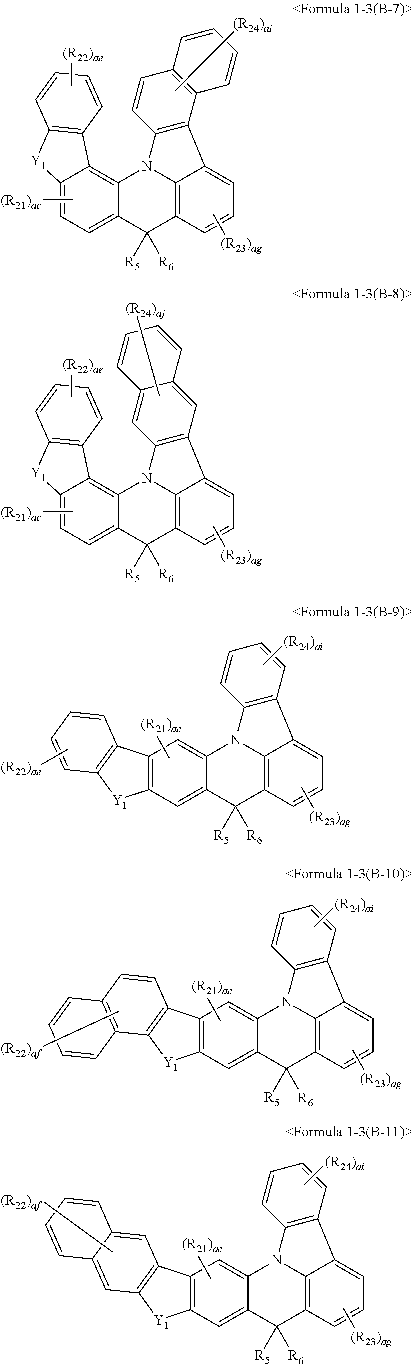 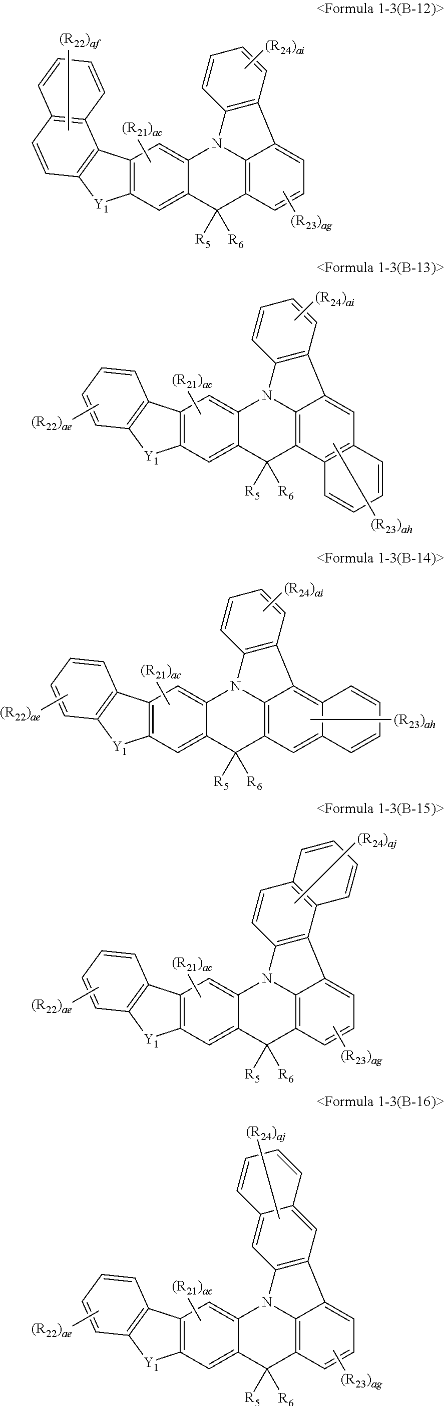 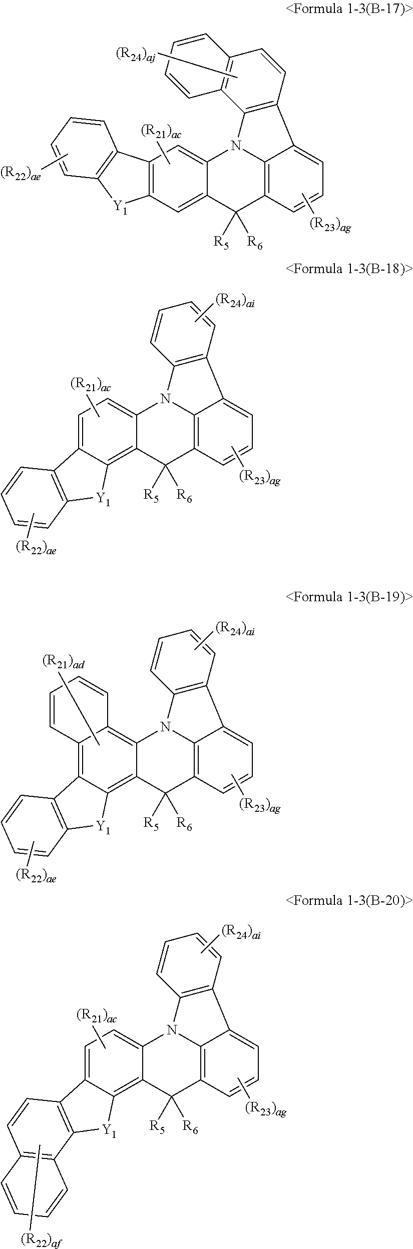 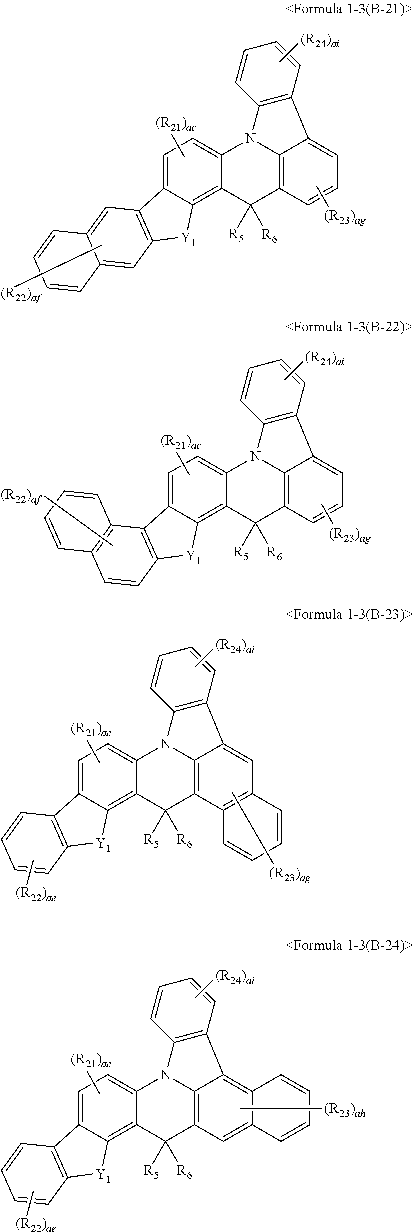 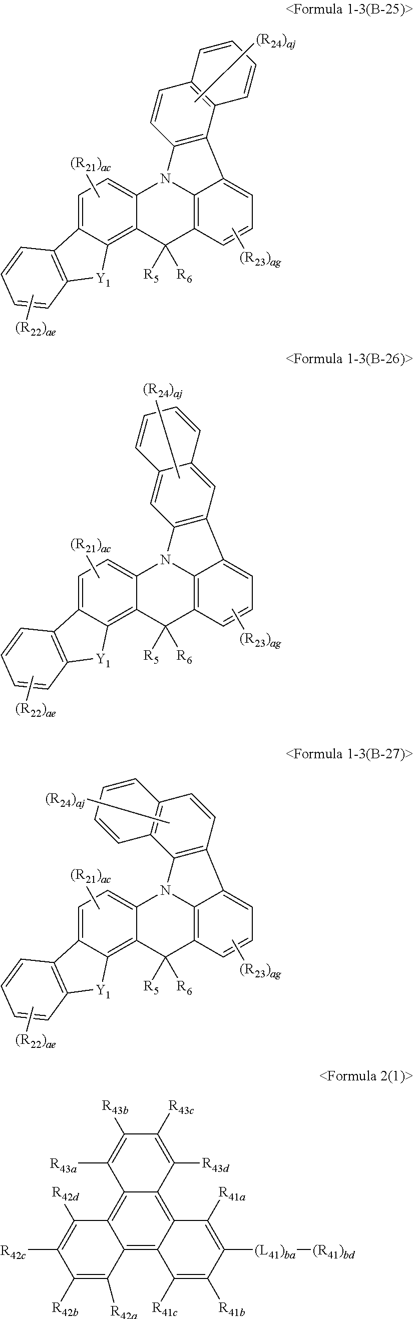 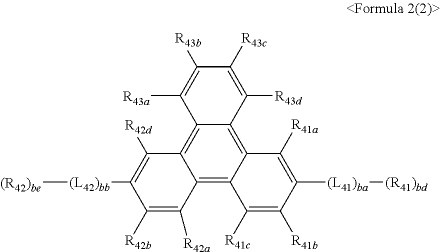
wherein, in Formulae 1-1(A-1) to 1-1(A-20), Formulae 1-1(B-1) to 1-1(B-20), Formulae 1-2(A-1) to 1-2(A-27), Formulae 1-2(B-1) to 1-2(B-19), Formulae 1-3(A-1) to 1-3(A-29), and Formulae 1-3(B-1) to 1-3(B-27),
descriptions of Y₁, and R₁ to R₆ are understood by referring to the descriptions as claimed in claim 1, R₂₁ to R₂₄ have a same definition as R₁₁, R₄₁ to R₄₃, and R₅₁ to R₅₃ in claim 1;
ac is selected from 0, 1, and 2, and two R₂₁s are the same or different when ac is 2;
ad, ae, ag, and ai are each independently selected from 0, 1, 2, 3, and 4, at least two R₂₁s are the same or different when ad is 2 or greater, at least two R₂₂s are the same or different when ae is 2 or greater, at least two R₂₃s are the same or different when ag is 2 or greater, and at least two R₂₄s are the same or different when ai is 2 or greater; and
af, ah, and aj are each independently selected from 0, 1, 2, 3, 4, 5, and 6, at least two R₂₂s are the same or different when of is 2 or greater, at least two R₂₃s are the same or different when ah is 2 or greater, and at least two R₂₄s are the same or different when aj is 2 or greater, and
in Formulae 2(1) and 2(2),
L₄₁, L₄₂, R₄₁, R₄₂, ba, bb, bd, and be are defined the same as L₄₁, L₄₂, R₄₁, R₄₂, ba, bb, bd, and be of Formula 2;
R₄₁ₐ to R_{41c} are defined the same as R₄₁ of Formula 2;
R₄₂ₐ to R_{42d} are defined the same as R₄₂ of Formula 2; and
R₄₃ₐ to R_{43d} are defined the same as R₄₃ of Formula 2.

16. The organic light-emitting device as claimed in claim 1, wherein:
the first compound is one of the following Compounds 1 to 37, and
the second compound is one of the following Compounds 101 to 107:

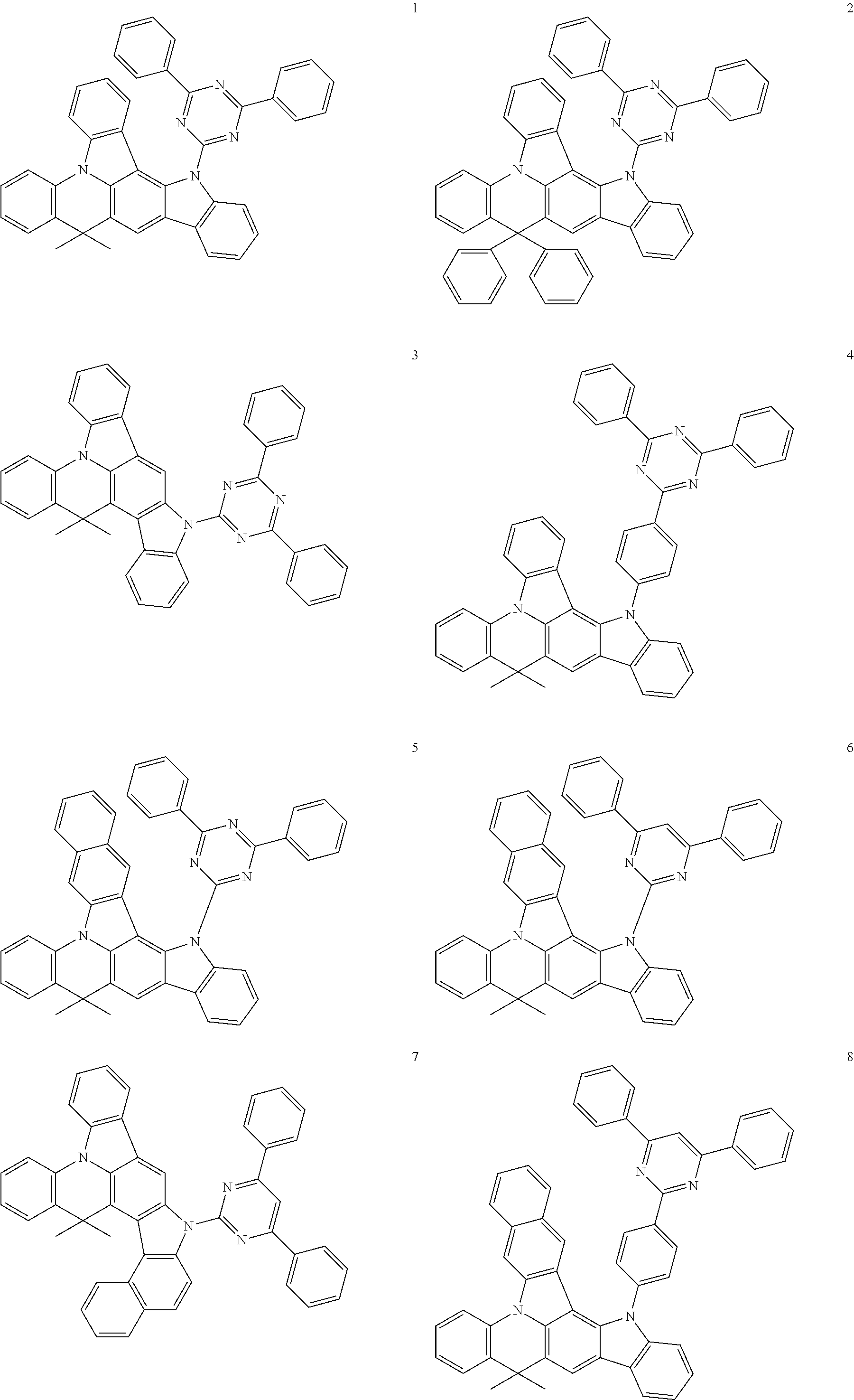

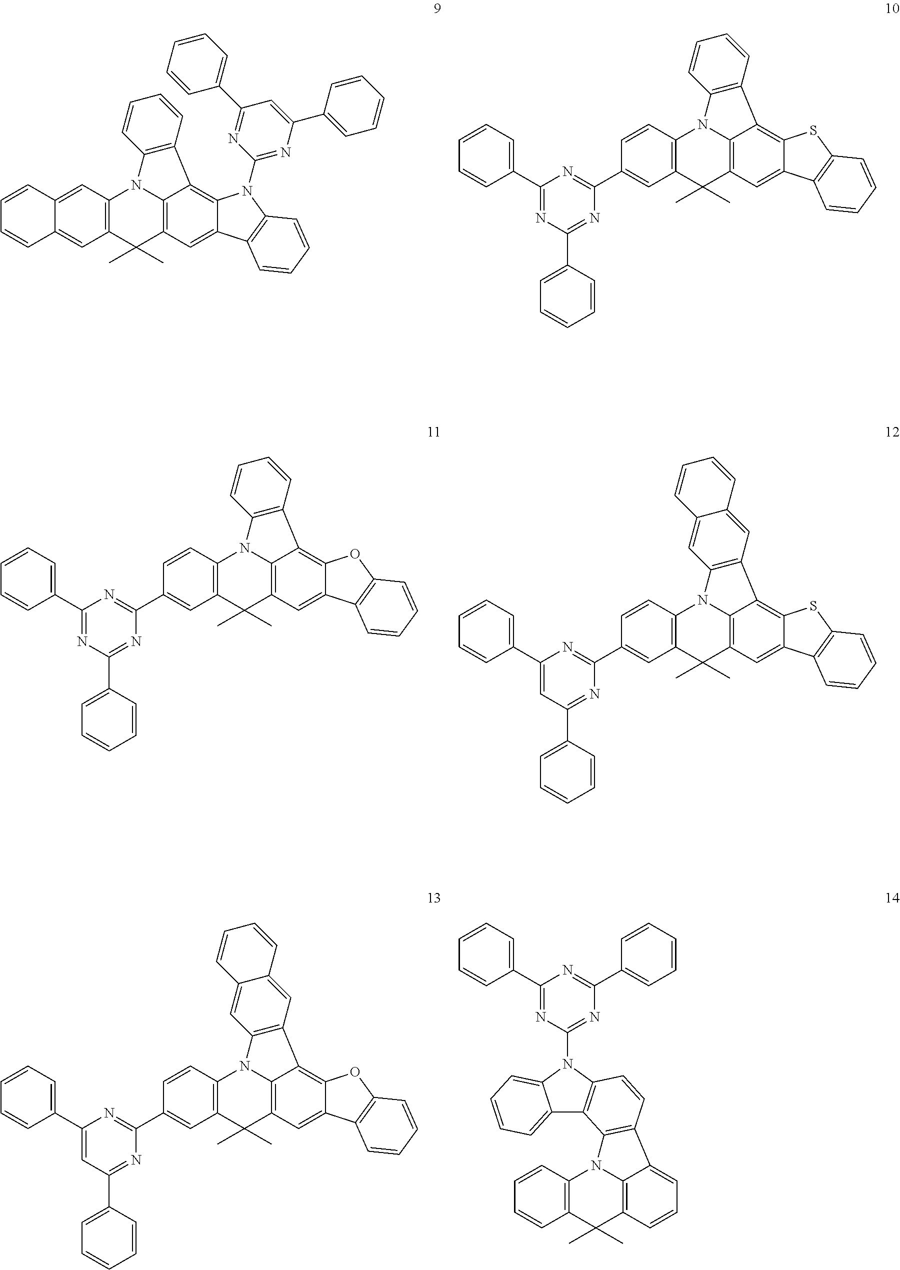

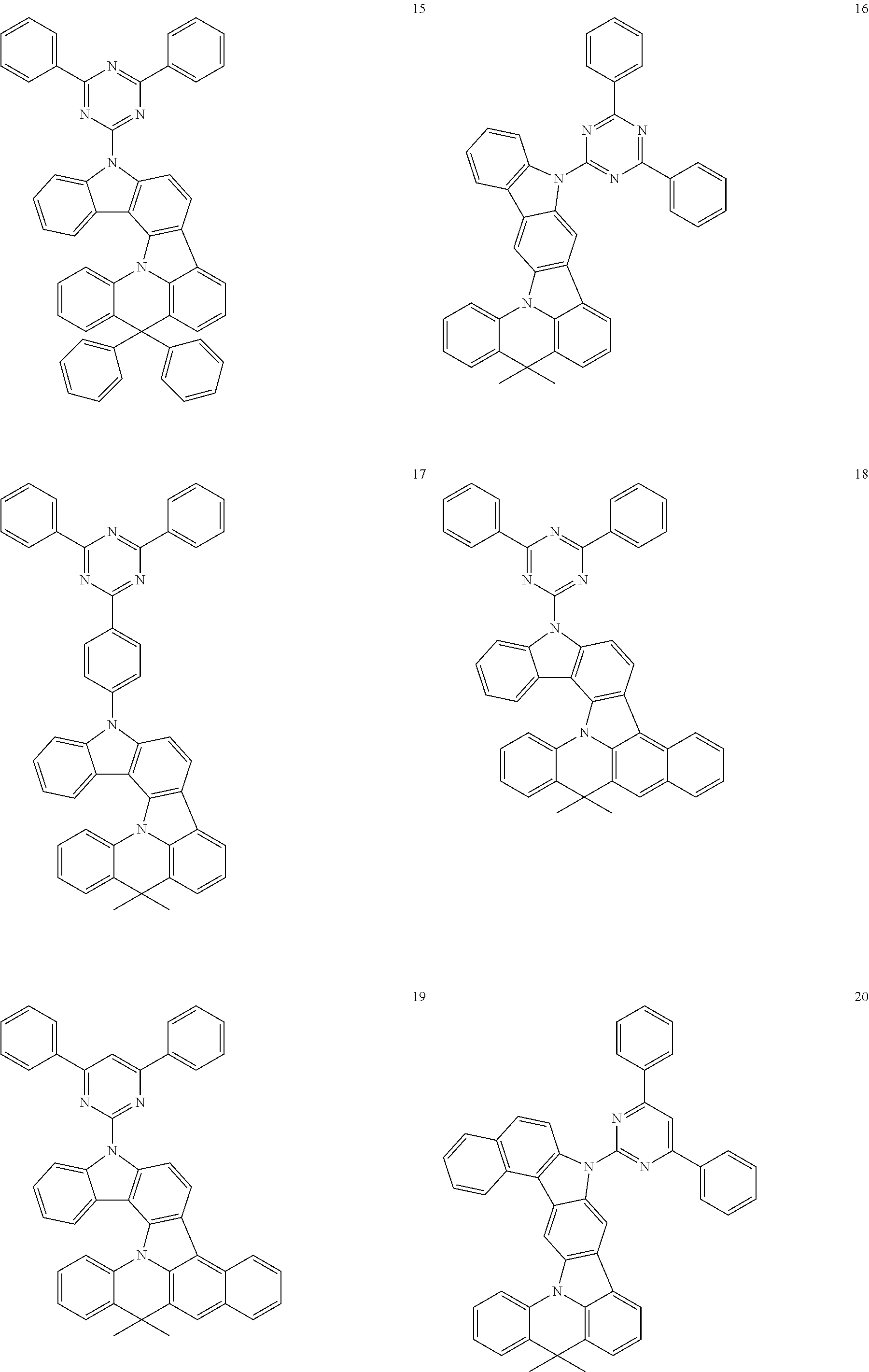

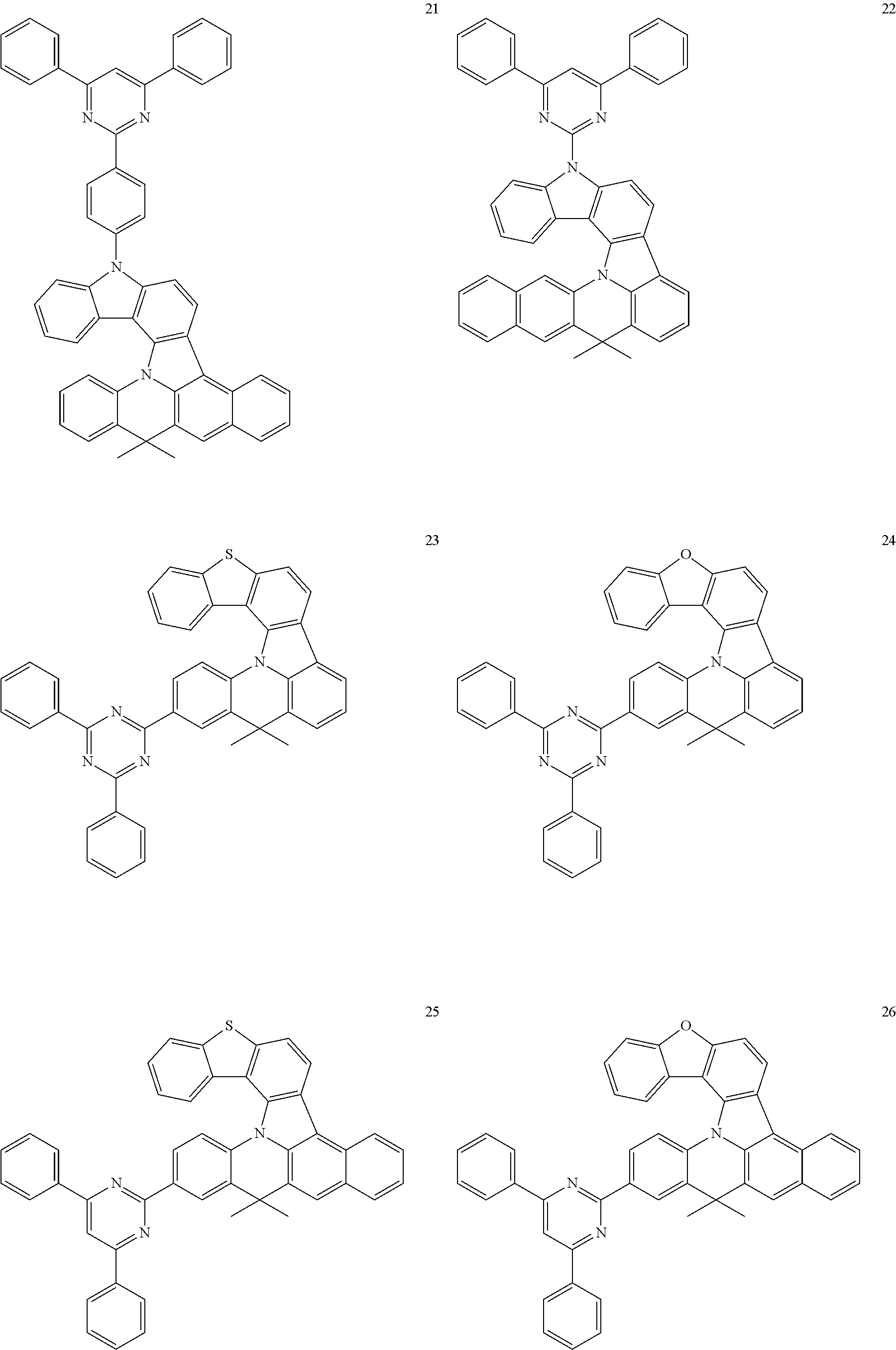

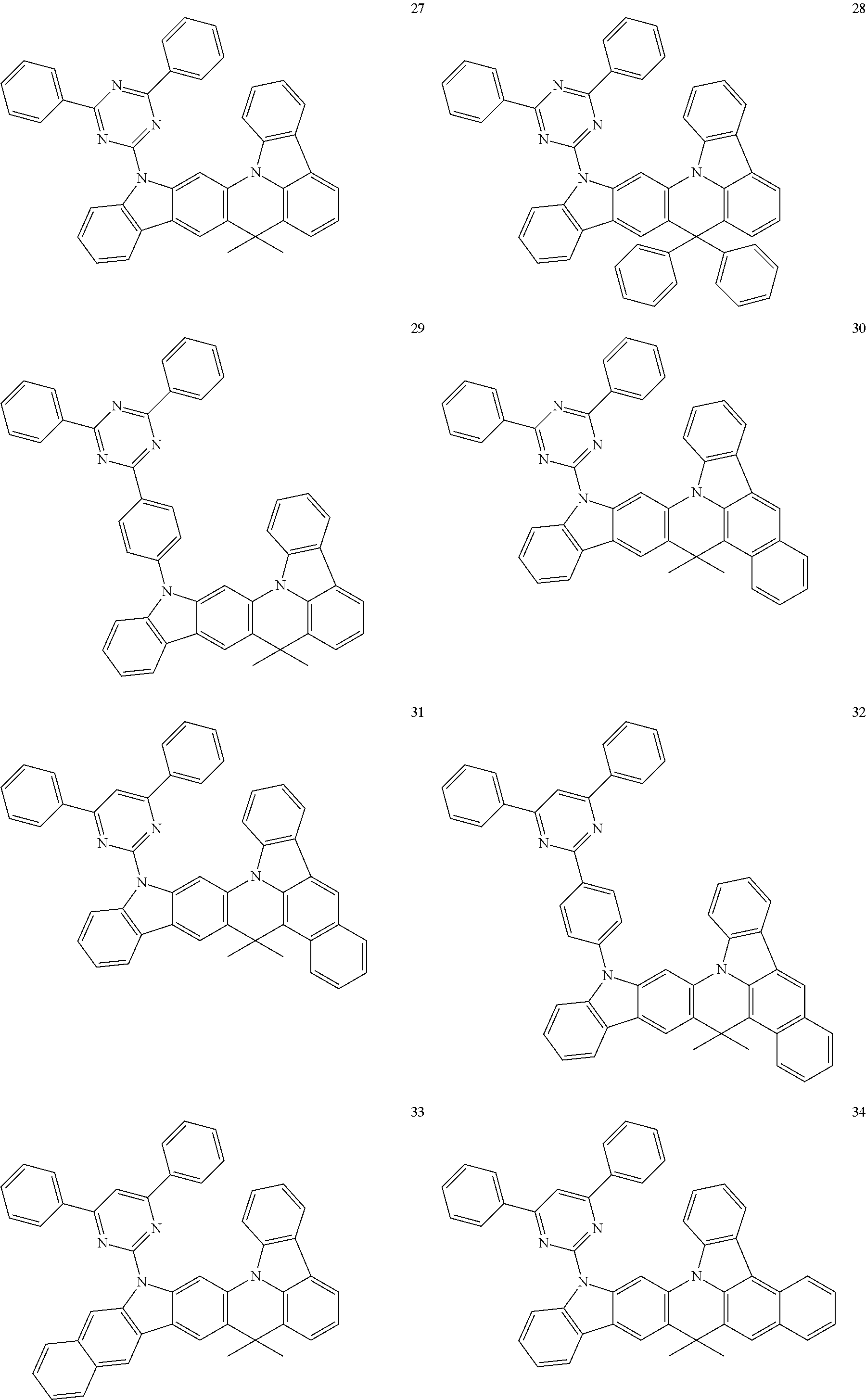

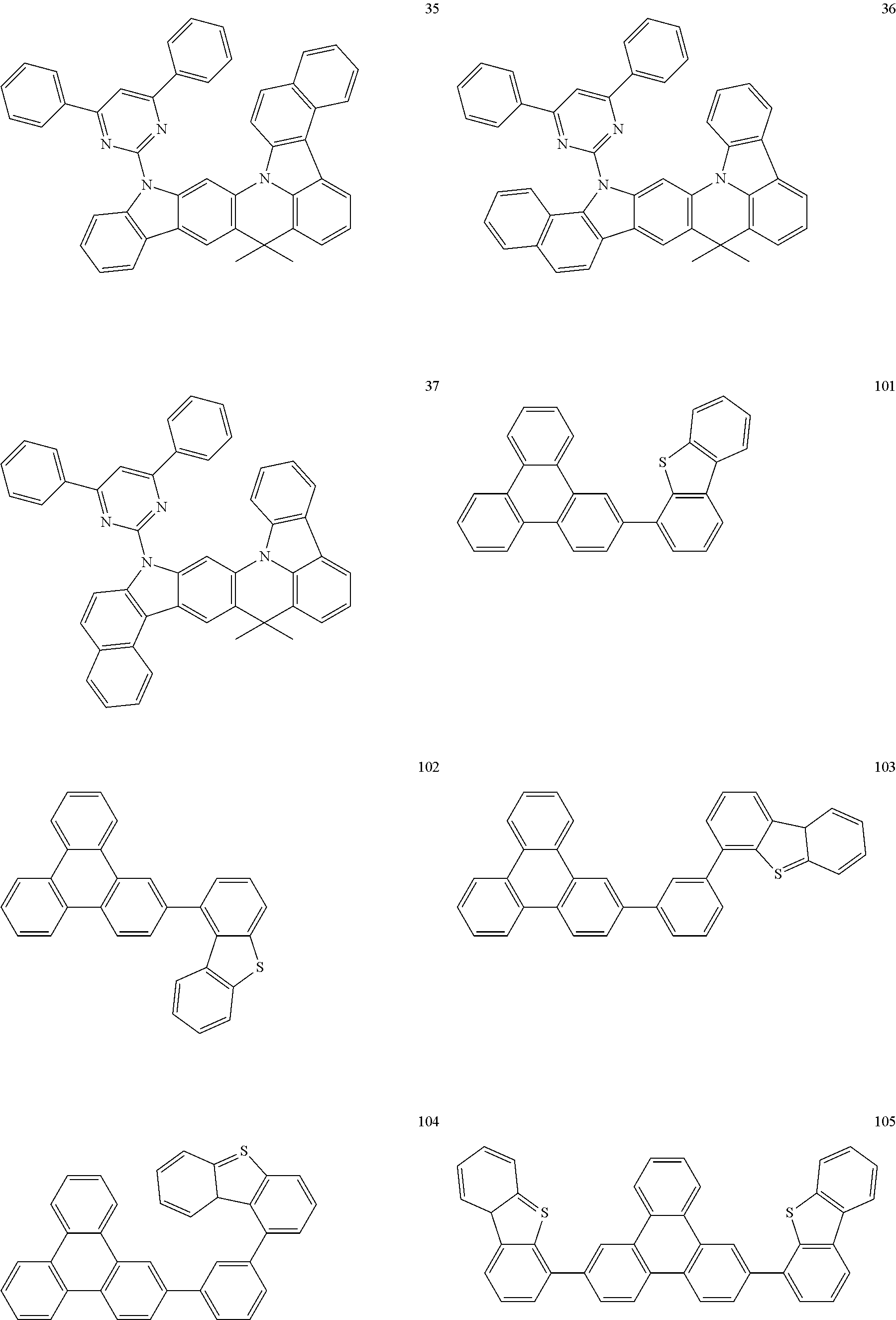

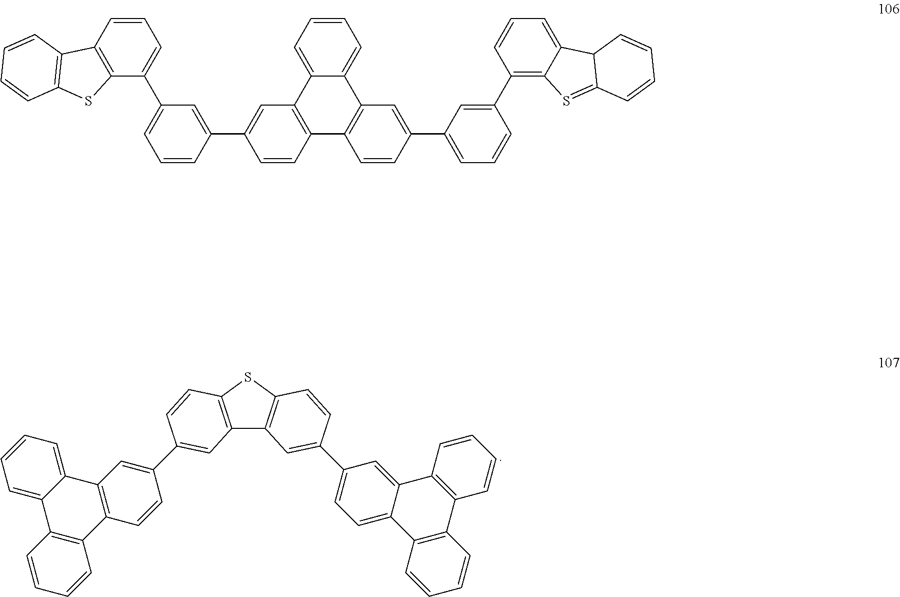

17. The organic light-emitting device as claimed in claim 1, wherein:
the first electrode is an anode,
the second electrode is a cathode, and
the organic layer includes:
a hole transport region between the first electrode and the emission layer, the hole transport region including at least one of a hole injection layer, a hole transport layer, a buffer layer, and an electron blocking layer, and
an electron transport region between the emission layer and the second electrode, the electron transport region including at least one of a hole blocking layer, an electron transport layer, and an electron injection layer.

18. The organic light-emitting device as claimed in claim 1, wherein the first compound and the second compound are in the emission layer.

19. The organic light-emitting device as claimed in claim 1, wherein a weight ratio of the first compound to the second compound is in a range of about 10:90 to about 90:10.

20. The organic light-emitting device as claimed in claim 18, wherein:
the emission layer includes a host and a dopant,
the host includes the first compound and the second compound, and
an amount of the host in the emission layer is greater than an amount of the dopant in the emission layer.
